(19) United States
(12) Patent Application Publication
(10) Pub. No.: US 2024/0206337 A1
(43) Pub. Date: Jun. 20, 2024

(54) LIGHT EMITTING ELEMENT AND FUSED POLYCYCLIC COMPOUND FOR THE SAME

(71) Applicant: Samsung Display Co., LTD., Yongin-si (KR)

(72) Inventors: MUN-KI SIM, Yongin-si (KR); MINJUNG JUNG, Yongin-si (KR); TAEIL KIM, Yongin-si (KR); SUN YOUNG PAK, Yongin-si (KR); MinJae SUNG, Yongin-si (KR); CHANSEOK OH, Yongin-si (KR); Seonhyoung HUR, Yongin-si (KR)

(21) Appl. No.: 18/362,836

(22) Filed: Jul. 31, 2023

(30) Foreign Application Priority Data
Nov. 11, 2022 (KR) 10-2022-0150327

(51) Int. Cl. H10K 85/60; C07F 5/02; H10K 50/12; H10K 85/30

(52) U.S. Cl. CPC H10K 85/658; C07F 5/02; H10K 50/12; H10K 85/342; H10K 85/346

(57) ABSTRACT

A light emitting element of an embodiment may include a first electrode, a second electrode disposed on the first electrode, and an emission layer disposed between the first electrode and the second electrode. The emission layer may include a first compound and at least one among second to fourth compounds. The first compound may be represented by Formula 1, the second compound may be represented by Formula HT-1, the third compound may be represented by Formula ET-1, and the fourth compound may be represented by Formula M-b. Accordingly, the light emitting element of an embodiment may show a low driving voltage, high efficiency and long-life characteristics.

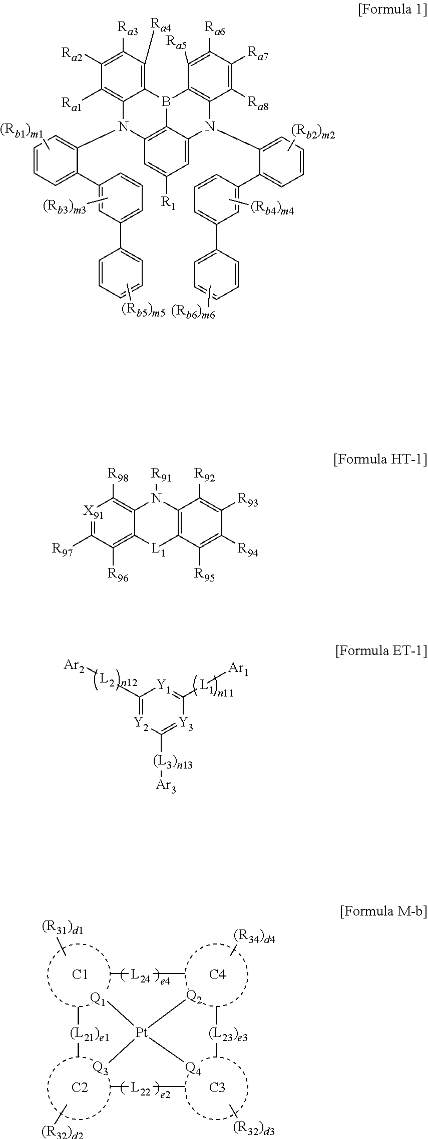

### CROSS-REFERENCE TO RELATED APPLICATIONS

This application claims priority to and the benefit of Korean Patent Application No. 10-2022-0150327, filed on Nov. 11, 2022, the entire content of which is hereby incorporated by reference.

### BACKGROUND

### 1. Field

The present disclosure herein relates to a light emitting element and a fused polycyclic compound utilized therein.

### 2. Description of the Related Art

Recently, the development of an organic electroluminescence display device as an image display device is being actively conducted. The organic electroluminescence display device is a so-called display device including a self-luminescent-type light emitting element in which holes and electrons injected from a first electrode and a second electrode recombine in an emission layer so that a light emitting material in the emission layer emits light to achieve display (e.g., to display an image).

In the application of a light emitting element to a display device, the improvement of properties, e.g., light efficiency, lifetime, etc., are required or desired, and development on materials for a light emitting element capable of stably attaining such characteristics is being consistently pursued.

### SUMMARY

An aspect according to embodiments of the present disclosure is directed toward a light emitting element having improved light efficiency and lifetime.

An aspects according to embodiments of the present disclosure is directed toward a fused polycyclic compound which is a material for a light emitting element improving light efficiency and lifetime.

Additional aspects will be set forth in part in the description which follows and, in part, will be apparent from the description, or may be learned by practice of the presented embodiments of the disclosure.

According to an embodiment of the present disclosure, a light emitting element includes: a first electrode; a second electrode on the first electrode; and an emission layer between the first electrode and the second electrode, wherein the emission layer includes: a first compound represented by Formula 1; and at least one among a second compound represented by Formula HT-1, a third compound represented by Formula ET-1, and a fourth compound represented by Formula M-b.

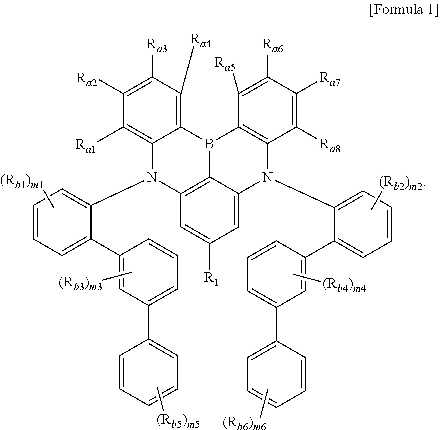

In Formula 1, R₁ may be a hydrogen atom, a deuterium atom, a substituted or unsubstituted alkyl group of 1 to 60 carbon atoms, a substituted or unsubstituted aryl group of 6 to 60 ring-forming carbon atoms, or a substituted or unsubstituted heteroaryl group of 2 to 60 ring-forming carbon atoms, m1 to m4 may each independently be an integer of 0 to 4, m5 and m6 may each independently be an integer of 0 to 5, R_{b1} to R_{b6} may each independently be a hydrogen atom, a deuterium atom, a cyano group, a halogen atom, a substituted or unsubstituted alkyl group of 1 to 60 carbon atoms, a substituted or unsubstituted aryl group of 6 to 60 ring-forming carbon atoms, or a substituted or unsubstituted heteroaryl group of 2 to 60 ring-forming carbon atoms, at least one among Rₐ₁ to Rₐ₄ may be a substituted or unsubstituted aryl amine group, a substituted or unsubstituted aryl group of 6 to 60 ring-forming carbon atoms, or a substituted or unsubstituted heteroaryl group of 2 to 60 ring-forming carbon atoms, and any remainder thereof may each independently be a hydrogen atom or a deuterium atom, and at least one among Rₐ₅ to Rₐ₈ may be a substituted or unsubstituted aryl amine group, a substituted or unsubstituted aryl group of 6 to 60 ring-forming carbon atoms, or a substituted or unsubstituted heteroaryl group of 2 to 60 ring-forming carbon atoms, and any remainder thereof may each independently be a hydrogen atom or a deuterium atom.

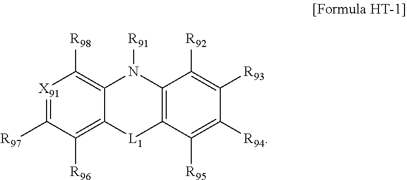

In Formula HT-1, L¹ may be a direct linkage, CR₉₉R₁₀₀, or SiR₁₀₁R₁₀₂, X₉₁ may be N or CR₁₀₃, and R₉₁ to R₁₀₃ may each independently be a hydrogen atom, a deuterium atom, a cyano group, a substituted or unsubstituted silyl group, a substituted or unsubstituted oxy group, a substituted or unsubstituted alkyl group of 1 to 60 carbon atoms, a substituted or unsubstituted aryl group of 6 to 60 ring-forming carbon atoms, or a substituted or unsubstituted heteroaryl group of 2 to 60 ring-forming carbon atoms, and/or combined with an adjacent group to form a ring.

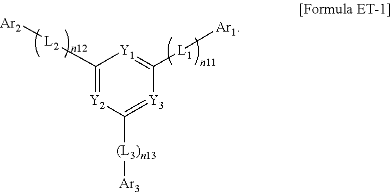

In Formula ET-1, at least one among Y₁ to Y₃ may be N, and any remainder thereof may be CR₈₁, R₈₁ may be a hydrogen atom, a deuterium atom, a substituted or unsubstituted alkyl group of 1 to 20 carbon atoms, a substituted or unsubstituted aryl group of 6 to 60 ring-forming carbon atoms, or a substituted or unsubstituted heteroaryl group of 2 to 60 ring-forming carbon atoms, n11 to n13 may each independently be an integer of 0 to 10, L¹ to L₃ may each independently be a direct linkage, a substituted or unsubstituted arylene group of 6 to 30 ring-forming carbon atoms, or a substituted or unsubstituted heteroarylene group of 2 to 30 ring-forming carbon atoms, and Ar₁ to Ar₃ may each independently be a hydrogen atom, a deuterium atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms.

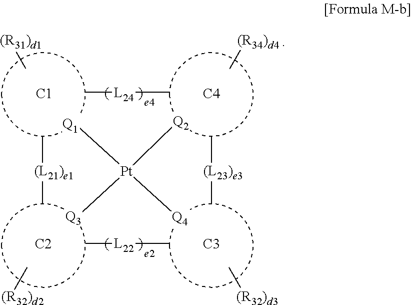

In Formula M-b, Q₁ to Q₄ may each independently be C or N, C1 to C4 may each independently be a substituted or unsubstituted hydrocarbon ring of 5 to 30 ring-forming carbon atoms, or a substituted or unsubstituted heterocycle of 2 to 30 ring-forming carbon atoms, e1 to e4 may each independently be 0 or 1, L₂₁ to L₂₄ may each independently be a direct linkage,

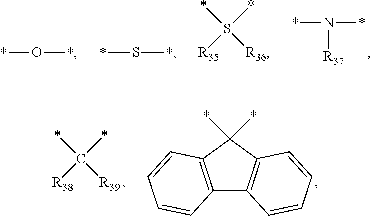

a substituted or unsubstituted divalent alkyl group of 1 to 20 carbon atoms, a substituted or unsubstituted arylene group of 6 to 30 ring-forming carbon atoms, or a substituted or unsubstituted heteroarylene group of 2 to 30 ring-forming carbon atoms, d1 to d4 may each independently be an integer of 0 to 4, and R₃₁ to R₃₉ may each independently be a hydrogen atom, a deuterium atom, a halogen atom, a cyano group, a substituted or unsubstituted amine group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, and/or combined with an adjacent group (e.g., from each other) to form a ring.

In an embodiment, the first compound represented by Formula 1 may be represented by any one among Formula 1-1 to Formula 1-3.

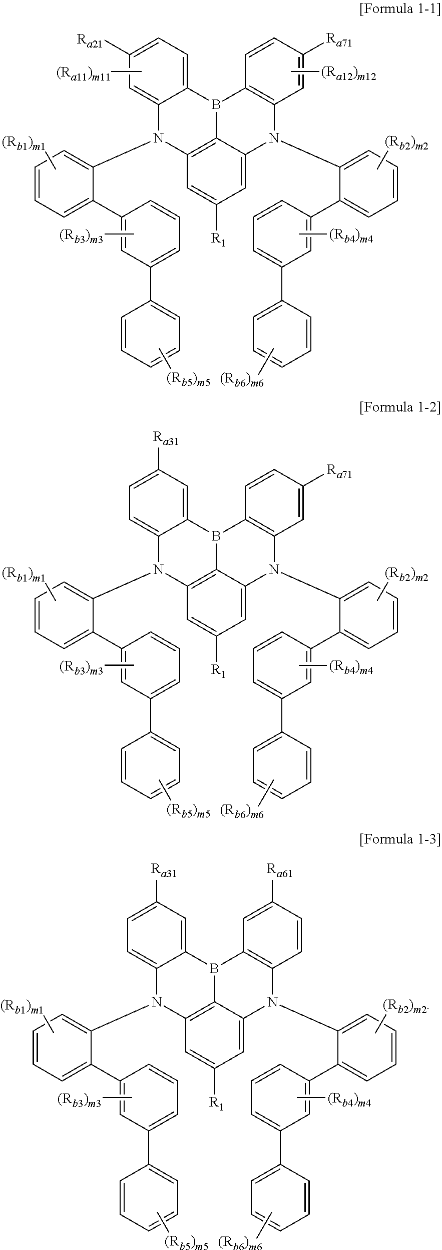

In Formula 1-1, m11 and m12 may each independently be an integer of 0 to 3, and Rₐ₁₁ and Rₐ₁₂ may each independently be a hydrogen atom or a deuterium atom, and in Formula 1-1 to Formula 1-3, Rₐ₂₁, Rₐ₃₁, Rₐ₆₁, and Rₐ₇₁ may each independently be a substituted or unsubstituted aryl amine group, a substituted or unsubstituted aryl group of 6 to 60 ring-forming carbon atoms, or a substituted or unsubstituted heteroaryl group of 2 to 60 ring-forming carbon atoms, and R₁, m1 to m6, and R_{b1} to R_{b6} may each independently be the same as defined in Formula 1.

In an embodiment, in Formula 1-1 to Formula 1-3, Rₐ₂₁, Rₐ₃₁, Rₐ₆₁, and Rₐ₇₁ may each independently be a substituted or unsubstituted diphenylamine group, a substituted or unsubstituted phenyl group, a substituted or unsubstituted carbazole group, a substituted or unsubstituted dibenzofuran group, or a substituted or unsubstituted phenoxazine group.

In an embodiment, in Formula 1-1 to Formula 1-3, Rₐ₂₁, Rₐ₃₁, Rₐ₆₁, and Rₐ₇₁ may each independently be represented by any one among Formulae RA-1 to RA-6.

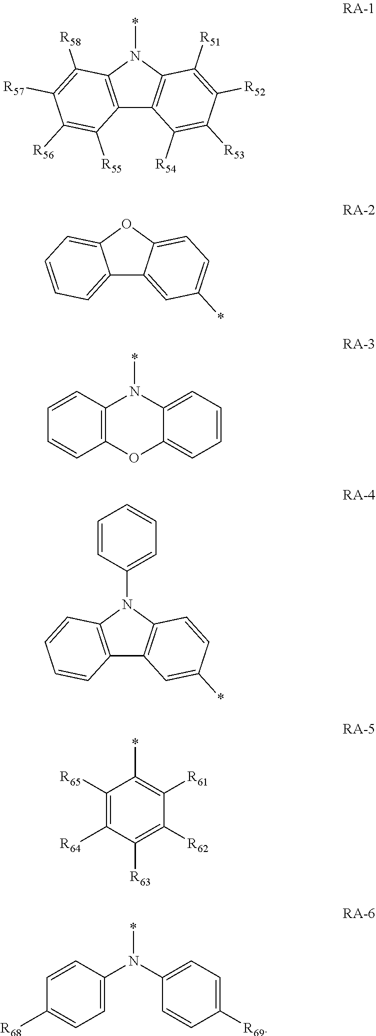

In Formula RA-1, R₅₁ to R₅₈ may each independently be a hydrogen atom, a deuterium atom, a cyano group, an unsubstituted t-butyl group, or an unsubstituted phenyl group, in Formula RA-5, R₆₁ to R₆₅ may each independently be a hydrogen atom, a deuterium atom, an unsubstituted t-butyl group, an unsubstituted phenyl group, or an unsubstituted carbazole group, and in Formula RA-6, R₆₈ and R₆₉ may each independently be a hydrogen atom, a deuterium atom, or an unsubstituted t-butyl group.

In an embodiment, the first compound represented by Formula 1 may be represented by Formula 1-A or Formula 1-B.

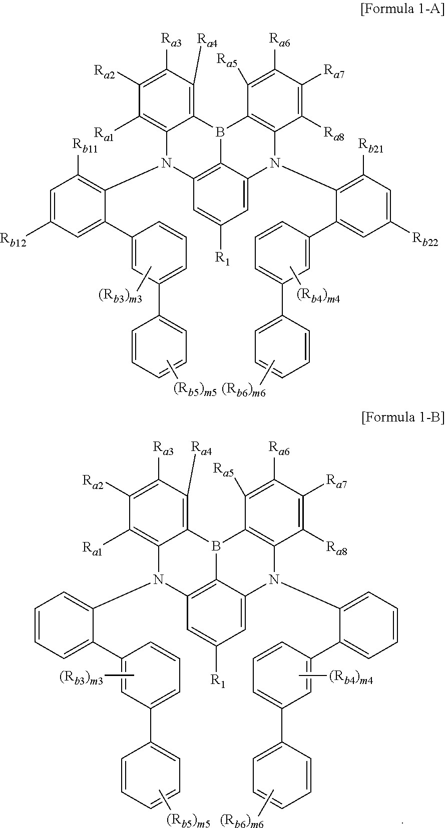

In Formula 1-A, R_{b11}, R_{b12}, R_{b21}, and R_{b22} may each independently be a substituted or unsubstituted alkyl group of 1 to 20 carbon atoms or a substituted or unsubstituted aryl group of 6 to 20 ring-forming carbon atoms, and in Formula 1-A and Formula 1-B, Rₐ₁ to Rₐ₈, R₁, m3 to m6, and R_{b3} to R_{b6} may each independently be the same as defined in Formula 1.

In an embodiment, in Formula 1-A, R_{b11}, R_{b12}, R_{b21}, and R_{b22} may each independently be a substituted or unsubstituted t-butyl group or a substituted or unsubstituted phenyl group.

In an embodiment, the first compound represented by Formula 1-A may be represented by Formula 1-A1 or Formula 1-A2.

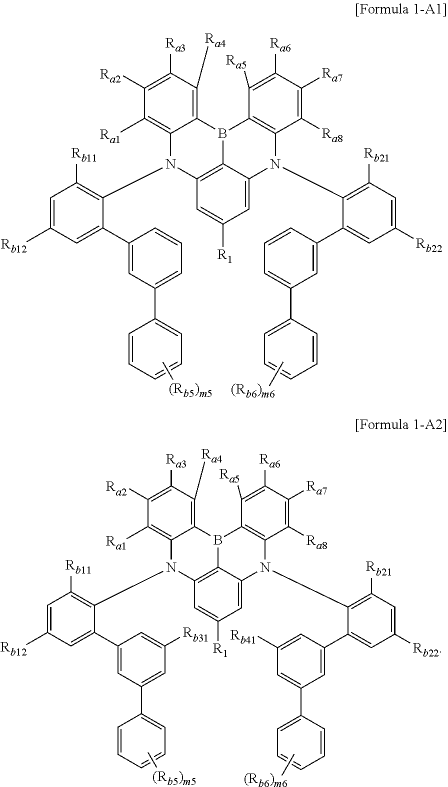

In Formula 1-A2, R_{b31} and R_{b41} may each independently be a substituted or unsubstituted alkyl group of 1 to 20 carbon atoms or a substituted or unsubstituted aryl group of 6 to 20 ring-forming carbon atoms, and in Formula 1-A1 and Formula 1-A2, Rₐ₁ to Rₐ₈, R₁, m5, m6, R_{b5}, R_{b6}, R_{b11}, R_{b12}, R_{b21}, and R_{b22} may each independently be the same as defined in Formula 1-A.

In an embodiment, the first compound represented by Formula 1-A1 may be represented by Formula 1-A11 or Formula 1-A12.

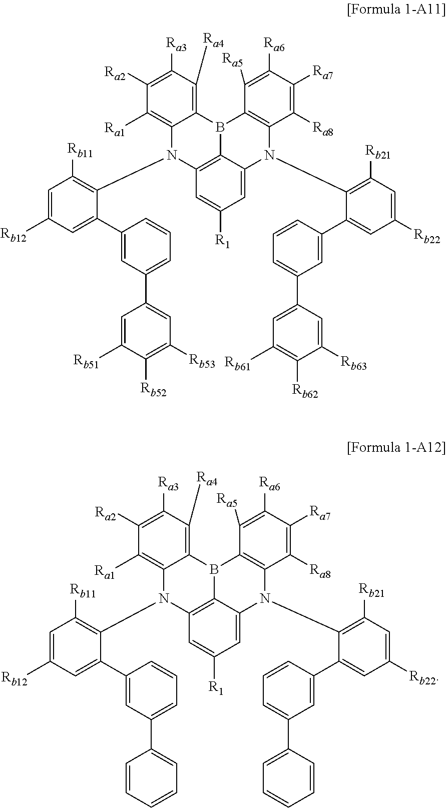

In Formula 1-A11, at least one among R_{b51} to R_{b53} may be a substituted or unsubstituted alkyl group of 1 to 20 carbon atoms or a substituted or unsubstituted aryl group of 6 to 20 ring-forming carbon atoms, and any remainder thereof are hydrogen atoms, and at least one among R_{b61} to R_{b63} may be a substituted or unsubstituted alkyl group of 1 to 20 carbon atoms or a substituted or unsubstituted aryl group of 6 to 20 ring-forming carbon atoms, and any remainder thereof are hydrogen atoms, and in Formula 1-A11 and Formula 1-A12, Rai to Rₐ₈, R₁, R_{b11}, R_{b12}, R_{b21}, and R_{b22} may each independently be the same as defined in Formula 1-A1.

In an embodiment, in Formula 1, R₁ may be a substituted or unsubstituted t-butyl group, a substituted or unsubstituted phenyl group, a substituted or unsubstituted dibenzofuran group, or a substituted or unsubstituted carbazole group.

In an embodiment, in Formula 1, R₁ may be represented by any one among R₁-1 to R₁-9.

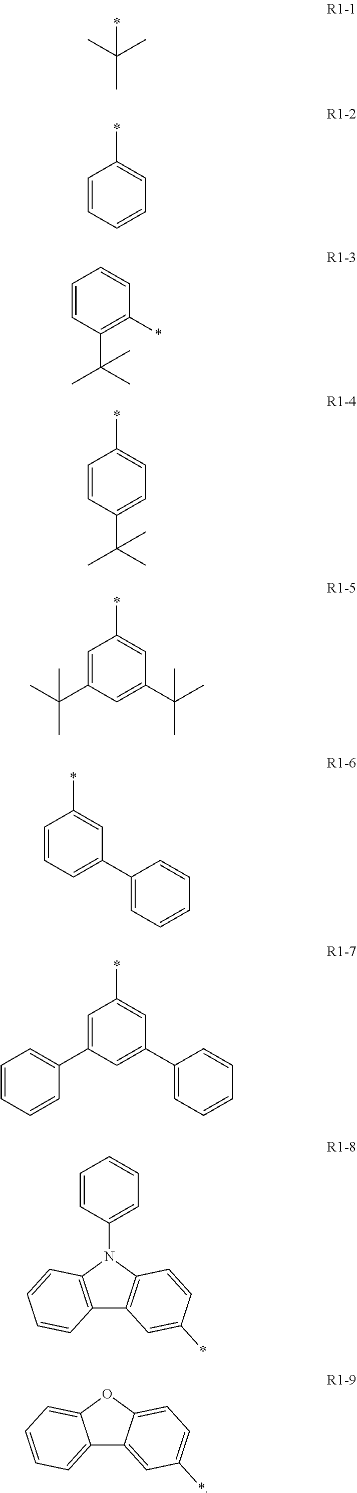

In an embodiment, in Formula 1, at least one among Rₐ₁ to Rₐ₈ may include a deuterium atom, or a substituent including a deuterium atom.

According to another embodiment of the present disclosure, a fused polycyclic compound represented by Formula 1 is provided.

### BRIEF DESCRIPTION OF THE DRAWINGS

The accompanying drawings are included to provide a further understanding of the present disclosure and are incorporated in and constitute a part of this specification. The drawings illustrate embodiments of the present disclosure and, together with the description, serve to explain principles of the present disclosure. In the drawings:

FIG. 1 is a plan view showing a display device according to an embodiment;

FIG. 2 is a cross-sectional view showing a part corresponding to the line I-I′ in FIG. 1;

FIG. 3 is a cross-sectional view schematically showing a light emitting element of an embodiment;

FIG. 4 is a cross-sectional view schematically showing a light emitting element of an embodiment;

FIG. 5 is a cross-sectional view schematically showing a light emitting element of an embodiment;

FIG. 6 is a cross-sectional view schematically showing a light emitting element of an embodiment;

FIG. 7 is a cross-sectional view showing a display device according to an embodiment;

FIG. 8A is a three-dimensional image of a fused polycyclic compound of an embodiment;

FIG. 8B is a three-dimensional image of a fused polycyclic compound of an embodiment;

FIG. 9 is a cross-sectional view showing a display device according to an embodiment;

FIG. 10 is a cross-sectional view showing a display device according to an embodiment;

FIG. 11 is a cross-sectional view showing a display device according to an embodiment;

FIG. 12 is a cross-sectional view showing a display device according to an embodiment; and

FIG. 13 is a diagram showing the interior of a vehicle in which display devices of embodiments are disposed.

### DETAILED DESCRIPTION

The present disclosure may have various suitable modifications and may be embodied in different forms, and example embodiments will be explained in more detail with reference to the accompany drawings. The subject matter of the present disclosure may, however, be embodied in different forms and should not be construed as limited to the embodiments set forth herein. Rather, all modifications, equivalents, and substituents which are included in the spirit and technical scope of the present disclosure should be included in the present disclosure.

In the description, when an element (or a region, a layer, a part, etc.) is referred to as being “on”, “connected with” or “combined with” another element, it can be directly connected with/bonded on the other element, or intervening third elements may also be disposed.

Like reference numerals refer to like elements throughout. In the drawings, the thicknesses, ratios, and dimensions of elements may be exaggerated for effective explanation of technical contents. The term “and/or” may include one or more combinations that may define relevant elements.

It will be understood that, although the terms first, second, etc. may be used herein to describe various elements, these elements should not be limited by these terms. These terms are only used to distinguish one element from another element. For example, a first element could be termed a second element without departing from the scope of the present disclosure. Similarly, a second element could be termed a first element. As used herein, the singular forms are intended to include the plural forms as well, unless the context clearly indicates otherwise.

In some embodiments, the terms “below”, “beneath”, “on” and “above” are used for explaining the relation of elements shown in the drawings. The terms are relative concept and are explained based on the direction shown in the drawing.

It will be further understood that the terms “comprises” and/or “comprising,” when used in this specification, specify the presence of stated features, numerals, acts (e.g., steps), operations, elements, parts, or the combination thereof, but do not preclude the presence or addition of one or more other features, numerals, acts (e.g., steps), operations, elements, parts, or the combination thereof.

Unless otherwise defined, all terms (including technical and scientific terms) used herein have the same meaning as commonly understood by one of ordinary skill in the art to which this present disclosure belongs. In some embodiments, it will be further understood that terms, such as those defined in commonly used dictionaries, should be interpreted as having a meaning for example consistent with their meaning in the context of the relevant art and will not be interpreted in an idealized or overly formal sense unless expressly so defined herein.

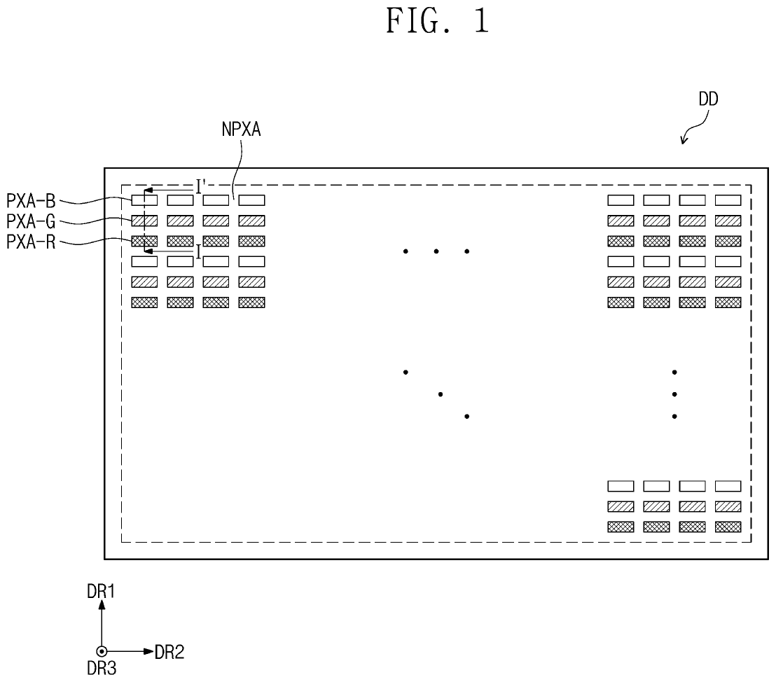

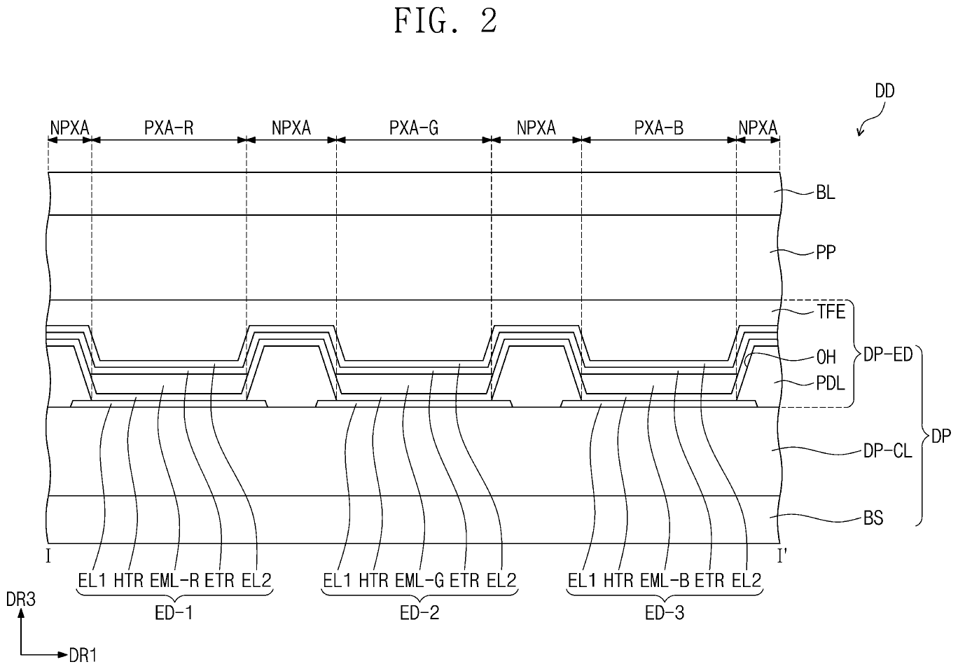

Hereinafter, embodiments of the present disclosure will be explained referring to the drawings. FIG. 1 is a plan view showing an embodiment of a display device DD. FIG. 2 is a cross-sectional view of a display device DD of an embodiment. FIG. 2 is a cross-sectional view showing a part corresponding to the line I-I′ of FIG. 1.

The display device DD may include a display panel DP and an optical layer PP disposed on the display panel DP. The display panel DP may include light emitting elements ED-1, ED-2 and ED-3. The display device DD may include multiple light emitting elements ED-1, ED-2 and ED-3. The optical layer PP may be disposed on the display panel DP and control reflection of external light at the display panel DP. The optical layer PP may include, for example, a polarization layer and/or a color filter layer. Different from the drawing shown in FIG. 2, the optical layer PP may be omitted in the display device DD of an embodiment.

The display panel DP may include a base layer BS, a circuit layer DP-CL provided on the base layer BS and a display element layer DP-ED. The display element layer DP-ED may include a pixel definition layer PDL, light emitting elements ED-1, ED-2 and ED-3 disposed in the pixel definition layer PDL, and an encapsulating layer TFE disposed on the light emitting elements ED-1, ED-2 and ED-3.

The base layer BS may be a member providing a base surface where the display element layer DP-ED is disposed. The base layer BS may be a glass substrate, a metal substrate, a plastic substrate, etc. However, an embodiment of the present disclosure is not limited thereto, and the base layer BS may be an inorganic layer, an organic layer or a composite material layer.

In an embodiment, the circuit layer DP-CL is disposed on the base layer BS, and the circuit layer DP-CL may include multiple transistors (not shown). Each of the transistors (not shown) may include a control electrode, an input electrode, and an output electrode. For example, the circuit layer DP-CL may include switching transistors and driving transistors for driving the light emitting elements ED-1, ED-2 and ED-3 of the display element layer DP-ED.

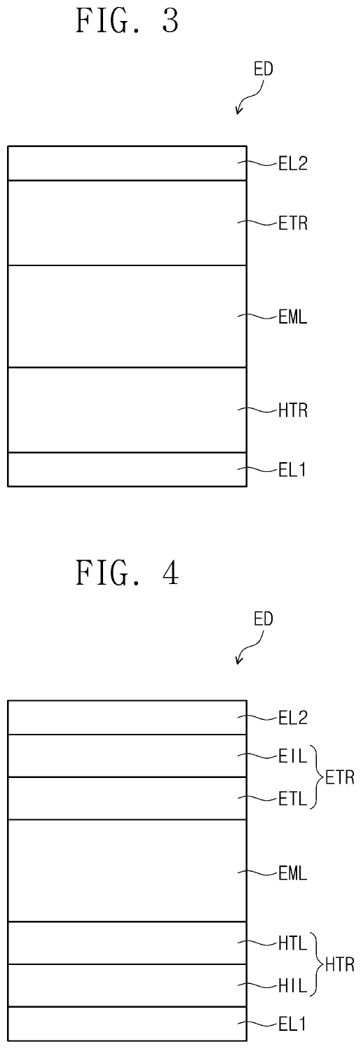

The light emitting elements ED-1, ED-2 and ED-3 may have the structures of the light emitting elements ED of embodiments according to FIG. 3 to FIG. 7, which will be explained in more detail later. The light emitting elements ED-1, ED-2 and ED-3 may include a first electrode EL1, a hole transport region HTR, emission layers EML-R, EML-G and EML-B, an electron transport region ETR and a second electrode EL2.

In FIG. 2, shown is an embodiment where the emission layers EML-R, EML-G and EML-B of light emitting elements ED-1, ED-2 and ED-3 are disposed in opening portions OH defined in a pixel definition layer PDL, and a hole transport region HTR, an electron transport region ETR and a second electrode EL2 are provided as common layers in all light emitting elements ED-1, ED-2 and ED-3. However, an embodiment of the present disclosure is not limited thereto. Different from FIG. 2, in an embodiment, the hole transport region HTR and the electron transport region ETR may be patterned and provided in the opening portions OH defined in the pixel definition layer PDL. For example, in an embodiment, the hole transport region HTR, the emission layers EML-R, EML-G and EML-B, and the electron transport region ETR of the light emitting elements ED-1, ED-2 and ED-3 may be patterned by an inkjet printing method and provided.

An encapsulating layer TFE may cover the light emitting elements ED-1, ED-2 and ED-3. The encapsulating layer TFE may encapsulate the display element layer DP-ED. The encapsulating layer TFE may be disposed on the second electrode EL2 and may be disposed while filling the opening portion OH.

The encapsulating layer TFE may be a thin film encapsulating layer. The encapsulating layer TFE may be one layer or a stacked layer of multiple layers. The encapsulating layer TFE includes at least one insulating layer. The encapsulating layer TFE according to an embodiment may include at least one inorganic layer (hereinafter, encapsulating inorganic layer). In some embodiments, the encapsulating layer TFE according to an embodiment may include at least one organic layer (hereinafter, encapsulating organic layer) and at least one encapsulating inorganic layer.

The encapsulating inorganic layer may protect the display element layer DP-ED from moisture/oxygen, and the encapsulating organic layer may protect the display element layer DP-ED from foreign materials such as dust particles. The encapsulating inorganic layer may include silicon nitride, silicon oxy nitride, silicon oxide, titanium oxide, or aluminum oxide, without specific limitation. The encapsulating organic layer may include an acrylic compound, an epoxy-based compound, etc. The encapsulating organic layer may include a photopolymerizable organic material, without specific limitation.

Referring to FIG. 1 and FIG. 2, the display device DD may include a non-luminous area NPXA and luminous areas PXA-R, PXA-G and PXA-B. The luminous areas PXA-R, PXA-G and PXA-B may be areas emitting light produced from the light emitting elements ED-1, ED-2 and ED-3, respectively. The luminous areas PXA-R, PXA-G and PXA-B may be separated from each other on a plane (e.g., in a plan view).

The luminous areas PXA-R, PXA-G and PXA-B may be areas separated by the pixel definition layer PDL. The non-luminous areas NPXA may be areas between neighboring luminous areas PXA-R, PXA-G and PXA-B and may be areas corresponding to the pixel definition layer PDL. In some embodiments, in the disclosure, each of the luminous areas PXA-R, PXA-G and PXA-B may correspond to each pixel. The pixel definition layer PDL may divide the light emitting elements ED-1, ED-2 and ED-3. The emission layers EML-R, EML-G and EML-B of the light emitting elements ED-1, ED-2 and ED-3 may be disposed and divided in the opening portions OH defined in the pixel definition layer PDL.

The luminous areas PXA-R, PXA-G and PXA-B may be divided into multiple groups according to the color of light produced from the light emitting elements ED-1, ED-2 and ED-3. In the display device DD of an embodiment, shown in FIG. 1 and FIG. 2, three luminous areas PXA-R, PXA-G and PXA-B emitting red light, green light and blue light, respectively, are illustrated as an embodiment. For example, the display device DD of an embodiment may include a red luminous area PXA-R, a green luminous area PXA-G and a blue luminous area PXA-B, which are separated from each other.

In the display device DD according to an embodiment, multiple light emitting elements ED-1, ED-2 and ED-3 may emit light having different wavelength regions. For example, in an embodiment, the display device DD may include a first light emitting element ED-1 emitting red light, a second light emitting element ED-2 emitting green light, and a third light emitting element ED-3 emitting blue light. For example, each of the red luminous area PXA-R, the green luminous area PXA-G, and the blue luminous area PXA-B of the display device DD may correspond to the first light emitting element ED-1, the second light emitting element ED-2, and the third light emitting element ED-3, respectively.

However, an embodiment of the present disclosure is not limited thereto, and the first to third light emitting elements ED-1, ED-2 and ED-3 may emit light in substantially the same wavelength region, or at least one thereof may emit light in a different wavelength region. For example, the first to third light emitting elements ED-1, ED-2 and ED-3 may all emit blue light.

The luminous areas PXA-R, PXA-G and PXA-B in the display device DD according to an embodiment may be arranged in a stripe shape. Referring to FIG. 1, multiple red luminous areas PXA-R may be arranged with each other along a second directional axis DR2, multiple green luminous areas PXA-G may be arranged with each other along the second directional axis DR2, and multiple blue luminous areas PXA-B may be arranged with each other along the second directional axis DR2. In some embodiments, the red luminous area PXA-R, the green luminous area PXA-G and the blue luminous area PXA-B may be arranged by turns along a first directional axis DR1.

In FIG. 1 and FIG. 2, the areas of the luminous areas PXA-R, PXA-G and PXA-B are shown as similar in size, but an embodiment of the present disclosure is not limited thereto. The areas of the luminous areas PXA-R, PXA-G and PXA-B may be different from each other according to the wavelength region of light emitted. In some embodiments, the areas of the luminous areas PXA-R, PXA-G and PXA-B may refer to areas on a plane defined by the first directional axis DR1 and the second directional axis DR2 (e.g., in a plan view).

In some embodiments, the arrangement of the luminous areas PXA-R, PXA-G and PXA-B is not limited to the configuration shown in FIG. 1, and the arrangement order of the red luminous areas PXA-R, the green luminous areas PXA-G and the blue luminous areas PXA-B may be provided in various suitable combinations according to the properties of display quality required for the display device DD. For example, the luminous areas PXA-R, PXA-G and PXA-B may be arranged in a pentile (PENTILE®) arrangement form, or a diamond (Diamond Pixel™) arrangement form. PENTILE® and Diamond Piel™ are trademarks of Samsung Display Co., Ltd.

In some embodiments, the areas of the luminous areas PXA-R, PXA-G and PXA-B may be different from each other. For example, in an embodiment, the area of the green luminous area PXA-G may be smaller than the area of the blue luminous area PXA-B, but an embodiment of the present disclosure is not limited thereto.

Hereinafter, FIG. 3 to FIG. 7 are cross-sectional views schematically showing light emitting elements according to embodiments. The light emitting element ED according to an embodiment may include a first electrode EL1, a hole transport region HTR, an emission layer EML, an electron transport region ETR, and a second electrode EL2, stacked sequentially in the stated order.

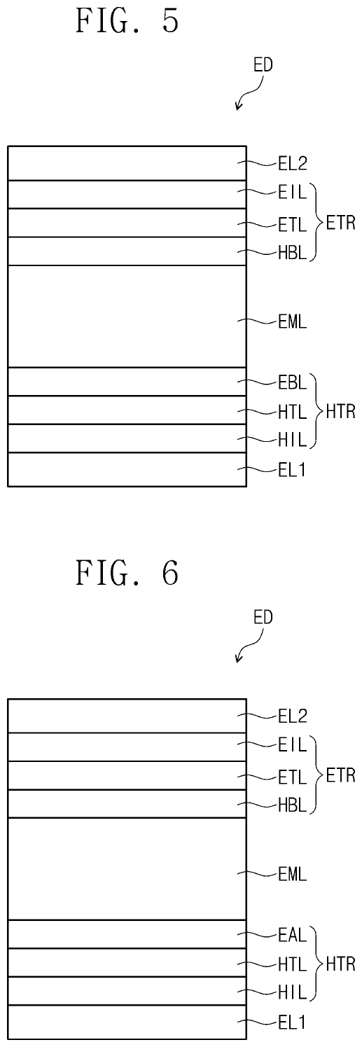

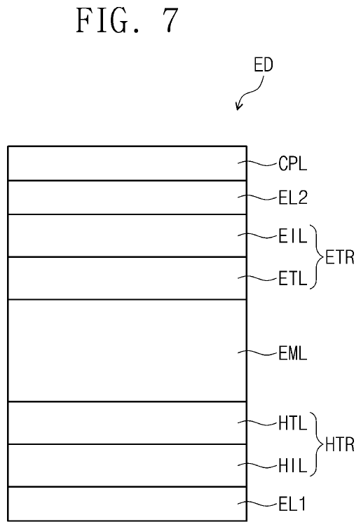

When compared to FIG. 3, FIG. 4 shows the cross-sectional view of a light emitting element ED of an embodiment, wherein a hole transport region HTR includes a hole injection layer HIL and a hole transport layer HTL, and an electron transport region ETR includes an electron injection layer EIL and an electron transport layer ETL. When compared to FIG. 3, FIG. 5 shows the cross-sectional view of a light emitting element ED of an embodiment, wherein a hole transport region HTR includes a hole injection layer HIL, a hole transport layer HTL, and an electron blocking layer EBL, and an electron transport region ETR includes an electron injection layer EIL, an electron transport layer ETL, and a hole blocking layer HBL. When compared to FIG. 3, FIG. 6 shows the cross-sectional view of a light emitting element ED of an embodiment, wherein a hole transport region HTR includes a hole injection layer HIL, a hole transport layer HTL and an emission auxiliary layer EAL, and an electron transport region ETR includes an electron injection layer EIL, an electron transport layer ETL, and a hole blocking layer HBL. When compared to FIG. 4, FIG. 7 shows the cross-sectional view of a light emitting element ED of an embodiment, including a capping layer CPL disposed on the second electrode EL2.

In the light emitting element ED of an embodiment, an emission layer EML may include at least one among second to fourth compounds, and a first compound. The second compound may include a fused ring (e.g., fused ring structure) of three rings, including a nitrogen atom as a ring-forming atom. The third compound may include a hexagonal ring including at least one nitrogen atom as a ring-forming atom. The fourth compound may include an organometallic complex. The second to fourth compounds will be explained in more detail later.

The first compound may be referred to as the fused polycyclic compound of an embodiment. In the description, the first compound and the fused polycyclic compound of an embodiment are the same. The fused polycyclic compound of an embodiment may include a fused ring (e.g., fused ring structure) of five rings, including two nitrogen atoms and one boron atom as ring-forming atoms, as a central structure. In the central structure of the fused polycyclic compound of an embodiment, a substituent of three linearly (e.g., sequentially) connected phenyl groups may be bonded to each of the two nitrogen atoms. The substituent of the three linearly (e.g., sequentially) connected phenyl groups may protect the central structure and may prevent or reduce intermolecular interaction. Accordingly, a light emitting element including the fused polycyclic compound of an embodiment may show a reduced driving voltage, and improved light efficiency and lifetime. Hereinafter, the fused polycyclic compound of an embodiment will be explained referring to Formula 1.

In the description, the term “substituted or unsubstituted” corresponds to a functional group that is substituted or unsubstituted with at least one substituent selected from the group consisting of a deuterium atom, a halogen atom, a cyano group, a nitro group, an amine group, a silyl group, an oxy group, a thio group, a sulfinyl group, a sulfonyl group, a carbonyl group, a boron group, a phosphine oxide group, a phosphine sulfide group, an alkyl group, an alkenyl group, an alkynyl group, a hydrocarbon ring group, an aryl group, and a heterocyclic group. In some embodiments, each of the exemplified substituents may be substituted or unsubstituted. For example, a biphenyl group may be interpreted as an aryl group or a phenyl group substituted with a phenyl group.

In the description, the term “forming a ring via the combination with an adjacent group” may refer to that a group is bonded to an adjacent group to form a substituted or unsubstituted hydrocarbon ring, or a substituted or unsubstituted heterocycle. The hydrocarbon ring includes an aliphatic hydrocarbon ring and an aromatic hydrocarbon ring. The heterocycle includes an aliphatic heterocycle and an aromatic heterocycle. The hydrocarbon ring and the heterocycle may be monocycles or polycycles. In some embodiments, the ring formed via the combination with an adjacent group may be combined with another ring to form a spiro structure.

In the description, the term “adjacent group” may refer to a substituent substituted for an atom which is directly combined with an atom substituted with a corresponding substituent, another substituent substituted for an atom which is substituted with a corresponding substituent, or a substituent sterically positioned at the nearest position to a corresponding substituent. For example, in 1,2-dimethylbenzene, the two methyl groups may be interpreted as “adjacent groups” to each other, and in 1,1-diethylcyclopentene, the two ethyl groups may be interpreted as “adjacent groups” to each other. In some embodiments, in 4,5-dimethylphenanthrene, the two methyl groups may be interpreted as “adjacent groups” to each other.

In the description, a halogen atom may be a fluorine atom, a chlorine atom, a bromine atom or an iodine atom.

In the description, an alkyl group may be a linear, branched, or cyclic alkyl group. For example, the number of carbon atoms of the alkyl group may be 1 to 60, 1 to 50, 1 to 30, 1 to 20, 1 to 10, or 1 to 6. Examples of the alkyl group may include a methyl group, an ethyl group, an n-propyl group, an isopropyl group, an n-butyl group, an s-butyl group, a t-butyl group, an i-butyl group, a 2-ethylbutyl group, a 3,3-dimethylbutyl group, an n-pentyl group, an i-pentyl group, a neopentyl group, a t-pentyl group, a cyclopentyl group, a 1-methylpentyl group, a 3-methylpentyl group, a 2-ethylpentyl group, a 4-methyl-2-pentyl group, an n-hexyl group, a 1-methylhexyl group, a 2-ethylhexyl group, a 2-butylhexyl group, a cyclohexyl group, a 4-methylcyclohexyl group, a 4-t-butylcyclohexyl group, an n-heptyl group, a 1-methylheptyl group, a 2,2-dimethylheptyl group, a 2-ethylheptyl group, a 2-butylheptyl group, an n-octyl group, a t-octyl group, a 2-ethyloctyl group, a 2-butyloctyl group, a 2-hexyloctyl group, a 3,7-dimethyloctyl group, a cyclooctyl group, an n-nonyl group, an n-decyl group, an adamantyl group, a 2-ethyldecyl group, a 2-butyldecyl group, a 2-hexyldecyl group, a 2-octyldecyl group, an n-undecyl group, an n-dodecyl group, a 2-ethyldodecyl group, a 2-butyldodecyl group, a 2-hexyldocecyl group, a 2-octyldodecyl group, an n-tridecyl group, an n-tetradecyl group, an n-pentadecyl group, an n-hexadecyl group, a 2-ethylhexadecyl group, a 2-butylhexadecyl group, a 2-hexylhexadecyl group, a 2-octylhexadecyl group, an n-heptadecyl group, an n-octadecyl group, an n-nonadecyl group, an n-eicosyl group, a 2-ethyleicosyl group, a 2-butyleicosyl group, a 2-hexyleicosyl group, a 2-octyleicosyl group, an n-henicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, etc., without being limited thereto.

In the description, an alkenyl group refers to a hydrocarbon group including one or more carbon-carbon double bonds in the middle and/or at the terminal end of an alkyl group having a carbon number of 2 or more. The alkenyl group may be a linear chain or a branched chain. The number of carbon atoms is not specifically limited, but may be 2 to 60, 2 to 30, 2 to 20, or 2 to 10. Examples of the alkenyl group may include a vinyl group, a 1-butenyl group, a 1-pentenyl group, a 1,3-butadienyl aryl group, a styrenyl group, a styrylvinyl group, etc., without being limited thereto.

In the description, an alkynyl group refers to a hydrocarbon group including one or more carbon-carbon triple bonds in the middle and/or at the terminal end of an alkyl group having a carbon number of 2 or more. The alkynyl group may be a linear chain or a branched chain. The number of carbon atoms is not specifically limited, but may be 2 to 60, 2 to 30, 2 to 20, or 2 to 10. Examples of the alkynyl group may include an ethynyl group, a propynyl group, etc., without being limited thereto.

In the description, a hydrocarbon ring group refers to an optional functional group or substituent derived from an aliphatic hydrocarbon ring. The hydrocarbon ring group may be a saturated hydrocarbon ring group. The number of ring-forming carbon of the hydrocarbon ring group may be 5 to 60, 5 to 30, or 5 to 20.

In the description, an aryl group refers to an optional functional group or substituent derived from an aromatic hydrocarbon ring. The aryl group may be a monocyclic aryl group or a polycyclic aryl group. The number of carbon atoms for forming rings in the aryl group may be 6 to 60, 6 to 30, 6 to 20, or 6 to 15. Examples of the aryl group may include a phenyl group, a naphthyl group, a fluorenyl group, an anthracenyl group, a phenanthryl group, a biphenyl group, a terphenyl group, a quaterphenyl group, a quinquephenyl group, a sexiphenyl group, a triphenylenyl group, a pyrenyl group, a benzofluoranthenyl group, a chrysenyl group, etc., without being limited thereto.

In the description, a fluorenyl group may be substituted, and two substituents may be combined with each other to form a spiro structure. Examples of a substituted fluorenyl group are as follows, but an embodiment of the present disclosure is not limited thereto.

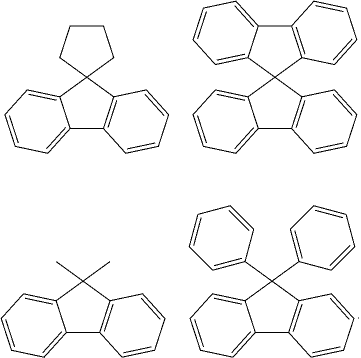

In the description, a heterocyclic group refers to an optional functional group or substituent derived from a ring including one or more among B, O, N, P, Si, Se, Te and S as ring-forming heteroatoms. The heterocyclic group includes an aliphatic heterocyclic group and an aromatic heterocyclic group. The aromatic heterocyclic group may be a heteroaryl group. The aliphatic heterocyclic group and the aromatic heterocyclic group may be a monocycle or a polycycle.

In the description, a heterocyclic group may include one or more among B, O, N, P, Si, Se, Te and S as ring-forming heteroatoms. When the heterocyclic group includes two or more heteroatoms, the two or more heteroatoms may be the same or different. The heterocyclic group may be a monocyclic heterocyclic group or polycyclic heterocyclic group and may include a heteroaryl group. The number of carbon atoms for forming rings of the heterocyclic group may be 2 to 60, 2 to 30, 2 to 20, or 2 to 10.

In the description, an aliphatic heterocyclic group may include one or more among B, O, N, P, Si, Se, Te and S as ring-forming heteroatoms. The number of ring-forming carbon atoms of the aliphatic heterocyclic group may be 2 to 60, 2 to 30, 2 to 20, or 2 to 10. Examples of the aliphatic heterocyclic group may include an oxirane group, a thiirane group, a pyrrolidine group, a piperidine group, a tetrahydrofuran group, a tetrahydrothiophene group, a thiane group, a tetrahydropyran group, a 1,4-dioxane group, etc., without being limited thereto.

In the description, a heteroaryl group may include one or more among B, O, N, P, Si, Se, Te and S as ring-forming heteroatoms. When the heteroaryl group includes two or more heteroatoms, the two or more heteroatoms may be the same or different. The heteroaryl group may be a monocyclic heterocyclic group or polycyclic heterocyclic group. The number of carbon atoms for forming rings of the heteroaryl group may be 2 to 60, 2 to 30, 2 to 20, or 2 to 10. Examples of the heteroaryl group may include thiophene group, a furan group, a pyrrole group, an imidazole group, a pyridine group, a bipyridine group, a pyrimidine group, a triazine group, a triazole group, an acridyl group, a pyridazine group, a pyrazinyl group, a quinoline group, a quinazoline group, a quinoxaline group, a phenoxazine group, a phthalazine group, a pyrido pyrimidine group, a pyrido pyrazine group, a pyrazino pyrazine group, an isoquinoline group, an indole group, a carbazole group, an N-arylcarbazole group, an N-heteroarylcarbazole group, an N-alkylcarbazole group, a benzoxazole group, a benzoimidazole group, a benzothiazole group, a benzocarbazole group, a benzothiophene group, a dibenzothiophene group, a thienothiophene group, a benzofuran group, a phenanthroline group, a thiazole group, an isooxazole group, an oxazole group, an oxadiazole group, a thiadiazole group, a phenothiazine group, a dibenzosilole group, a dibenzofuran, etc., without being limited thereto.

In the description, the same explanation on the above-described aryl group may be applied to an arylene group except that the arylene group is a divalent group. The same explanation on the above-described heteroaryl group may be applied to a heteroarylene group except that the heteroarylene group is a divalent group.

In the description, a silyl group may include an alkyl silyl group and an aryl silyl group. The alkyl silyl group and the aryl silyl group may refer to the above-defined alkyl group or aryl group to which a silicon atom is bonded. The number of carbon atoms of the silyl group is not specifically limited, but may be 1 to 60, 1 to 30, 1 to 20, or 1 to 10. Examples of the silyl group may include a trimethylsilyl group, a triethylsilyl group, a t-butyldimethylsilyl group, an ethyldimethylsilyl group, a propyldimethylsilyl group, a triphenylsilyl group, a diphenylsilyl group, a phenylsilyl group, etc., without being limited thereto.

In the description, the number of carbon atoms of a carbonyl group is not specifically limited, but the number of carbon atoms may be 1 to 40, 1 to 30, or 1 to 20. For example, the carbonyl group may have the structures below, but is not limited thereto.

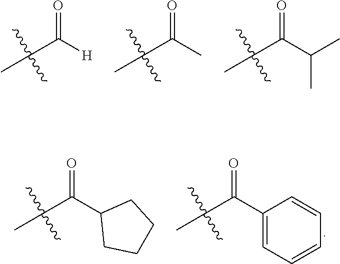

In the description, the number of carbon atoms of a sulfinyl group and the number of carbon atoms of a sulfonyl group are not specifically limited, but may be 1 to 60, 1 to 30, 1 to 20, or 1 to 10. The sulfinyl group may include an alkyl sulfinyl group and an aryl sulfinyl group. The sulfonyl group may include an alkyl sulfonyl group and an aryl sulfonyl group.

In the description, a thio group may include an alkyl thio group and an aryl thio group. The thio group may refer to the above-defined alkyl group or aryl group to which a sulfur atom is bonded. The number of carbon atoms of the thio group is not specifically limited, but may be, for example, 1 to 60, 1 to 30, 1 to 20, or 1 to 10. Examples of the thio group may include a methylthio group, an ethylthio group, a propylthio group, a pentylthio group, a hexylthio group, an octylthio group, a dodecylthio group, a cyclopentylthio group, a cyclohexylthio group, a phenylthio group, a naphthylthio group, etc., without being limited thereto.

In the description, an oxy group may refer to the above-defined alkyl group or aryl group which is combined with an oxygen atom. The oxy group may include an alkoxy group and an aryl oxy group. The alkoxy group may be a linear, branched or cyclic chain. The number of carbon atoms of the alkoxy group is not specifically limited but may be, for example, 1 to 60, 1 to 30, 1 to 20 or 1 to 10. Examples of the oxy group may include a methoxy group, an ethoxy group, an n-propoxy group, an isopropoxy group, a butoxy group, a pentyloxy group, a hexyloxy group, an octyloxy group, a nonyloxy group, a decyloxy group, a benzyloxy group, etc. However, an embodiment of the present disclosure is not limited thereto.

In the description, a boron group may refer to the above-defined alkyl group or aryl group to which a boron atom is bonded. The boron group may include an alkyl boron group and an aryl boron group. The number of carbon atoms of the boron group is not specifically limited, but may be 1 to 60, 1 to 30, 1 to 20, or 1 to 10. Examples of the boron group may include a dimethylboron group, a diethylboron group, a t-butylmethylboron group, a diphenylboron group, a phenylboron group, and/or the like, without being limited thereto.

In the description, the number of carbon atoms of an amine group is not specifically limited, but may be 1 to 60, 1 to 30, 1 to 20, or 1 to 10. The amine group may include an alkyl amine group and an aryl amine group. The alkyl amine group may refer to the above-defined alkyl group to which an amine group is bonded, and the aryl amine group may refer to the above-defined aryl group to which an amine group is bonded. Examples of the amine group may include a methylamine group, a dimethylamine group, a phenylamine group, a diphenylamine group, a naphthylamine group, a 9-methyl-anthracenylamine group, etc., without being limited thereto.

In the description, alkyl groups in the alkyl thio group, the alkyl sulfinyl group, the alkyl sulfonyl group, the alkoxy group, the alkyl boron group, the alkyl silyl group, and the alkyl amine group may be the same as the examples of the above-described alkyl group.

In the description, aryl groups in the aryl oxy group, the aryl thio group, the aryl sulfinyl group, the aryl sulfonyl group, the aryl boron group, the aryl silyl group, and the aryl amine group may be the same as the examples of the above-described aryl group.

In the description, a direct linkage may refer to a single bond. In the description,

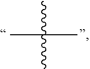

and “−*” may refer to positions to be connected.

The light emitting element ED of an embodiment may include the fused polycyclic compound of an embodiment. The fused polycyclic compound of an embodiment may be represented by Formula 1 below.

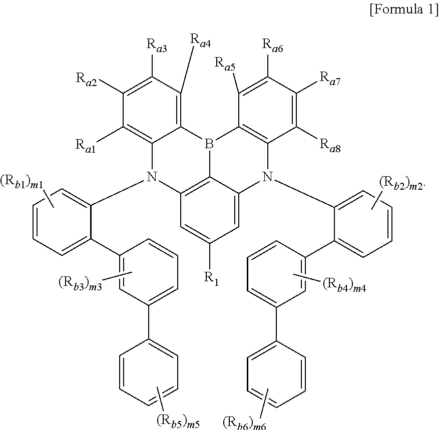

In Formula 1, R₁ may be a hydrogen atom, a deuterium atom, a substituted or unsubstituted alkyl group of 1 to 60 carbon atoms, a substituted or unsubstituted aryl group of 6 to 60 ring-forming carbon atoms, or a substituted or unsubstituted heteroaryl group of 2 to 60 ring-forming carbon atoms. For example, R₁ may be a substituted or unsubstituted t-butyl group, a substituted or unsubstituted phenyl group, a substituted or unsubstituted dibenzofuran group, or a substituted or unsubstituted carbazole group.

R₁ may be represented by any one among Formulae R1-1 to R1-9. Formula R1-1 represents an unsubstituted t-butyl group, and Formulae R1-2 to R1-7 represent substituted or unsubstituted phenyl groups. Formula R1-8 represents a substituted carbazole group, and Formula R1-9 represents an unsubstituted dibenzofuran group.

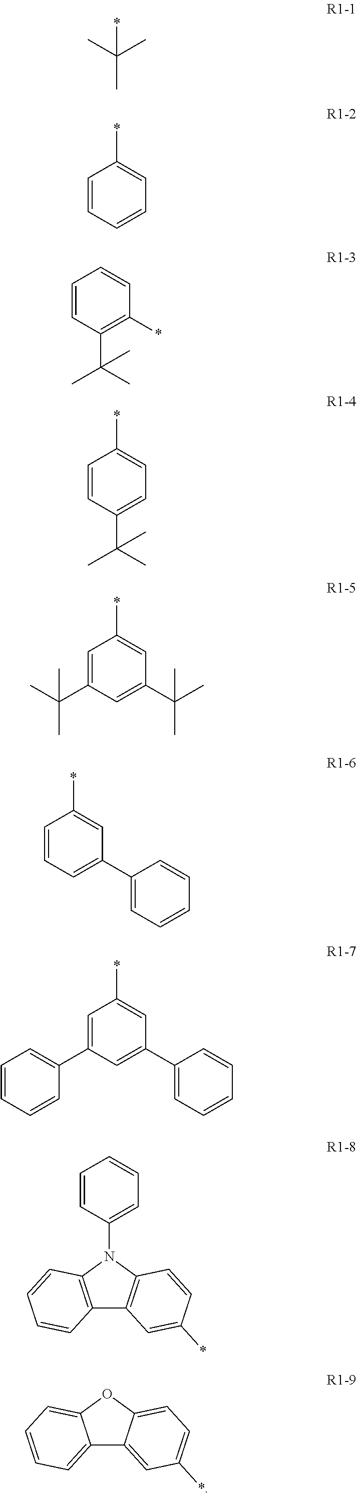

In Formula 1, m1 to m4 may each independently be an integer of 0 to 4. m5 and m6 may each independently be an integer of 0 to 5. When m1 is an integer of 2 or more, multiple R_{b1} may be the same, or at least one may be different. When m2 is an integer of 2 or more, multiple R_{b2} may be the same, or at least one may be different. When m3 is an integer of 2 or more, multiple R_{b3} may be the same, or at least one may be different. When m4 is an integer of 2 or more, multiple R_{b4} may be the same, or at least one may be different. When m5 is an integer of 2 or more, multiple R_{b5} may be the same, or at least one may be different. When m6 is an integer of 2 or more, multiple R_{b6} may be the same, or at least one may be different.

R_{b1} to R_{b6} may each independently be a hydrogen atom, a deuterium atom, a cyano group, a halogen atom, a substituted or unsubstituted alkyl group of 1 to 60 carbon atoms, a substituted or unsubstituted aryl group of 6 to 60 ring-forming carbon atoms, or a substituted or unsubstituted heteroaryl group of 2 to 60 ring-forming carbon atoms.

For example, at least one among R_{b1} to R_{b6} may be a substituted or unsubstituted alkyl group of 1 to 60 carbon atoms, or a substituted or unsubstituted aryl group of 6 to 60 ring-forming carbon atoms. However, these are illustrations, and an embodiment of the present disclosure is not limited thereto.

In Formula 1, at least one among Rₐ₁ to Rₐ₄ may be a substituted or unsubstituted aryl amine group, a substituted or unsubstituted aryl group of 6 to 60 ring-forming carbon atoms, or a substituted or unsubstituted heteroaryl group of 2 to 60 ring-forming carbon atoms, and any remainder thereof may each independently be a hydrogen atom or a deuterium atom. At least one among Rₐ₅ to Rₐ₈ may be a substituted or unsubstituted aryl amine group, a substituted or unsubstituted aryl group of 6 to 60 ring-forming carbon atoms, or a substituted or unsubstituted heteroaryl group of 2 to 60 ring-forming carbon atoms, and any remainder thereof may each independently be a hydrogen atom or a deuterium atom. For example, at least one among Rₐ₁ to Rₐ₄ and at least one among Rₐ₅ to Rₐ₈ may each independently be a substituted or unsubstituted diphenylamine group, a substituted or unsubstituted phenyl group, a substituted or unsubstituted carbazole group, a substituted or unsubstituted dibenzofuran group, or a substituted or unsubstituted phenoxazine group. Rₐ₁ to Rₐ₈ may be substituents directly bonded to the fused ring of five rings, which is a central structure (e.g., core structure).

The fused polycyclic compound of an embodiment, represented by Formula 1 may include at least one deuterium atom. In Formula 1, at least one among Rₐ₁ to Rₐ₈ may include a deuterium atom, or a substituent including a deuterium atom. For example, at least one among Rai to Rₐ₄ and at least one among Rₐ₅ to Rₐ₈ may each independently be an aryl group of 6 to 60 ring-forming carbon atoms, which is substituted with a deuterium atom, or a heteroaryl group of 2 to 60 ring-forming carbon atoms, which is substituted with a deuterium atom. In an embodiment, one to three among Rₐ₁ to Rₐ₄ may be deuterium atoms, and one to three among Rₐ₅ to Rₐ₈ may be deuterium atoms.

In Formula 1, three phenyl groups including R_{b1}, R_{b3}, and R_{b5} (hereinafter, will be referred to as first to third phenyl groups) may be connected linearly (e.g., sequentially). Three phenyl groups including R_{b2}, R_{b4}, and R_{b6} (hereinafter, will be referred to as fourth to sixth phenyl groups) may be connected linearly (e.g., sequentially). The first phenyl group including R_{b1} may make a direct linkage to the fused ring of five rings, which is the central structure, the second phenyl group including R_{b3} may make a direct linkage to the first phenyl group, and the third phenyl group including R_{b5} may make a direct linkage to the second phenyl group. The fourth phenyl group including R_{b2} may make a direct linkage to the fused ring of five rings, which is the central structure, the fifth phenyl group including R_{b4} may make a direct linkage to the fourth phenyl group, and the sixth phenyl group including R_{b6} may make a direct linkage to the fifth phenyl group. A substituent in which the first to third phenyl groups are connected, and a substituent in which the fourth to sixth phenyl groups are connected are bulky substituents and may protect the fused ring of five rings.

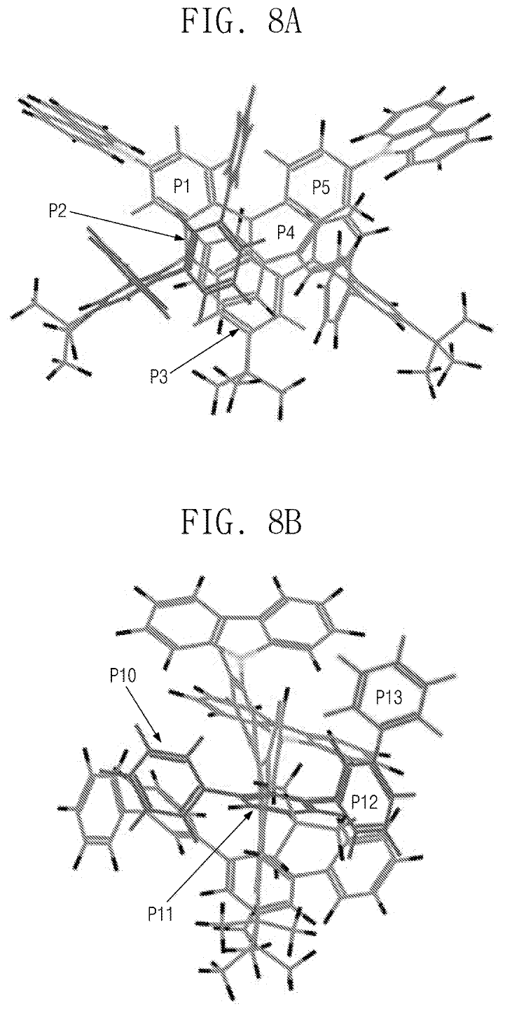

FIG. 8A and FIG. 8B are three-dimensional images showing the fused polycyclic compound according to an embodiment. FIG. 8A and FIG. 8B show three-dimensional images of Compound 8 in Compound Group 1, which will be explained in more detail later. Compound 8 is a fused polycyclic compound of an embodiment having a structure as shown below.

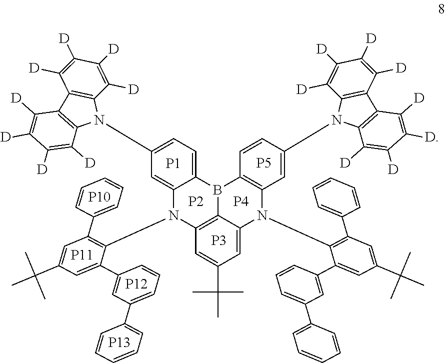

In the structure of Compound 8, P1 to P5, and P10 to P13 are for designating ring groups. FIG. 8A is an image of the ring groups of P1 to P5 when viewed from the front, and FIG. 8B is an image of the ring groups of P1 to P5 when viewed from the side.

The ring groups of P1 to P5 in the structure of Compound 8 correspond to the ring groups of P1 to P5 of FIG. 8A. The ring groups of P1 to P5 correspond to the fused ring of five rings, which is the central structure in the fused polycyclic compound of an embodiment. The ring groups of P10 to P13 in the structure of Compound 8 correspond to the ring groups of P10 to P13 of FIG. 8B. In addition, the ring groups of P11 to P13 correspond to the above-described first to third phenyl groups.

Referring to FIG. 8A and FIG. 8B, three phenyl groups including the ring groups of P12 and P13 may protect the central structure composed of the ring groups of P1 to P5 (i.e., the fused ring of five rings), and may suppress the planarity of the molecule. The ring groups of P10 to P12 may be placed on a plane, for example, perpendicular to a plane including the central structure composed of the ring groups of P1 to P5. In addition, the ring group of P13 (i.e., the third phenyl group) may be arranged in the stable shape of low energy so as not to increase steric hindrance and may protect the central structure composed of the ring groups of P1 to P5.

Accordingly, intermolecular distance may increase, approach to other materials may be prevented or reduced, and intermolecular interaction may be prevented or reduced in the fused polycyclic compound of an embodiment. Because intermolecular distance may increase, and intermolecular interaction may be prevented or reduced in the fused polycyclic compound of an embodiment, dexter energy transfer may be minimized or reduced. According to the minimization or reduction of the dexter energy transfer, the increase of the concentration of triplet excitons in the fused polycyclic compound may be prevented or reduced.

The triplet excitons may present in an excited state for a long time to induce the decomposition of a compound and produce hot excitons having relatively high energy through triplet-triplet annihilation (TTA), resulting in the deterioration of the lifetime of a light emitting element. In addition, the triplet-triplet annihilation (TTA) phenomenon may induce the nonradiative decay of a light emitting material to induce the deterioration in efficiency of a light emitting element.

The intermolecular interaction of the fused polycyclic compound of an embodiment is prevented or reduced, and the efficiency and lifetime of a light emitting element ED may be improved. A light emitting element ED including the fused polycyclic compound of an embodiment may show high efficiency and long-life characteristics. In some embodiments, a light emitting element ED including the fused polycyclic compound of an embodiment may have a reduced driving voltage.

In an embodiment, the fused polycyclic compound represented by Formula 1 may be represented by any one among Formula 1-1 to Formula 1-3. Formula 1-1 to Formula 1-3 may represent Formula 1 where any one among Rₐ₂ and Rₐ₃, and any one among Rₐ₆ and Rₐ₇ may each independently be a substituted or unsubstituted aryl amine group, a substituted or unsubstituted aryl group of 6 to 60 ring-forming carbon atoms, or a substituted or unsubstituted heteroaryl group of 2 to 60 ring-forming carbon atoms.

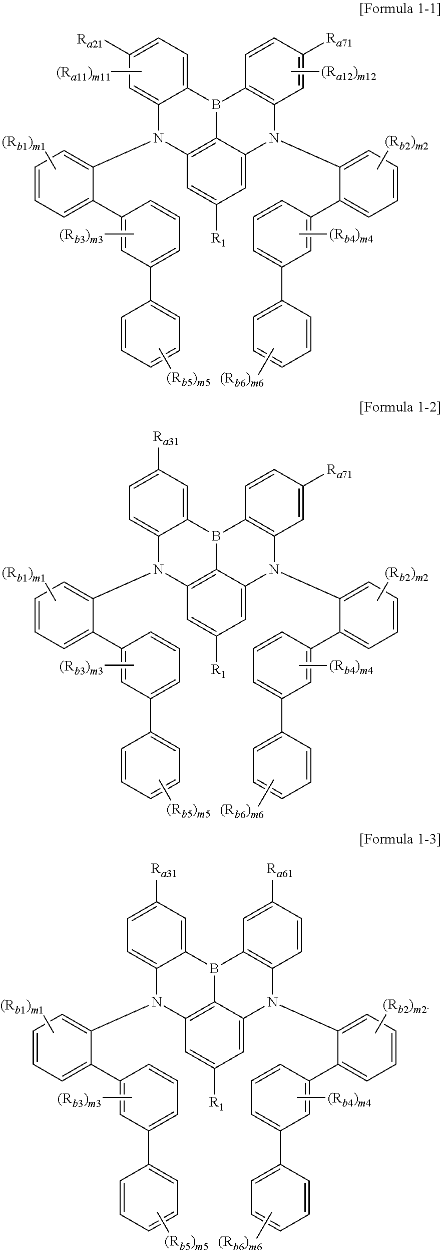

In Formula 1-1, m11 and m12 may each independently be an integer of 0 to 3, and Rₐ₁₁ and Rₐ₁₂ may each independently be a hydrogen atom or a deuterium atom. When m11 is an integer of 2 or more, multiple Rₐ₁₁ may be the same, or at least one may be different. When m12 is an integer of 2 or more, multiple Rₐ₁₂ may be the same, or at least one may be different.

In Formula 1-1 to Formula 1-3, Rₐ₂₁, Rₐ₃₁, Ras1, and Rₐ₇₁ may each independently be a substituted or unsubstituted aryl amine group, a substituted or unsubstituted aryl group of 6 to 60 ring-forming carbon atoms, or a substituted or unsubstituted heteroaryl group of 2 to 60 ring-forming carbon atoms. In Formula 1-1 to Formula 1-3, the same contents explained in Formula 1 may be applied for R₁, m1 to m6, and R_{b1} to R_{b6}.

For example, in Formula 1-1 to Formula 1-3, Rₐ₂₁, Rₐ₃₁, Rₐ₆₁, and Rₐ₇₁ may each independently be a substituted or unsubstituted diphenylamine group, a substituted or unsubstituted phenyl group, a substituted or unsubstituted carbazole group, a substituted or unsubstituted dibenzofuran group, or a substituted or unsubstituted phenoxazine group. Rₐ₂₁, Rₐ₃₁, Rₐ₆₁, and Rₐ₇₁ may each independently be represented by any one among Formulae RA-1 to RA-6.

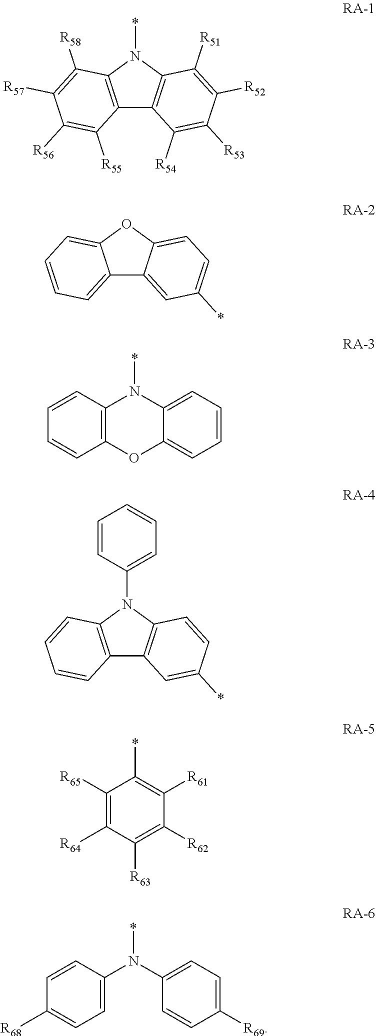

In Formula RA-1, R₅₁ to R₅₈ may each independently be a hydrogen atom, a deuterium atom, a cyano group, an unsubstituted t-butyl group, or an unsubstituted phenyl group. In Formula RA-5, R₆₁ to R₆₅ may each independently be a hydrogen atom, a deuterium atom, an unsubstituted t-butyl group, an unsubstituted phenyl group, or an unsubstituted carbazole group. In Formula RA-6, R₆₈ and R₆₉ may each independently be a hydrogen atom, a deuterium atom, or an unsubstituted t-butyl group.

For example, Formula RA-1 may be represented by any one among Formulae RA-10 to RA-19. Formula RA-5 may be represented by any one among Formulae RA-50 to RA-55. Formula RA-6 may be represented by Formula RA-60 or RA-61.

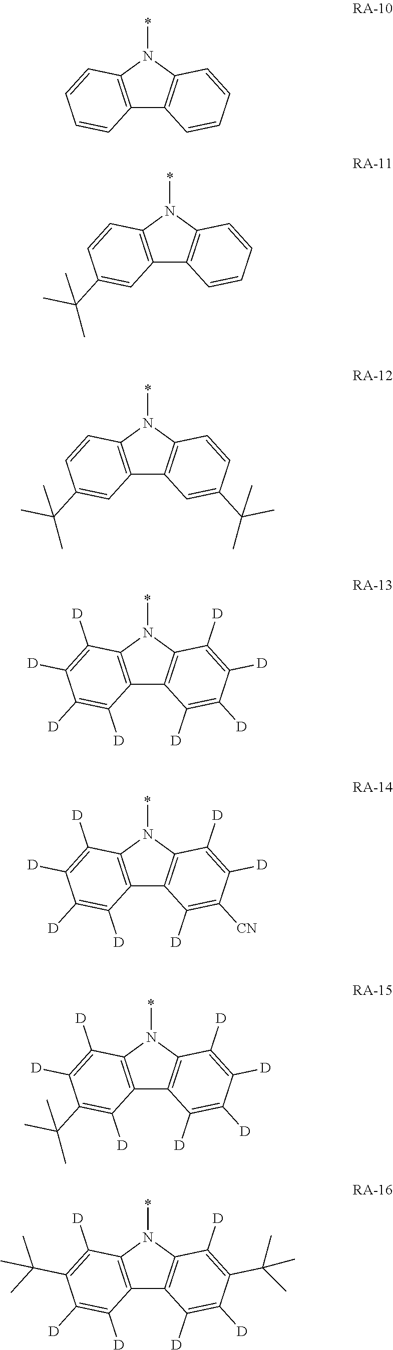

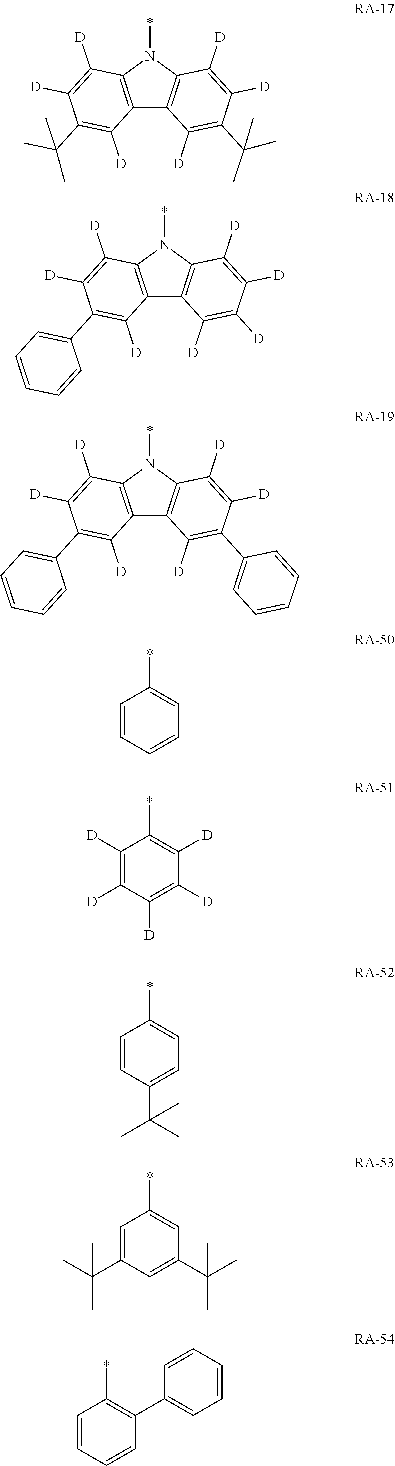

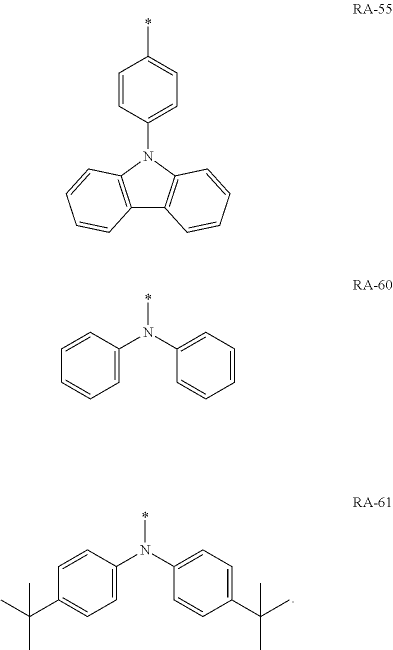 [SMILES: *c1ccc(-n2c3ccccc3c3ccccc32)cc1 ; *N(c1ccccc1)c1ccccc1 ; *N(c1ccc(C(C)(C)C)cc1)c1ccc(C(C)(C)C)cc1]

In an embodiment, the fused polycyclic compound represented by Formula 1 may be represented by Formula 1-A or Formula 1-B. Formula 1-A may represent Formula 1 where m1 and m2 are 2, and two R_{b1} and two R_{b2} are embodied. Formula 1-B may represent Formula 1 where m1 and m2 are 0. In some embodiments, Formula 1-B may represent Formula 1 where m1 and m2 are 4, and all four R_{b1} and all four R_{b2} are hydrogen atoms.

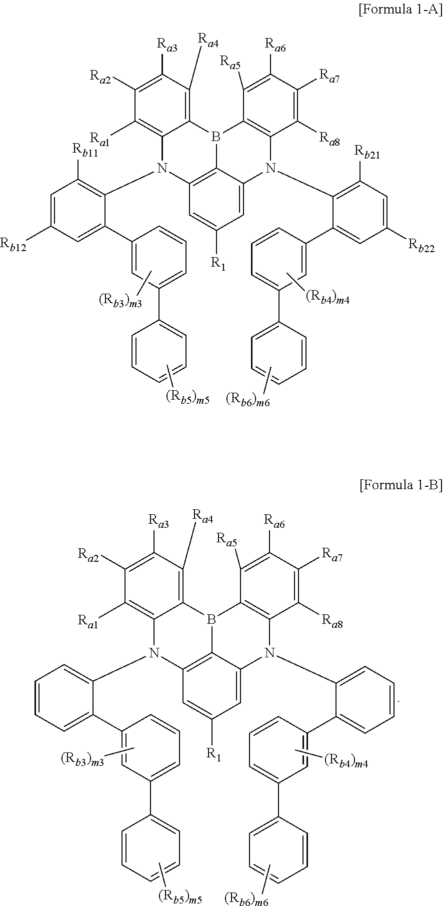

In Formula 1-A, R_{b11}, R_{b12}, R_{b21}, and R_{b22} may each independently be a substituted or unsubstituted alkyl group of 1 to 20 carbon atoms or a substituted or unsubstituted aryl group of 6 to 20 ring-forming carbon atoms. In Formula 1-A and Formula 1-B, the same contents explained in Formula 1 may be applied for Rai to Rₐ₈, R₁, m3 to m6, and R_{b3} to R_{b6}.

For example, in Formula 1-A, R_{b11}, R_{b12}, R_{b21}, and R_{b22} may each independently be a substituted or unsubstituted t-butyl group or a substituted or unsubstituted phenyl group. R_{b11}, R_{b12}, R_{b21}, and R_{b22} may each independently be represented by any one among Formulae RB-1 to RB-3.

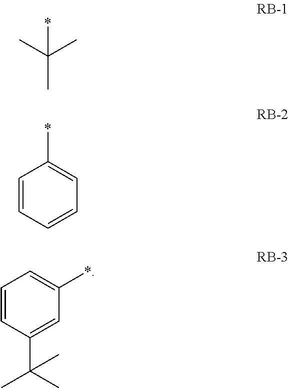

In an embodiment, Formula 1-A may be represented by Formula 1-A1 or Formula 1-A2. Formula 1-A1 may represent Formula 1-A where m3 and m4 are 0. In some embodiments, Formula 1-A1 may represent Formula 1-A where m3 and m4 are 4, and four R_{b3} and four R_{b4} are hydrogen atoms. Formula 1-A2 may represent Formula 1-A where m3 and m4 are 1, and one R_{b3} and one R_{b4} are embodied.

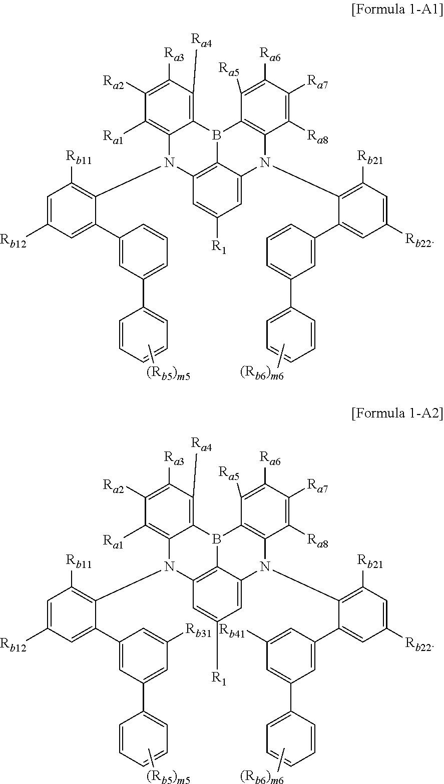

In Formula 1-A1 and Formula 1-A2, the same contents explained in Formula 1-A may be applied for Rₐ₁ to Rₐ₈, R₁, m5, m6, R_{b5}, R_{b6}, R_{b11}, R_{b12}, R_{b21}, and R_{b22}. In Formula 1-A2, R_{b31} and R_{b41} may each independently be a substituted or unsubstituted alkyl group of 1 to 20 carbon atoms or a substituted or unsubstituted aryl group of 6 to 20 ring-forming carbon atoms.

For example, in Formula 1-A2, R_{b31} and R_{b41} may each independently be an unsubstituted t-butyl group or an unsubstituted phenyl group. In Formula 1-A2, R_{b5} and R_{b6} may be hydrogen atoms. However, these are illustrations, and an embodiment of the present disclosure is not limited thereto.

In an embodiment, the fused polycyclic compound represented by Formula 1-A1 may be represented by Formula 1-A11 or Formula 1-A12. Formula 1-A11 may represent Formula 1-A1 where m5 and m6 are 3, and three R_{b5} and three R_{b6} are embodied. Formula 1-A12 may represent Formula 1-A1 where m5 and m6 are 0. In an embodiment, Formula 1-A12 may represent Formula 1-A1 where m5 and m6 are 5, and five R_{b5} and five R_{b6} are hydrogen atoms.

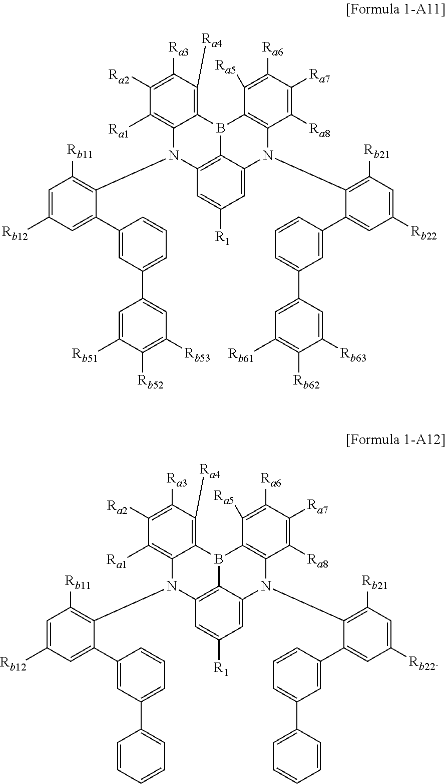

In Formula 1-A11 and Formula 1-A12, the same contents explained in Formula 1-A1 may be applied for Rai to Rₐ₈, R₁, R_{b11}, R_{b12}, R_{b21}, and R_{b22}. In Formula 1-A11, at least one among R_{b51} to R_{b53} may be a substituted or unsubstituted alkyl group of 1 to 20 carbon atoms or a substituted or unsubstituted aryl group of 6 to 20 ring-forming carbon atoms, and any remainder thereof may be hydrogen atoms. At least one among R_{b61} to R_{b63} may be a substituted or unsubstituted alkyl group of 1 to 20 carbon atoms or a substituted or unsubstituted aryl group of 6 to 20 ring-forming carbon atoms, and any remainder thereof may be hydrogen atoms.

For example, at least one among R_{b51} to R_{b53} may be an unsubstituted t-butyl group or an unsubstituted phenyl group. At least one among R_{b61} to R_{b63} may be an unsubstituted t-butyl group or an unsubstituted phenyl group. However, these are illustrations, and an embodiment of the present disclosure is not limited thereto.

The fused polycyclic compound of an embodiment may be represented by any one among the compounds in Compound Group 1. A light emitting element ED of an embodiment may include at least one among the compounds in Compound Group 1. In Compound Group 1, D is a deuterium atom.

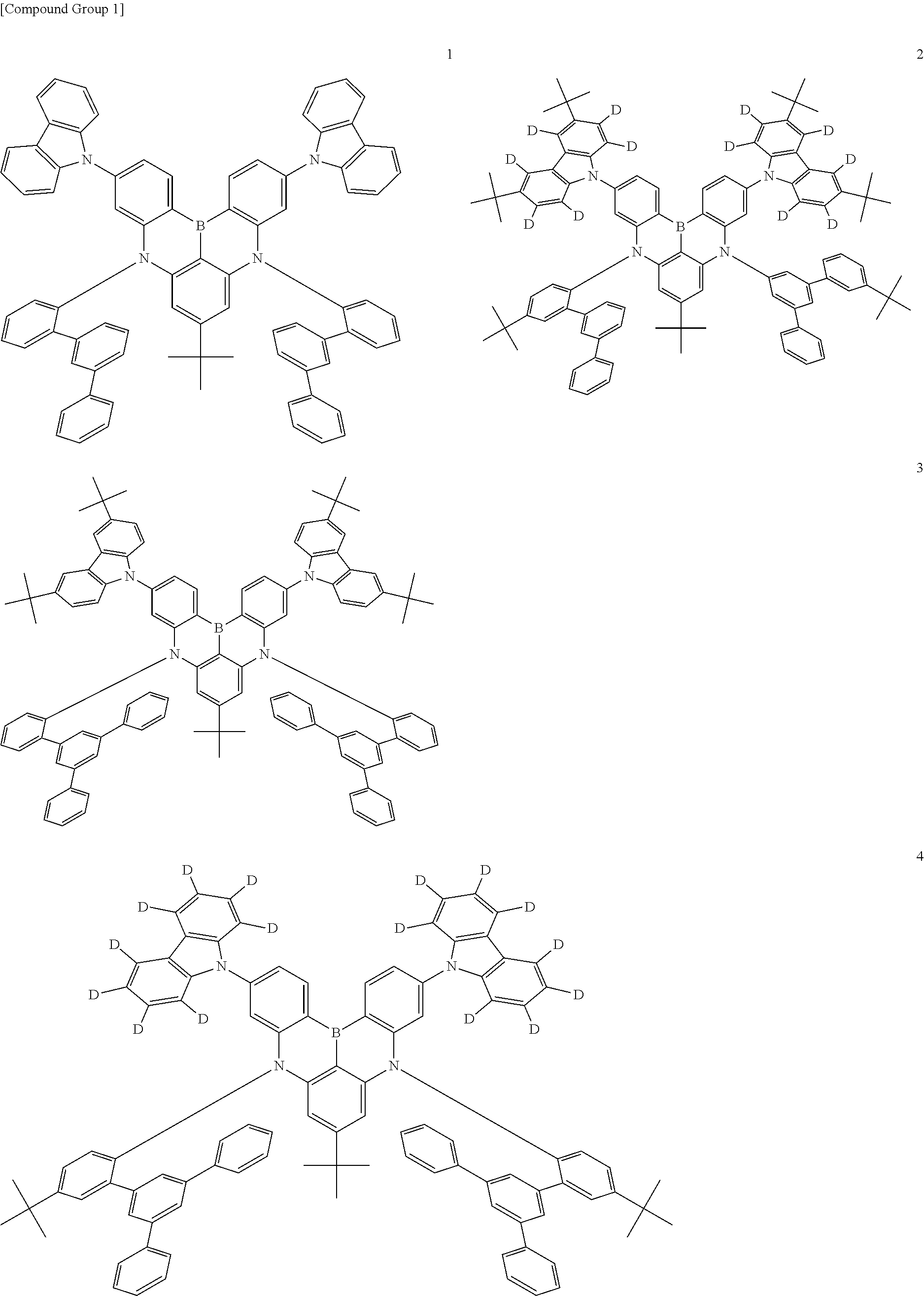

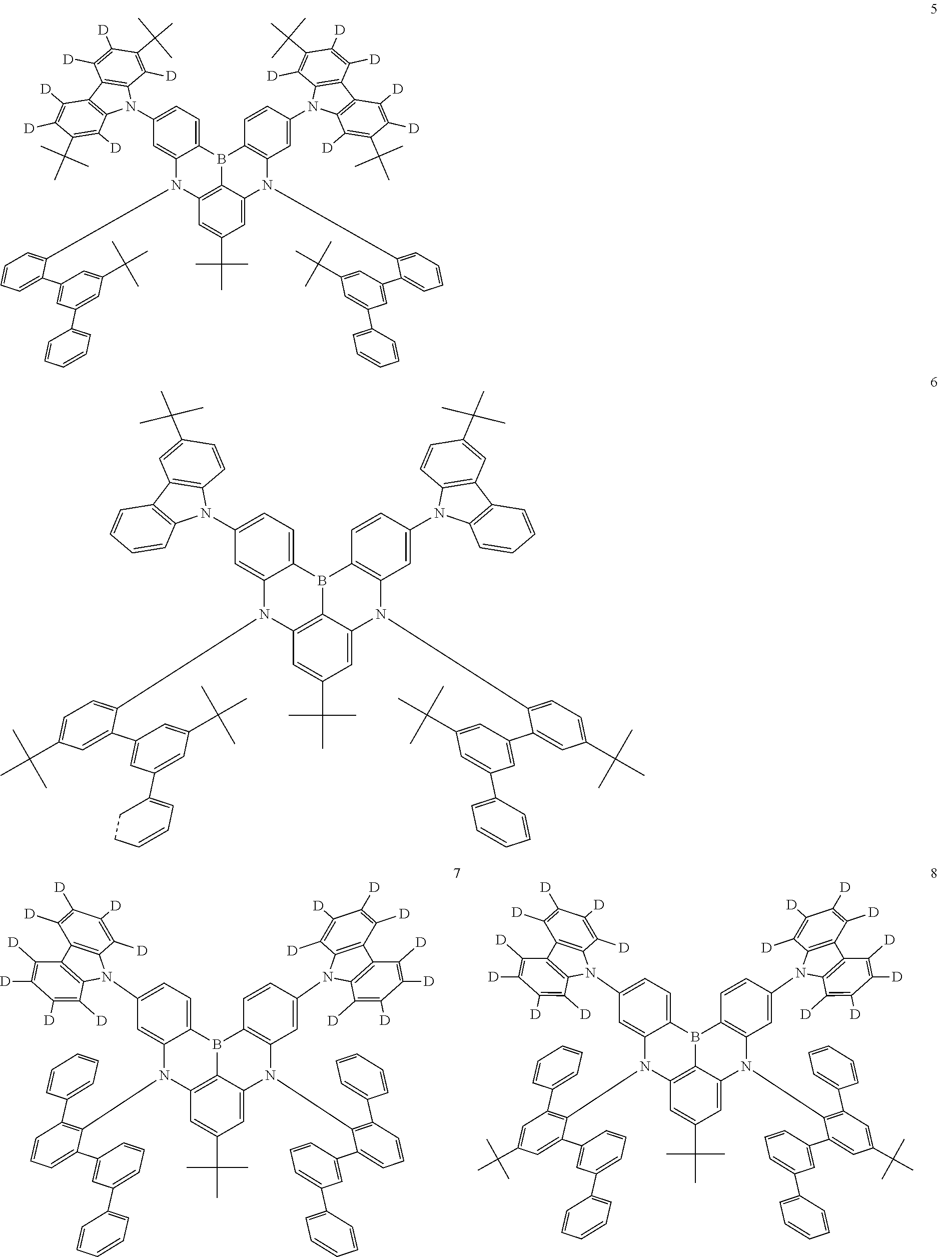

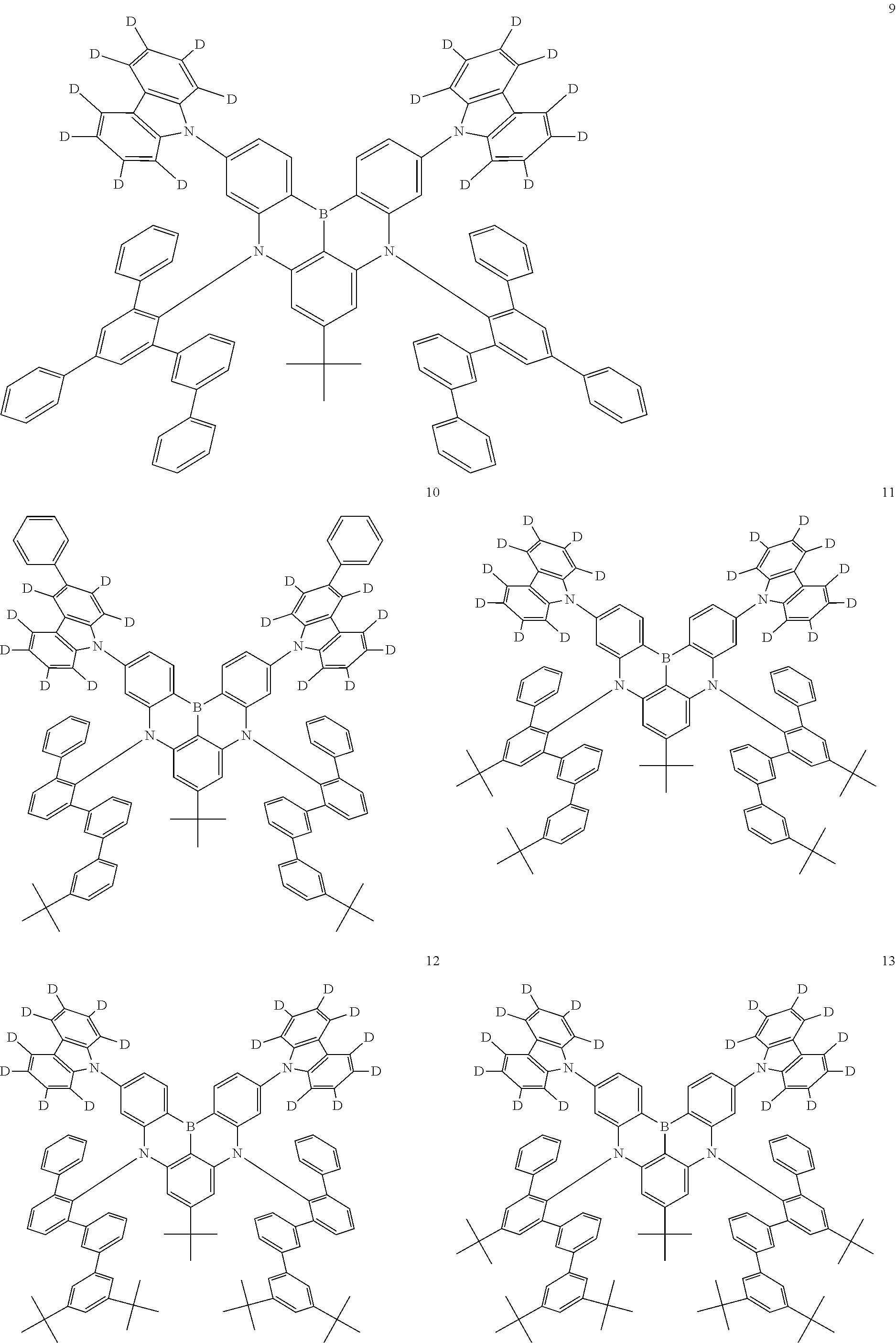

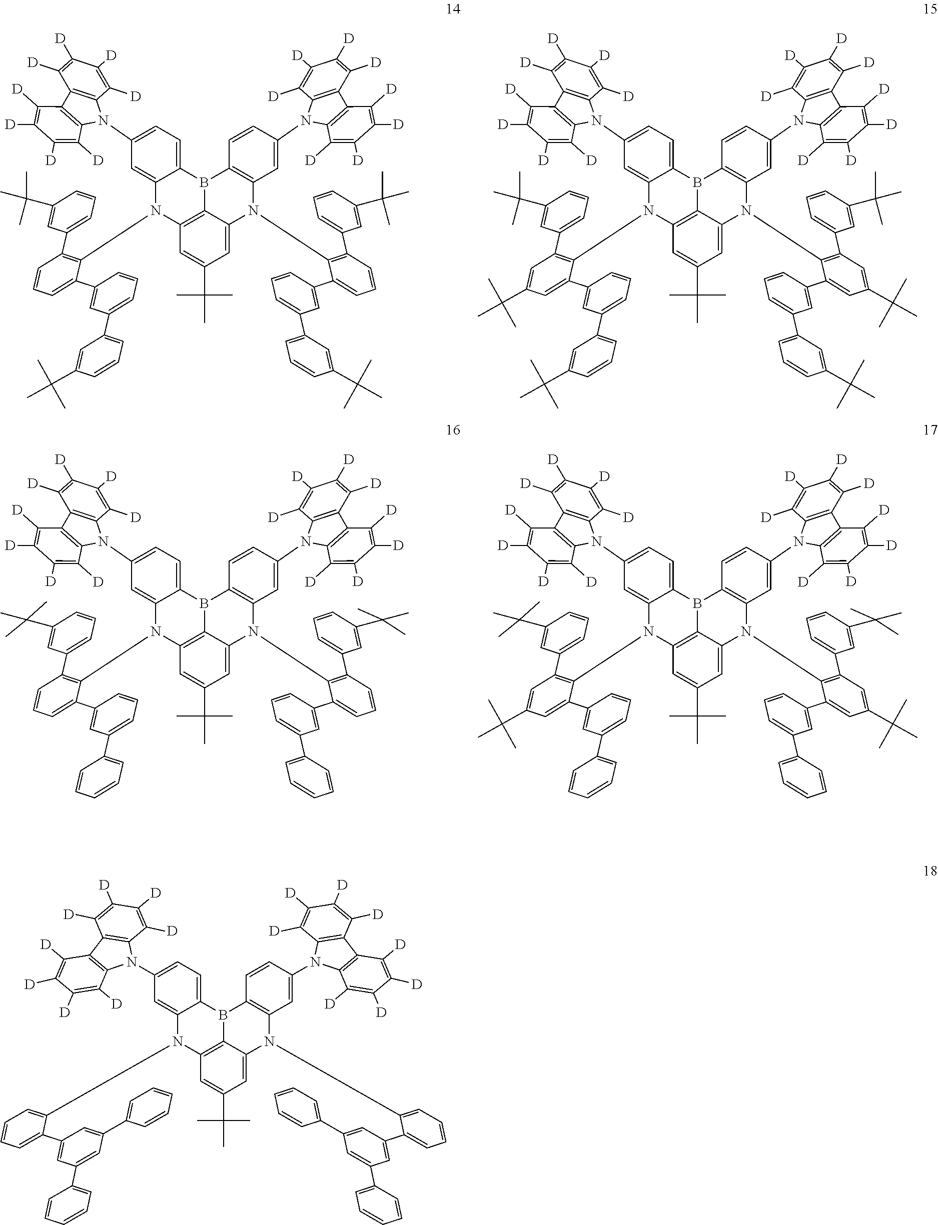

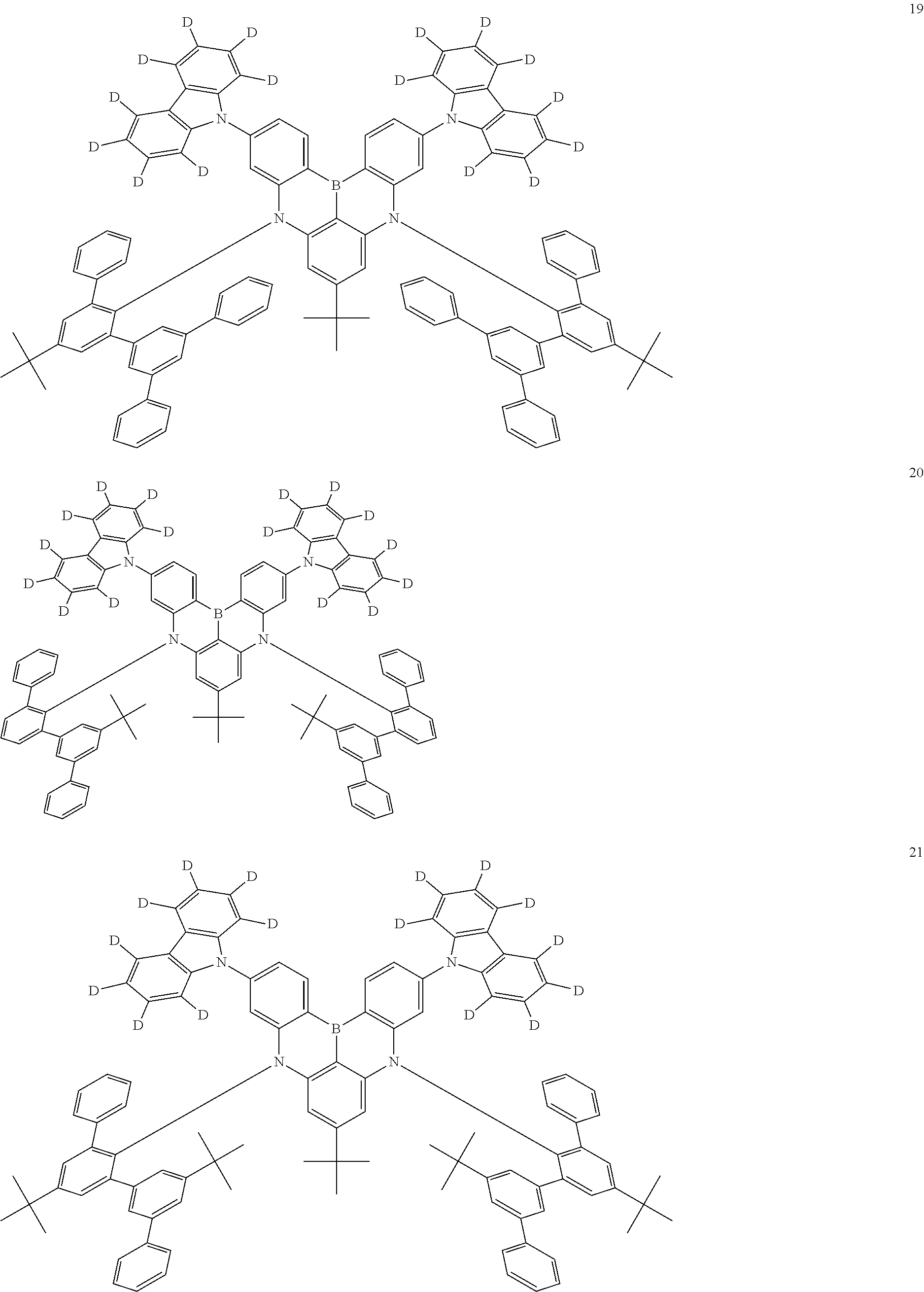

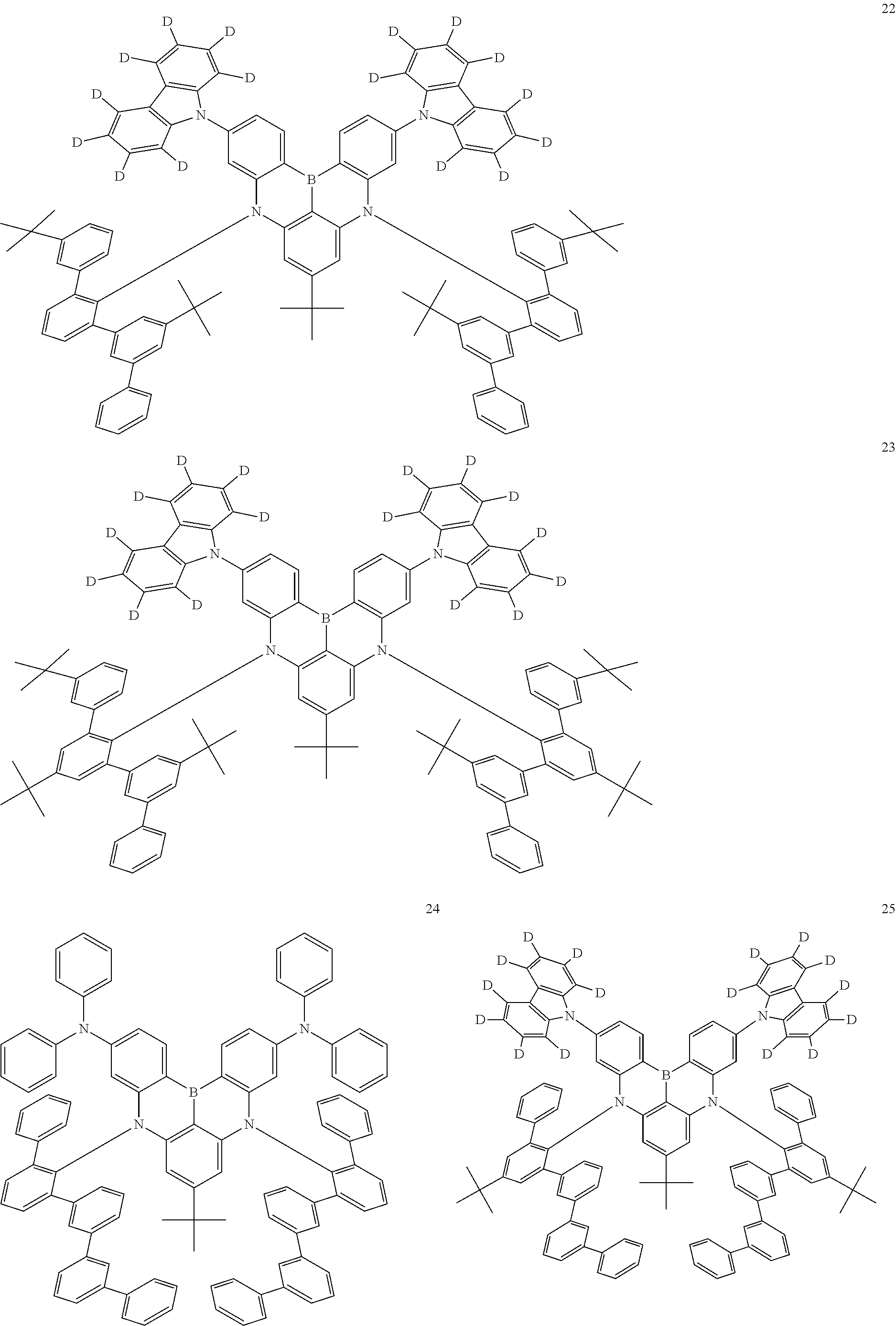

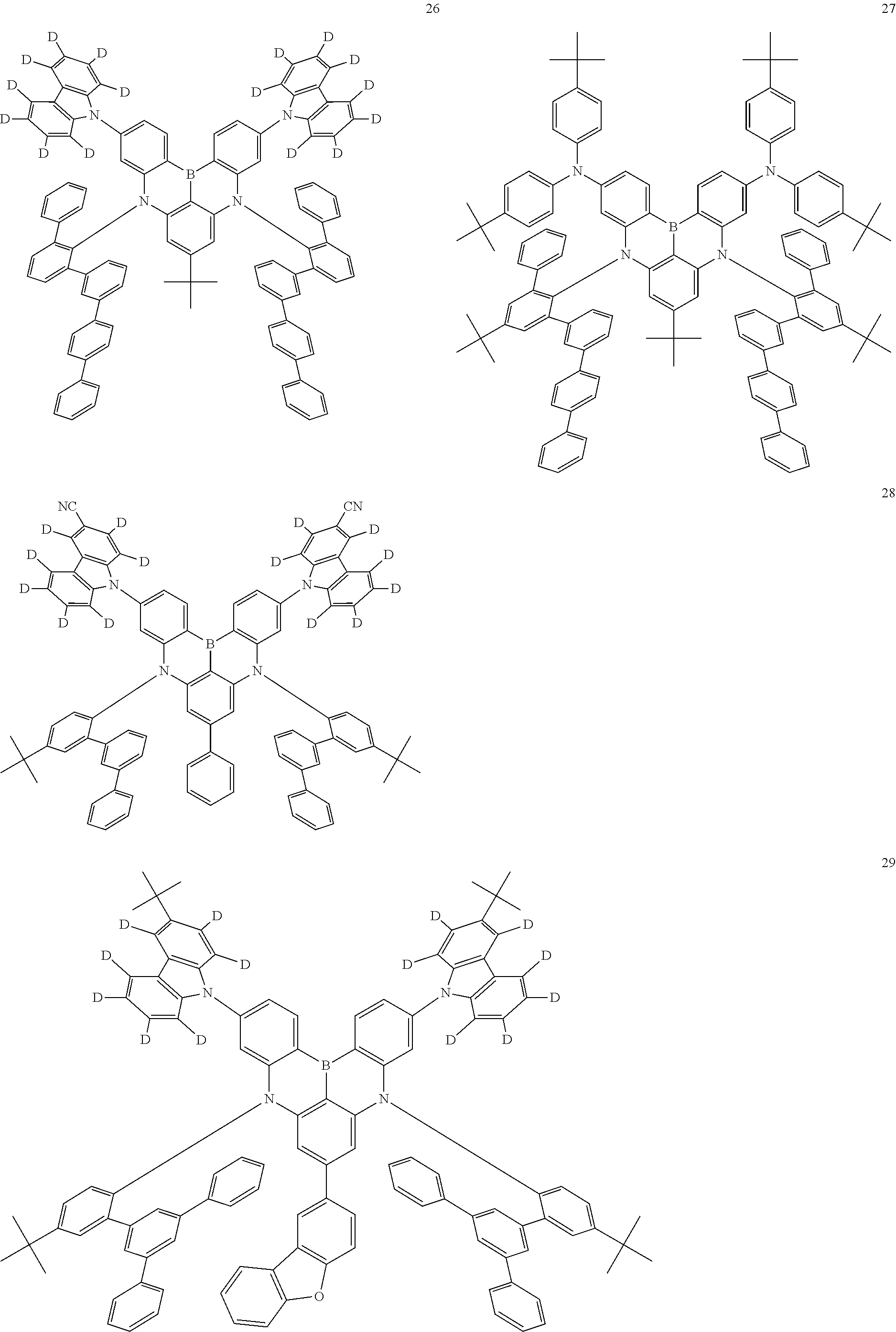

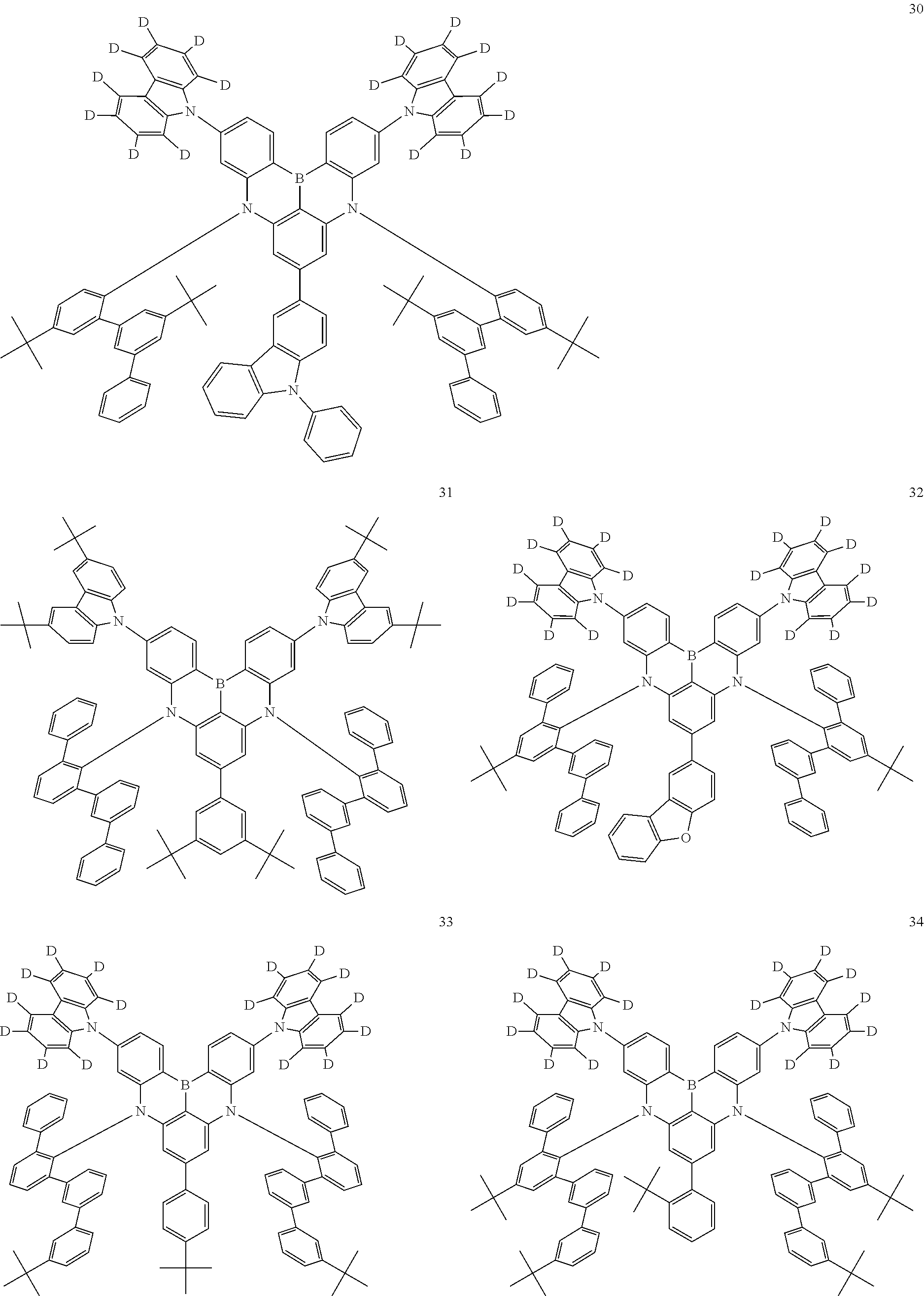

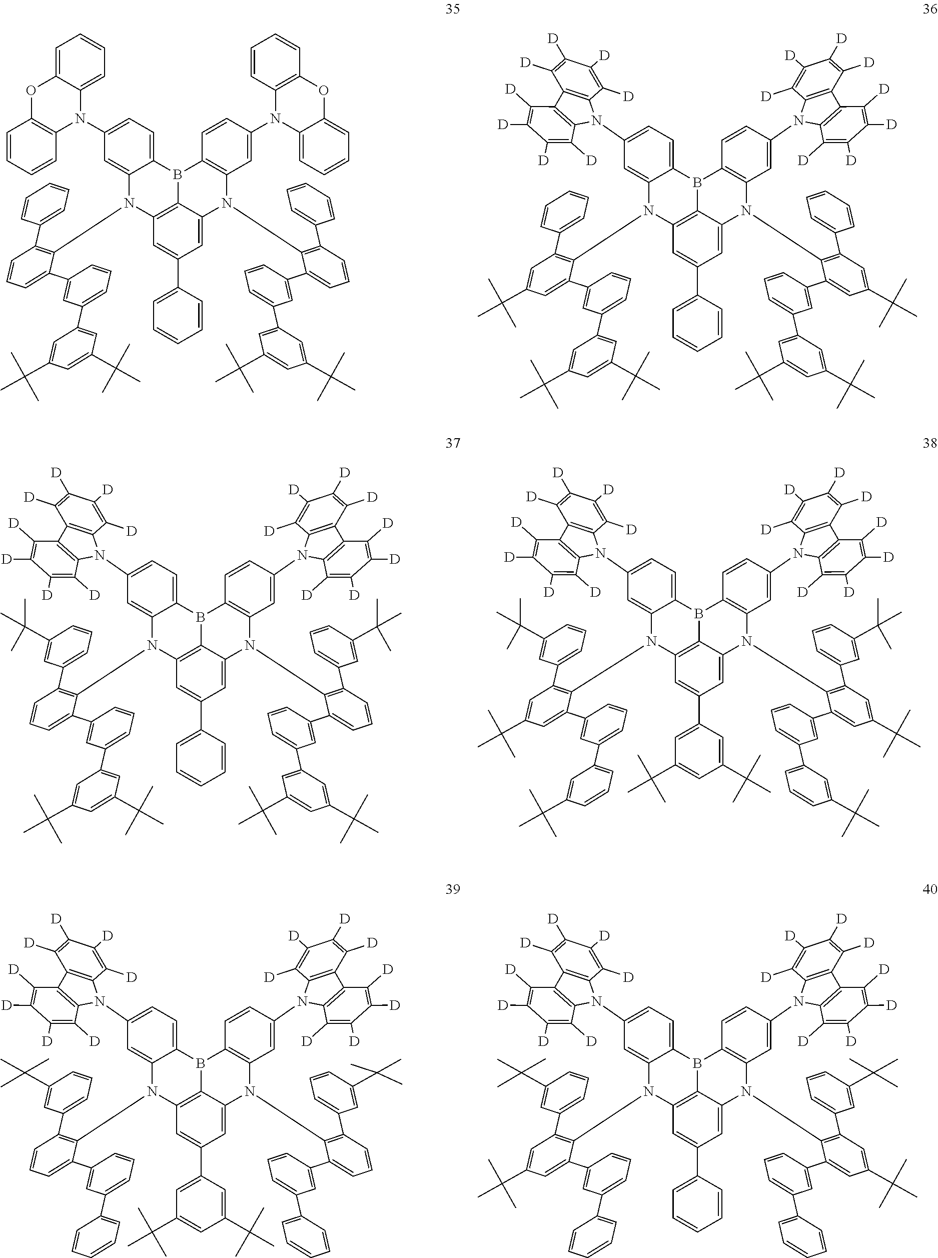

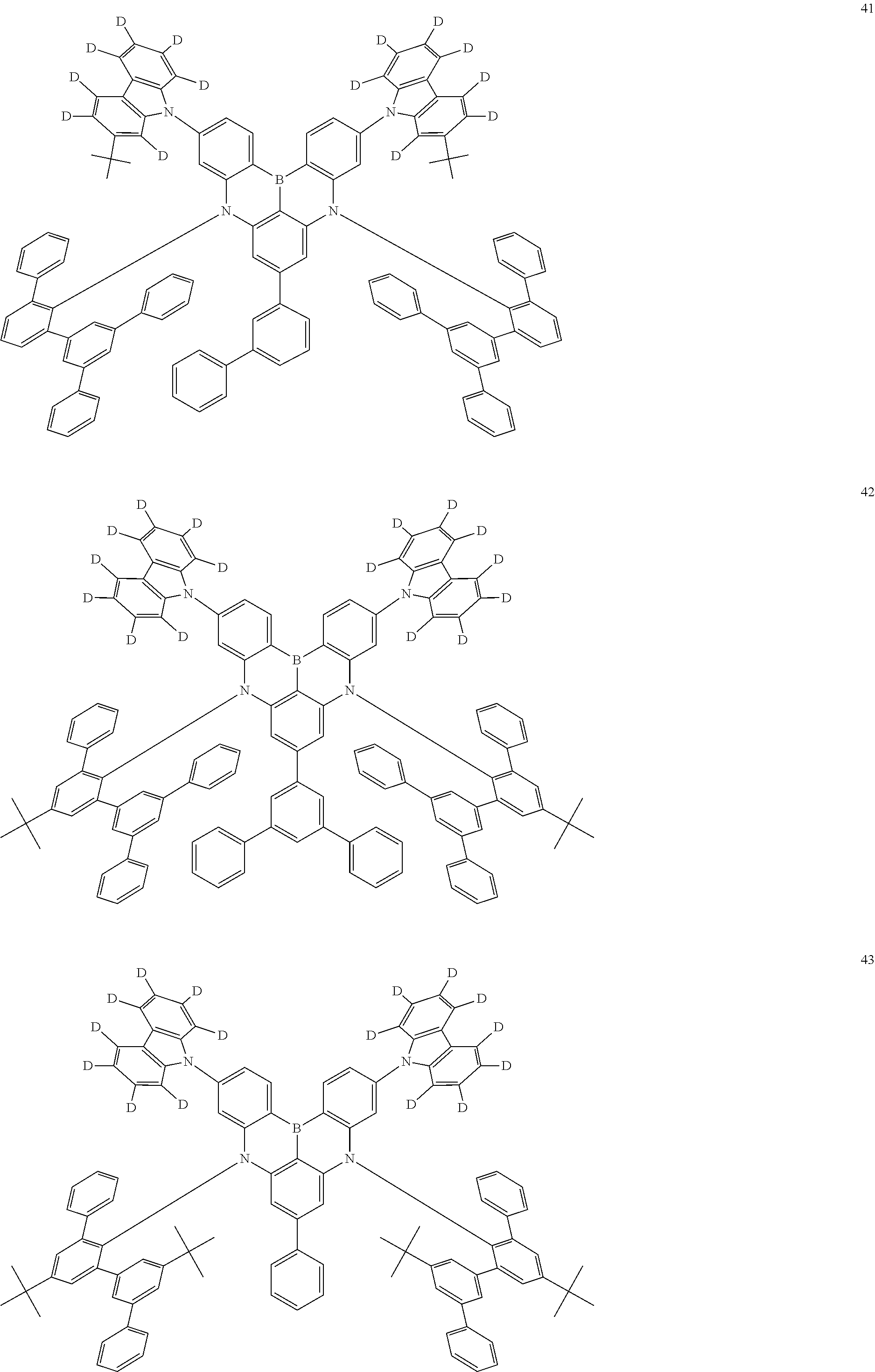

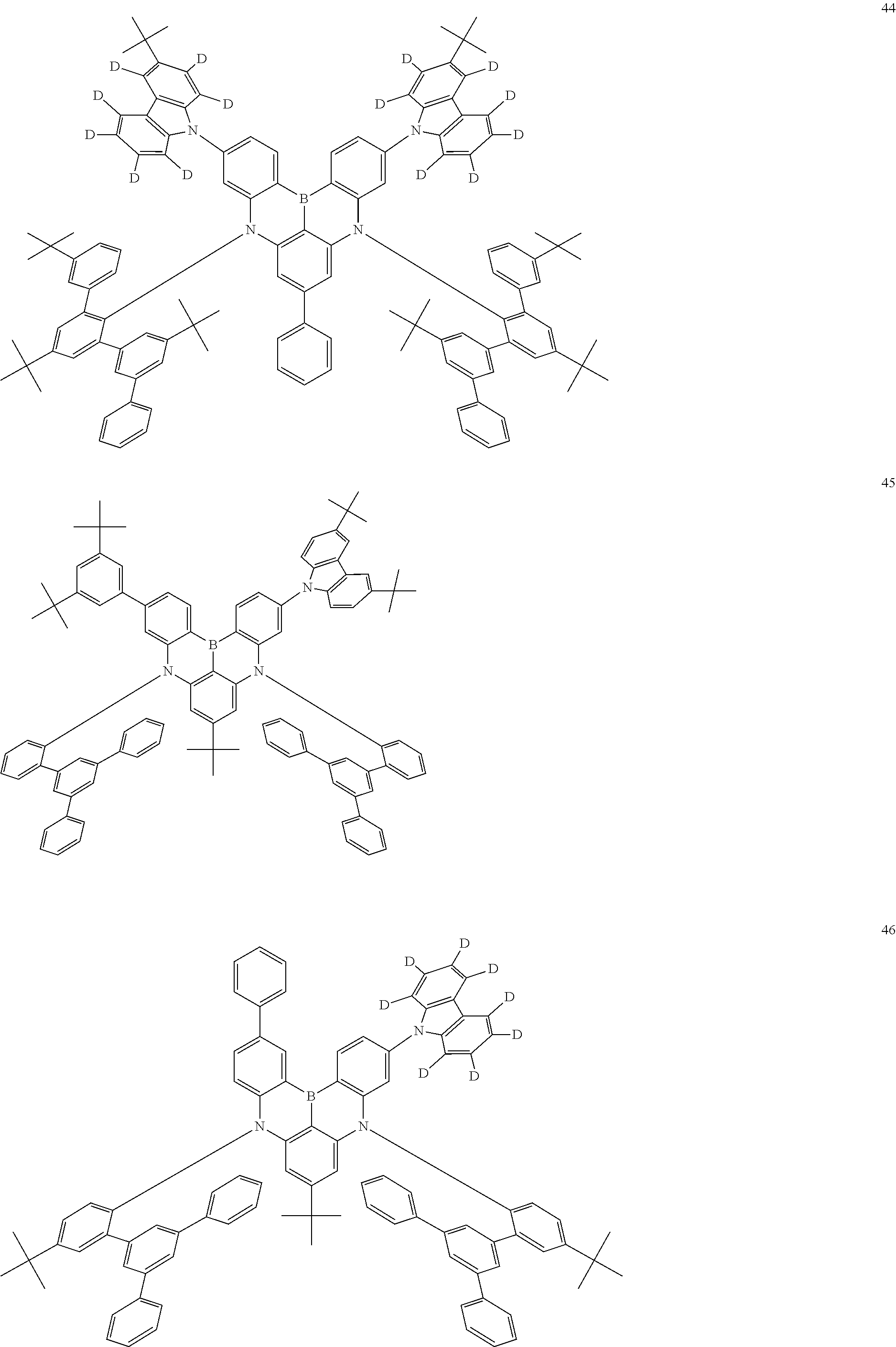

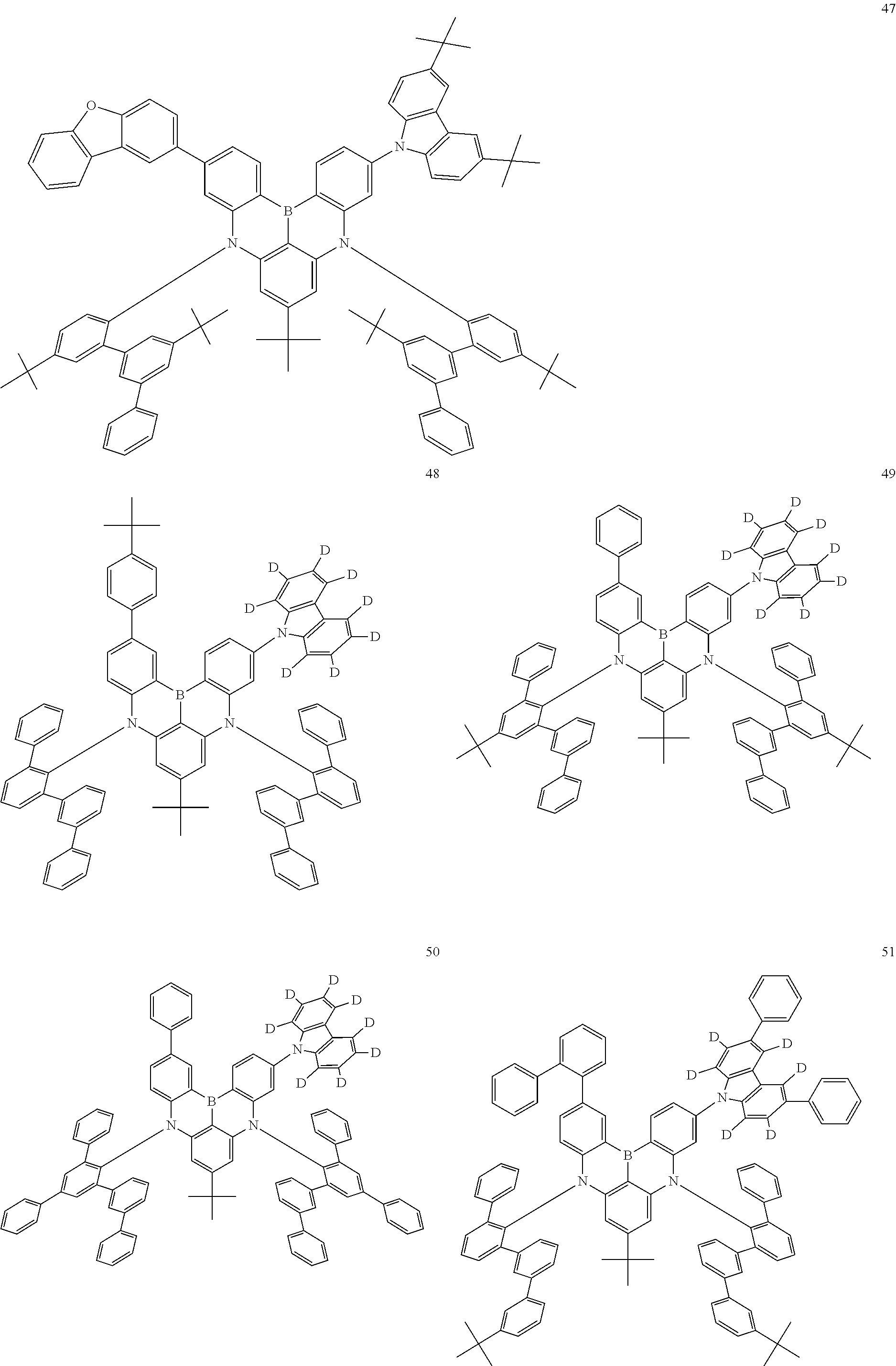

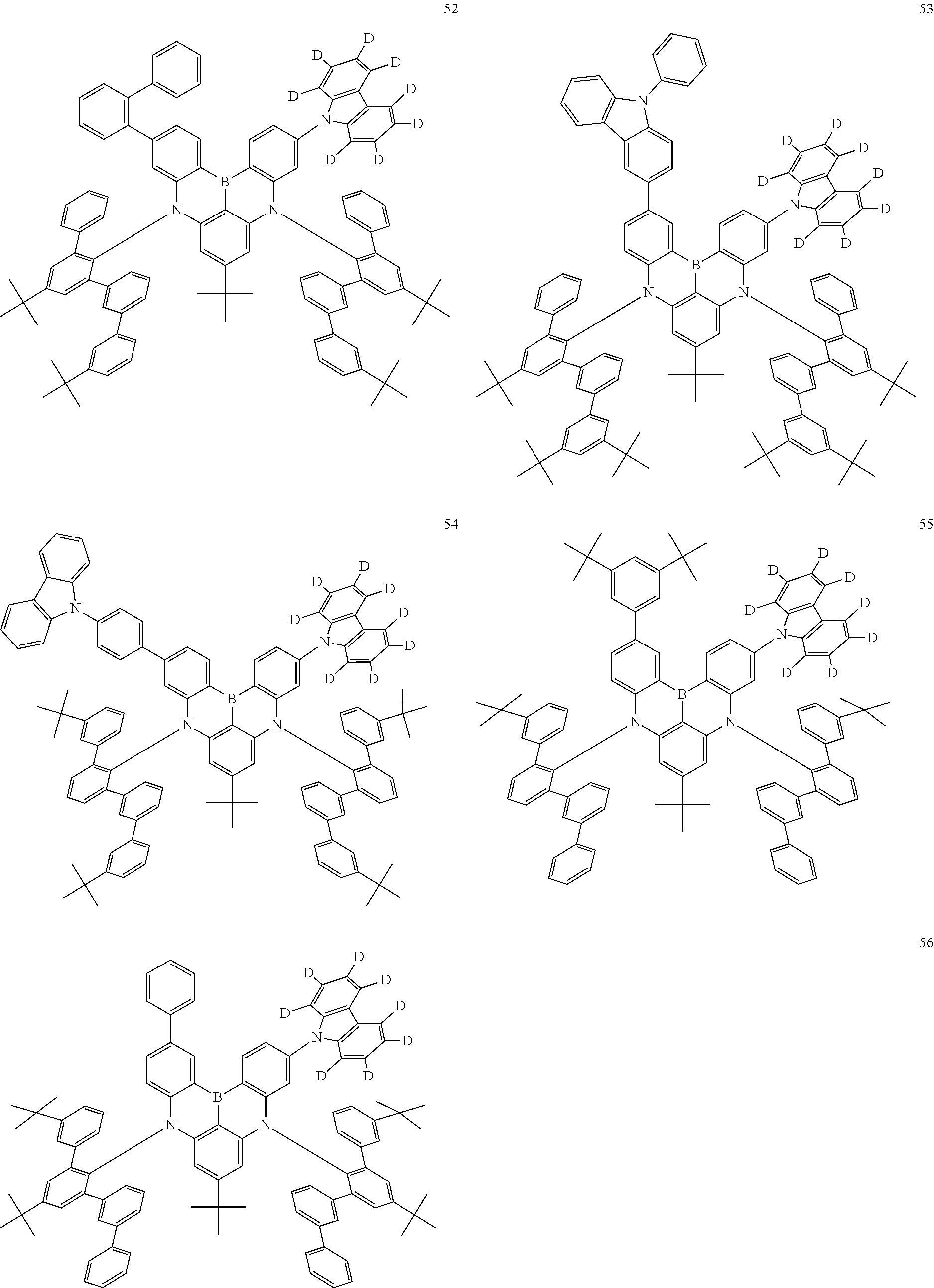

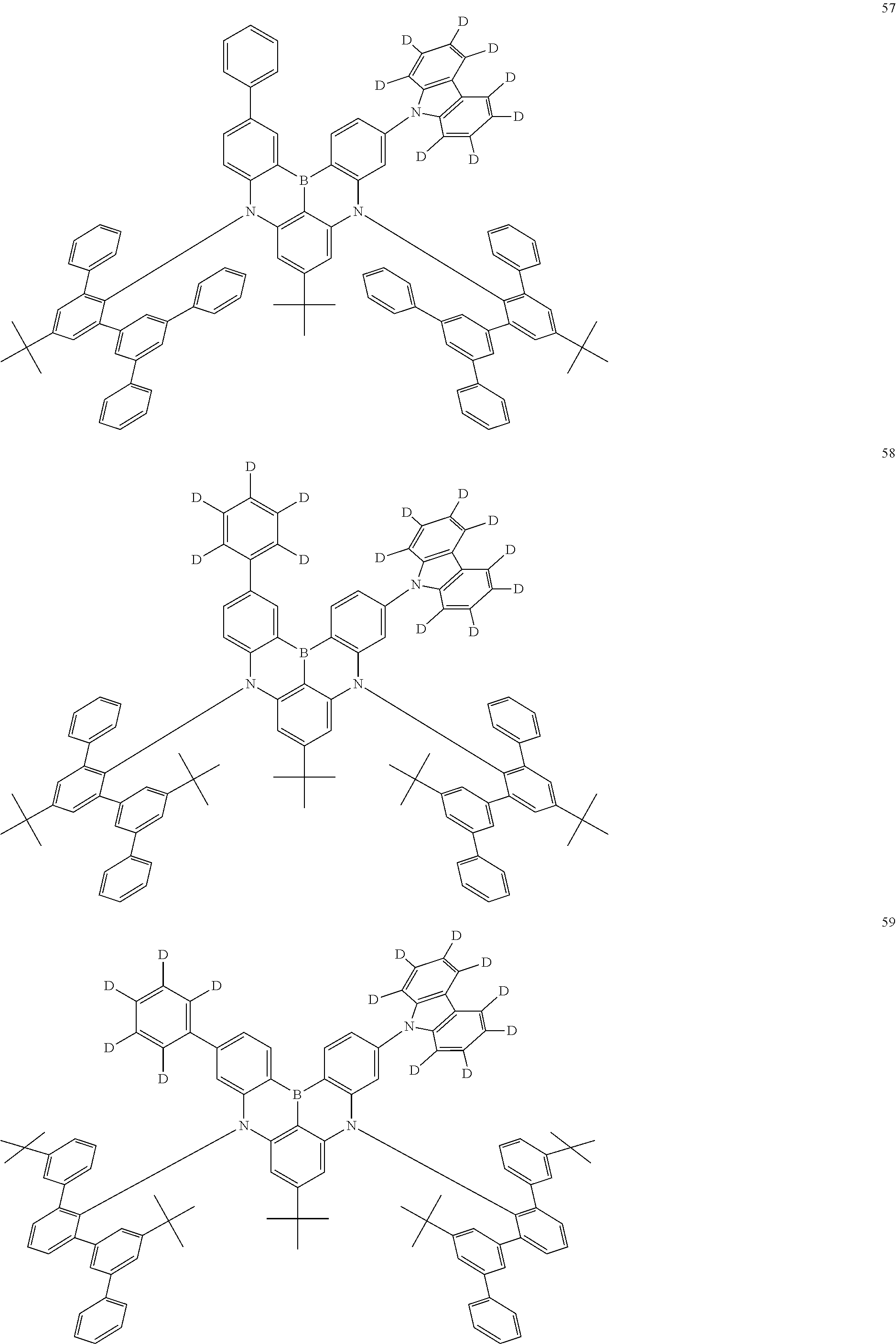

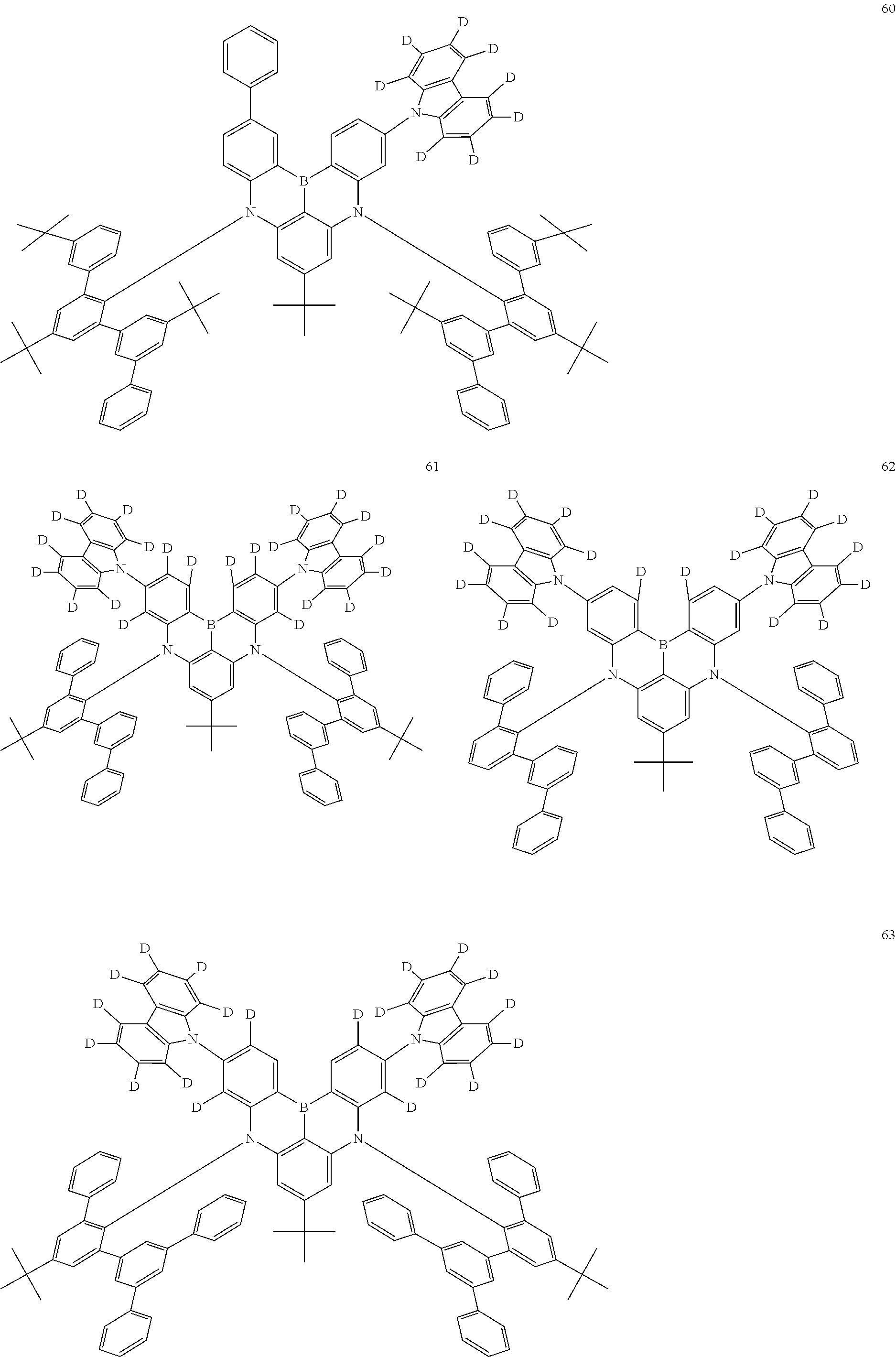

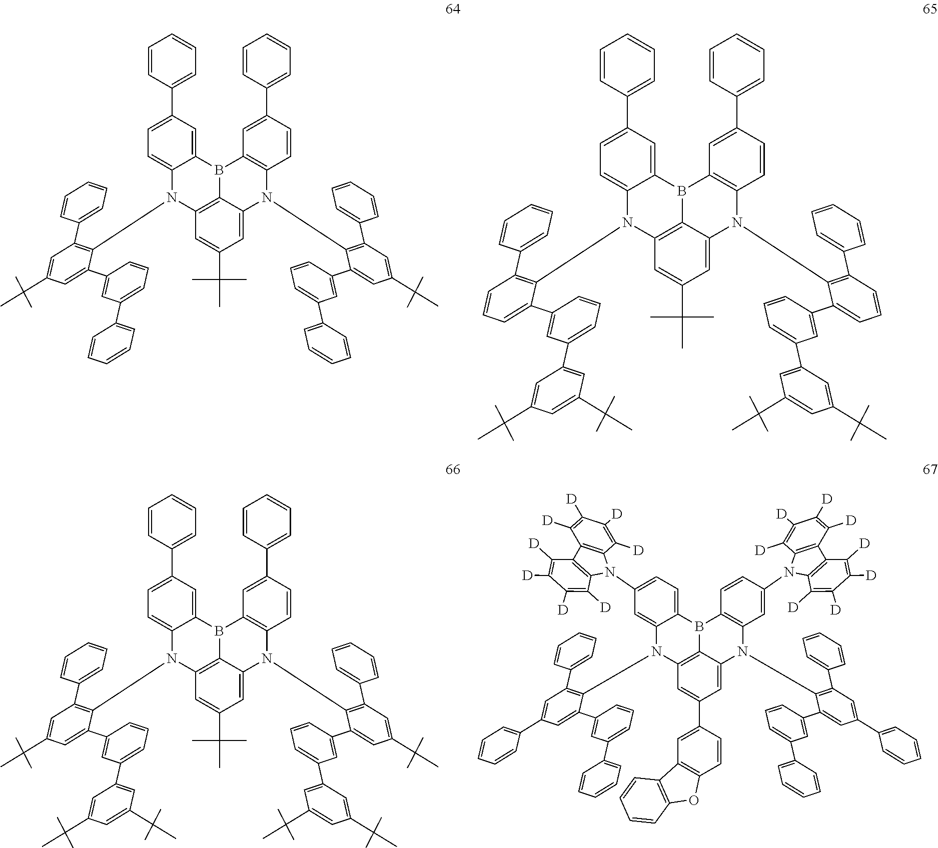

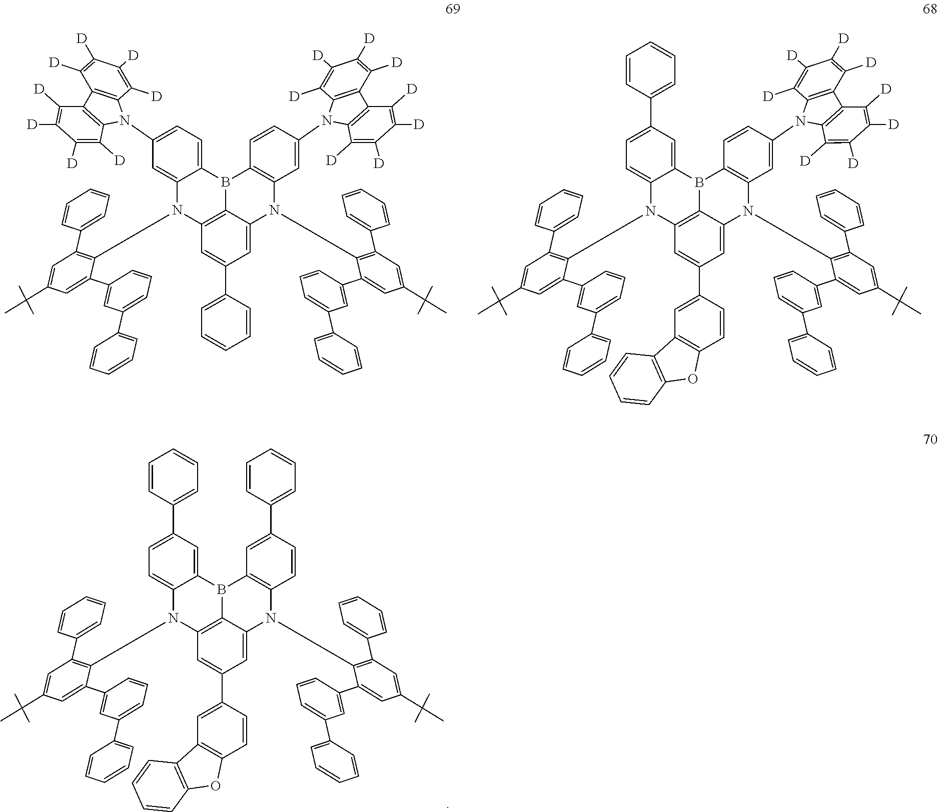

An emission layer EML may include a host and a dopant. For example, the emission layer EML may include two or more hosts, a sensitizer and a dopant. The emission layer EML may include a hole transport host and an electron transport host. The emission layer EML may include a phosphorescence sensitizer as the sensitizer.

The emission layer EML may include the fused polycyclic compound of an embodiment as the dopant. The emission layer EML including the fused polycyclic compound of an embodiment may emit thermally activated delayed fluorescence (TADF). The fused polycyclic compound of an embodiment may be a multiple resonance (MR) thermally activated delayed fluorescence dopant.

In the emission layer EML, the hole transport host and the electron transport host may form exciplex. In this case, the triplet energy of the exciplex formed by the hole transport host and the electron transport host may correspond to the difference between the lowest unoccupied molecular orbital (LUMO) energy level of the electron transport host and the highest occupied molecular orbital (HOMO) energy level of the hole transport host. For example, the absolute value of the triplet energy level (T1) of the exciplex formed by the hole transport host and the electron transport host may be about 2.4 eV to about 3.0 eV. In some embodiments, the triplet energy of the exciplex may be a value smaller than the energy gap of each host material. The exciplex may have a triplet energy of about 3.0 eV or less, which is the energy gap between the hole transport host and the electron transport host. However, these are illustrations, and an embodiment of the present disclosure is not limited thereto.

When the emission layer EML includes a hole transport host, an electron transport host, a sensitizer and a dopant, the hole transport host and the electron transport host may form exciplex, and energy transfer from the exciplex to the sensitizer, and from the sensitizer to the dopant may occur to emit light. However, this is only an illustration, and materials included in the emission layer EML are not limited thereto. Also, the hole transport host and the electron transport host may not form exciplex. When the hole transport host and the electron transport host do not form exciplex, energy transfer from the hole transport host and the electron transport host to the sensitizer, and from the sensitizer to the dopant may occur to emit light.

As described above, in an embodiment, the emission layer EML may include the fused polycyclic compound of an embodiment and at least one among second to fourth compounds. For example, the emission layer EML may include the fused polycyclic compound of an embodiment, the second compound, and the third compound. In an embodiment, the emission layer EML may include the fused polycyclic compound of an embodiment, the second compound, the third compound, and the fourth compound.

In an embodiment, the second compound may be represented by Formula HT-1. For example, the emission layer EML may include the second compound as a hole transport host material.

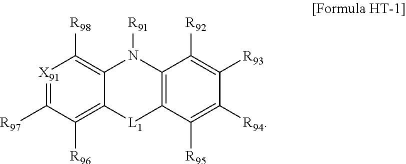

In Formula HT-1, L₁ may be a direct linkage, CR₉₉R₁₀₀, or SiR₁₀₁R₁₀₂. In Formula HT-1, X₉₁ may be N or CR₁₀₃. When L₁ is a direct linkage, and X₉₁ is CR₁₀₃, the second compound represented by Formula HT-1 may include a carbazole group.

R₉₁ to R₁₀₃ may each independently be a hydrogen atom, a deuterium atom, a cyano group, a substituted or unsubstituted silyl group, a substituted or unsubstituted oxy group, a substituted or unsubstituted alkyl group of 1 to 60 carbon atoms, a substituted or unsubstituted aryl group of 6 to 60 ring-forming carbon atoms, or a substituted or unsubstituted heteroaryl group of 2 to 60 ring-forming carbon atoms, and/or combined with an adjacent group (e.g., from each other) to form a ring. For example, R₉₁ may be a substituted phenyl group, an unsubstituted dibenzofuran group, or a substituted fluorenyl group. Any one among R₉₂ to R₉₈ may be a substituted or unsubstituted carbazole group. R₉₄ and R₉₅ may be combined with each other to form a ring. However, these are only illustrations, and an embodiment of the present disclosure is not limited thereto.

The second compound may be represented by any one among the compounds in Compound Group 2. In Compound Group 2, D is a deuterium atom, and Ph is a phenyl group.

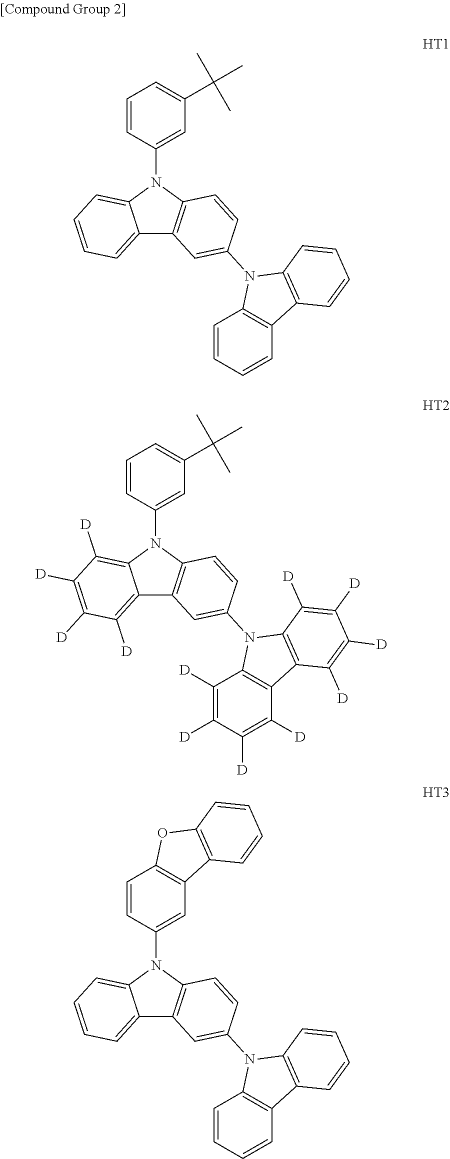

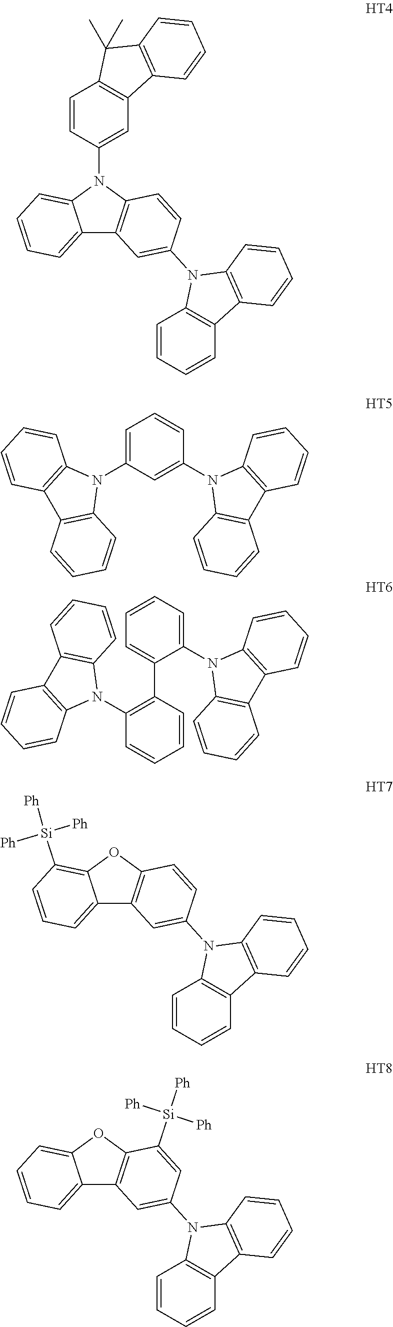

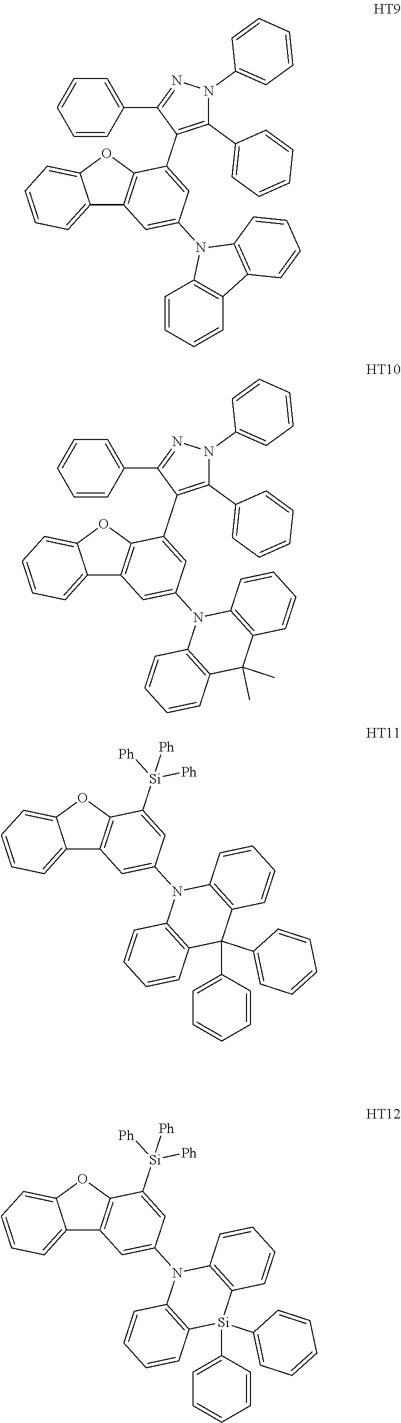

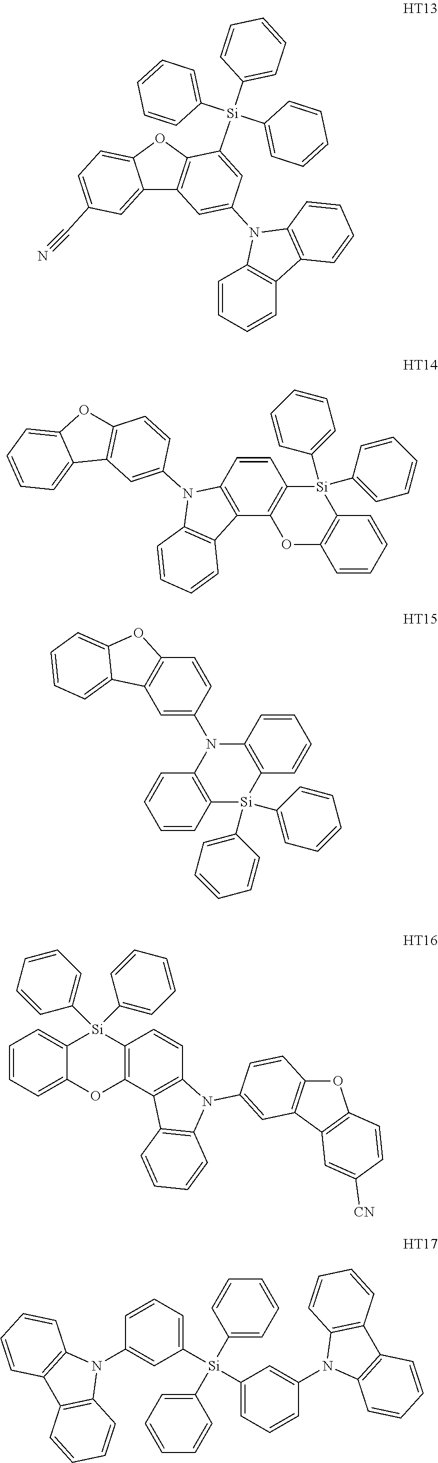 [SMILES: N#Cc1ccc2oc3c([Si](c4ccccc4)(c4ccccc4)c4ccccc4)cc(-n4c5ccccc5c5ccccc54)cc3c2c1 ; c1ccc([Si]2(c3ccccc3)c3ccccc3Oc3c2ccc2c3c3ccccc3n2-c2ccc3oc4ccccc4c3c2)cc1 ; c1ccc([Si]2(c3ccccc3)c3ccccc3N(c3ccc4oc5ccccc5c4c3)c3ccccc32)cc1 ; N#Cc1ccc2oc3ccc(-n4c5ccccc5c5c6c(ccc54)[Si](c4ccccc4)(c4ccccc4)c4ccccc4O6)cc3c2c1 ; c1ccc([Si](c2ccccc2)(c2cccc(-n3c4ccccc4c4ccccc43)c2)c2cccc(-n3c4ccccc4c4ccccc43)c2)cc1]

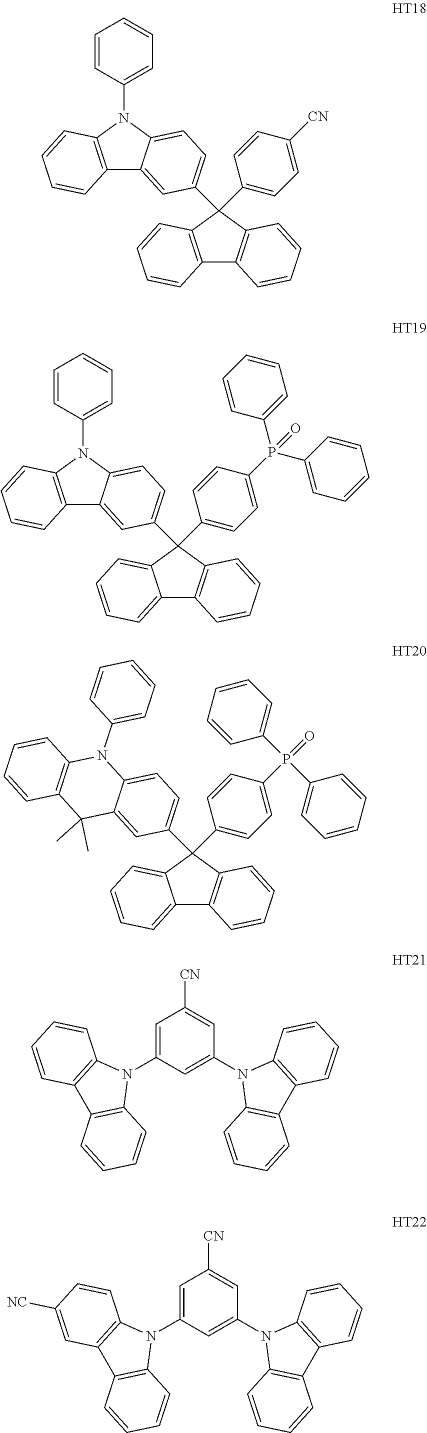

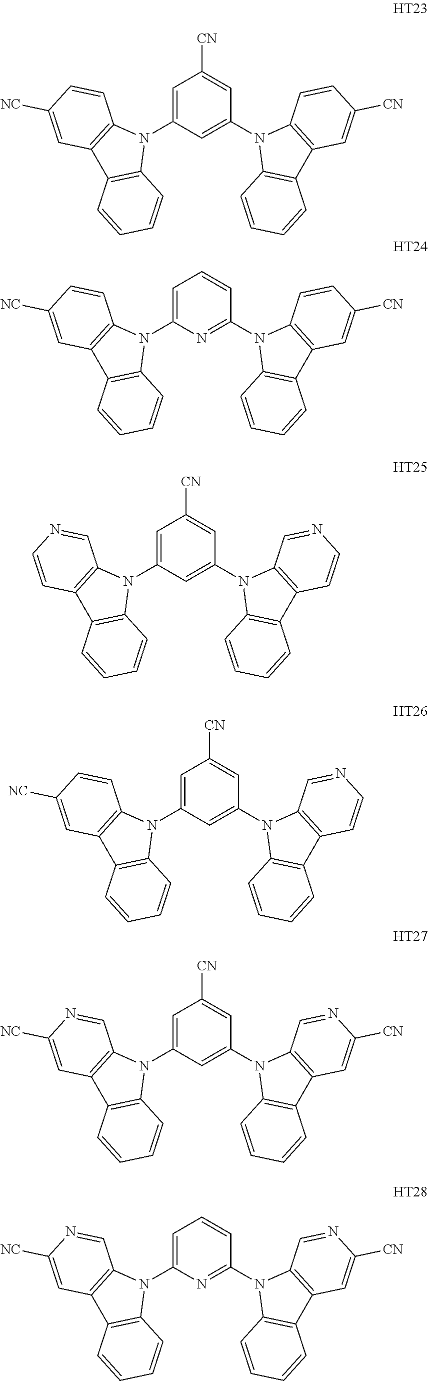 [SMILES: N#Cc1cc(-n2c3ccccc3c3cc(C#N)ccc32)cc(-n2c3ccccc3c3cc(C#N)ccc32)c1 ; N#Cc1ccc2c(c1)c1ccccc1n2-c1cccc(-n2c3ccccc3c3cc(C#N)ccc32)n1 ; N#Cc1cc(-n2c3ccccc3c3ccncc32)cc(-n2c3ccccc3c3ccncc32)c1 ; N#Cc1cc(-n2c3ccccc3c3cc(C#N)ccc32)cc(-n2c3ccccc3c3ccncc32)c1 ; N#Cc1cc(-n2c3ccccc3c3cc(C#N)ncc32)cc(-n2c3ccccc3c3cc(C#N)ncc32)c1 ; N#Cc1cc2c3ccccc3n(-c3cccc(-n4c5ccccc5c5cc(C#N)ncc54)n3)c2cn1]

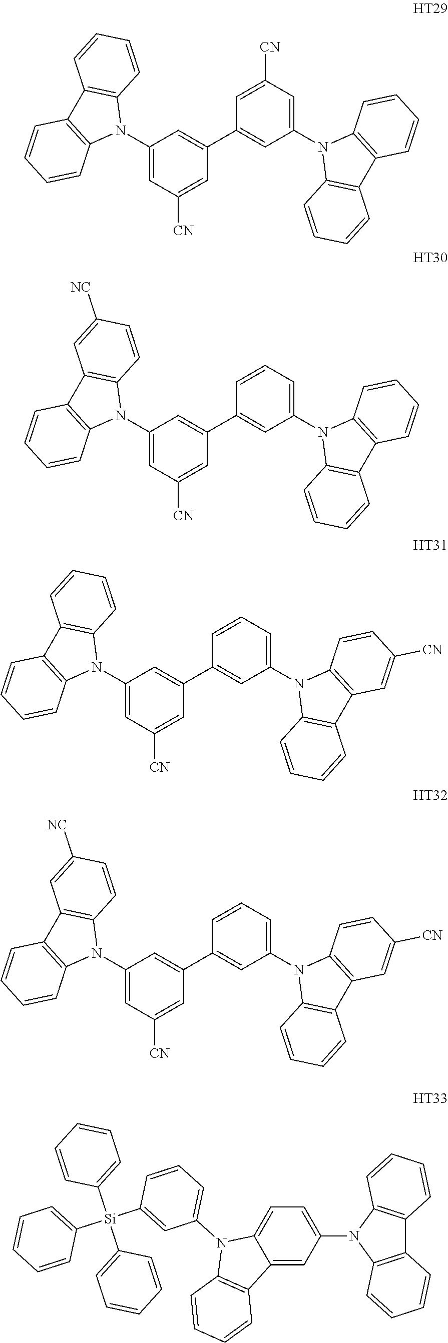 [SMILES: N#Cc1cc(-c2cc(C#N)cc(-n3c4ccccc4c4ccccc43)c2)cc(-n2c3ccccc3c3ccccc32)c1 ; N#Cc1cc(-c2cccc(-n3c4ccccc4c4ccccc43)c2)cc(-n2c3ccccc3c3cc(C#N)ccc32)c1 ; N#Cc1cc(-c2cccc(-n3c4ccccc4c4cc(C#N)ccc43)c2)cc(-n2c3ccccc3c3ccccc32)c1 ; N#Cc1cc(-c2cccc(-n3c4ccccc4c4cc(C#N)ccc43)c2)cc(-n2c3ccccc3c3cc(C#N)ccc32)c1 ; c1ccc([Si](c2ccccc2)(c2ccccc2)c2cccc(-n3c4ccccc4c4cc(-n5c6ccccc6c6ccccc65)ccc43)c2)cc1]

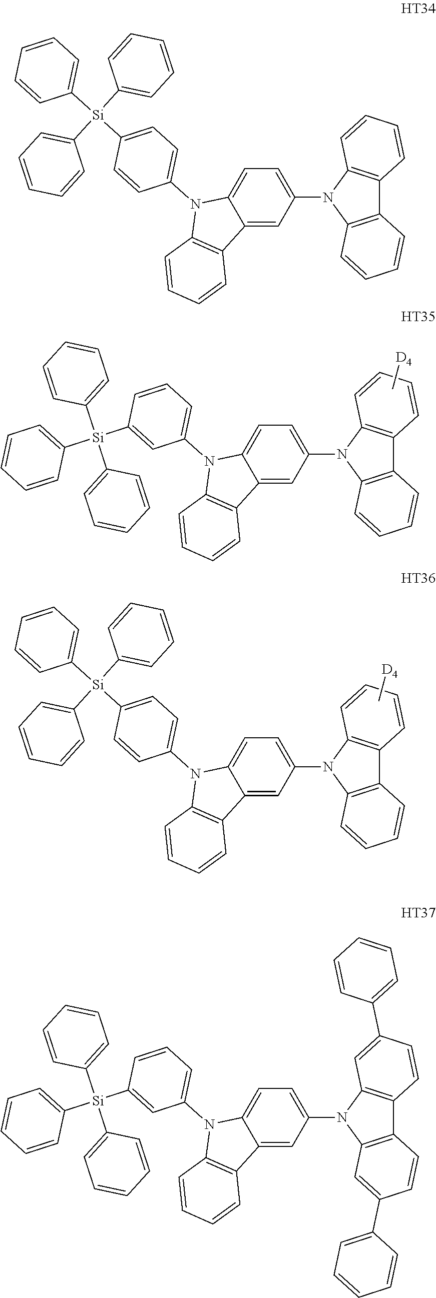

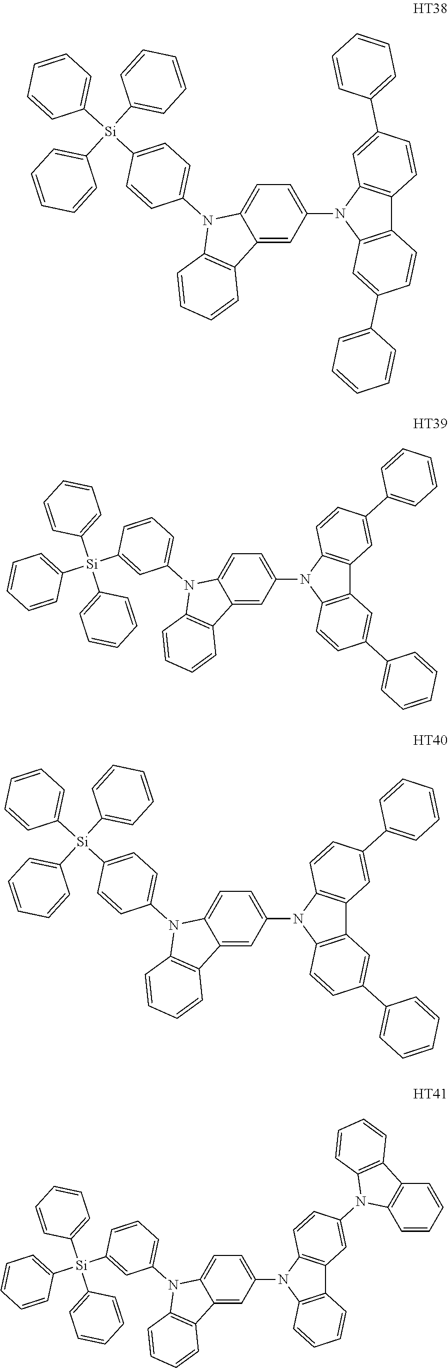 [SMILES: c1ccc(-c2ccc3c4ccc(-c5ccccc5)cc4n(-c4ccc5c(c4)c4ccccc4n5-c4ccc([Si](c5ccccc5)(c5ccccc5)c5ccccc5)cc4)c3c2)cc1 ; c1ccc(-c2ccc3c(c2)c2cc(-c4ccccc4)ccc2n3-c2ccc3c(c2)c2ccccc2n3-c2cccc([Si](c3ccccc3)(c3ccccc3)c3ccccc3)c2)cc1 ; c1ccc(-c2ccc3c(c2)c2cc(-c4ccccc4)ccc2n3-c2ccc3c(c2)c2ccccc2n3-c2ccc([Si](c3ccccc3)(c3ccccc3)c3ccccc3)cc2)cc1 ; c1ccc([Si](c2ccccc2)(c2ccccc2)c2cccc(-n3c4ccccc4c4cc(-n5c6ccccc6c6cc(-n7c8ccccc8c8ccccc87)ccc65)ccc43)c2)cc1]

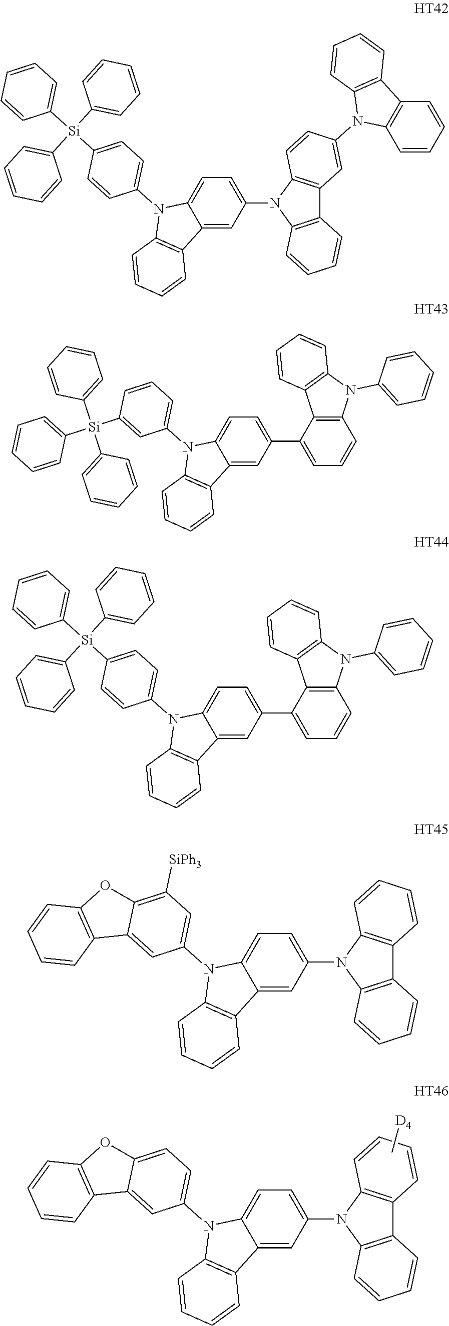

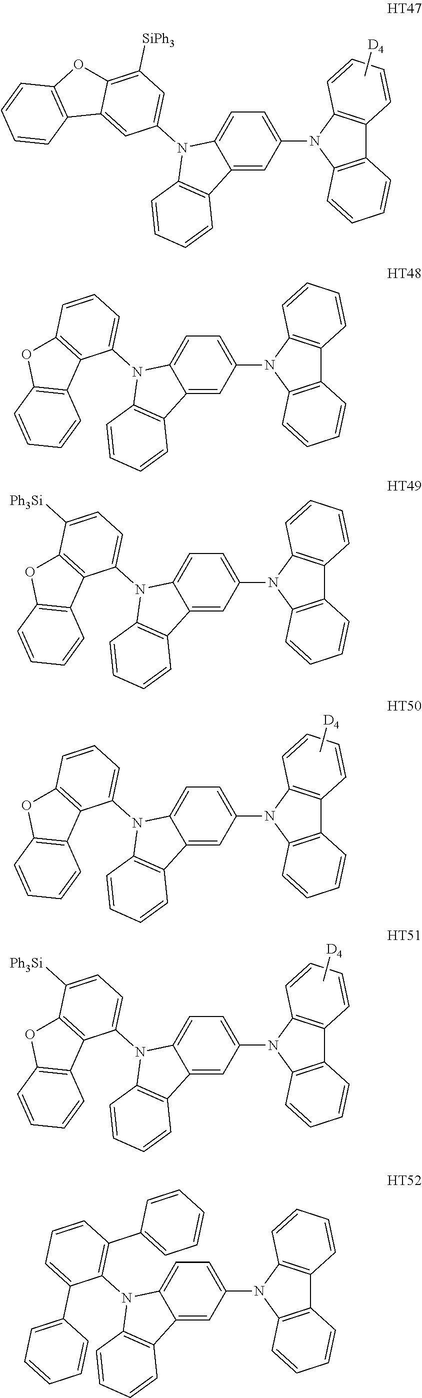

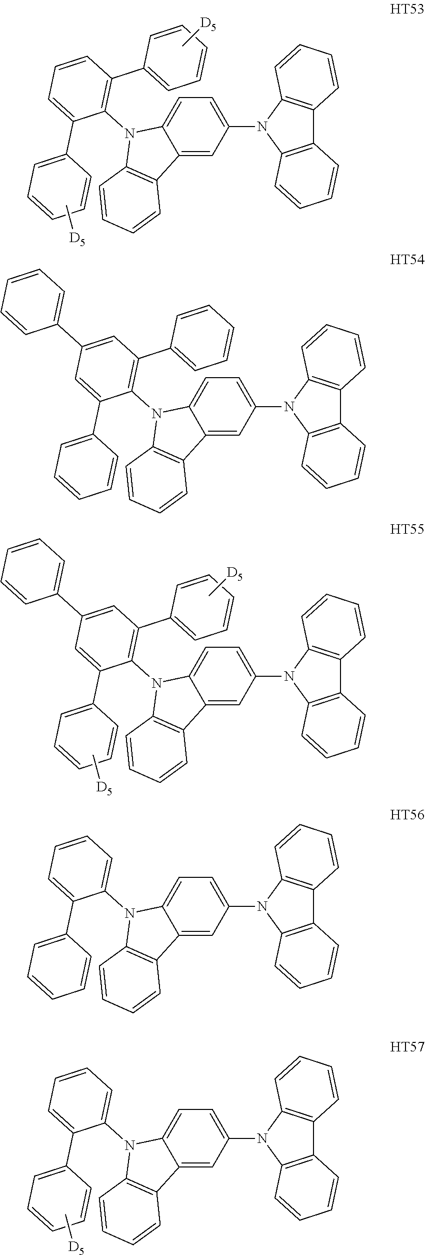

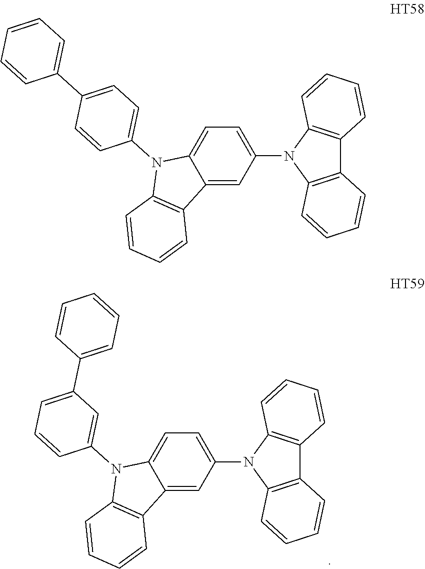 [SMILES: c1ccc(-c2ccc(-n3c4ccccc4c4cc(-n5c6ccccc6c6ccccc65)ccc43)cc2)cc1 ; c1ccc(-c2cccc(-n3c4ccccc4c4cc(-n5c6ccccc6c6ccccc65)ccc43)c2)cc1]

In an embodiment, the third compound may be represented by Formula ET-1. For example, the emission layer EML may include the third compound as an electron transport host material.

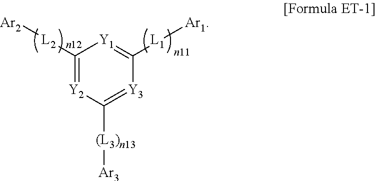

In Formula ET-1, at least one among Y₁ to Y₃ may be N, and any remainder thereof may each independently be CR₈₁. R₈₁ may be a hydrogen atom, a deuterium atom, a substituted or unsubstituted alkyl group of 1 to 20 carbon atoms, a substituted or unsubstituted aryl group of 6 to 60 ring-forming carbon atoms, or a substituted or unsubstituted heteroaryl group of 2 to 60 ring-forming carbon atoms.

When any one among Y₁ to Y₃ is N, the third compound represented by Formula ET-1 may include a pyridine group. When any two among Y₁ to Y₃ are N, the third compound represented by Formula ET-1 may include a pyrimidine group. When Y₁ to Y₃ are all N, the third compound represented by Formula ET-1 may include a triazine group.

n11 to n13 may each independently be an integer of 0 to 10. L₁ to L₃ may each independently be a direct linkage, a substituted or unsubstituted arylene group of 6 to 30 ring-forming carbon atoms, or a substituted or unsubstituted heteroarylene group of 2 to 30 ring-forming carbon atoms. When n11 to n13 are integers of 2 or more, L¹ to L₃ may each independently be a substituted or unsubstituted arylene group of 6 to 30 ring-forming carbon atoms, or a substituted or unsubstituted heteroarylene group of 2 to 30 ring-forming carbon atoms.

Ar₁ to Ar₃ may each independently be a hydrogen atom, a deuterium atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms. For example, Ar₁ to Ar₃ may be substituted or unsubstituted phenyl groups or substituted or unsubstituted carbazole groups. However, these are illustrations, and an embodiment of the present disclosure is not limited thereto.

The third compound may be represented by any one among the compounds in Compound Group 3. The light emitting element ED of an embodiment may include any one among the compounds in Compound Group 3. In Compound Group 3, D is a deuterium atom, and Ph is a phenyl group.

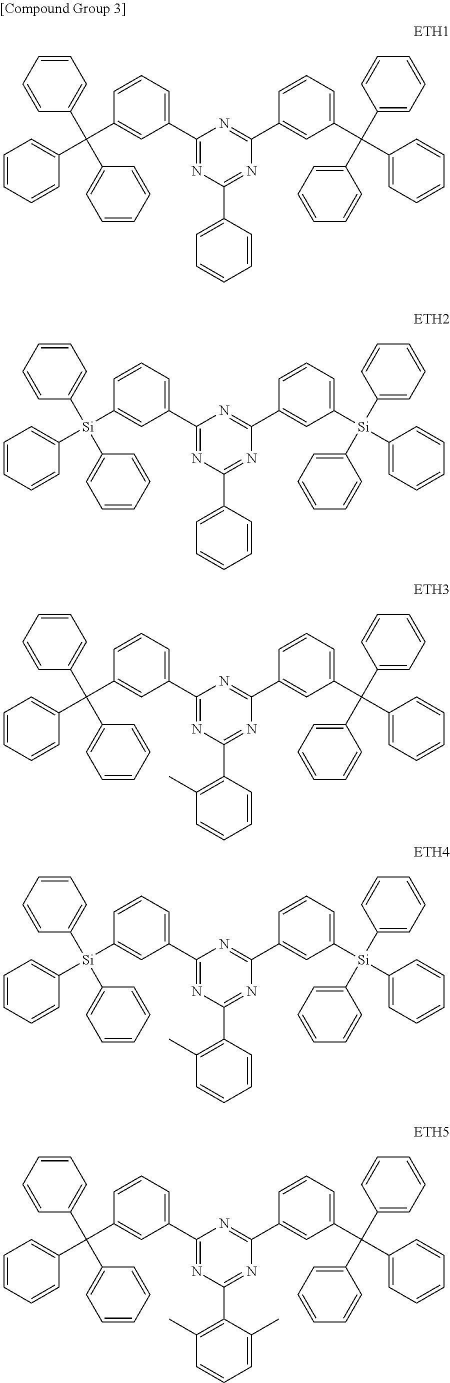

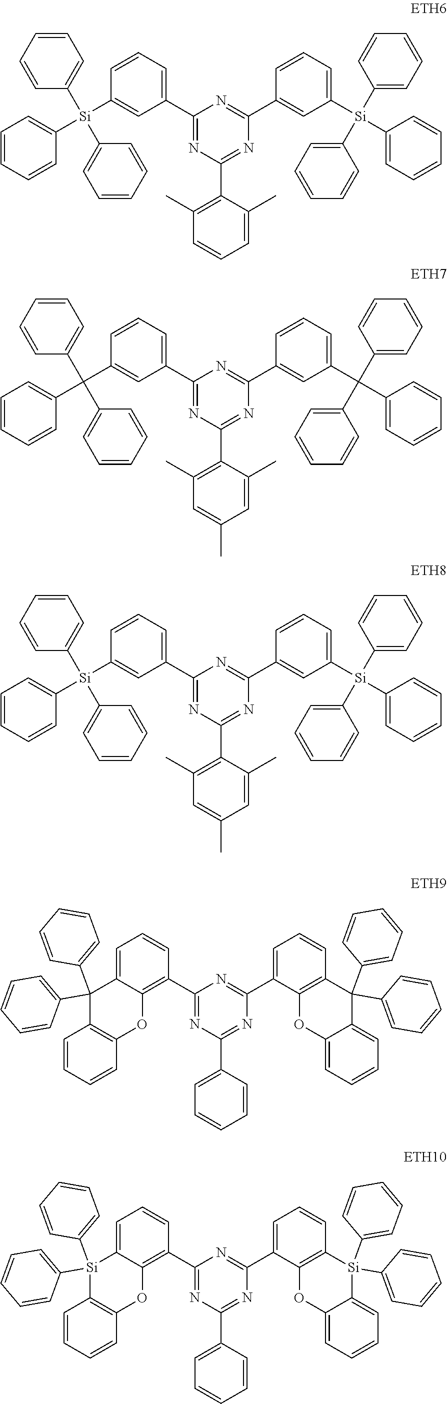

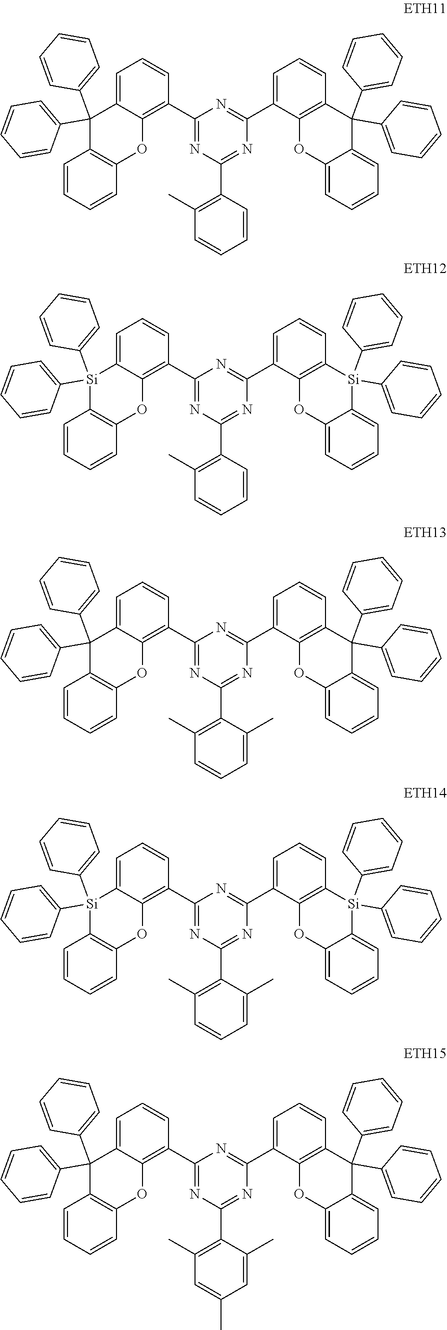

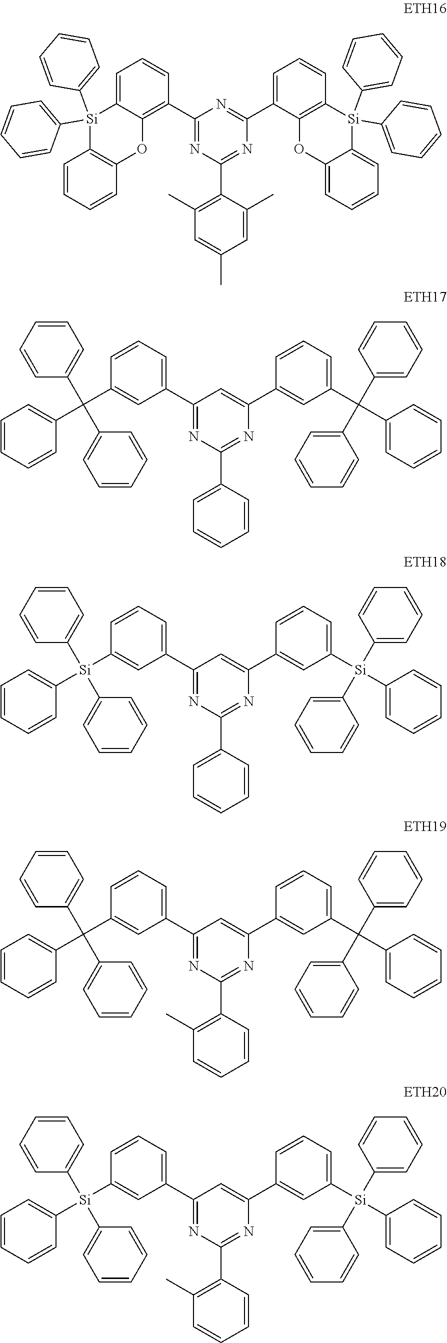

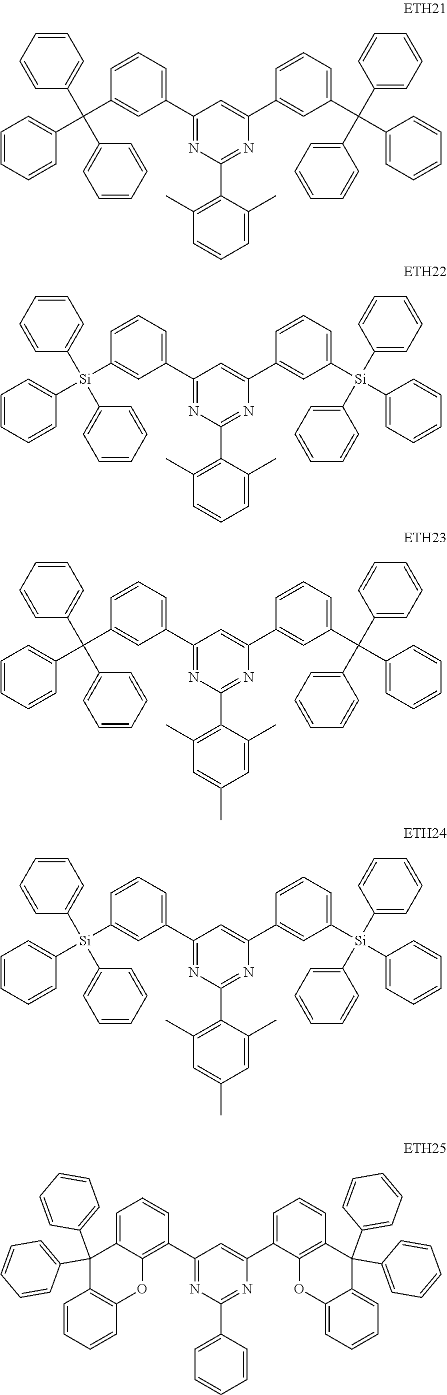

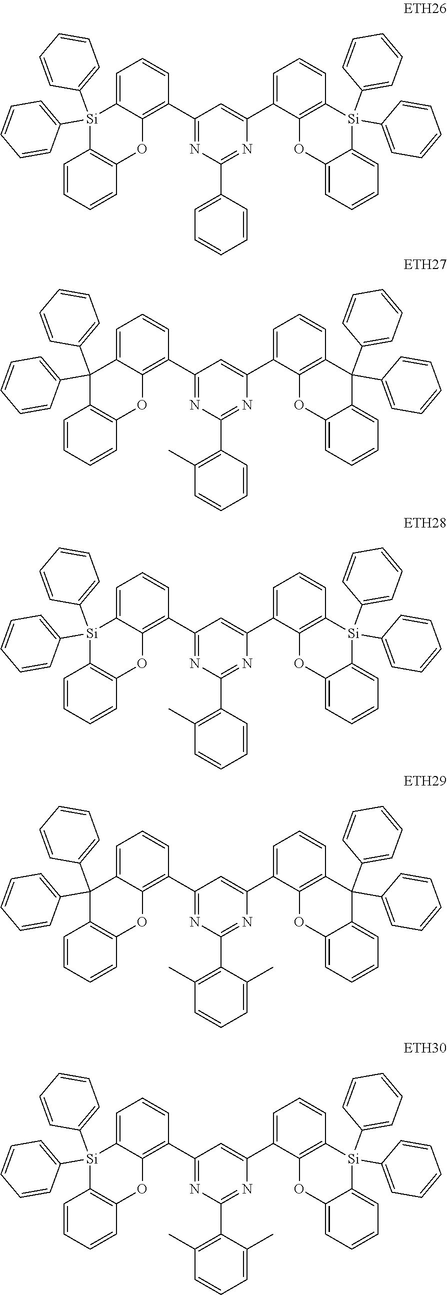

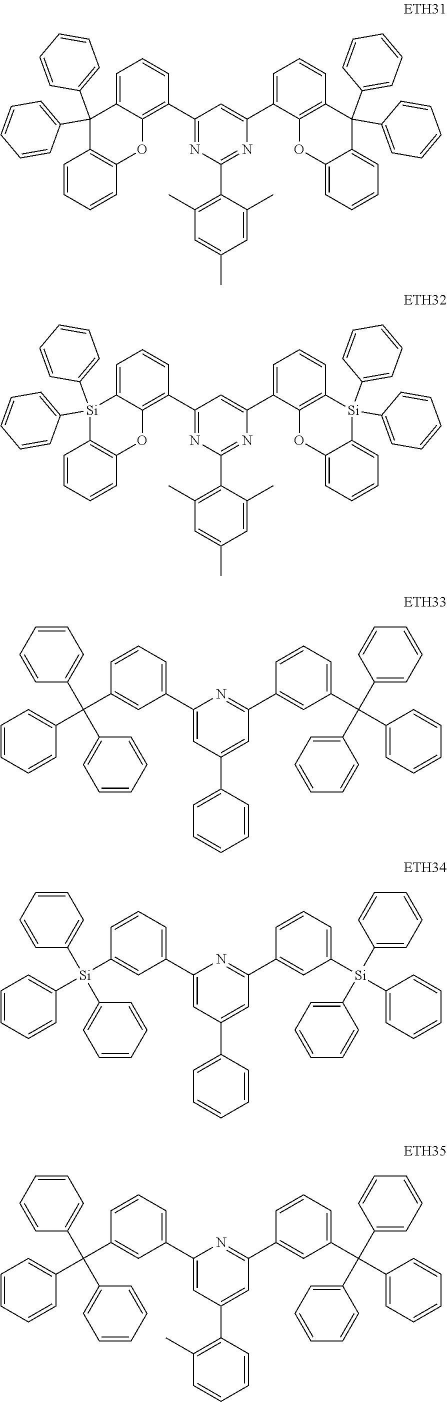

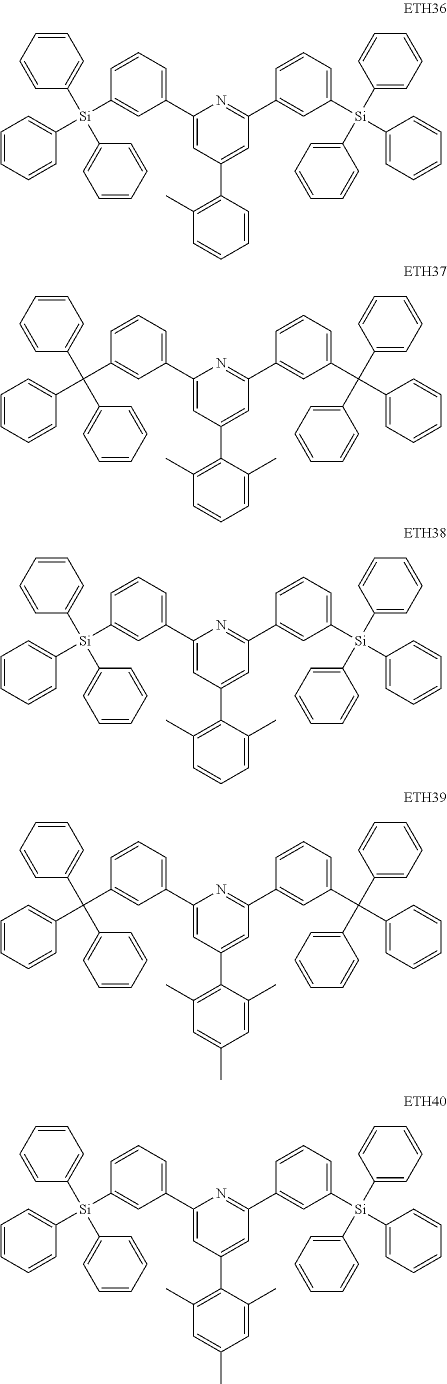

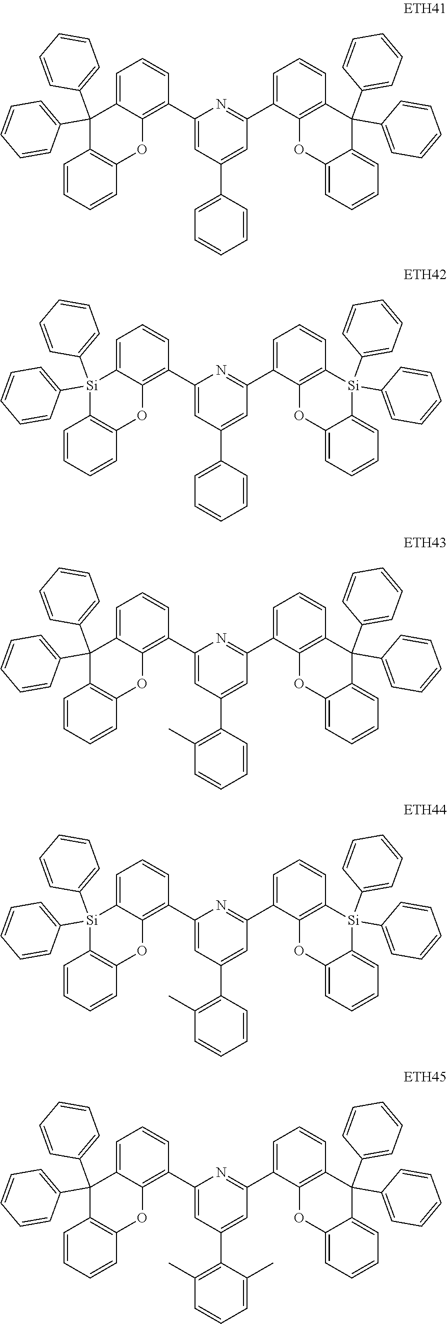

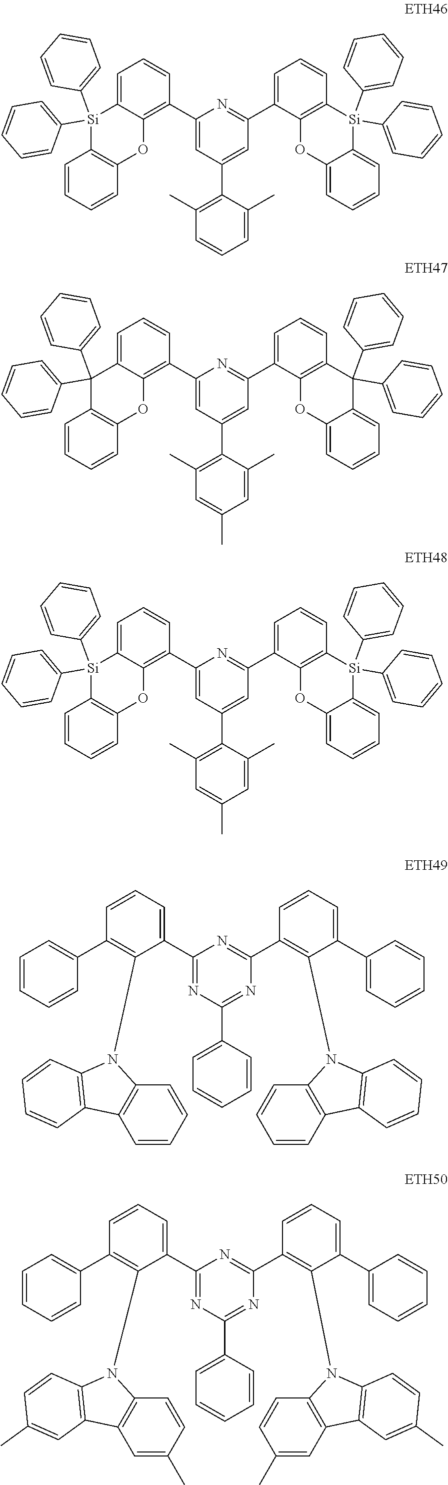

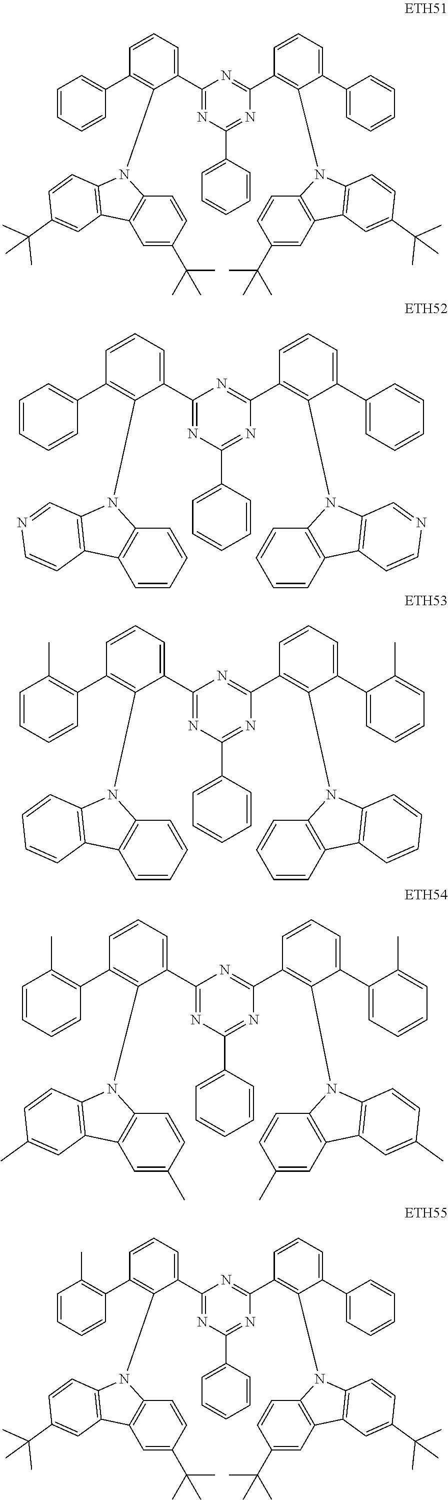

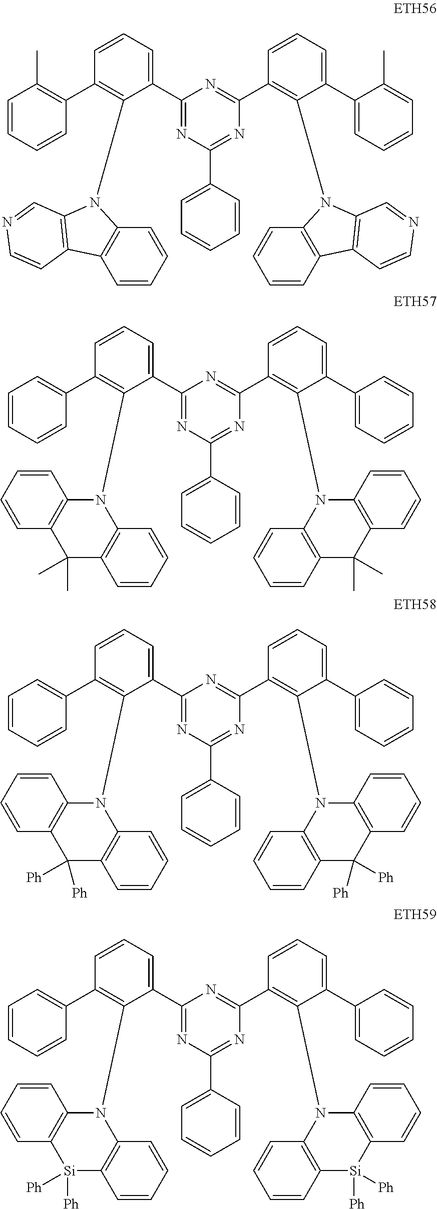

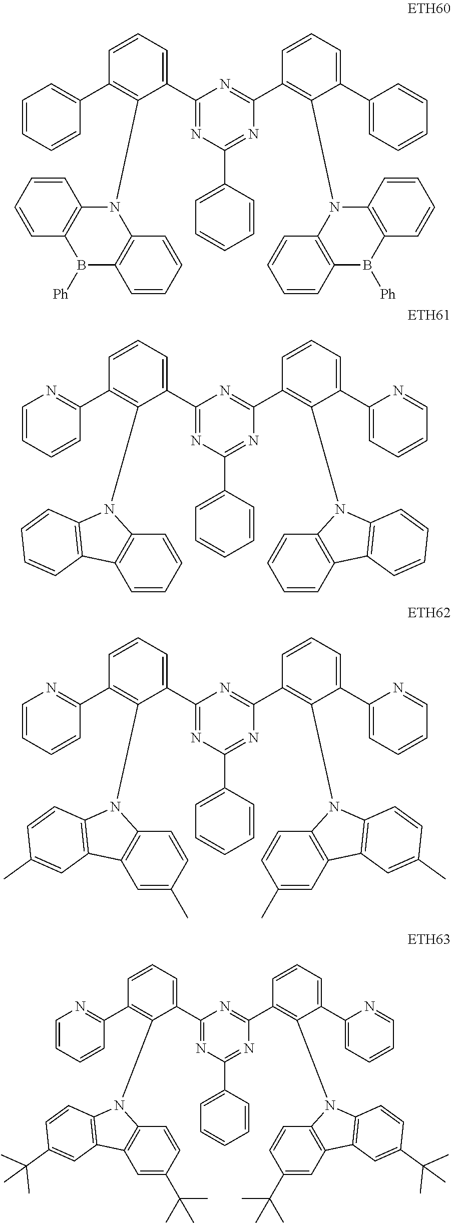

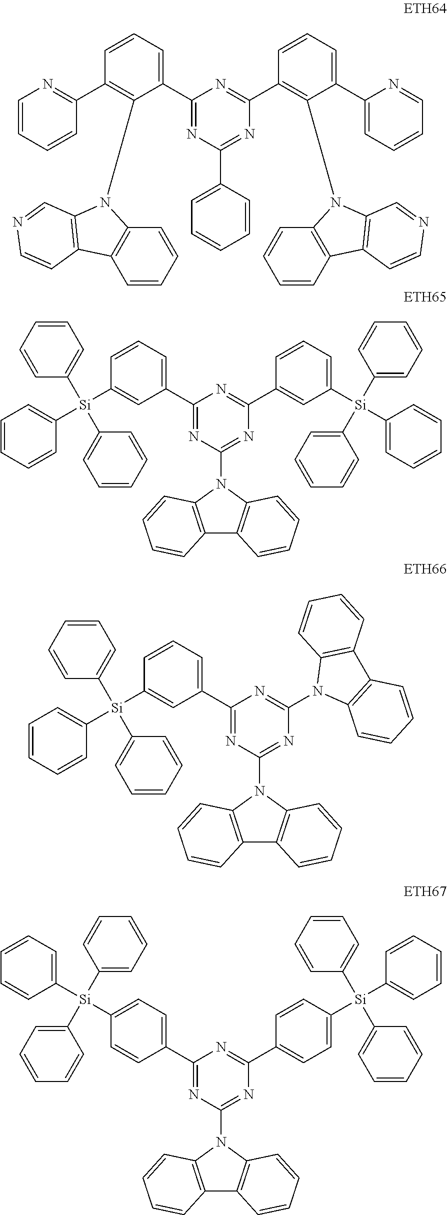 [SMILES: c1ccc(-c2nc(-c3cccc(-c4ccccn4)c3-n3c4ccccc4c4ccncc43)nc(-c3cccc(-c4ccccn4)c3-n3c4ccccc4c4ccncc43)n2)cc1 ; c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5ccccc54)n3)c2)cc1 ; c1ccc([Si](c2ccccc2)(c2ccccc2)c2cccc(-c3nc(-n4c5ccccc5c5ccccc54)nc(-n4c5ccccc5c5ccccc54)n3)c2)cc1 ; c1ccc([Si](c2ccccc2)(c2ccccc2)c2ccc(-c3nc(-c4ccc([Si](c5ccccc5)(c5ccccc5)c5ccccc5)cc4)nc(-n4c5ccccc5c5ccccc54)n3)cc2)cc1]

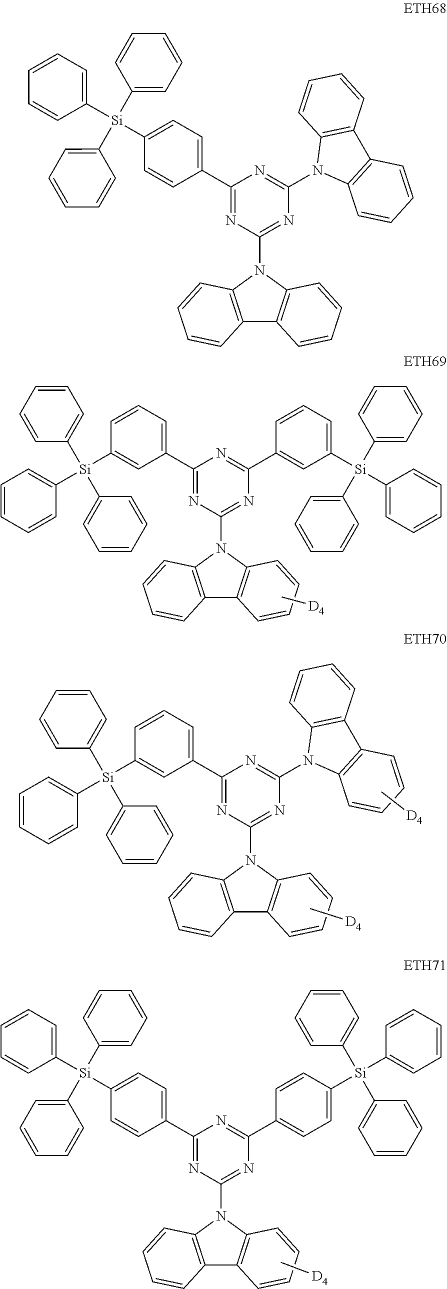

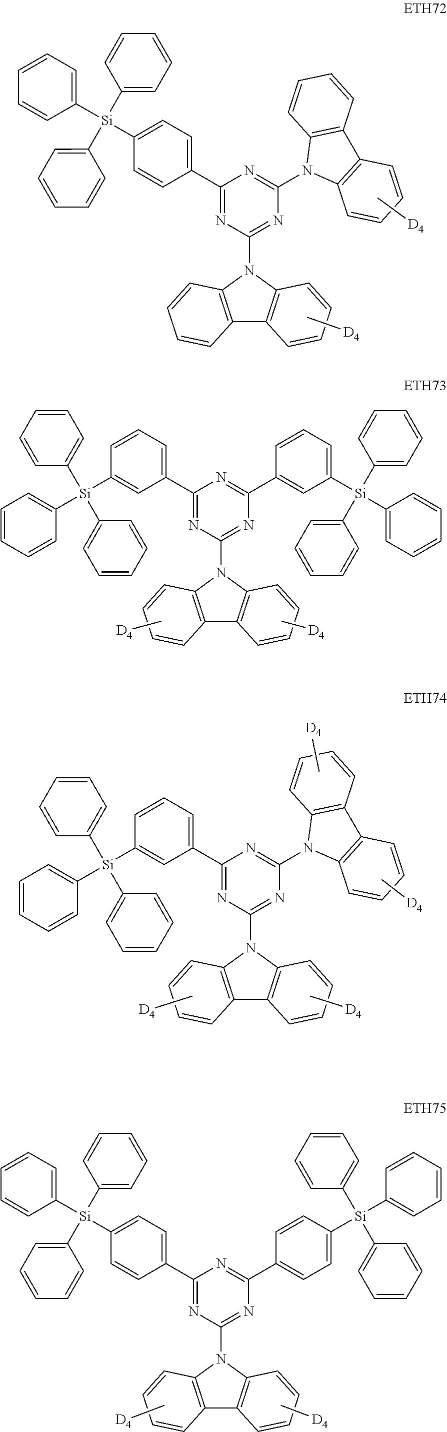

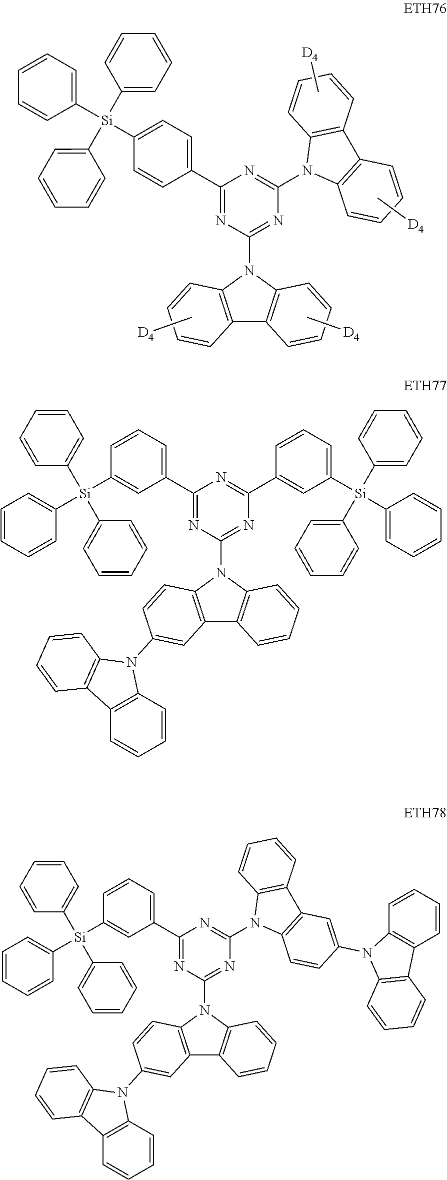

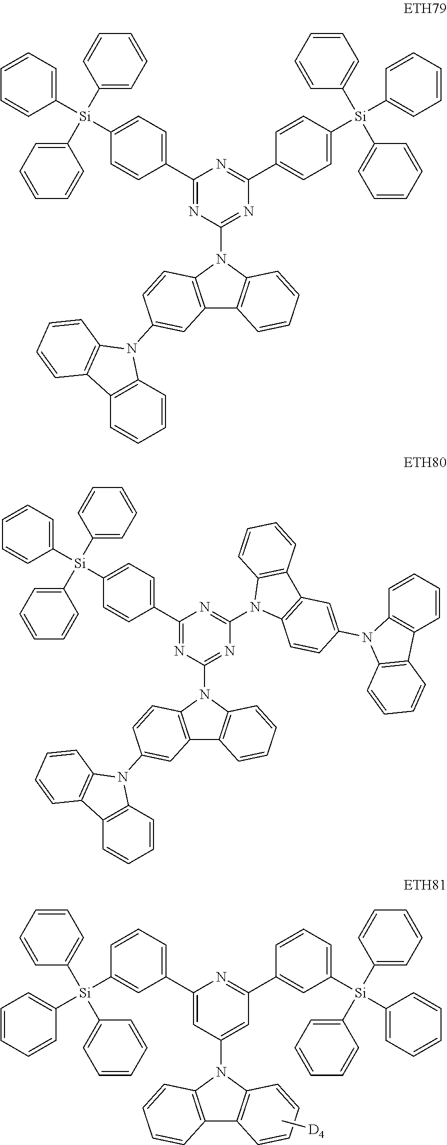

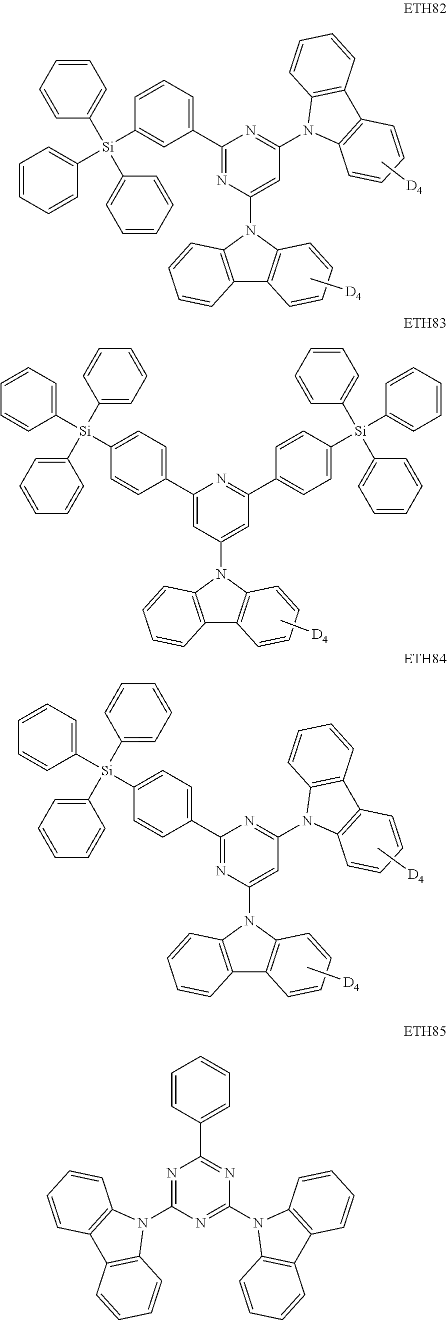

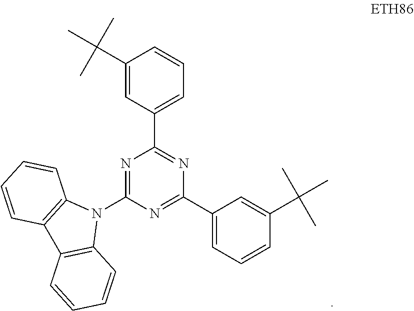 [SMILES: CC(C)(C)c1cccc(-c2nc(-c3cccc(C(C)(C)C)c3)nc(-n3c4ccccc4c4ccccc43)n2)c1]

In an embodiment, the fourth compound may be represented by Formula M-b. The fourth compound may be utilized as a phosphorescence dopant material or a sensitizer. For example, the emission layer EML may include the fourth compound as a sensitizer.

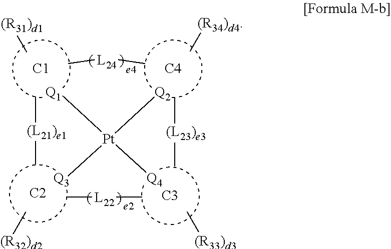

In Formula M-b, Q₁ to 04 may each independently be C or N. C1 to 04 may each independently be a substituted or unsubstituted hydrocarbon ring of 5 to 30 ring-forming carbon atoms, or a substituted or unsubstituted heterocycle of 2 to 30 ring-forming carbon atoms.

e1 to e4 may each independently be 0 or 1. L₂₁ to L₂₄ may each independently be a direct linkage,

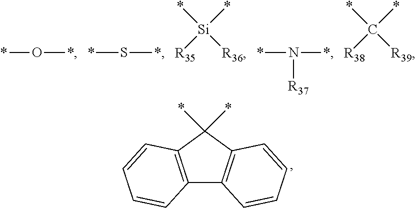

a substituted or unsubstituted divalent alkyl group of 1 to 20 carbon atoms, a substituted or unsubstituted arylene group of 6 to 30 ring-forming carbon atoms, or a substituted or unsubstituted heteroarylene group of 2 to 30 ring-forming carbon atoms.

d1 to d4 may each independently be an integer of 0 to 4. R₃₁ to R₃₉ may each independently be a hydrogen atom, a deuterium atom, a halogen atom, a cyano group, a substituted or unsubstituted amine group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, and/or combined with an adjacent group (e.g., from each other) to form a ring.

In some embodiments, the compound represented by Formula M-b may be utilized as a blue phosphorescence dopant or a green phosphorescence dopant. The compound represented by Formula M-b may be represented by any one among the compounds in Compound Group 4. The light emitting element ED of an embodiment may include any one among the compounds in Compound Group 4. However, the compounds are only illustrations, and the compound represented by Formula M-b is not limited to the compounds represented below.

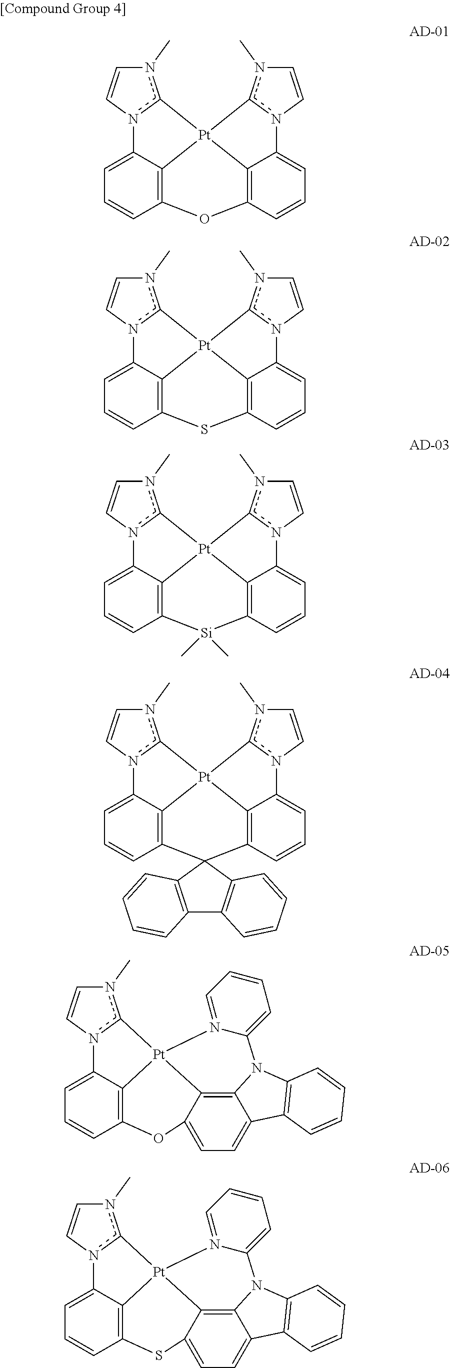

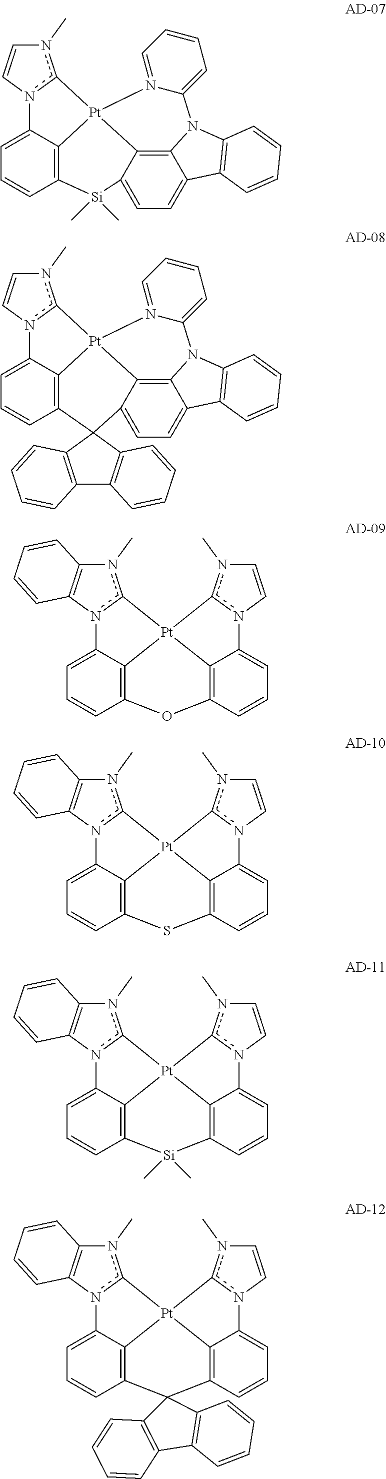

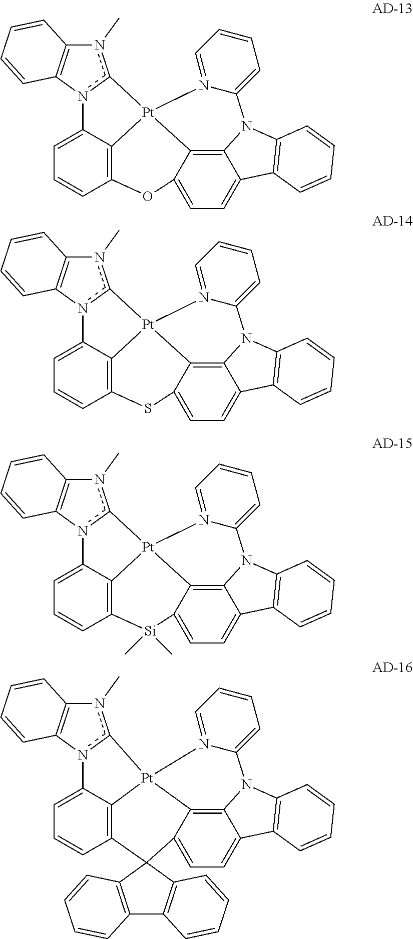

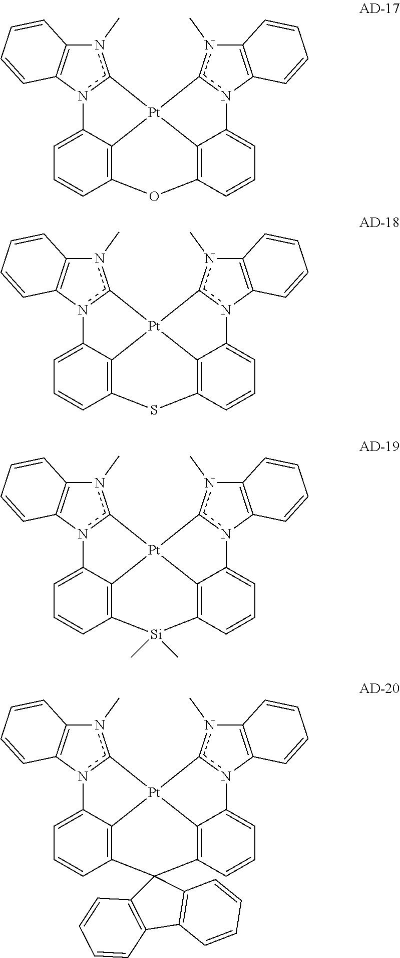

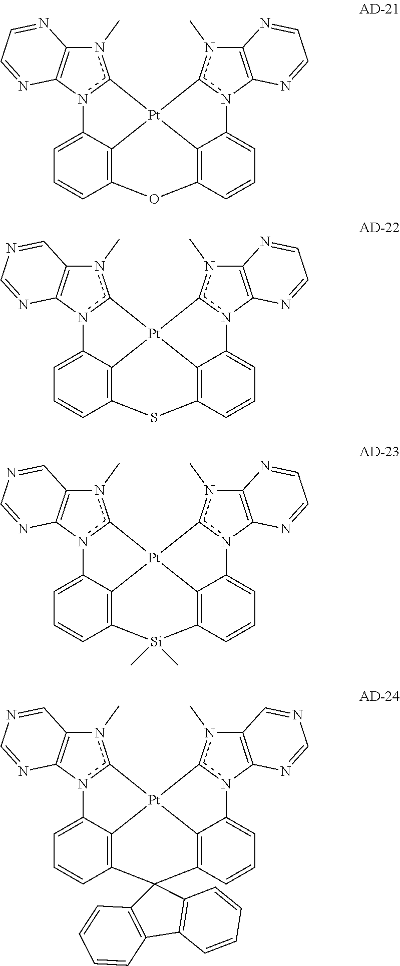

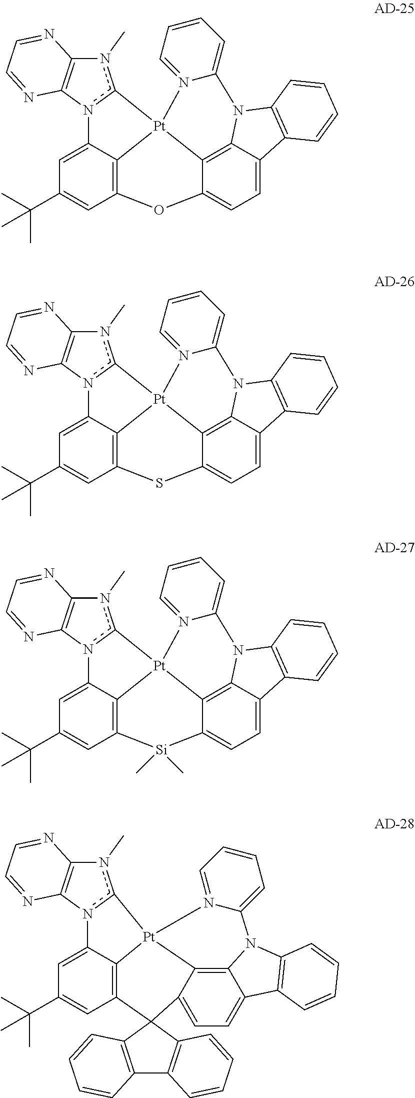

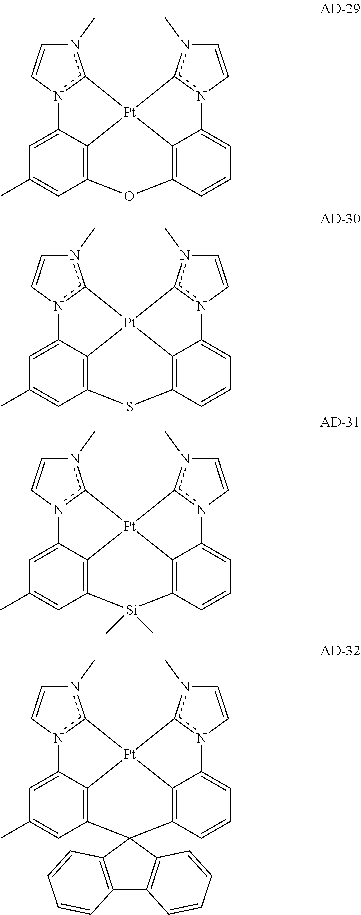

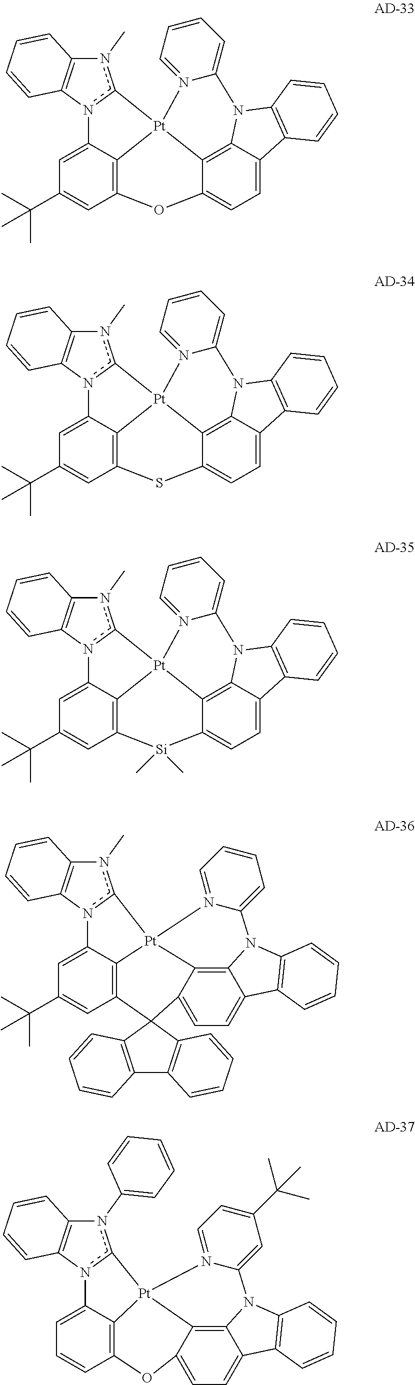

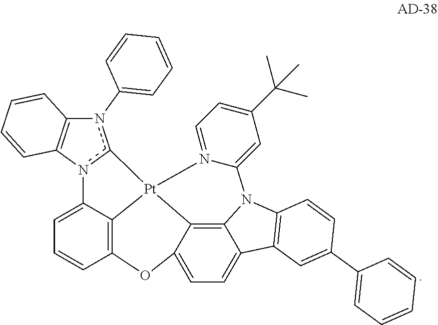

The emission layer EML may have a thickness of, for example, about 100 Å to about 1,000 Å or about 100 Å to about 300 Å. The emission layer EML may have a single layer formed utilizing a single material, a single layer formed utilizing multiple different materials, or a multilayer structure having multiple layers formed utilizing multiple different materials.

The emission layer EML may further include a compound explained below in addition to the first compound (i.e., the fused polycyclic compound), and the second to fourth compounds. The emission layer EML may include one or more anthracene derivatives, pyrene derivatives, fluoranthene derivatives, chrysene derivatives, dihydrobenzanthracene derivatives, and/or triphenylene derivatives. In an embodiment, the emission layer EML may include one or more anthracene derivatives and/or pyrene derivatives.

The emission layer EML may include a compound represented by Formula E-1 below. The compound represented by Formula E-1 below may be utilized as a fluorescence host material.

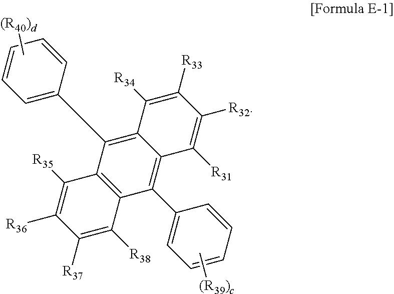

In Formula E-1, R₃₁ to R₄₀ may each independently be a hydrogen atom, a deuterium atom, a halogen atom, a substituted or unsubstituted silyl group, a substituted or unsubstituted thio group, a substituted or unsubstituted oxy group, a substituted or unsubstituted alkyl group of 1 to 10 carbon atoms, a substituted or unsubstituted alkenyl group of 2 to 10 carbon atoms, a substituted or unsubstituted aryl group of 6 to 30 ring-forming carbon atoms, or a substituted or unsubstituted heteroaryl group of 2 to 30 ring-forming carbon atoms, and/or may be combined with an adjacent group to form a ring. In some embodiments, R₃₁ to R₄₀ may be combined with an adjacent group to form a saturated hydrocarbon ring, an unsaturated hydrocarbon ring, a saturated heterocycle, or an unsaturated heterocycle.

In Formula E-1, “c” and “d” may each independently be an integer of 0 to 5. When “c” is an integer of 2 or more, multiple R₃₉ may be the same, or at least one thereof may be different. When “d” is an integer of 2 or more, multiple R₄₀ may be the same, or at least one thereof may be different. Formula E-1 may be represented by any one among Compound E1 to Compound E19 below.

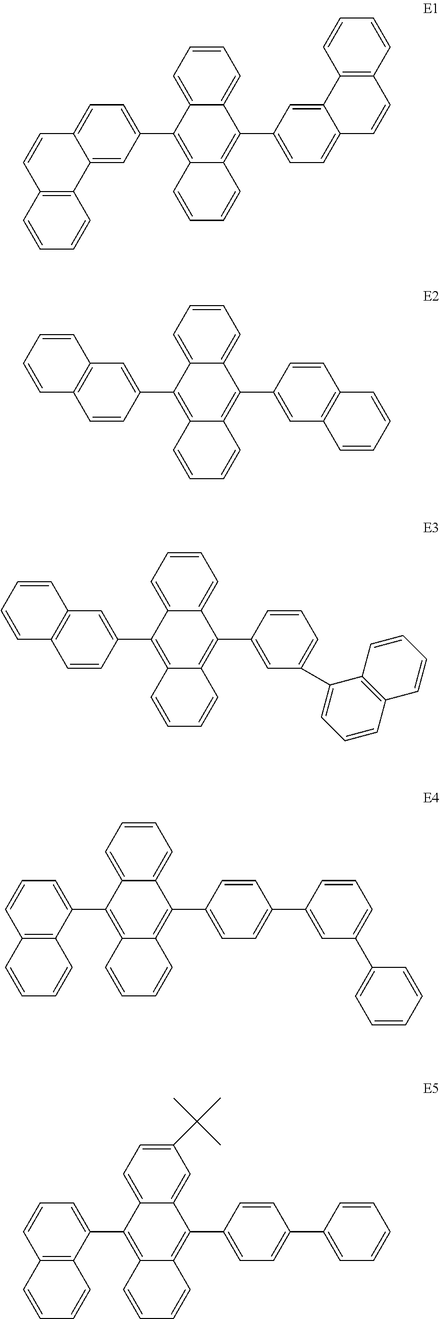

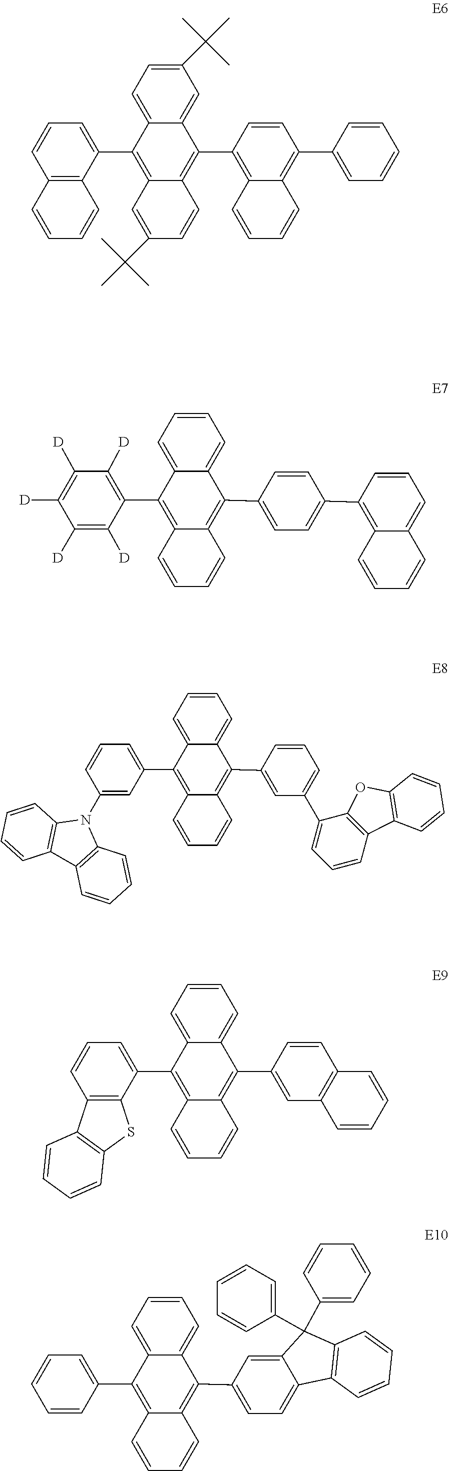

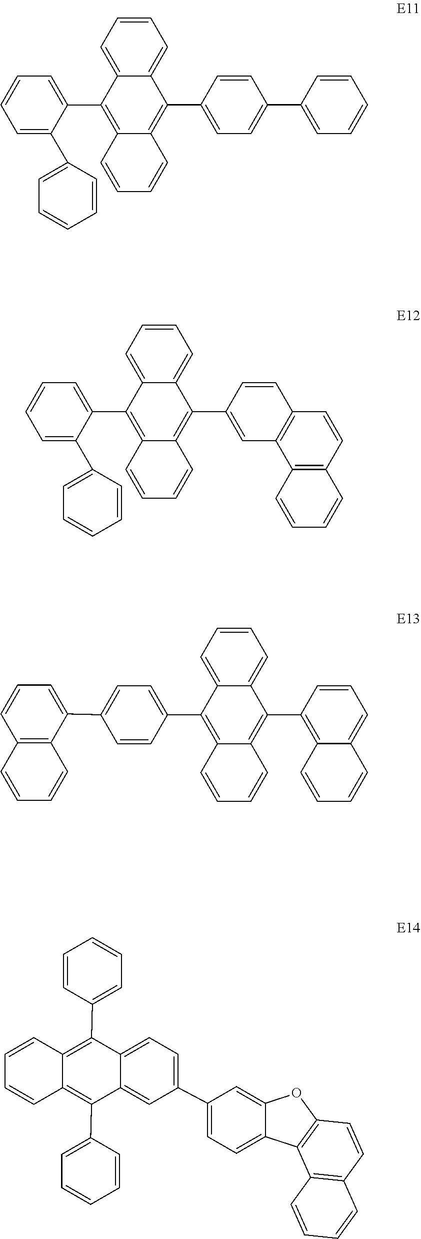

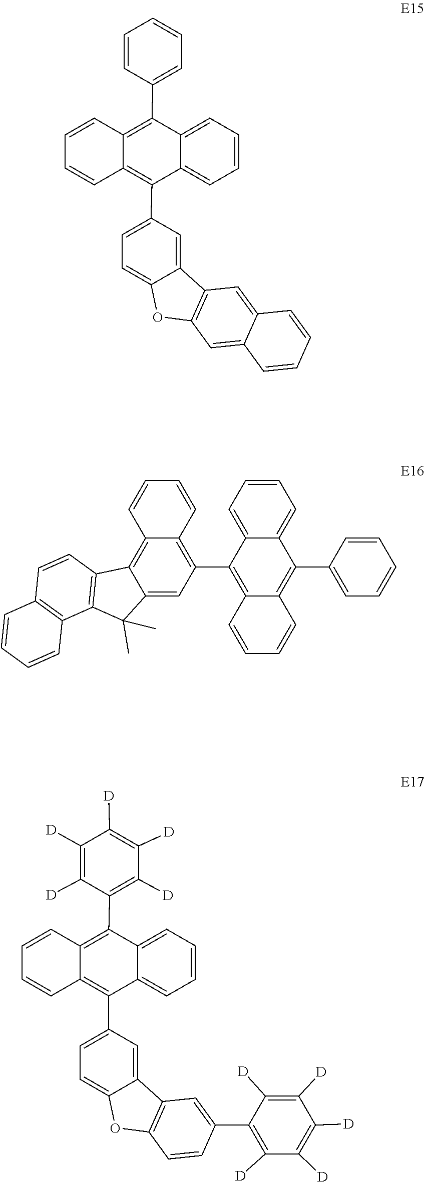

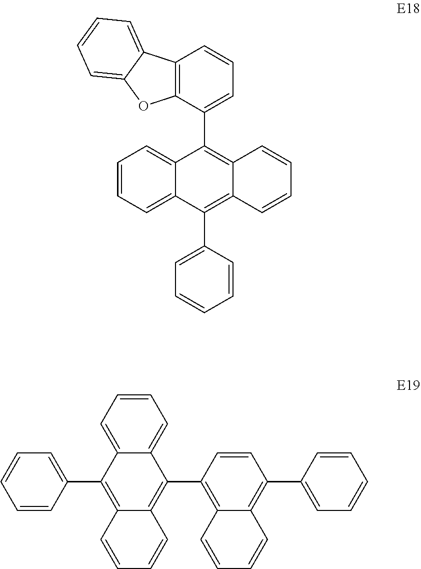

In an embodiment, the emission layer EML may include a compound represented by Formula E-2a or Formula E-2b below. The compound represented by Formula E-2a or Formula E-2b may be utilized as a phosphorescence host material.

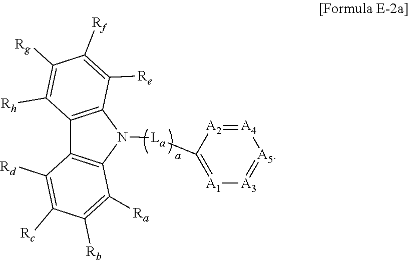

In Formula E-2a, “a” may be an integer of 0 to 10, and La may be a direct linkage, a substituted or unsubstituted arylene group of 6 to 30 ring-forming carbon atoms, or a substituted or unsubstituted heteroarylene group of 2 to 30 ring-forming carbon atoms. In some embodiments, when “a” is an integer of 2 or more, multiple La may each independently be a substituted or unsubstituted arylene group of 6 to 30 ring-forming carbon atoms, or a substituted or unsubstituted heteroarylene group of 2 to 30 ring-forming carbon atoms.

In some embodiments, in Formula E-2a, A₁ to A₅ may each independently be N or CRᵢ. Rₐ to Rᵢ may each independently be a hydrogen atom, a deuterium atom, a substituted or unsubstituted amine group, a substituted or unsubstituted thio group, a substituted or unsubstituted oxy group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, and/or may be combined with an adjacent group to form a ring. In an embodiment, Rₐ to Rᵢ may be combined with an adjacent group to form a hydrocarbon ring or a heterocycle including N, O, S, etc. as ring-forming atoms.

In some embodiments, in Formula E-2a, two or three selected from A₁ to A₅ may be N, and any remainder thereof may be CRᵢ.

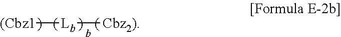

In Formula E-2b, Cbz1 and Cbz2 may each independently be an unsubstituted carbazole group, or a carbazole group substituted with an aryl group of 6 to 30 ring-forming carbon atoms. L_{b} may be a direct linkage, a substituted or unsubstituted arylene group of 6 to 30 ring-forming carbon atoms, or a substituted or unsubstituted heteroarylene group of 2 to 30 ring-forming carbon atoms. “b” is an integer of 0 to 10, and when “b” is an integer of 2 or more, multiple L_{b} may each independently be a substituted or unsubstituted arylene group of 6 to 30 ring-forming carbon atoms, or a substituted or unsubstituted heteroarylene group of 2 to 30 ring-forming carbon atoms.

The compound represented by Formula E-2a or Formula E-2b may be represented by any one among the compounds in Compound Group E-2 below. However, the compounds listed in Compound Group E-2 below are only illustrations, and the compound represented by Formula E-2a or Formula E-2b is not limited to the compounds represented in Compound Group E-2 below.

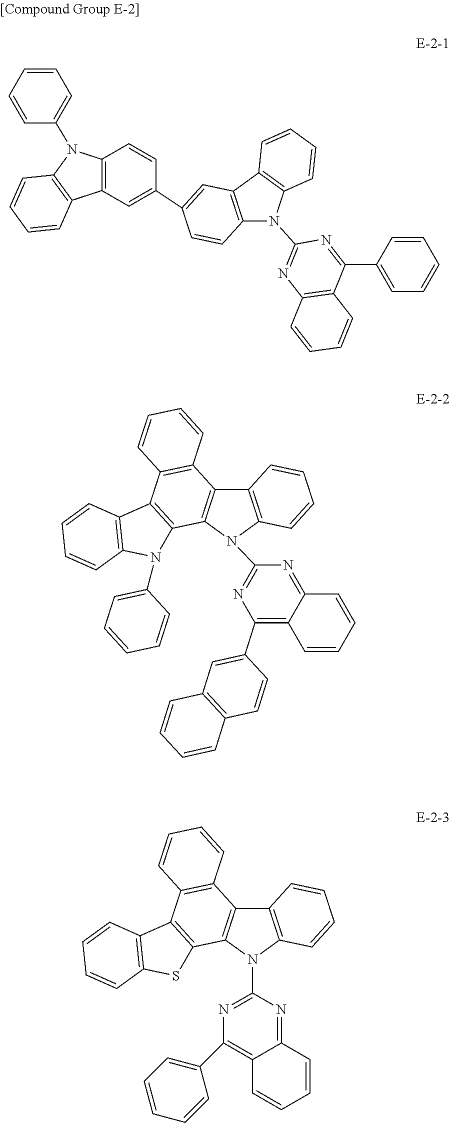 [SMILES: c1ccc(-c2nc(-n3c4ccccc4c4cc(-c5ccc6c(c5)c5ccccc5n6-c5ccccc5)ccc43)nc3ccccc23)cc1 ; c1ccc(-n2c3ccccc3c3c4ccccc4c4c5ccccc5n(-c5nc(-c6ccc7ccccc7c6)c6ccccc6n5)c4c32)cc1 ; c1ccc(-c2nc(-n3c4ccccc4c4c5ccccc5c5c6ccccc6sc5c43)nc3ccccc23)cc1]

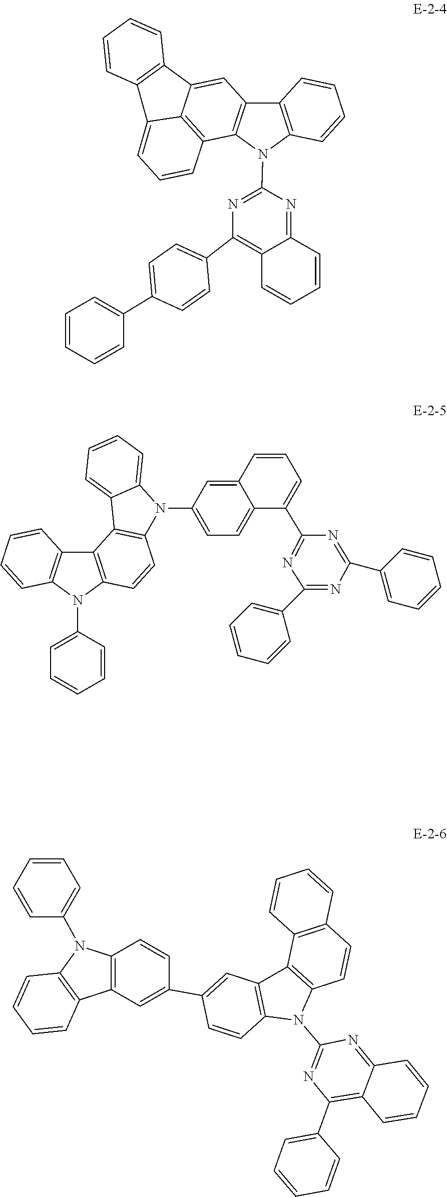 [SMILES: c1ccc(-c2ccc(-c3nc(-n4c5ccccc5c5cc6c7c(cccc7c54)-c4ccccc4-6)nc4ccccc34)cc2)cc1 ; c1ccc(-c2nc(-c3ccccc3)nc(-c3cccc4cc(-n5c6ccccc6c6c7c8ccccc8n(-c8ccccc8)c7ccc65)ccc34)n2)cc1 ; c1ccc(-c2nc(-n3c4ccc(-c5ccc6c(c5)c5ccccc5n6-c5ccccc5)cc4c4c5ccccc5ccc43)nc3ccccc23)cc1]

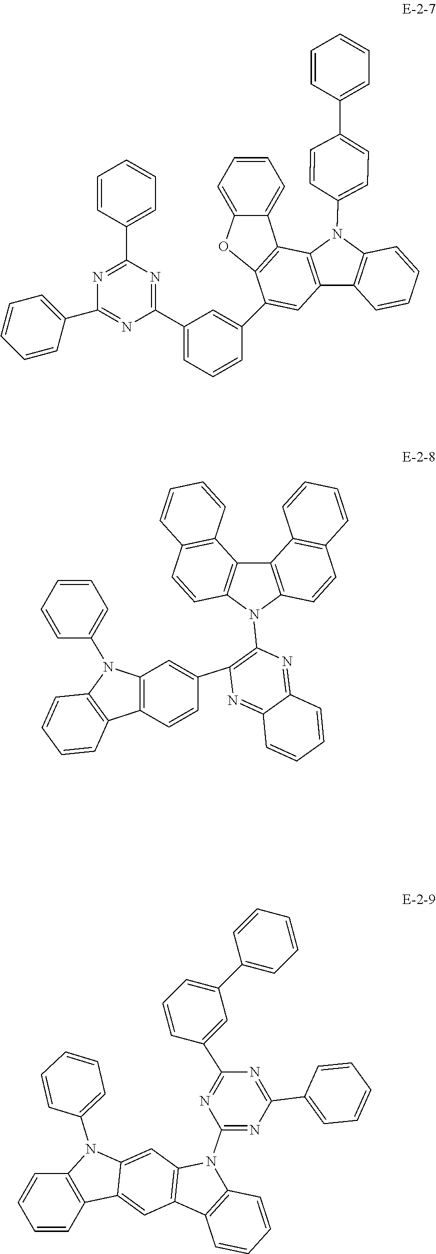 [SMILES: c1ccc(-c2ccc(-n3c4ccccc4c4cc(-c5cccc(-c6nc(-c7ccccc7)nc(-c7ccccc7)n6)c5)c5oc6ccccc6c5c43)cc2)cc1 ; c1ccc(-n2c3ccccc3c3ccc(-c4nc5ccccc5nc4-n4c5ccc6ccccc6c5c5c6ccccc6ccc54)cc32)cc1 ; c1ccc(-c2cccc(-c3nc(-c4ccccc4)nc(-n4c5ccccc5c5cc6c7ccccc7n(-c7ccccc7)c6cc54)n3)c2)cc1]

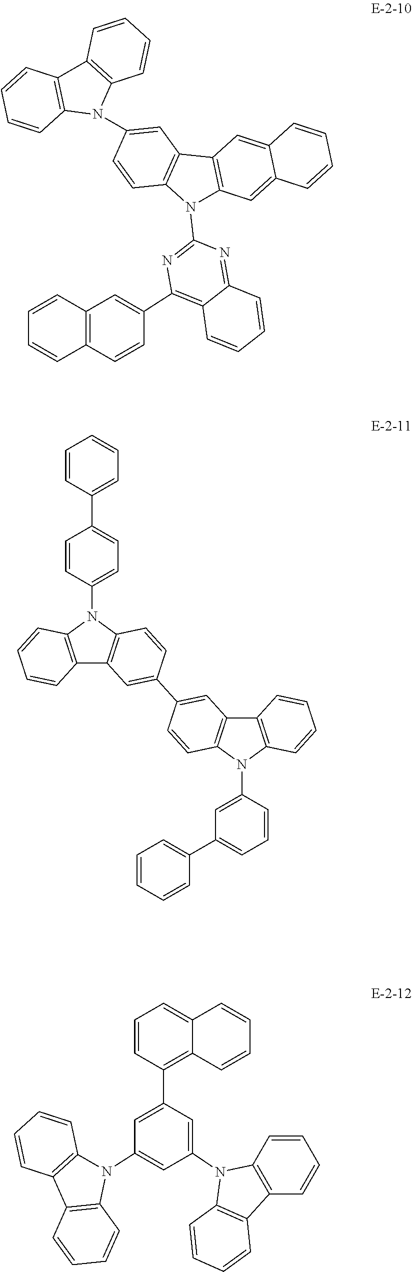 [SMILES: c1ccc2cc(-c3nc(-n4c5ccc(-n6c7ccccc7c7ccccc76)cc5c5cc6ccccc6cc54)nc4ccccc34)ccc2c1 ; c1ccc(-c2ccc(-n3c4ccccc4c4cc(-c5ccc6c(c5)c5ccccc5n6-c5cccc(-c6ccccc6)c5)ccc43)cc2)cc1 ; c1ccc2c(-c3cc(-n4c5ccccc5c5ccccc54)cc(-n4c5ccccc5c5ccccc54)c3)cccc2c1]

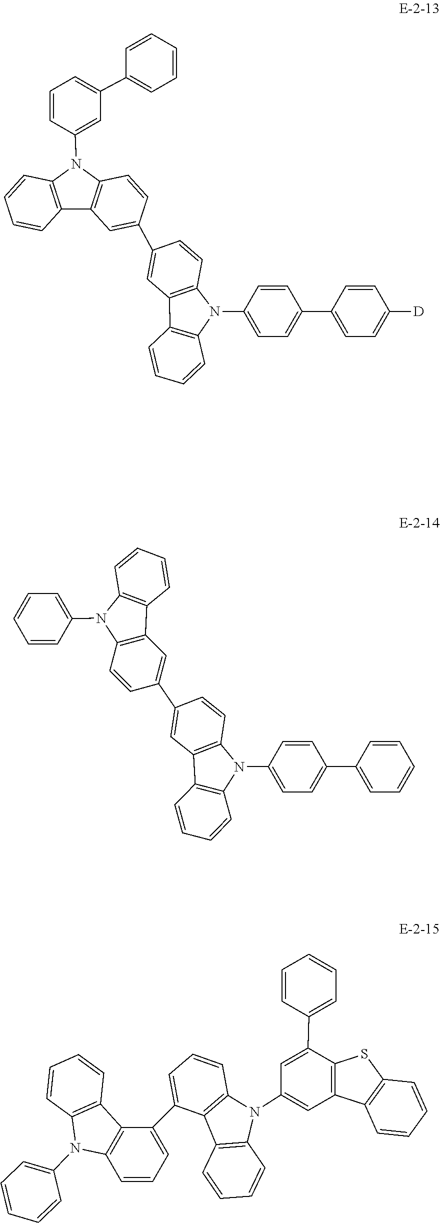 [SMILES: [2H]c1ccc(-c2ccc(-n3c4ccccc4c4cc(-c5ccc6c(c5)c5ccccc5n6-c5cccc(-c6ccccc6)c5)ccc43)cc2)cc1 ; c1ccc(-c2ccc(-n3c4ccccc4c4cc(-c5ccc6c(c5)c5ccccc5n6-c5ccccc5)ccc43)cc2)cc1 ; c1ccc(-c2cc(-n3c4ccccc4c4c(-c5cccc6c5c5ccccc5n6-c5ccccc5)cccc43)cc3c2sc2ccccc23)cc1]

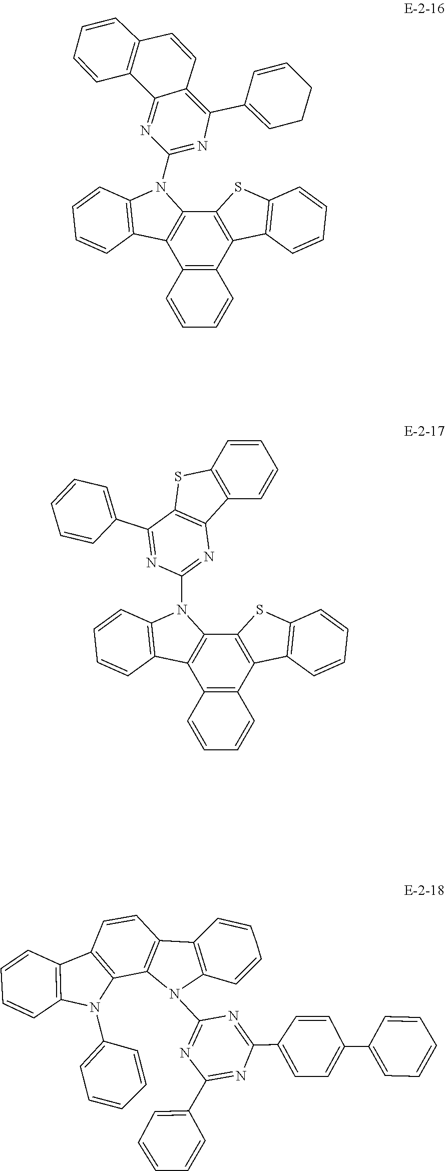 [SMILES: C1=CC2CC2C=C1c1nc(-n2c3ccccc3c3c4ccccc4c4c5ccccc5sc4c32)nc2c1ccc1ccccc12 ; c1ccc(-c2nc(-n3c4ccccc4c4c5ccccc5c5c6ccccc6sc5c43)nc3c2sc2ccccc23)cc1 ; C1=Cc2c(n(-c3nc(-c4ccccc4)nc(-c4ccc(-c5ccccc5)cc4)n3)c3c2ccc2c4ccccc4n(-c4ccccc4)c23)C=CC1]

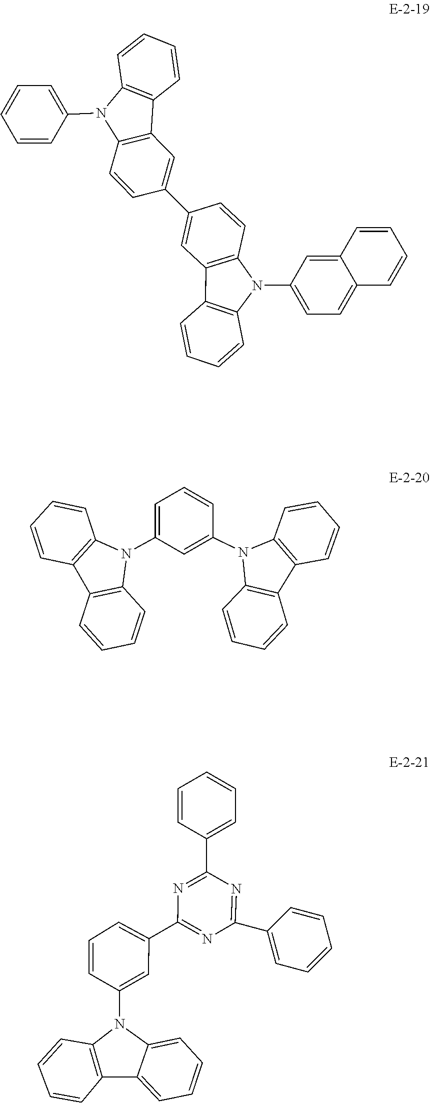 [SMILES: c1ccc(-n2c3ccccc3c3cc(-c4ccc5c(c4)c4ccccc4n5-c4ccc5ccccc5c4)ccc32)cc1 ; c1cc(-n2c3ccccc3c3ccccc32)cc(-n2c3ccccc3c3ccccc32)c1 ; c1ccc(-c2nc(-c3ccccc3)nc(-c3cccc(-n4c5ccccc5c5ccccc54)c3)n2)cc1]

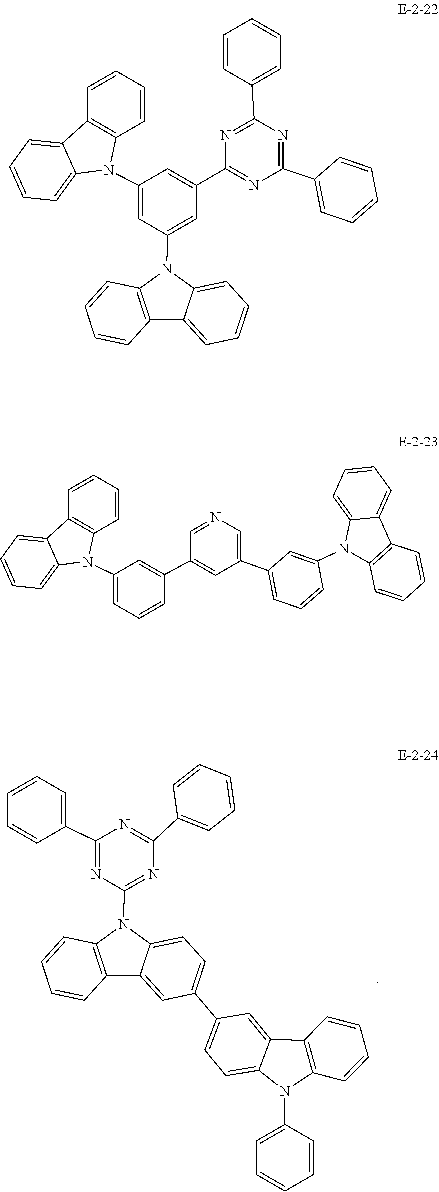 [SMILES: c1ccc(-c2nc(-c3ccccc3)nc(-c3cc(-n4c5ccccc5c5ccccc54)cc(-n4c5ccccc5c5ccccc54)c3)n2)cc1 ; c1cc(-c2cncc(-c3cccc(-n4c5ccccc5c5ccccc54)c3)c2)cc(-n2c3ccccc3c3ccccc32)c1 ; c1ccc(-c2nc(-c3ccccc3)nc(-n3c4ccccc4c4cc(-c5ccc6c(c5)c5ccccc5n6-c5ccccc5)ccc43)n2)cc1]

The emission layer EML may further include a suitable material known in the art as a host material. For example, the emission layer EML may include as a host material, at least one of bis (4-(9H-carbazol-9-yl) phenyl) diphenylsilane (BCPDS), (4-(1-(4-(diphenylamino) phenyl) cyclohexyl) phenyl) diphenyl-phosphine oxide (POPCPA), bis[2-(diphenylphosphino)phenyl] ether oxide (DPEPO), 4,4′-bis(N-carbazolyl)-1,1′-biphenyl (CBP), 1,3-bis(carbazol-9-yl)benzene (mCP), 2,8-bis(diphenylphosphoryl)dibenzo[b,d]furan (PPF), 4,4′,4″-tris(carbazol-9-yl)-triphenylamine (TCTA), or 1,3,5-tris(1-phenyl-1H-benzo[d]imidazole-2-yl)benzene (TPBi). However, an embodiment of the present disclosure is not limited thereto. For example, tris(8-hydroxyquinolino)aluminum (Alq₃), 9,10-di(naphthalene-2-yl)anthracene (ADN), 2-tert-butyl-9,10-di(naphth-2-yl)anthracene (TBADN), distyrylarylene (DSA), 4,4′-bis(9-carbazolyl)-2,2′-dimethyl-biphenyl (CDBP), 2-methyl-9,10-bis(naphthalen-2-yl)anthracene (MADN), hexaphenyl cyclotriphosphazene (CP1), 1,4-bis(triphenylsilyl)benzene (UGH2), hexaphenylcyclotrisiloxane (DPSiO₃), octaphenylcyclotetra siloxane (DPSiO₄), etc. may be utilized as the host material.

The emission layer EML may include a compound represented by Formula M-a. The compound represented by Formula M-a may be utilized as a phosphorescence dopant material.

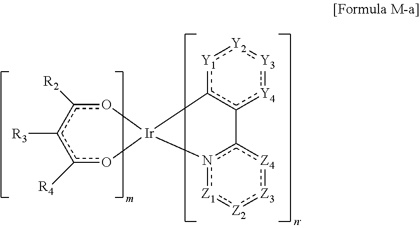

In Formula M-a, Y₁ to Y₄, and Z₁ to Z₄ may each independently be CR₁ or N, and R₁ to R₄ may each independently be a hydrogen atom, a deuterium atom, a substituted or unsubstituted amine group, a substituted or unsubstituted thio group, a substituted or unsubstituted oxy group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, and/or may be combined with an adjacent group to form a ring. In Formula M-a, “m” may be 0 or 1, and “n” may be 2 or 3. In Formula M-a, when “m” is 0, “n” may be 3, and when “m” is 1, “n” may be 2.

The compound represented by Formula M-a may be represented by any one among Compounds M-a1 to M-a25 below. However, Compounds M-a1 to M-a25 are illustrations, and the compound represented by Formula M-a is not limited to those represented by Compounds M-a1 to M-a25 below.

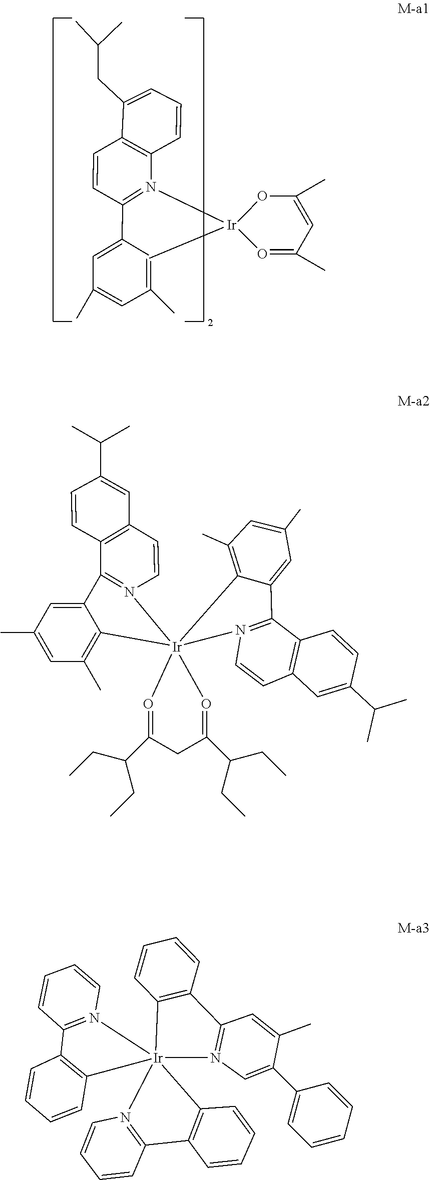

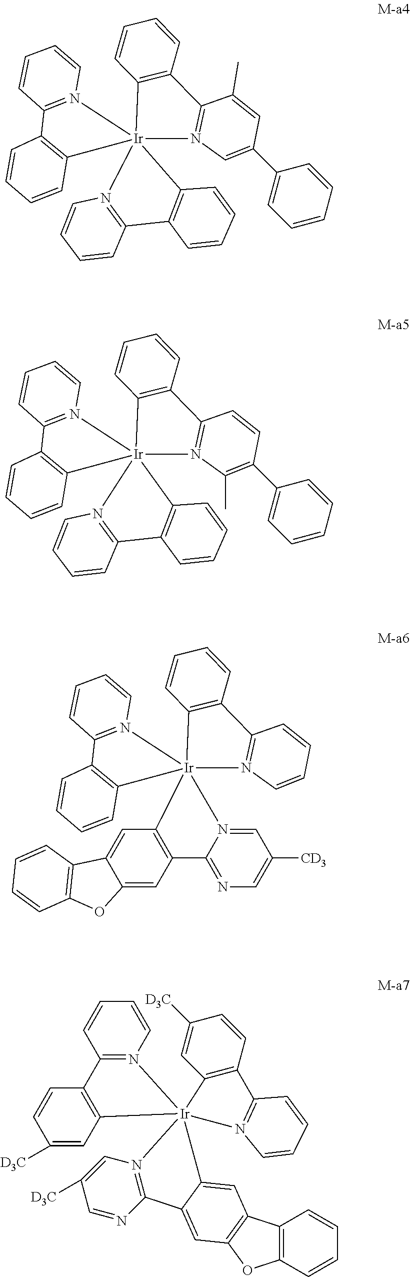

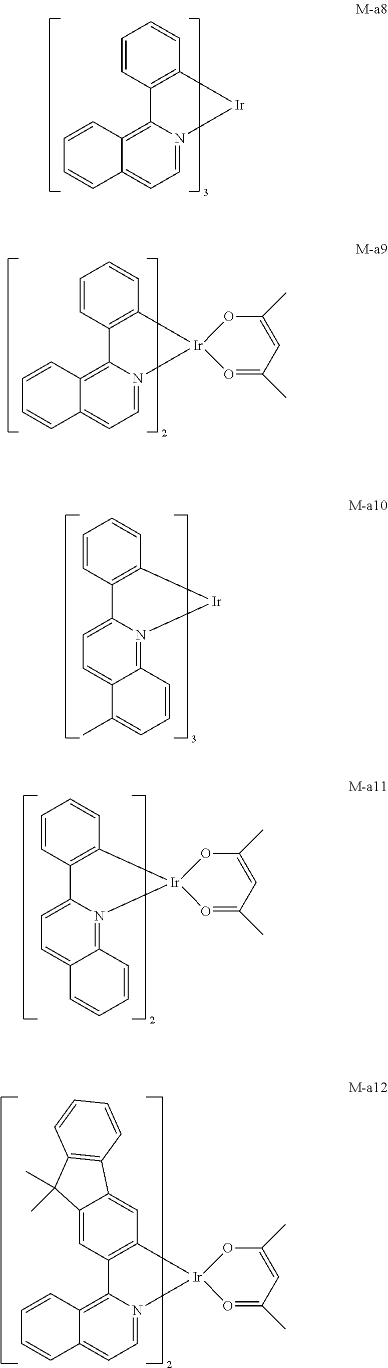

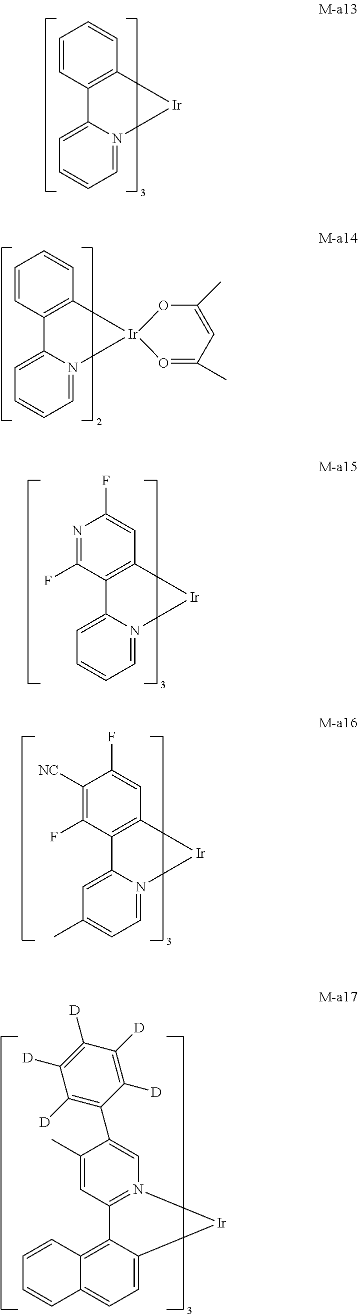

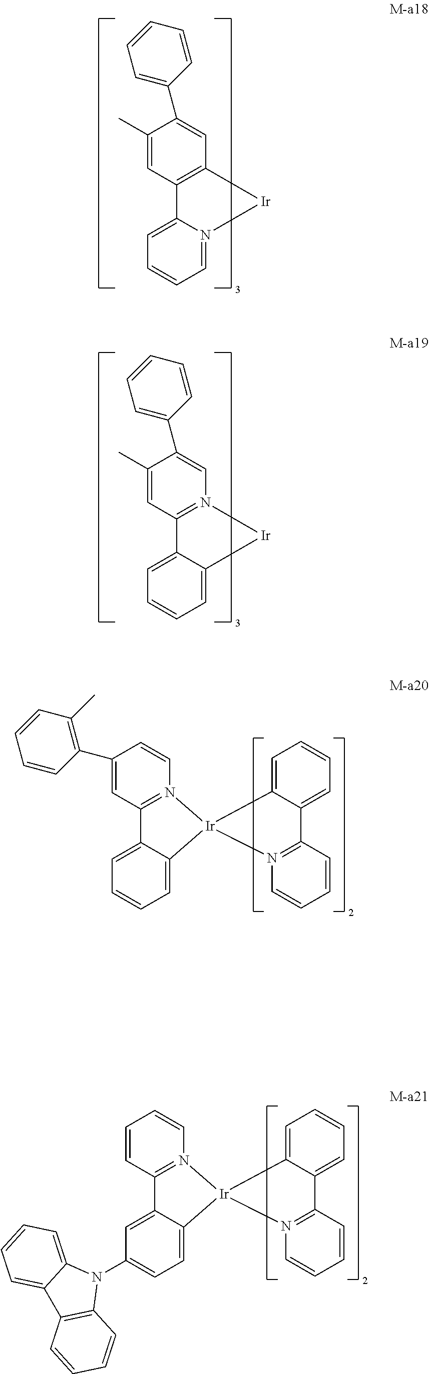

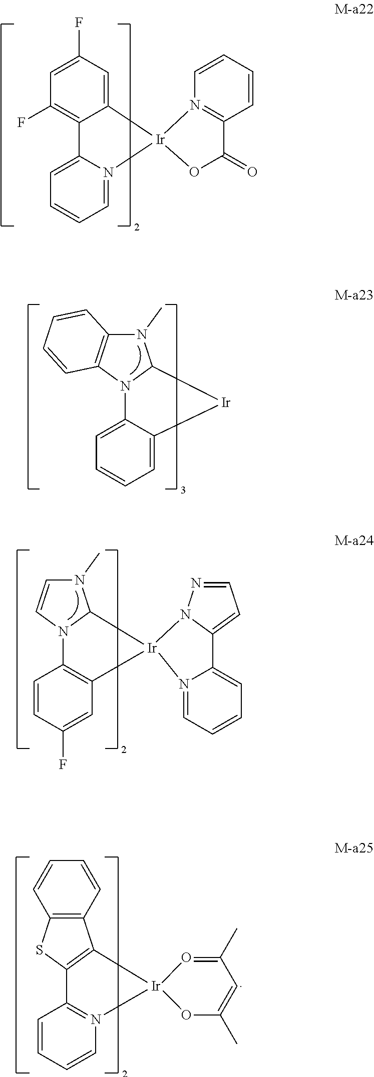

For example, Compound M-a1 and Compound M-a2 may be utilized as red dopant materials, and Compound M-a3 to Compound M-a7 may be utilized as green dopant materials.

The emission layer EML may further include a compound represented by any one among Formula F-a to Formula F-c below. The compounds represented by Formula F-a to Formula F-c may be utilized as fluorescence dopant materials.

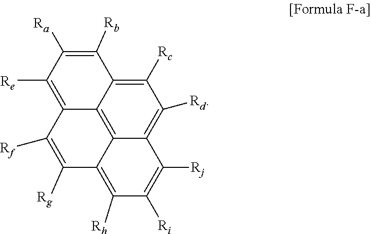

In Formula F-a, two selected from Rₐ to Rⱼ may each independently be substituted with *—NAr₁Ar₂. Any remainder thereof not substituted with *—NAr₁Ar₂ among Rₐ to Rⱼ may each independently be a hydrogen atom, a deuterium atom, a halogen atom, a cyano group, a substituted or unsubstituted amine group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms.

In *—NAr₁Ar₂, Ar₁ and Ar₂ may each independently be a substituted or unsubstituted aryl group of 6 to 30 ring-forming carbon atoms, or a substituted or unsubstituted heteroaryl group of 2 to 30 ring-forming carbon atoms. For example, Ar and/or Ar₂ may be a heteroaryl group including O or S as a ring-forming atom.

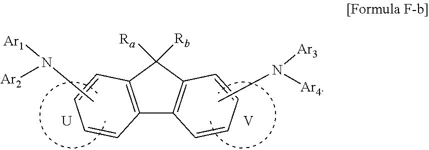

In Formula F-b, Rₐ and R_{b} may each independently be a hydrogen atom, a deuterium atom, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, and/or may be combined with an adjacent group to form a ring. Ar₁ to Ar₄ may each independently be a substituted or unsubstituted aryl group of 6 to 30 ring-forming carbon atoms, or a substituted or unsubstituted heteroaryl group of 2 to 30 ring-forming carbon atoms.

In Formula F-b, U and V may each independently be a substituted or unsubstituted hydrocarbon ring of 5 to 30 ring-forming carbon atoms, or a substituted or unsubstituted heterocycle of 2 to 30 ring-forming carbon atoms. In Formula F-b, the number of rings represented by U and V may each independently be 0 or 1.

For example, in Formula F-b, when the number of U or V is 1, one ring forms a fused ring at the part designated by U or V, and when the number of U or V is 0, a ring is not present at the part designated by U or V. For example, when the number of U is 0, and the number of V is 1, or when the number of U is 1, and the number of V is 0, a fused ring having a fluorene core of Formula F-b may be a ring compound with four rings. In some embodiments, when the number of U and the number of V are both 0, the fused ring having a fluorene core of Formula F-b may be a ring compound with three rings. In some embodiments, when the number of U and the number of V are both 1, a fused ring having a fluorene core of Formula F-b may be a ring compound with five rings.

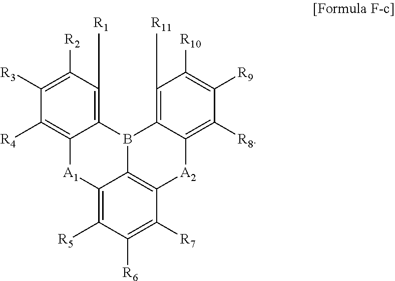

In Formula F-c, A₁ and A₂ may each independently be O, S, Se, or NRₘ, and Rₘ may be a hydrogen atom, a deuterium atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms. R₁ to R₁₁ may each independently be a hydrogen atom, a deuterium atom, a halogen atom, a cyano group, a substituted or unsubstituted amine group, a substituted or unsubstituted boron group, a substituted or unsubstituted oxy group, a substituted or unsubstituted thio group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, and/or combined with an adjacent group to form a ring.

In Formula F-c, A₁ and A₂ may each independently be combined with the substituents of an adjacent ring to form a fused ring. For example, when A₁ and A₂ may each independently be NRₘ, A₁ may be combined with R₄ or R₅ to form a ring. In some embodiments, A₂ may be combined with R₇ or R₈ to form a ring.

In an embodiment, the emission layer EML may include as a suitable dopant material, one or more styryl derivatives (for example, 1,4-bis[2-(3-N-ethylcarbazoryl)vinyl]benzene (BCzVB), 4-(di-p-tolylamino)-4′-[(di-p-tolylamino)styryl]stilbene (DPAVB), N-(4-((E)-2-(6-((E)-4-(diphenylamino)styryl)naphthalen-2-yl)vinyl)phenyl)-N-phenylbenzenamine (N-BDAVBi), and 4,4′-bis[2-(4-(N,N-diphenylamino)phenyl)vinyl]biphenyl (DPAVBi)), perylene and the derivatives thereof (for example, 2,5,8,11-tetra-t-butylperylene (TBP)), pyrene and the derivatives thereof (for example, 1,1′-dipyrene, 1,4-dipyrenylbenzene, and 1,4-bis(N,N-diphenylamino)pyrene), etc.

The emission layer EML may include a suitable phosphorescence dopant material. For example, the phosphorescence dopant may utilize a metal complex including iridium (Ir), platinum (Pt), osmium (Os), gold (Au), titanium (Ti), zirconium (Zr), hafnium (Hf), europium (Eu), terbium (Tb) and/or thulium (Tm). For example, iridium(III) bis(4,6-difluorophenylpyridinato-N,C2′)picolinate (Flrpic), bis(2,4-difluorophenylpyridinato)-tetrakis(1-pyrazolyl)borate iridium(III) (Fir6), and/or platinum octaethyl porphyrin (PtOEP) may be utilized as the phosphorescence dopant. However, an embodiment of the present disclosure is not limited thereto.

The emission layer EML may include a quantum dot material. The core of the quantum dot may be selected from II-VI group compounds, I-II-VI group compounds, II-IV-VI group compounds, I-II-IV-VI group compounds, III-VI group compounds, I-III-VI group compounds, III-V group compounds, III-II-V group compounds, II-IV-V group compounds, IV-VI group compounds, IV group elements, IV group compounds, and combinations thereof.

The II-VI group compound may be selected from the group consisting of: a binary compound selected from the group consisting of CdSe, CdTe, CdS, ZnS, ZnSe, ZnTe, ZnO, HgS, HgSe, HgTe, MgSe, MgS, and mixtures thereof; a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and mixtures thereof; and a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe and mixtures thereof. In some embodiments, the II-VI group compound may further include a metal in group I and/or an element in group IV. The I-II-VI group compound may be selected from CuSnS or CuZnS, and the II-IV-VI group compound may include ZnSnS, etc. The I-II-IV-VI group compound may be selected from a quaternary compound selected from the group consisting of Cu₂ZnSnS₂, Cu₂ZnSnS₄, Cu₂ZnSnSe₄, Ag₂ZnSnS₂ and mixtures thereof.

The III-VI group compound may include a binary compound such as In₂S₃, and/or In₂Se₃, a ternary compound such as InGaS₃, and/or InGaSe₃, or optional combinations thereof.

The I-III-VI group compound may be selected from a ternary compound selected from the group consisting of AgInS, AgInS₂, CulnS, CulnS₂, AgGaS₂, CuGaS₂, CuGaO₂, AgGaO₂, AgAlO₂ and mixtures thereof, or a quaternary compound such as AgInGaS₂, and/or CulnGaS₂.

The III-V group compound may be selected from the group consisting of a binary compound selected from the group consisting of GaN, GaP, GaAs, GaSb, AlN, AlP, AlAs, AlSb, InN, InP, InAs, InSb, and mixtures thereof, a ternary compound selected from the group consisting of GaNP, GaNAs, GaNSb, GaPAs, GaPSb, AINP, AlNAs, AlNSb, AlPAs, AlPSb, InGaP, InAlP, InNP, InNAs, InNSb, InPAs, InPSb, and mixtures thereof, and a quaternary compound selected from the group consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and mixtures thereof. In some embodiments, the III-V group compound may further include a II group metal. For example, InZnP, etc. may be selected as a III-II-V group compound.

The II-IV-V group compound may be selected from a ternary compound selected from the group consisting of ZnSnP, ZnSnP₂, ZnSnAs₂, ZnGeP₂, ZnGeAs₂, CdSnP₂, CdGeP₂ and mixtures thereof.

The IV-VI group compound may be selected from the group consisting of a binary compound selected from the group consisting of SnS, SnSe, SnTe, PbS, PbSe, PbTe, and mixtures thereof, a ternary compound selected from the group consisting of SnSeS, SnSeTe, SnSTe, PbSeS, PbSeTe, PbSTe, SnPbS, SnPbSe, SnPbTe, and mixtures thereof, and a quaternary compound selected from the group consisting of SnPbSSe, SnPbSeTe, SnPbSTe, and mixtures thereof. The IV group element may be selected from the group consisting of Si, Ge, and a mixture thereof. The IV group compound may be a binary compound selected from the group consisting of SiC, SiGe, and a mixture thereof.

In this case, the binary compound, the ternary compound or the quaternary compound may be present at a substantially uniform concentration in a particle or may be present at a partially different concentration distribution state in the same particle. In some embodiments, the quantum dot may have a core/shell structure in which one quantum dot is around (e.g., wraps or encapsulates) another quantum dot may be possible. The interface between the core and the shell may have a concentration gradient in which the concentration of an element present in the shell is decreased toward the center of the core.

In some embodiments, the quantum dot may have the above-described core-shell structure including a core including a nanocrystal and a shell around (e.g., wrapping) the core. The shell of the quantum dot may play the role of a protection layer for preventing or reducing the chemical deformation of the core to maintain semiconductor properties and/or a charging layer for imparting the quantum dot with electrophoretic properties. The shell may have a single layer or a multilayer. Examples of the shell of the quantum dot may include a metal or non-metal oxide, a semiconductor compound, or any combinations thereof.

For example, the metal or non-metal oxide may include a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄ and/or NiO, or a ternary compound such as MgAl₂O₄, CoFe₂O₄, NiFe₂O₄ and/or CoMn₂O₄, but an embodiment of the present disclosure is not limited thereto.

Also, the semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, etc., but an embodiment of the present disclosure is not limited thereto.

The quantum dot may have a full width of half maximum (FWHM) of emission wavelength spectrum of about 45 nm or less, about 40 nm or less, or, about 30 nm or less. Within these range, color purity and/or color reproducibility may be improved. In some embodiments, light emitted via such quantum dot is emitted in all directions, and light view angle properties may be improved (e.g., a wider viewing angle may be obtained).

In some embodiments, the shape of the quantum dot may be any generally utilized shapes in the art, without specific limitation. For example, the quantum dot may have the shape of spherical, pyramidal, multi-arm, or cubic nanoparticle, nanotube, nanowire, nanofiber, nanoplate particle, etc.

The quantum dot may control the color of light emitted according to the particle size, and accordingly, the quantum dot may have various suitable emission colors such as blue, red and/or green.

Referring to FIG. 3 to FIG. 7, the first electrode EL1 has conductivity. The first electrode EL1 may be formed utilizing a metal material, a metal alloy or a conductive compound. The first electrode EL1 may be an anode or a cathode. However, an embodiment of the present disclosure is not limited thereto. In some embodiments, the first electrode EL1 may be a pixel electrode. The first electrode EL1 may be a transmissive electrode, a transflective electrode, or a reflective electrode. The first electrode EL1 may include at least one selected among Ag, Mg, Cu, Al, Pt, Pd, Au, Ni, Nd, Ir, Cr, Li, Ca, LiF, Mo, Ti, W, In, Sn and Zn, compounds of two or more selected therefrom, mixtures of two or more selected therefrom, or oxides thereof.

When the first electrode EL1 is the transmissive electrode, the first electrode EL1 may include a transparent metal oxide such as indium tin oxide (ITO), indium zinc oxide (IZO), zinc oxide (ZnO), and/or indium tin zinc oxide (ITZO). When the first electrode EL1 is the transflective electrode or the reflective electrode, the first electrode EL1 may include Ag, Mg, Cu, Al, Pt, Pd, Au, Ni, Nd, Ir, Cr, Li, Ca, LiF/Ca (a stacked structure of LiF and Ca), LiF/Al (a stacked structure of LiF and Al), Mo, Ti, W, compounds thereof, or mixtures thereof (for example, a mixture of Ag and Mg). Also, the first electrode EL1 may have a structure including multiple layers including a reflective layer or a transflective layer formed utilizing the above materials, and a transmissive conductive layer formed utilizing ITO, IZO, ZnO, and/or ITZO. For example, the first electrode EL1 may have a three-layer structure of ITO/Ag/ITO, without being limited thereto. In some embodiments, the first electrode EL1 may include the above-described metal materials, combinations of two or more metal materials selected from the above-described metal materials, or oxides of the above-described metal materials. However, an embodiment of the present disclosure is not limited thereto. The thickness of the first electrode EL1 may be from about 700 Å to about 10,000 Å. For example, the thickness of the first electrode EL1 may be from about 1,000 Å to about 3,000 Å.

The hole transport region HTR may be provided on the first electrode EL1. The hole transport region HTR may include at least one of a hole injection layer HIL, a hole transport layer HTL, an emission auxiliary layer EAL, or an electron blocking layer EBL. The emission auxiliary layer EAL may be referred to as a buffer layer.

The hole transport region HTR may have a single layer formed utilizing a single material, a single layer formed utilizing multiple different materials, or a multilayer structure including multiple layers formed utilizing multiple different materials. For example, the hole transport region HTR may have the structure of a single layer of a hole injection layer HIL or a hole transport layer HTL, and may have a structure of a single layer formed utilizing a hole injection material and a hole transport material.

In some embodiments, the hole transport region HTR may have a structure of a single layer formed utilizing multiple different materials, or a structure stacked from the first electrode EL1 of hole injection layer HIL/hole transport layer HTL, hole injection layer HTL/hole transport layer HTL/emission auxiliary layer EAL, hole injection layer HIL/emission auxiliary layer EAL, hole transport layer HTL/emission auxiliary layer EAL, hole injection layer HIL/hole transport layer HTL/electron blocking layer EBL, or hole injection layer HIL/hole transport layer HTL/emission auxiliary layer EAL. However, these are illustrations, and an embodiment of the present disclosure is not limited thereto.

The hole transport region HTR may be formed utilizing various suitable methods such as a vacuum deposition method, a spin coating method, a cast method, a Langmuir-Blodgett (LB) method, an inkjet printing method, a laser printing method, and/or a laser induced thermal imaging (LITI) method.

The hole transport region HTR may include a compound represented by Formula H-1 below.

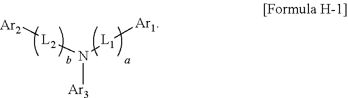

In Formula H-1 above, L₁ and L₂ may each independently be a direct linkage, a substituted or unsubstituted arylene group of 6 to 30 ring-forming carbon atoms, or a substituted or unsubstituted heteroarylene group of 2 to 30 ring-forming carbon atoms. “a” and “b” may each independently be an integer of 0 to 10. In some embodiments, when “a” or “b” is an integer of 2 or more, multiple L₁ and L₂ may each independently be a substituted or unsubstituted arylene group of 6 to 30 ring-forming carbon atoms, or a substituted or unsubstituted heteroarylene group of 2 to 30 ring-forming carbon atoms.

In Formula H-1, Ar₁ and Ar₂ may each independently be a substituted or unsubstituted aryl group of 6 to 30 ring-forming carbon atoms, or a substituted or unsubstituted heteroaryl group of 2 to 30 ring-forming carbon atoms. In some embodiments, in Formula H-1, Ar₃ may be a substituted or unsubstituted aryl group of 6 to 30 ring-forming carbon atoms.

The compound represented by Formula H-1 may be a monoamine compound (e.g., a compound including a single amine group). In an embodiment, the compound represented by Formula H-1 may be a diamine compound in which at least one among Ar₁ to Ar₃ includes an amine group as a substituent. In some embodiments, the compound represented by Formula H-1 may be a carbazole-based compound in which Ar₁ and/or Ar₂ includes a substituted or unsubstituted carbazole group, or a fluorene-based compound in which Ar₁ and/or Ar₂ includes a substituted or unsubstituted fluorene group.

The compound represented by Formula H-1 may be represented by any one among the compounds in Compound Group H below. However, the compounds listed in Compound Group H are only illustrations, and the compound represented by Formula H-1 is not limited to the compounds represented in Compound Group H below.

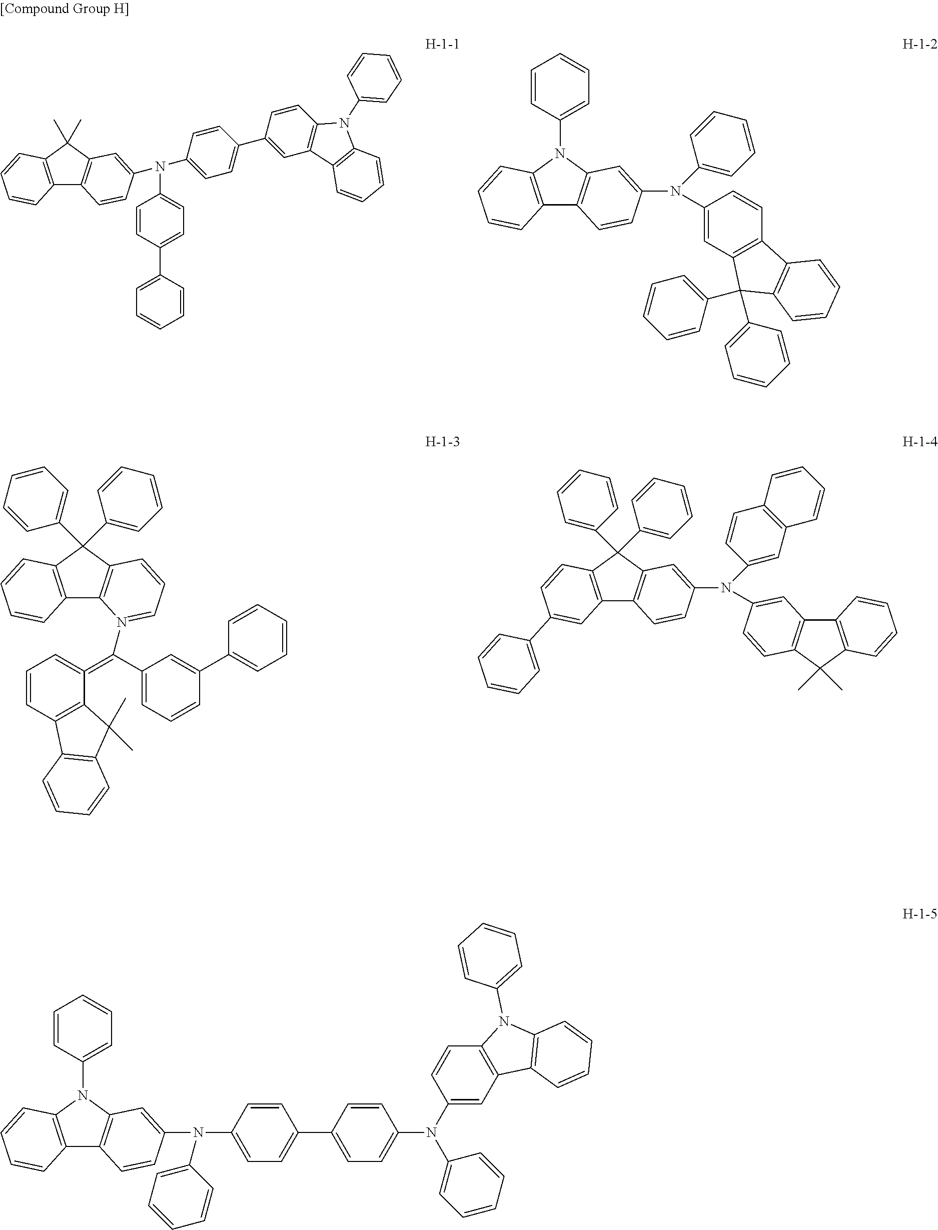

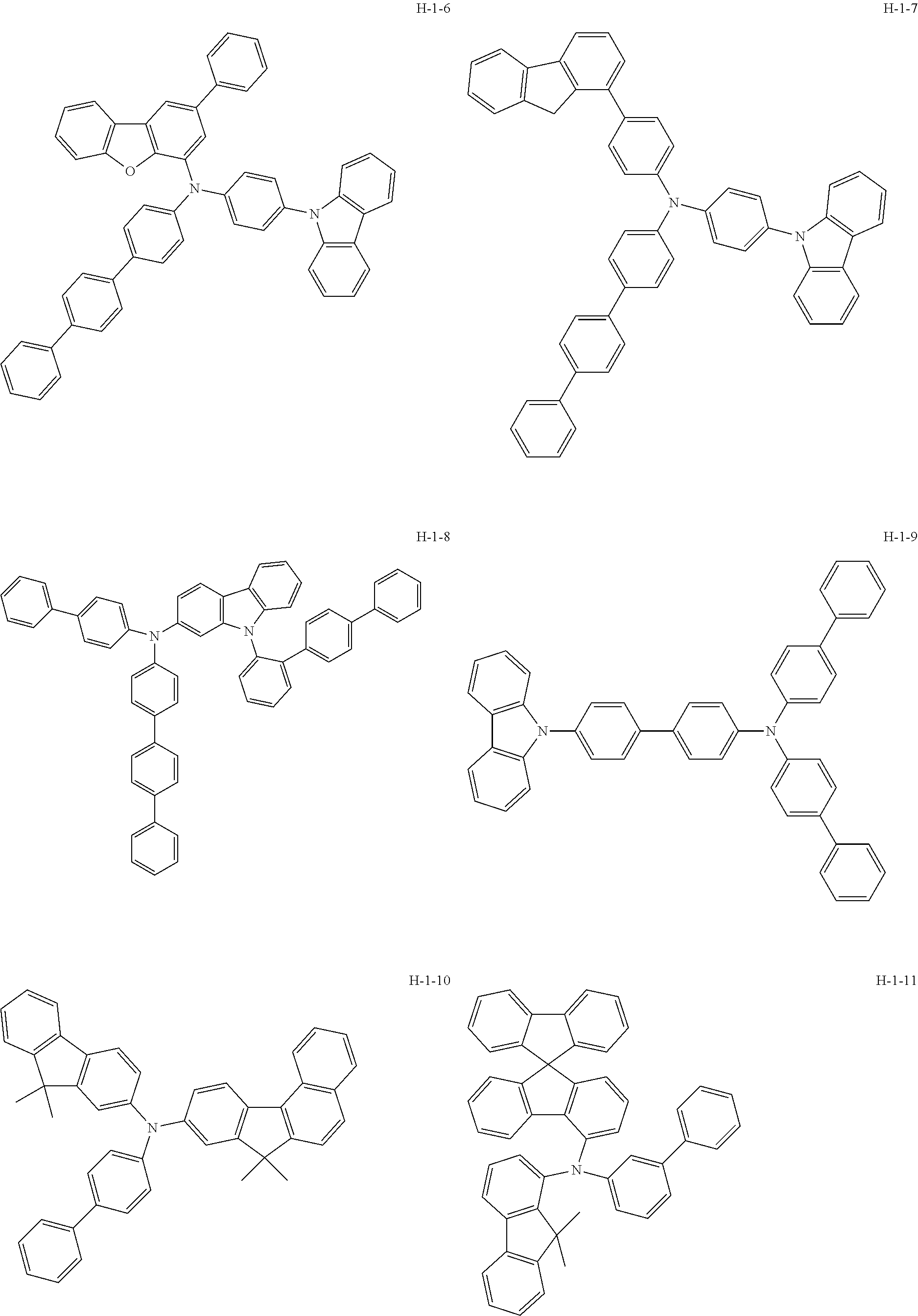

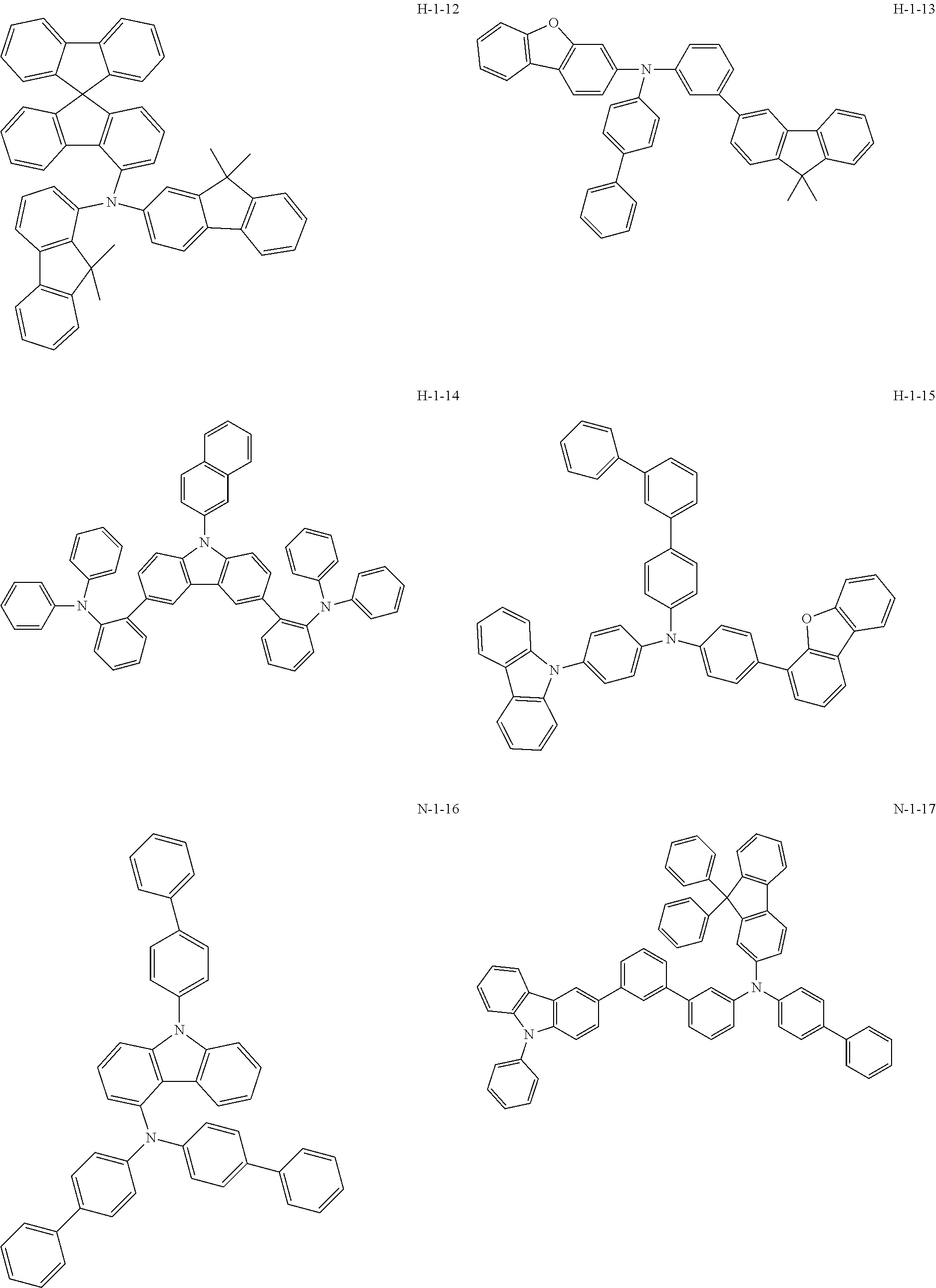

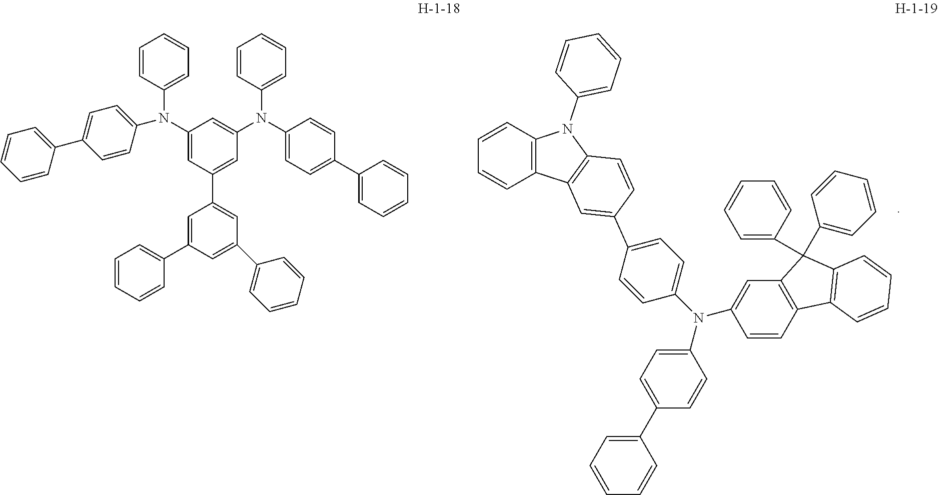 [SMILES: c1ccc(-c2ccc(N(c3ccccc3)c3cc(-c4cc(-c5ccccc5)cc(-c5ccccc5)c4)cc(N(c4ccccc4)c4ccc(-c5ccccc5)cc4)c3)cc2)cc1 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

The hole transport region HTR may include a phthalocyanine compound such as copper phthalocyanine, N¹,N¹′-([1,1′-biphenyl]-4,4′-diyl)bis(N¹-phenyl-N⁴,N⁴-di-m-tolylbenzene-1,4-diamine) (DNTPD), 4,4′,4″-[tris(3-methylphenyl)phenylamino]triphenylamine (m-MTDATA), 4,4′,4″-tris(N,N-diphenylamino)triphenylamine (TDATA), 4,4′,4″-tris[N(2-naphthyl)-N-phenylamino]-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonic acid (PANI/CSA), polyaniline/poly(4-styrenesulfonate) (PANI/PSS), N,N′-di(1-naphthalene-1-yl)-N,N′-diphenyl-benzidine (NPB), triphenylamine-containing polyetherketone (TPAPEK), 4-isopropyl-4′-methyldiphenyliodonium [tetrakis(pentafluorophenyl)borate], and dipyrazino[2,3-f:2′,3′-h] quinoxaline-2,3,6,7,10,11-hexacarbonitrile (HATCN).

In some embodiments, the hole transport region HTR may include carbazole derivatives such as N-phenyl carbazole and polyvinyl carbazole, fluorene-based derivatives, N,N′-bis(3-methylphenyl)-N,N′-diphenyl-[1,1′-biphenyl]-4,4′-diamine (TPD), triphenylamine-based derivatives such as 4,4′,4″-tris(N-carbazolyl)triphenylamine (TCTA), 4,4′-cyclohexylidene bis[N,N-bis(4-methylphenyl)benzeneamine] (TAPC), 4,4′-bis[N,N′-(3-tolyl)amino]-3,3′-dimethylbiphenyl (HMTPD), 9-(4-tert-butylphenyl)-3,6-bis(triphenylsilyl)-9H-carbazole (CzSi), 9-phenyl-9H-3,9′-bicarbazole (CCP), 1,3-bis(N-carbazolyl)benzene (mCP), or 1,3-bis(1,8-dimethyl-9H-carbazol-9-yl)benzene (mDCP), etc. The hole transport region HTR may include the compounds of the hole transport region in at least one among the hole injection layer HIL, hole transport layer HTL, electron blocking layer EBL and emission auxiliary layer EAL.

The thickness of the hole transport region HTR may be from about 50 Å to about 15,000 Å. The thickness of the hole transport region HTR may be from about 100 Å to about 10,000 Å, for example, from about 100 Å to about 5,000 Å. In case where the hole transport region HTR includes a hole injection layer HIL, the thickness of the hole injection region HIL may be, for example, from about 30 Å to about 1,000 Å. In case where the hole transport region HTR includes a hole transport layer HTL, the thickness of the hole transport layer HTL may be from about 30 Å to about 1,000 Å. For example, in case where the hole transport region HTR includes an electron blocking layer EBL, the thickness of the electron blocking layer EBL may be from about 10 Å to about 1,000 Å. When the thicknesses of the hole transport region HTR, the hole injection layer HIL, the hole transport layer HTL and the electron blocking layer EBL satisfy the above-described ranges, satisfactory hole transport properties may be achieved without a substantial increase of a driving voltage.

The hole transport region HTR may further include a charge generating material to increase conductivity, in addition to the above-described materials. The charge generating material may be dispersed uniformly or non-uniformly in the hole transport region HTR. The charge generating material may be, for example, a p-dopant. The p-dopant may include one or more metal halide compounds, quinone derivatives, metal oxides, and cyano group-containing compounds, without being limited thereto. For example, the p-dopant may include one or more metal halide compounds such as Cul and/or R_{b1}, quinone derivatives such as tetracyanoquinodimethane (TCNQ) and/or 2,3,5,6-tetrafluoro-7,7,8,8-tetracyanoquinodimethane (F4-TCNQ), metal oxides such as tungsten oxide and/or molybdenum oxide, cyano group-containing compounds such as dipyrazino[2,3-f: 2′,3′-h] quinoxaline-2,3,6,7,10,11-hexacarbonitrile (HATCN) and 4-[[2,3-bis[cyano-(4-cyano-2,3,5,6-tetrafluorophenyl)methylidene]cyclopropylidene]-cyanomethyl]-2,3,5,6-tetrafluorobenzonitrile (NDP9), etc., without being limited thereto.

As described above, the hole transport region HTR may further include at least one among an emission auxiliary layer EAL and an electron blocking layer EBL in addition to the hole injection layer HIL and the hole transport layer HTL. The emission auxiliary layer EAL may compensate resonance distance according to the wavelength of light emitted from an emission layer EML, may control hole charge balance and may increase light emission efficiency. In some embodiments, the emission auxiliary layer EAL may play the role of preventing the injection of electrons to the hole transport region HTR. As materials included in the emission auxiliary layer EAL, materials which may be included in the hole transport region HTR may be utilized. The electron blocking layer EBL is a layer playing the role of preventing or reducing the injection of electrons from the electron transport region ETR to the hole transport region HTR.

In the light emitting elements ED of embodiments, the electron transport region ETR may be provided on the emission layer EML. The electron transport region ETR may include at least one of a hole blocking layer HBL, an electron transport layer ETL or an electron injection layer EIL. However, an embodiment of the present disclosure is not limited thereto. The electron transport region ETR may have a single layer formed utilizing a single material, a single layer formed utilizing multiple different materials, or a multilayer structure having multiple layers formed utilizing multiple different materials.

For example, the electron transport region ETR may have a single layer structure of an electron injection layer EIL or an electron transport layer ETL, or a single layer structure formed utilizing an electron injection material and an electron transport material. Further, the electron transport region ETR may have a single layer structure formed utilizing multiple different materials, or a structure stacked from the emission layer EML of electron transport layer ETL/electron injection layer EIL, or hole blocking layer HBL/electron transport layer ETL/electron injection layer EIL, without being limited thereto. The thickness of the electron transport region ETR may be, for example, about 1000 Å to about 1500 Å.

The electron transport region ETR may be formed utilizing various suitable methods such as a vacuum deposition method, a spin coating method, a cast method, a Langmuir-Blodgett (LB) method, an inkjet printing method, a laser printing method, and/or a laser induced thermal imaging (LITI) method.

The electron transport region ETR may include the above-described third compound represented by Formula ET-1. The electron transport region ETR may include an anthracene-based compound. However, an embodiment of the present disclosure is not limited thereto. The electron transport region ETR may include, for example, tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazolyl-1-yl)phenyl)-9,10-dinaphthylanthracene, 1,3,5-tri(1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,O8)-(1,1′-biphenyl-4-olato)aluminum (BAlq), berylliumbis(benzoquinolin-10-olate (Bebq₂), 9,10-di(naphthalene-2-yl)anthracene (ADN), 1,3-bis[3,5-di(pyridin-3-yl)phenyl]benzene (BmPyPhB), and mixtures thereof, without being limited thereto.

In some embodiments, the electron transport region ETR may include a metal halide such as LiF, NaCl, CsF, RbCl, R_{b1}, Cul and/or Kl, a metal in lanthanides such as Yb, or a co-depositing material of the metal halide and the metal in lanthanides. For example, the electron transport region ETR may include Kl:Yb, Rbl:Yb, LiF:Yb, etc., as the co-depositing material. In some embodiments, the electron transport region ETR may utilize a metal oxide such as Li₂O and/or BaO, or 8-hydroxy-lithium quinolate (Liq). However, an embodiment of the present disclosure is not limited thereto. The electron transport region ETR also may be formed utilizing a mixture material of an electron transport material and an insulating organo metal salt. The organo metal salt may be a material having an energy band gap of about 4 eV or more. For example, the organo metal salt may include, for example, one or more metal acetates, metal benzoates, metal acetoacetates, metal acetylacetonates, and/or metal stearates.

The electron transport region ETR may include at least one of 2,9-dimethyl-4,7-diphenyl-1,10-phenanthroline (BCP), diphenyl(4-(triphenylsilyl)phenyl)phosphine oxide (TSPO1) or 4,7-diphenyl-1,10-phenanthroline (Bphen) in some embodiments to the aforementioned materials. However, an embodiment of the present disclosure is not limited thereto. The electron transport region ETR may include the compounds of the electron transport region in at least one among an electron injection layer EIL, an electron transport layer ETL, and a hole blocking layer HBL.

When the electron transport region ETR includes the electron transport layer ETL, the thickness of the electron transport layer ETL may be from about 100 Å to about 1,000 Å, for example, from about 150 Å to about 500 Å. When the thickness of the electron transport layer ETL satisfies the above-described ranges, satisfactory electron transport properties may be obtained without substantial increase of a driving voltage. When the electron transport region ETR includes the electron injection layer EIL, the thickness of the electron injection layer EIL may be from about 1 Å to about 100 Å, or from about 3 Å to about 90 Å. When the thickness of the electron injection layer EIL satisfies the above described range, satisfactory electron injection properties may be obtained without inducing substantial increase of a driving voltage.

The second electrode EL2 is provided on the electron transport region ETR. The second electrode EL2 may be a common electrode. The second electrode EL2 may be a cathode or an anode, but an embodiment of the present disclosure is not limited thereto. For example, when the first electrode EL1 is an anode, the second electrode EL2 may be a cathode, and when the first electrode EL1 is a cathode, the second electrode EL2 may be an anode. The second electrode EL2 may include at least one selected among Ag, Mg, Cu, Al, Pt, Pd, Au, Ni, Nd, Ir, Cr, Li, Ca, LiF, Mo, Ti, W, In, Sn, and Zn, compounds of two or more selected therefrom, mixtures of two or more selected therefrom, or oxides thereof.

The second electrode EL2 may be a transmissive electrode, a transflective electrode or a reflective electrode. When the second electrode EL2 is the transmissive electrode, the second electrode EL2 may include a transparent metal oxide, for example, ITO, IZO, ZnO, ITZO, etc.

When the second electrode EL2 is the transflective electrode or the reflective electrode, the second electrode EL2 may include Ag, Mg, Cu, Al, Pt, Pd, Au, Ni, Nd, Ir, Cr, Li, Ca, LiF/Ca, LiF/Al, Mo, Ti, Yb, W, compounds including thereof, or mixtures thereof (for example, AgMg, AgYb, or MgYb). In an embodiment, the second electrode EL2 may have a multilayered structure including a reflective layer or a transflective layer formed utilizing the above-described materials and a transparent conductive layer formed utilizing ITO, IZO, ZnO, ITZO, etc. For example, the second electrode EL2 may include the aforementioned metal materials, combinations of two or more metal materials selected from the aforementioned metal materials, or oxides of the aforementioned metal materials.

In some embodiments, the second electrode EL2 may be connected with an auxiliary electrode. When the second electrode EL2 is connected with the auxiliary electrode, the resistance of the second electrode EL2 may decrease.

In some embodiments, on the second electrode EL2 in the light emitting element ED of an embodiment, a capping layer CPL may be further disposed. The capping layer CPL may include a multilayer or a single layer.

In an embodiment, the capping layer CPL may be an organic layer or an inorganic layer. For example, when the capping layer CPL includes an inorganic material, the inorganic material may include an alkali metal compound such as LiF, an alkaline earth metal compound such as SiON, SiNₓ, SiO_{y}, etc.

For example, when the capping layer CPL includes an organic material, the organic material may include α-NPD, NPB, TPD, m-MTDATA, Alq₃, CuPc, N4,N4,N4′,N4′-tetra(biphenyl-4-yl) biphenyl-4,4′-diamine (TPD15), 4,4′,4″-tris(carbazol-9-yl) triphenylamine (TCTA), etc., and/or an epoxy resin, and/or acrylate such as methacrylate. In some embodiments, a capping layer CPL may include at least one among Compounds P1 to P5 below, but an embodiment of the present disclosure is not limited thereto.

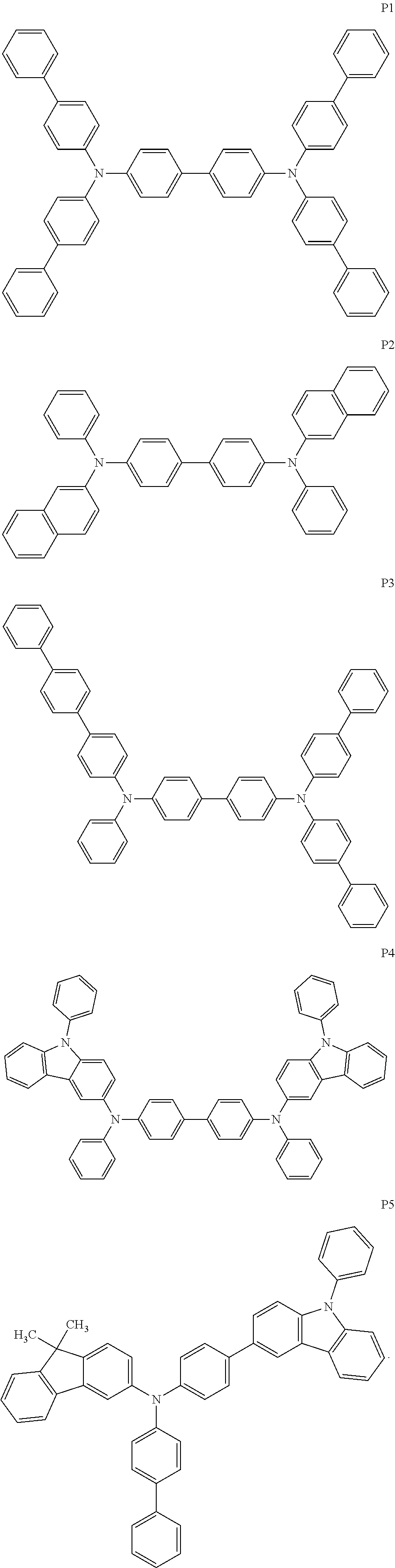 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; CC1(C)c2ccccc2-c2cc(N(c3ccc(-c4ccccc4)cc3)c3ccc(-c4ccc5c(c4)c4ccccc4n5-c4ccccc4)cc3)ccc21]

In some embodiments, the refractive index of the capping layer CPL may be about 1.6 or more. For example, the refractive index of the capping layer CPL with respect to light in a wavelength range of about 550 nm to about 660 nm may be about 1.6 or more.

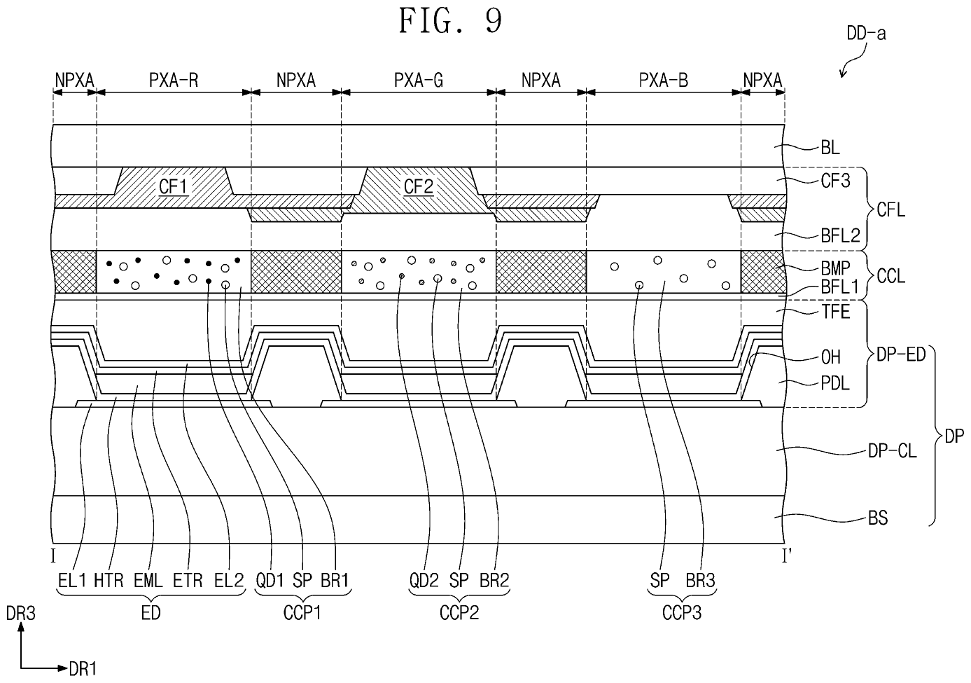

FIG. 9 to FIG. 12 are cross-sectional views on display devices according to embodiments. Hereinafter, in the explanation on the display devices of embodiments, referring to FIG. 9 to FIG. 12, the overlapping parts with the explanation on FIG. 1 to FIG. 7 will not be explained again, and the different features will be mainly explained.

Referring to FIG. 9, a display device DD-a according to an embodiment may include a display panel DP including a display element layer DP-ED, a light controlling layer CCL disposed on the display panel DP, and a color filter layer CFL. In an embodiment shown in FIG. 9, the display panel DP includes a base layer BS, a circuit layer DP-CL provided on the base layer BS and a display element layer DP-ED, and the display element layer DP-ED may include a light emitting element ED.

The light emitting element ED may include a first electrode EL1, a hole transport region HTR disposed on the first electrode EL1, an emission layer EML disposed on the hole transport region HTR, an electron transport region ETR disposed on the emission layer EML, and a second electrode EL2 disposed on the electron transport region ETR. In the light emitting element ED shown in FIG. 9, the emission layer EML may include the fused polycyclic compound of an embodiment. In some embodiments, the emission layer EML may include at least one among the second to fourth compounds. The structures of the light emitting elements of FIG. 3 to FIG. 7 may be applied to the structure of the light emitting element ED shown in FIG. 9.

Referring to FIG. 9, the emission layer EML may be disposed in an opening portion OH defined in a pixel definition layer PDL. For example, the emission layer EML divided by the pixel definition layer PDL and correspondingly provided to each of luminous areas PXA-R, PXA-G and PXA-B may emit light in substantially the same wavelength region. In the display device DD-a of an embodiment, the emission layer EML may emit blue light. In some embodiments, different from the drawings, in an embodiment, the emission layer EML may be provided as a common layer for all luminous areas PXA-R, PXA-G and PXA-B.

The light controlling layer CCL may be disposed on the display panel DP. The light controlling layer CCL may include a light converter. The light converter may be a quantum dot or a phosphor. The light converter may transform the wavelength of light provided and then emit. For example, the light controlling layer CCL may be a layer including a quantum dot or a layer including a phosphor.

The light controlling layer CCL may include multiple light controlling parts CCP1, CCP2 and CCP3. The light controlling parts CCP1, CCP2 and CCP3 may be separated from one another.

Referring to FIG. 9, a partition pattern BMP may be disposed between the separated light controlling parts CCP1, CCP2 and CCP3, but an embodiment of the present disclosure is not limited thereto. In FIG. 9, the partition pattern BMP is shown to not overlap with the light controlling parts CCP1, CCP2 and CCP3, but in some embodiments, at least a portion of the edge of the light controlling parts CCP1, CCP2 and CCP3 may overlap with the partition pattern BMP.

The light controlling layer CCL may include a first light controlling part CCP1 including a first quantum dot QD1 converting a first color light provided from the light emitting element ED into a second color light, a second light controlling part CCP2 including a second quantum dot QD2 converting the first color light into a third color light, and a third light controlling part CCP3 transmitting the first color light.

In an embodiment, the first light controlling part CCP1 may provide red light which is the second color light, and the second light controlling part CCP2 may provide green light which is the third color light. The third color controlling part CCP3 may transmit and provide blue light which is the first color light provided from the light emitting element ED. For example, the first quantum dot QD1 may be a red quantum dot, and the second quantum dot QD2 may be a green quantum dot. The quantum dots QD1 and QD2 may be the same as those described above.

In some embodiments, the light controlling layer CCL may further include a scatterer SP. The first light controlling part CCP1 may include the first quantum dot QD1 and the scatterer SP, the second light controlling part CCP2 may include the second quantum dot QD2 and the scatterer SP, and the third light controlling part CCP3 may not include a quantum dot but include the scatterer SP.

The scatterer SP may be an inorganic particle. For example, the scatterer SP may include at least one among TiO₂, ZnO, Al₂O₃, SiO₂, and hollow silica. The scatterer SP may include at least one among TiO₂, ZnO, Al₂O₃, SiO₂, and hollow silica, or may be a mixture of two or more materials selected among TiO₂, ZnO, Al₂O₃, SiO₂, and hollow silica.

Each of the first light controlling part CCP1, the second light controlling part CCP2, and the third light controlling part CCP3 may include a corresponding one of the base resins BR1, BR2 and BR3 for dispersing the quantum dots QD1 and QD2 and the scatterer SP. In an embodiment, the first light controlling part CCP1 may include the first quantum dot QD1 and the scatterer SP dispersed in the first base resin BR1, the second light controlling part CCP2 may include the second quantum dot QD2 and the scatterer SP dispersed in the second base resin BR2, and the third light controlling part CCP3 may include the scatterer particle SP dispersed in the third base resin BR3.

The base resins BR1, BR2 and BR3 are mediums in which the quantum dots QD1 and QD2 and the scatterer SP are dispersed, and may be composed of various suitable resin compositions which may be generally referred to as a binder. For example, the base resins BR1, BR2 and BR3 may be acrylic resins, urethane-based resins, silicone-based resins, epoxy-based resins, etc. The base resins BR1, BR2 and BR3 may be transparent resins. In an embodiment, the first base resin BR1, the second base resin BR2 and the third base resin BR3 may be the same or different from each other.

The light controlling layer CCL may include a barrier layer BFL1. The barrier layer BFL1 may play the role of blocking the penetration of moisture and/or oxygen (hereinafter, will be referred to as “humidity/oxygen”). The barrier layer BFL1 may block the exposure of the light controlling parts CCP1, CCP2 and CCP3 to humidity/oxygen. In some embodiments, the barrier layer BFL1 may cover the light controlling parts CCP1, CCP2 and CCP3. In some embodiments, the barrier layer BFL2 may be provided between the light controlling parts CCP1, CCP2 and CCP3 and a color filter layer CFL (e.g., along the thickness direction).

The barrier layers BFL1 and BFL2 may include at least one inorganic layer. For example, the barrier layers BFL1 and BFL2 may be formed by including an inorganic material. For example, the barrier layers BFL1 and BFL2 may be formed by including silicon nitride, aluminum nitride, zirconium nitride, titanium nitride, hafnium nitride, tantalum nitride, silicon oxide, aluminum oxide, titanium oxide, tin oxide, cerium oxide and silicon oxynitride and/or a metal thin film for securing light transmittance. In some embodiments, the barrier layers BFL1 and BFL2 may further include an organic layer. The barrier layers BFL1 and BFL2 may be composed of a single layer or multiple layers.

In the display device DD-a of an embodiment, the color filter layer CFL may be disposed on the light controlling layer CCL. For example, the color filter layer CFL may be disposed directly on the light controlling layer CCL. In this case, the barrier layer BFL2 may be omitted.

The color filter layer CFL may include filters CF1, CF2 and CF3. The color filter layer CFL may include a first filter CF1 for transmitting second color light, a second filter CF2 for transmitting third color light, and a third filter CF3 for transmitting first color light. The first to third filters CF1, CF2 and CF3 may be disposed correspondingly to the red luminous area PXA-R, green luminous area PXA-G and blue luminous area PXA-B, respectively.

For example, the first filter CF1 may be a red filter, the second filter CF2 may be a green filter, and the third filter CF3 may be a blue filter. Each of the filters CF1, CF2 and CF3 may include a polymer photosensitive resin and a pigment and/or dye. The first filter CF1 may include a red pigment and/or dye, the second filter CF2 may include a green pigment and/or dye, and the third filter CF3 may include a blue pigment and/or dye. However, an embodiment of the present disclosure is not limited thereto, and the third filter CF3 may not include any pigment or dye. The third filter CF3 may include a polymer photosensitive resin and not include any pigment or dye. The third filter CF3 may be transparent. The third filter CF3 may be formed utilizing a transparent photosensitive resin.

In some embodiments, in an embodiment, the first filter CF1 and the second filter CF2 may be yellow filters. The first filter CF1 and the second filter CF2 may be provided in one body without distinction.

In some embodiments, the color filter layer CFL may further include a light blocking part (not shown). The light blocking part may be a black matrix. The light blocking part may be formed by including an organic light blocking material or an inorganic light blocking material, including a black pigment and/or black dye. The light blocking part may prevent or reduce light leakage and may divide the boundaries among adjacent filters CF1, CF2 and CF3.

On the color filter layer CFL, a base substrate BL may be disposed. The base substrate BL may be a member for providing a base surface on which the color filter layer CFL, the light controlling layer CCL, etc. are disposed. The base substrate BL may be a glass substrate, a metal substrate, a plastic substrate, etc. However, an embodiment of the present disclosure is not limited thereto, and the base substrate BL may be an inorganic layer, an organic layer or a composite material layer. In some embodiments, different from the drawing, the base substrate BL may be omitted in an embodiment.

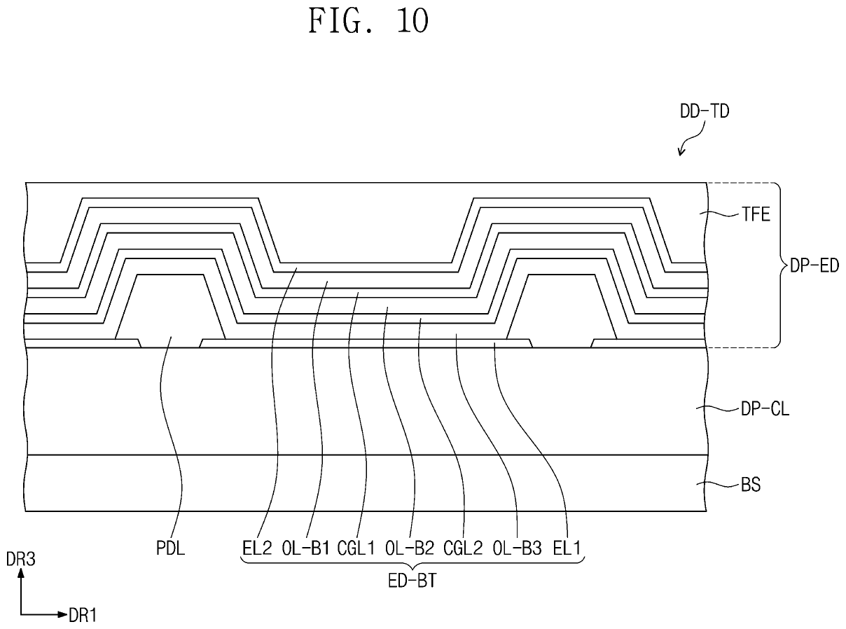

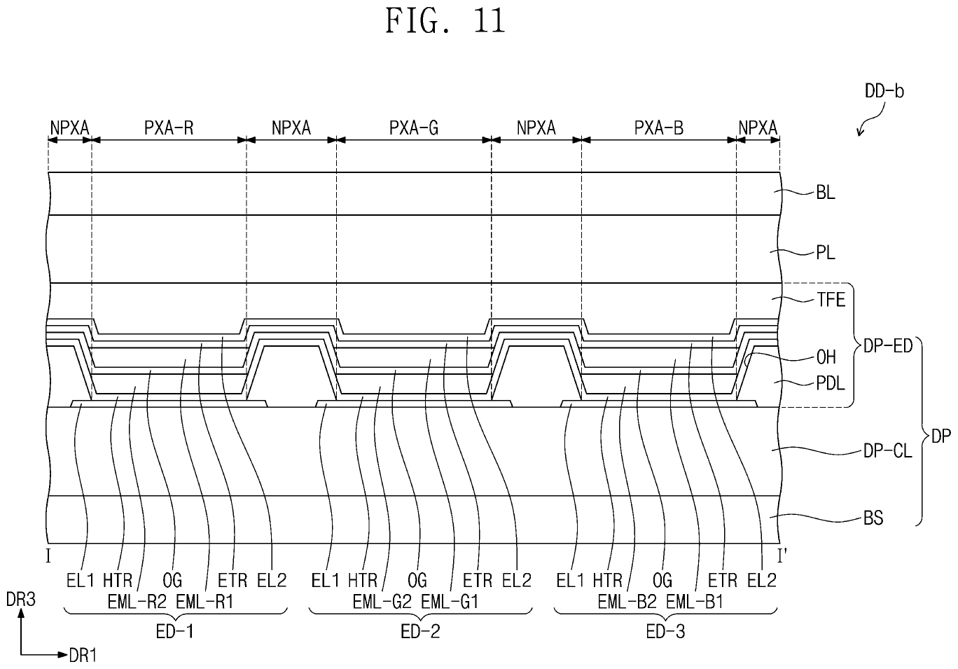

FIG. 10 is a cross-sectional view showing a part of the display device according to an embodiment. FIG. 10 shows another embodiment of a part corresponding to the display panel DP in FIG. 9. In a display device DD-TD of an embodiment, the light emitting element ED-BT may include multiple light emitting structures OL-B1, OL-B2 and OL-B3. The light emitting element ED-BT may include oppositely disposed first electrode EL1 and second electrode EL2, and the multiple light emitting structures OL-B1, OL-B2 and OL-B3 stacked in the stated order in a thickness direction and provided between the first electrode EL1 and the second electrode EL2. At least one among multiple light emitting structures OL-B1, OL-B2 and OL-B3 may include the fused polycyclic compound of an embodiment and at least one among the second to fourth compounds.

Each of the light emitting structures OL-B1, OL-B2 and OL-B3 may include an emission layer EML (FIG. 9), and a hole transport region HTR and an electron transport region ETR disposed with the emission layer EML (FIG. 9) therebetween. For example, the light emitting element ED-BT included in the display device DD-TD of an embodiment may be a light emitting element of a tandem structure including multiple emission layers.

In an embodiment shown in FIG. 10, light emitted from the light emitting structures OL-B1, OL-B2 and OL-B3 may all be blue light. However, an embodiment of the present disclosure is not limited thereto, and the wavelength regions of light emitted from the light emitting structures OL-B1, OL-B2 and OL-B3 may be different from each other. For example, the light emitting element ED-BT including the multiple light emitting structures OL-B1, OL-B2 and OL-B3 emitting light in different wavelength regions may emit white light.

Between neighboring light emitting structures OL-B1, OL-B2 and OL-B3, charge generating layers CGL1 and CGL2 may be disposed. The charge generating layers CGL1 and CGL2 may include a p-type or kind charge generating layer and/or an n-type or kind charge generating layer.

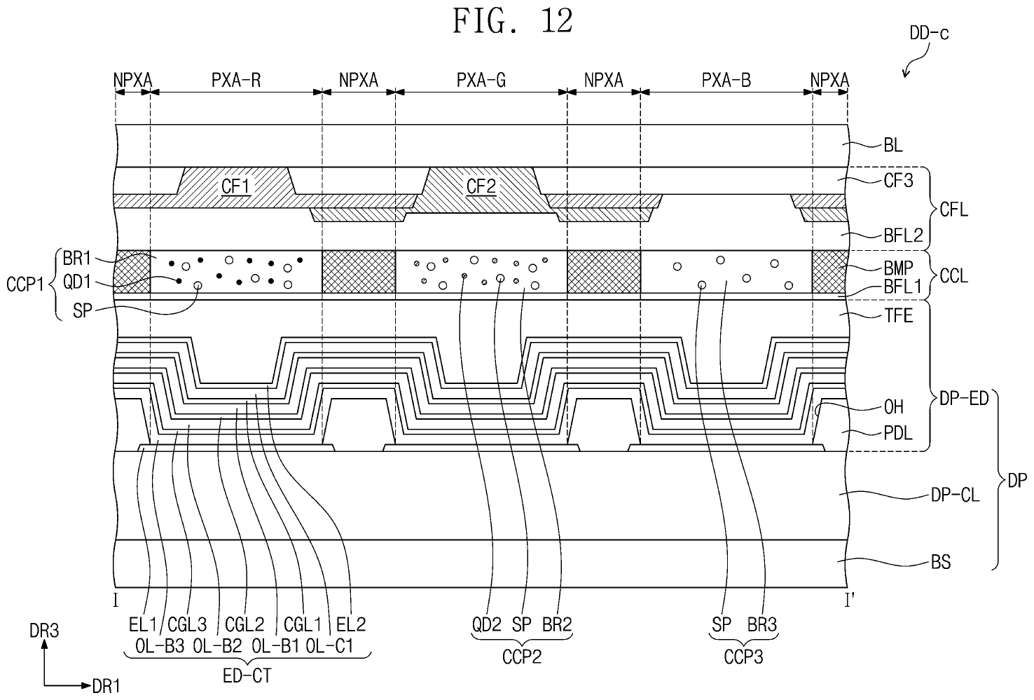

Referring to FIG. 11, a display device DD-b according to an embodiment may include light emitting elements ED-1, ED-2 and ED-3, formed by stacking two emission layers. Compared to the display device DD of an embodiment, shown in FIG. 2, an embodiment shown in FIG. 11 is different in that the first to third light emitting elements ED-1, ED-2 and ED-3 each include two emission layers stacked in a thickness direction. In the first to third light emitting elements ED-1, ED-2 and ED-3, the two emission layers may emit light in substantially the same wavelength region. At least one among the first to third light emitting elements ED-1, ED-2 and ED-3 may include the fused polycyclic compound of an embodiment and at least one among the second to fourth compounds.

The first light emitting element ED-1 may include a first red emission layer EML-R1 and a second red emission layer EML-R2. The second light emitting element ED-2 may include a first green emission layer EML-G1 and a second green emission layer EML-G2. In some embodiments, the third light emitting element ED-3 may include a first blue emission layer EML-B1 and a second blue emission layer EML-B2. Between the first red emission layer EML-R1 and the second red emission layer EML-R2, between the first green emission layer EML-G1 and the second green emission layer EML-G2, and between the first blue emission layer EML-B1 and the second blue emission layer EML-B2, an emission auxiliary part OG may be disposed.

The emission auxiliary part OG may include a single layer or a multilayer. The emission auxiliary part OG may include a charge generating layer. For example, the emission auxiliary part OG may include an electron transport region, a charge generating layer, and a hole transport region stacked in the stated order. The emission auxiliary part OG may be provided as a common layer in all of the first to third light emitting elements ED-1, ED-2 and ED-3. However, an embodiment of the present disclosure is not limited thereto, and the emission auxiliary part OG may be patterned and provided in an opening portion OH defined in a pixel definition layer PDL.

The first red emission layer EML-R1, the first green emission layer EML-G1 and the first blue emission layer EML-B1 may be disposed between the emission auxiliary part OG and the electron transport region ETR. The second red emission layer EML-R2, the second green emission layer EML-G2 and the second blue emission layer EML-B2 may be disposed between the hole transport region HTR and the emission auxiliary part OG.

For example, the first light emitting element ED-1 may include the first electrode EL1, the hole transport region HTR, the second red emission layer EML-R2, the emission auxiliary part OG, the first red emission layer EML-R1, the electron transport region ETR, and the second electrode EL2, stacked in the stated order. The second light emitting element ED-2 may include the first electrode EL1, the hole transport region HTR, the second green emission layer EML-G2, the emission auxiliary part OG, the first green emission layer EML-G1, the electron transport region ETR, and the second electrode EL2, stacked in the stated order. The third light emitting element ED-3 may include the first electrode EL1, the hole transport region HTR, the second blue emission layer EML-B2, the emission auxiliary part OG, the first blue emission layer EML-B1, the electron transport region ETR, and the second electrode EL2, stacked in the stated order.

In some embodiments, an optical auxiliary layer PL may be disposed on a display element layer DP-ED. The optical auxiliary layer PL may include a polarization layer. The optical auxiliary layer PL may be disposed on a display panel DP and may control reflected light at the display panel DP by external light. Different from the drawings, the optical auxiliary layer PL may be omitted from the display device according to an embodiment.

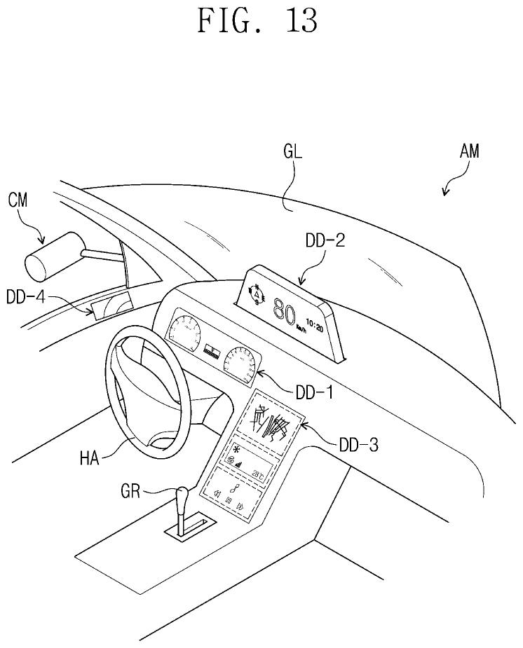

Different from FIG. 10 and FIG. 11, a display device DD-c in FIG. 12 is shown to include four light emitting structures OL-B1, OL-B2, OL-B3 and OL-C1. A light emitting element ED-CT may include oppositely disposed first electrode EL1 and second electrode EL2, and first to fourth light emitting structures OL-B1, OL-B2, OL-B3 and OL-C1 stacked in the stated order in a thickness direction between the first electrode EL1 and the second electrode EL2. At least one among the first to fourth light emitting structures OL-B1, OL-B2, OL-B3 and OL-C1 may include the fused polycyclic compound of an embodiment and at least one among the second to fourth compounds.

Among the four light emitting structures, the first to third light emitting structures OL-B1, OL-B2 and OL-B3 may emit blue light, and the fourth light emitting structure OL-C1 may emit green light. However, an embodiment of the present disclosure is not limited thereto, and the first to fourth light emitting structures OL-B1, OL-B2, OL-B3 and OL-C1 may emit different wavelengths of light.

Charge generating layers CGL1, CGL2 and CGL3 may be disposed among the third light emitting structure OL-B3, the second light emitting structure OL-B2, the first light emitting structure OL-B1, and the fourth light emitting structure OL-C1. The charge generating layers CGL1, CGL2 and CGL3 disposed between neighboring light emitting structures OL-B1, OL-B2, OL-B3, OL-C1 may include a p-type or kind charge generating layer and/or an n-type or kind charge generating layer.

FIG. 13 is a diagram showing an automobile AM in which first to fourth display devices DD-1, DD-2, DD-3 and DD-4 are disposed. At least one among the first to fourth display devices DD-1, DD-2, DD-3 and DD-4 may include the same configurations of the display devices DD, DD-TD, DD-a, DD-b and DD-c of embodiments, explained referring to FIGS. 1, 2, and 9 to 12.

In FIG. 13, a vehicle is shown as an automobile AM, but this is an illustration, and the first to fourth display devices DD-1, DD-2, DD-3 and DD-4 may be disposed on other transportation device such as bicycles, motorcycles, trains, ships and/or airplanes. In some embodiments, at least one among the first to fourth display devices DD-1, DD-2, DD-3 and DD-4 including the same configurations of the display devices DD, DD-TD, DD-a, DD-b and DD-c may be introduced in personal computers, laptop computers, personal digital terminals, game consoles, portable electronic devices, televisions, monitors, external billboards, and/or the like. However these are suggested as examples, and the display device may be introduced in other electronic equipment as long as not deviated from the subject matter of the present disclosure.

At least one among the first to fourth display devices DD-1, DD-2, DD-3 and DD-4 may include the light emitting elements ED of embodiments, explained by referring to FIG. 3 to FIG. 7. In the light emitting element ED of an embodiment, the emission layer EML may include the fused polycyclic compound of an embodiment. In some embodiments, the emission layer EML may include at least one among the second to fourth compounds. At least one among the first to fourth display devices DD-1, DD-2, DD-3 and DD-4 may include the light emitting element ED including the fused polycyclic compound of an embodiment, thereby showing improved display efficiency and display lifetime.

Referring to FIG. 13, an automobile AM may include a steering wheel HA for the operation of the automobile AM and a gear GR and a front window GL disposed to face a driver.

A first display device DD-1 may be disposed in a first region overlapping with the steering wheel HA. For example, the first display device DD-1 may be a digital cluster displaying the first information of the automobile AM. The first information may include a first graduation showing the running speed of the automobile AM, a second graduation showing the number of revolution of an engine (i.e., revolutions per minute (RPM)), and/or images showing a fuel state. The first graduation and the second graduation may be represented by digital images.

A second display device DD-2 may be disposed in a second region facing a driver's seat and overlapping with the front window GL. The driver's seat may be a seat where the steering wheel HA is disposed. For example, the second display device DD-2 may be a head up display (HUD) showing the second information of the automobile AM. The second display device DD-2 may be optically clear. The second information may include digital numbers showing the running speed of the automobile AM and may further include information including the current time. In an embodiment and different from the drawing, the second information of the second display device DD-2 may be projected and displayed on the front window GL.

A third display device DD-3 may be disposed in a third region adjacent to the gear GR. For example, the third display device DD-3 may be a center information display (CID) for an automobile, disposed between a driver's seat and a passenger seat and showing a third information. The passenger seat may be a seat separated from the driver's seat with the gear GR therebetween. The third information may include information on road conditions (for example, navigation information), on playing music or radio, on playing a dynamic image (or image), on the temperature in the automobile AM, and/or the like.

A fourth display device DD-4 may be disposed in a fourth region separated from the steering wheel HA and the gear GR and adjacent to the side of the automobile AM. For example, the fourth display device DD-4 may be a digital wing mirror displaying a fourth information. The fourth display device DD-4 may display the external image of the automobile AM, taken by a camera module CM disposed at the outside of the automobile AM. The fourth information may include the external image of the automobile AM.

The above-described first to fourth information is for illustration, and the first to fourth display devices DD-1, DD-2, DD-3 and DD-4 may further display information on the inside and outside of the automobile. The first to fourth information may include different information from each other. However, an embodiment of the present disclosure is not limited thereto, and a portion of the first to fourth information may include the same information.

Hereinafter, the fused polycyclic compound according to an embodiment and the light emitting element according to an embodiment of the present disclosure will be explained referring to embodiments and comparative embodiments. In some embodiments, the embodiments below are only illustrations to assist the understanding of the present disclosure, and the scope of the present disclosure is not limited thereto.

### Examples

### 1. Synthesis of Fused Polycyclic Compounds of Embodiments

The synthetic method of the fused polycyclic compound according to an embodiment will be explained in particular illustrating the synthetic methods of Compounds 8, 13, 18, 32, 45, 49 and 66. In addition, the synthetic methods of the fused polycyclic compounds explained hereinafter are embodiments, and the synthetic method of the compound according to an embodiment of the present disclosure is not limited to the Examples below.

### (1) Synthesis of Fused Polycyclic Compound 8

Fused Polycyclic Compound 8 according to an embodiment may be synthesized by, for example, the acts (e.g., steps) of Reaction 1 below.

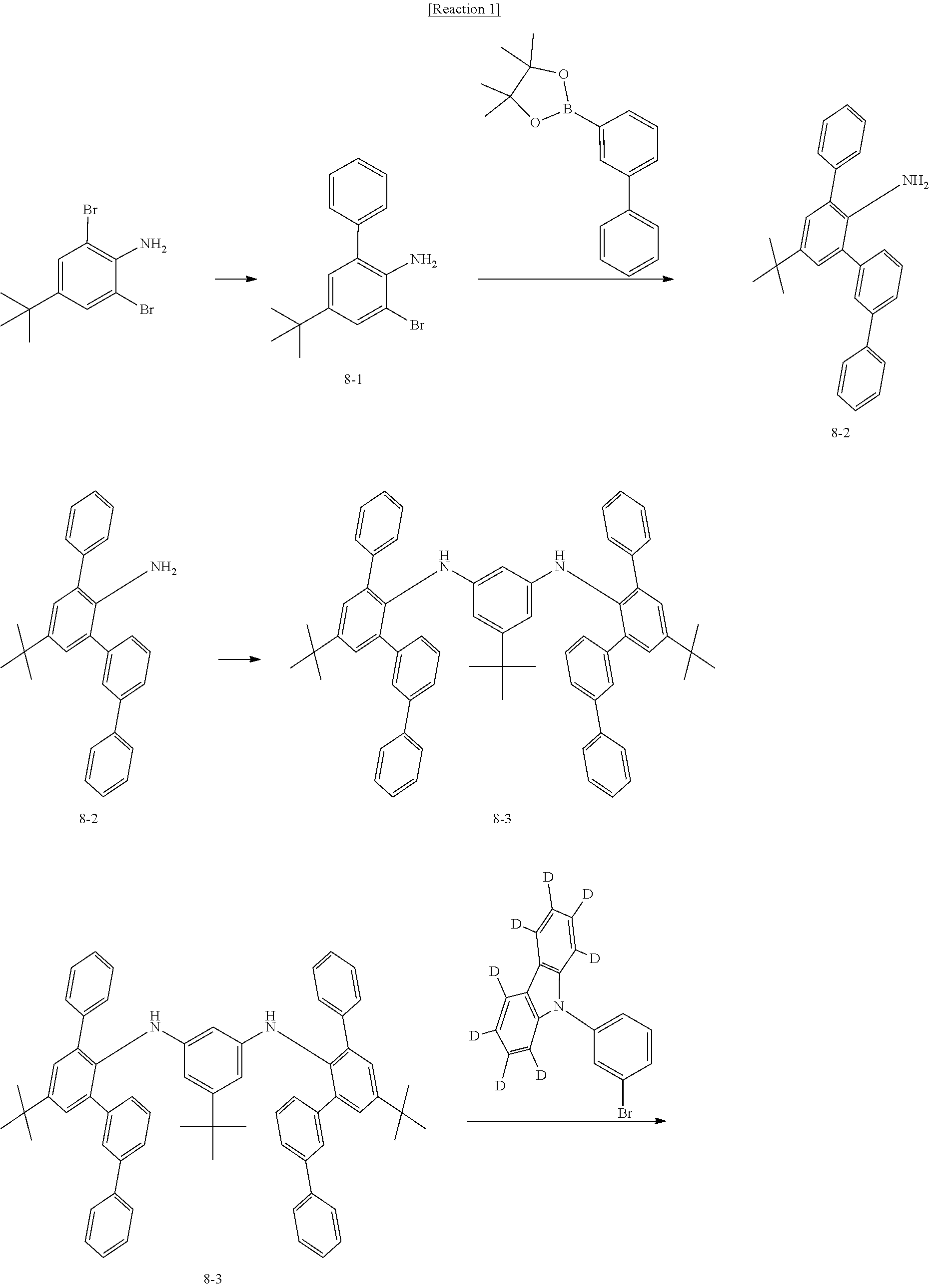

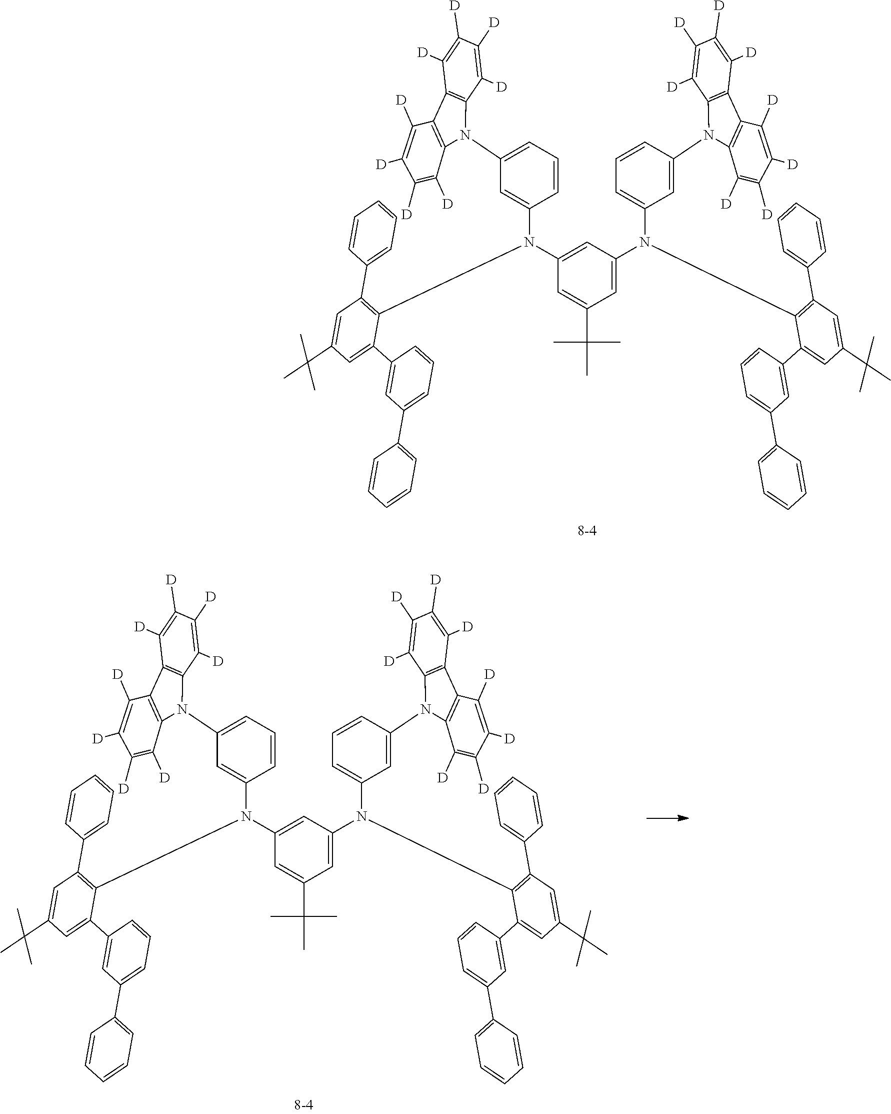

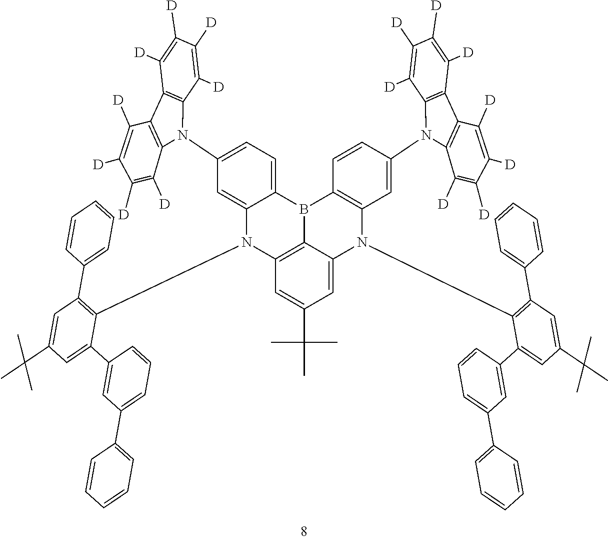 [SMILES: [2H]c1c([2H])c([2H])c2c(c1[2H])c1c([2H])c([2H])c([2H])c([2H])c1n2-c1ccc2c(c1)N(c1c(-c3ccccc3)cc(C(C)(C)C)cc1-c1cccc(-c3ccccc3)c1)c1cc(C(C)(C)C)cc3c1B2c1ccc(-n2c4c([2H])c([2H])c([2H])c([2H])c4c4c([2H])c([2H])c([2H])c([2H])c42)cc1N3c1c(-c2ccccc2)cc(C(C)(C)C)cc1-c1cccc(-c2ccccc2)c1]

### Synthesis of Intermediate 8-1

After dissolving 2,6-dibromo-4-(tert-butyl)aniline (1 eq), phenylboronic acid (0.7 eq), Pd(PPh₃)₄ (0.05 eq), and K₂CO₃ (3 eq) in a mixture solution of water and THF of 1:2 (volume ratio), the reactants were stirred at about 80 degrees centigrade (° C.) for about 6 hours. After cooling, the resultant was washed with ethyl acetate and water three times and subjected to layer separation to obtain an organic layer. The organic layer thus obtained was dried over MgSO₄, and dried under a reduced pressure. The resultant was purified by column chromatography utilizing methylene chloride (MC) and n-hexane to obtain Intermediate 8-1 (yield: 47%).

### Synthesis of Intermediate 8-2

After dissolving Intermediate 8-1 (1 eq), 2-([1,1′-biphenyl]-3-yl)-4,4,5,5-tetramethyl-1,3,2-dioxaborolane (1.5 eq), Pd(PPh₃)₄ (0.05 eq), and K₂CO₃ (3 eq) in a mixture solution of water and THF of 1:2 (volume ratio), the reactants were stirred at about 90 degrees centigrade (° C.) for about 24 hours. After cooling, the resultant was washed with ethyl acetate and water three times and subjected to layer separation to obtain an organic layer. The organic layer thus obtained was dried over MgSO₄, and dried under a reduced pressure. The resultant was purified by column chromatography utilizing MC and n-hexane to obtain Intermediate 8-2 (yield: 78%).

### Synthesis of Intermediate 8-3

After dissolving 1,3-dibromo-5-(tert-butyl)benzene (1 eq), Intermediate 8-2 (2 eq), tris(dibenzylideneacetone)dipalladium(0) (0.05 eq), tri-tert-butylphosphine (0.1 eq), and sodium tert-butoxide (3 eq) in o-xylene, the reactants were stirred at about 140 degrees centigrade (° C.) for about 12 hours. After cooling, the resultant was washed with ethyl acetate and water three times and subjected to layer separation to obtain an organic layer. The organic layer thus obtained was dried over MgSO₄, and dried under a reduced pressure. The resultant was purified by column chromatography utilizing MC and n-hexane to obtain Intermediate 8-3 (yield: 61%).

### Synthesis of Intermediate 8-4

After dissolving Intermediate 8-3 (1 eq), 9-(3-bromophenyl)-9H-carbazole-1,2,3,4,5,6,7,8-d8 (2.5 eq), tris(dibenzylideneacetone)dipalladium(0) (0.25 eq), tri-tert-butylphosphine (0.4 eq), and sodium tert-butoxide (5 eq) in o-xylene, the reactants were stirred at about 160 degrees centigrade (° C.) for about 72 hours. After cooling, the resultant was washed with ethyl acetate and water three times and subjected to layer separation to obtain an organic layer. The organic layer thus obtained was dried over MgSO₄, and dried under a reduced pressure. The resultant was purified by column chromatography utilizing MC and n-hexane to obtain Intermediate 8-4 (yield: 38%).

### Synthesis of Compound 8

Intermediate 8-4 (1 eq) was dissolved in o-dichlorobenzene and cooled to 0 degrees centigrade (° C.), and BBr₃ (3 eq) was slowly injected thereto under a nitrogen atmosphere. After finishing the dropwise addition, the temperature was raised to about 180 degrees centigrade (° C.), and stirring was performed for about 48 hours. After cooling, triethylamine was added to a flask containing the reaction product slowly and dropwisely to terminate the reaction, ethyl alcohol was added to precipitate the reaction product, and the precipitate was filtered to obtain a solid content (e.g., material). The solid content thus obtained was purified by column chromatography utilizing MC and n-hexane and recrystallized utilizing toluene and acetone to obtain Compound 8 (yield: 3%).

### (2) Synthesis of Fused Polycyclic Compound 13

Fused Polycyclic Compound 13 according to an embodiment may be synthesized by, for example, the acts (e.g., steps) of Reaction 2 below.

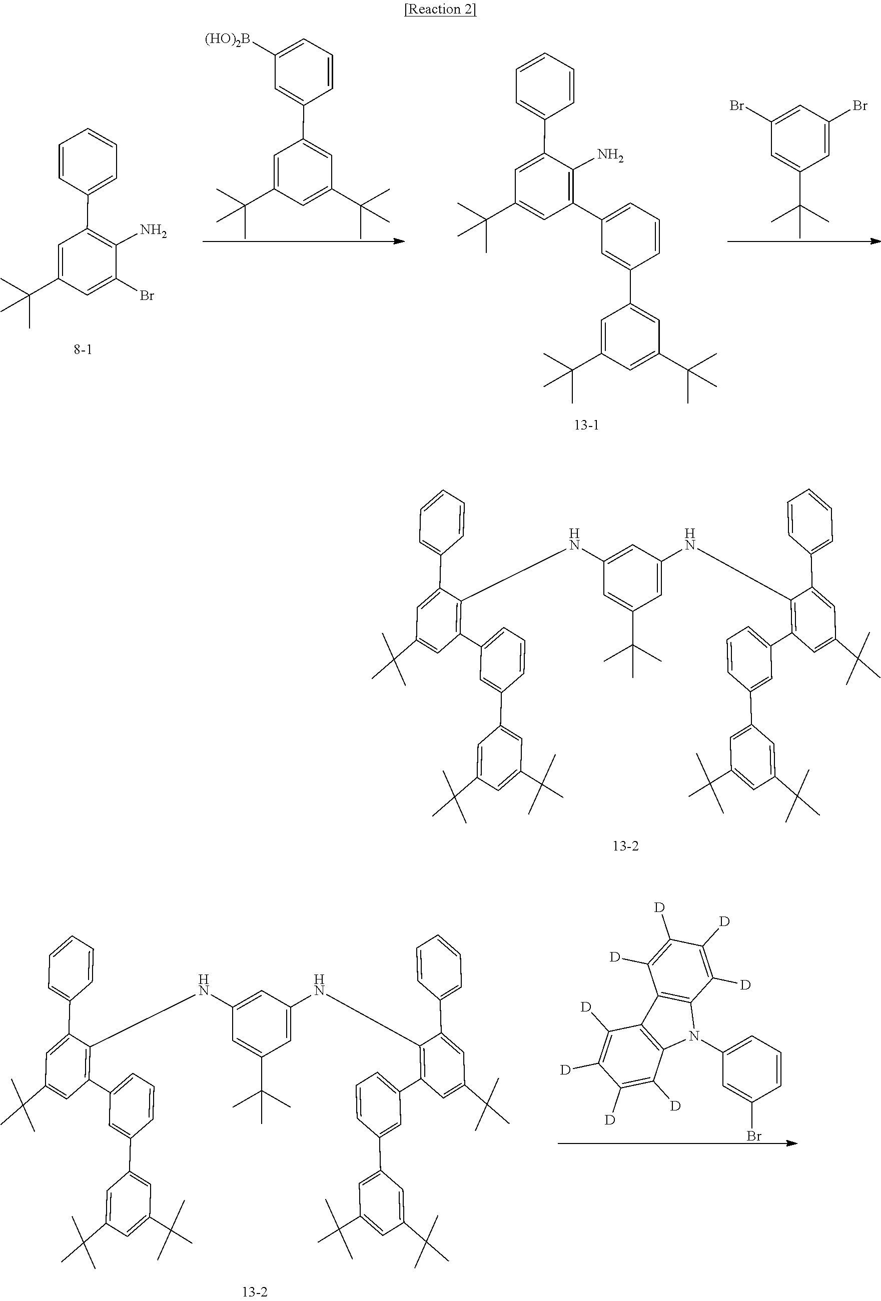

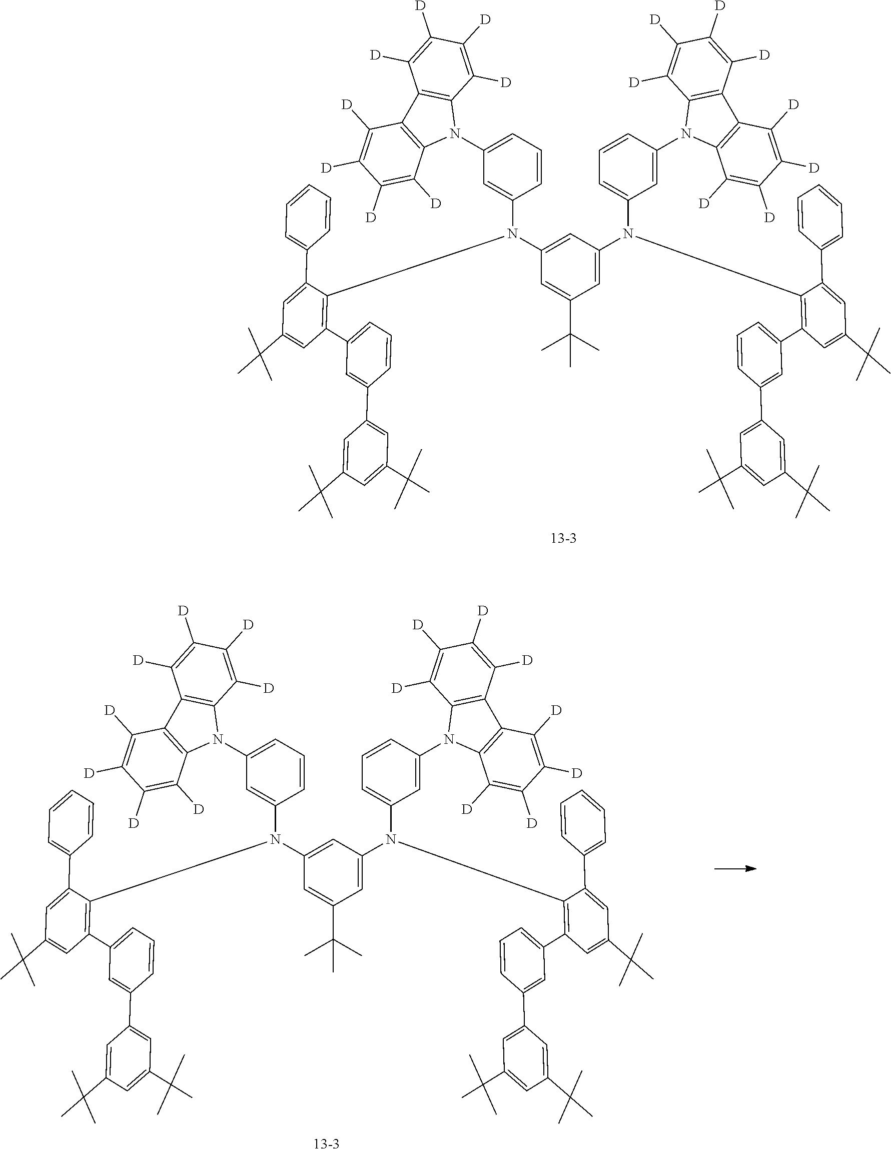

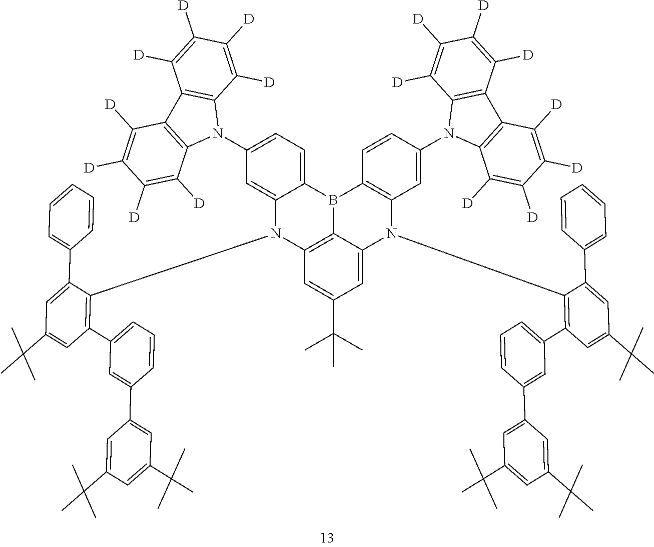 [SMILES: [2H]c1c([2H])c([2H])c2c(c1[2H])c1c([2H])c([2H])c([2H])c([2H])c1n2-c1ccc2c(c1)N(c1c(-c3ccccc3)cc(C(C)(C)C)cc1-c1cccc(-c3cc(C(C)(C)C)cc(C(C)(C)C)c3)c1)c1cc(C(C)(C)C)cc3c1B2c1ccc(-n2c4c([2H])c([2H])c([2H])c([2H])c4c4c([2H])c([2H])c([2H])c([2H])c42)cc1N3c1c(-c2ccccc2)cc(C(C)(C)C)cc1-c1cccc(-c2cc(C(C)(C)C)cc(C(C)(C)C)c2)c1]

### Syntheses of Intermediate 13-1

After dissolving Intermediate 8-1 (eq), (3,5-d-tert-butyl-[1,1′-biphenyl]3-yl)boronic acid (1.05 eq), Pd(PPh₃)₄ (0.05 eq), and K₂CO₃ (3 eq) in a mixture solution of water and THF of 1:2 (volume ratio), the reactants were stirred at about 80 degrees centigrade (° C.) for about 24 hours. After cooling, the resultant was washed with ethyl acetate and water three times and subjected to layer separation to obtain an organic layer. The organic layer thus obtained was dried over MgSO₄, and dried under a reduced pressure. The resultant was purified by column chromatography utilizing MC and n-hexane to obtain Intermediate 13-1 (yield: 76%).

### Synthesis of Intermediate 13-2

After dissolving 1,3-dibromo-5-(tert-butyl)benzene (1 eq), Intermediate 13-1 (2.2 eq), tris(dibenzylideneacetone)dipalladium(0) (0.10 eq), tri-tert-butylphosphine (0.2 eq), and sodium tert-butoxide (3 eq) in o-xylene, the reactants were stirred at about 150 degrees centigrade (° C.) for about 24 hours. After cooling, the resultant was washed with ethyl acetate and water three times and subjected to layer separation to obtain an organic layer. The organic layer thus obtained was dried over MgSO₄, and dried under a reduced pressure. The resultant was purified by column chromatography utilizing MC and n-hexane to obtain Intermediate 13-2 (yield: 65%).

### Synthesis of Intermediate 13-3

After dissolving Intermediate 13-2 (1 eq), 9-(3-bromophenyl)-9H-carbazole-D₈ (4 eq), tris(dibenzylideneacetone)dipalladium(0) (0.20 eq), tri-tert-butylphosphine (0.4 eq), and sodium tert-butoxide (3 eq) in o-xylene, the reactants were stirred at about 150 degrees centigrade (° C.) for about 60 hours. After cooling, the resultant was washed with ethyl acetate and water three times and subjected to layer separation to obtain an organic layer. The organic layer thus obtained was dried over MgSO₄, and dried under a reduced pressure. The resultant was purified by column chromatography utilizing MC and n-hexane to obtain Intermediate 13-3 (yield: 25%).

### Synthesis of Compound 13

Intermediate 13-3 (1 eq) was dissolved in o-dichlorobenzene and cooled to 0 degrees centigrade (° C.), and BBr₃ (4 eq) was slowly injected thereto under a nitrogen atmosphere. After finishing the dropwise addition, the temperature was raised to about 180 degrees centigrade (° C.), and stirring was performed for about 48 hours. After cooling, triethylamine was added to a flask containing the reaction product slowly and dropwisely to terminate the reaction, ethyl alcohol was added to precipitate the reaction product, and the precipitate was filtered to obtain a solid content (e.g., material). The solid content thus obtained was purified by column chromatography utilizing MC and n-hexane and recrystallized utilizing toluene and acetone to obtain Compound 13 (yield: 3%).

### (3) Synthesis of Fused Polycyclic Compound 18

Fused Polycyclic Compound 18 according to an embodiment may be synthesized by, for example, the acts (e.g., steps) of Reaction 3 below.

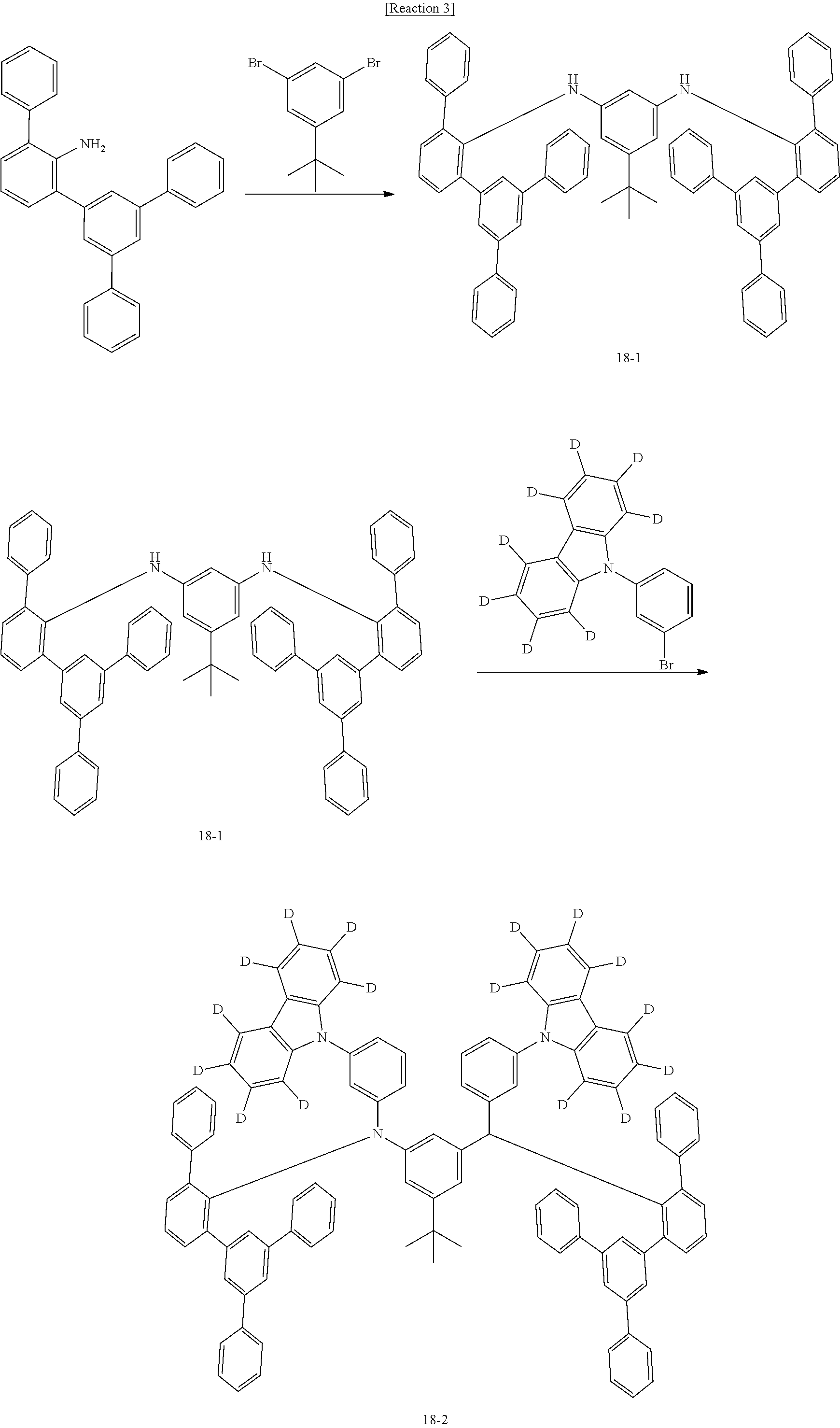

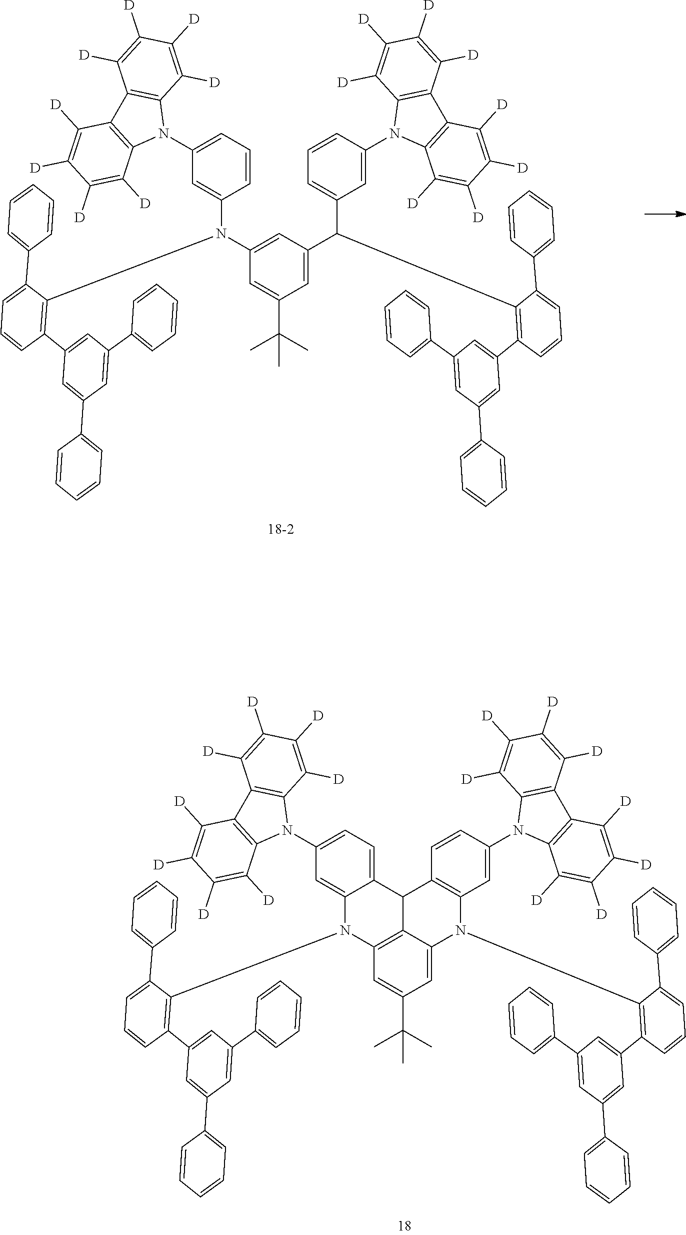

### Synthesis of Intermediate 18-1

After dissolving 1,3-dibromo-5-(tert-butyl)benzene (1 eq), 5″-phenyl-[1,1′:3′,1″:3,1′″-quaterphenyl]-2′-amine (2.2 eq), tris(dibenzylideneacetone)dipalladium(0) (0.15 eq), tri-tert-butylphosphine (0.3 eq), and sodium tert-butoxide (3 eq) in toluene, the reactants were stirred at about 150 degrees centigrade (° C.) for about 48 hours. After cooling, the resultant was washed with ethyl acetate and water three times and subjected to layer separation to obtain an organic layer. The organic layer thus obtained was dried over MgSO₄, and dried under a reduced pressure. The resultant was purified by column chromatography utilizing MC and n-hexane to obtain Intermediate 18-1 (yield: 63%).

### Synthesis of Intermediate 18-2

After dissolving Intermediate 18-1 (1 eq), 9-(3-bromophenyl)-9H-carbazole-D₈ (4 eq), tris(dibenzylideneacetone)dipalladium(0) (0.20 eq), tri-tert-butylphosphine (0.4 eq), and sodium tert-butoxide (3 eq) in o-xylene, the reactants were stirred at about 150 degrees centigrade (° C.) for about 60 hours. After cooling, the resultant was washed with ethyl acetate and water three times and subjected to layer separation to obtain an organic layer. The organic layer thus obtained was dried over MgSO₄, and dried under a reduced pressure. The resultant was purified by column chromatography utilizing MC and n-hexane to obtain Intermediate 18-2 (yield: 32%).

### Synthesis of Compound 18

Intermediate 18-2 (1 eq) was dissolved in o-dichlorobenzene and cooled to 0 degrees centigrade (° C.), and BBr₃ (4 eq) was slowly injected thereto under a nitrogen atmosphere. After finishing the dropwise addition, the temperature was raised to about 180 degrees centigrade (° C.), and stirring was performed for about 48 hours. After cooling, triethylamine was added to a flask containing the reaction product slowly and dropwisely to terminate the reaction, ethyl alcohol was added to precipitate the reaction product, and the precipitate was filtered to obtain a solid content (e.g., material). The solid content thus obtained was purified by column chromatography utilizing MC and n-hexane and recrystallized utilizing toluene and acetone to obtain Compound 18 (yield: 2%).

### (4) Synthesis of Fused Polycyclic Compound 32

Fused Polycyclic Compound 32 according to an embodiment may be synthesized by, for example, the acts (e.g., steps) of Reaction 4 below.

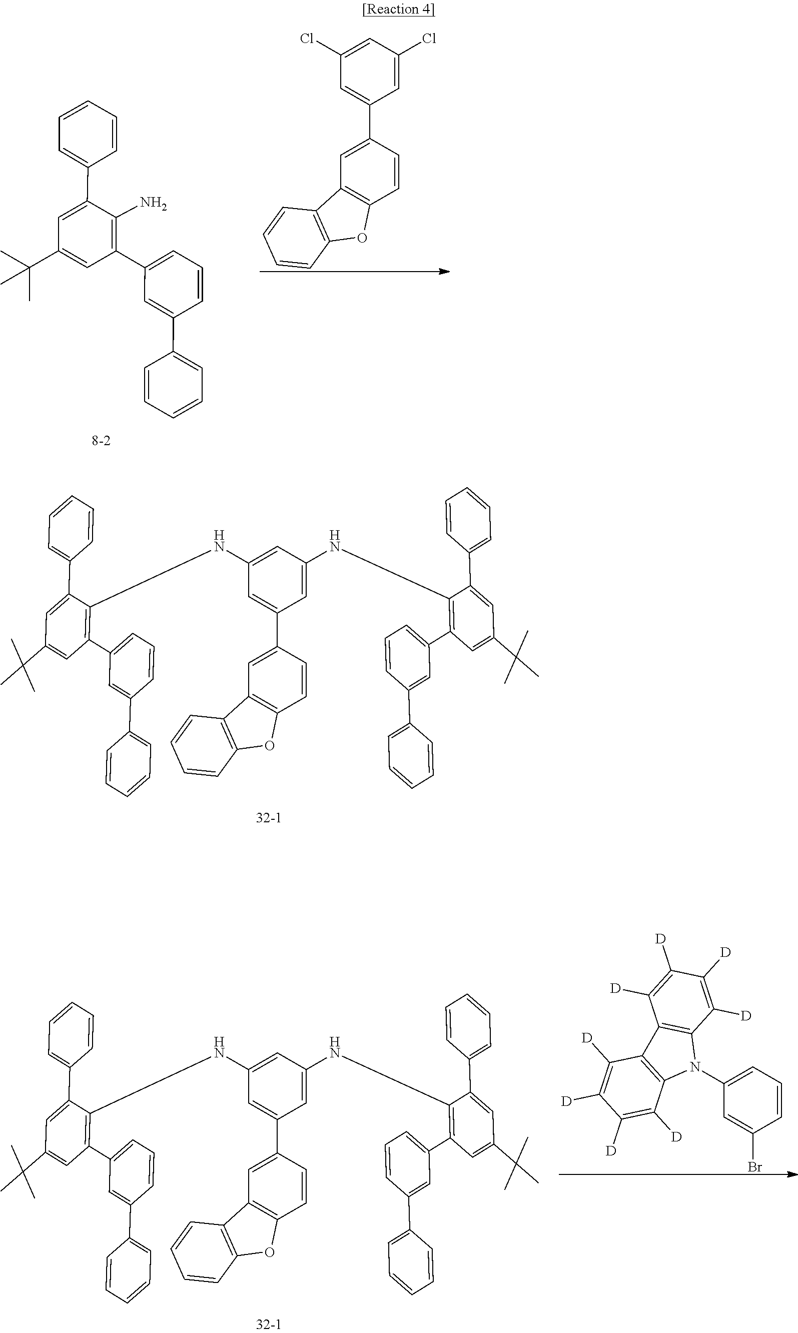

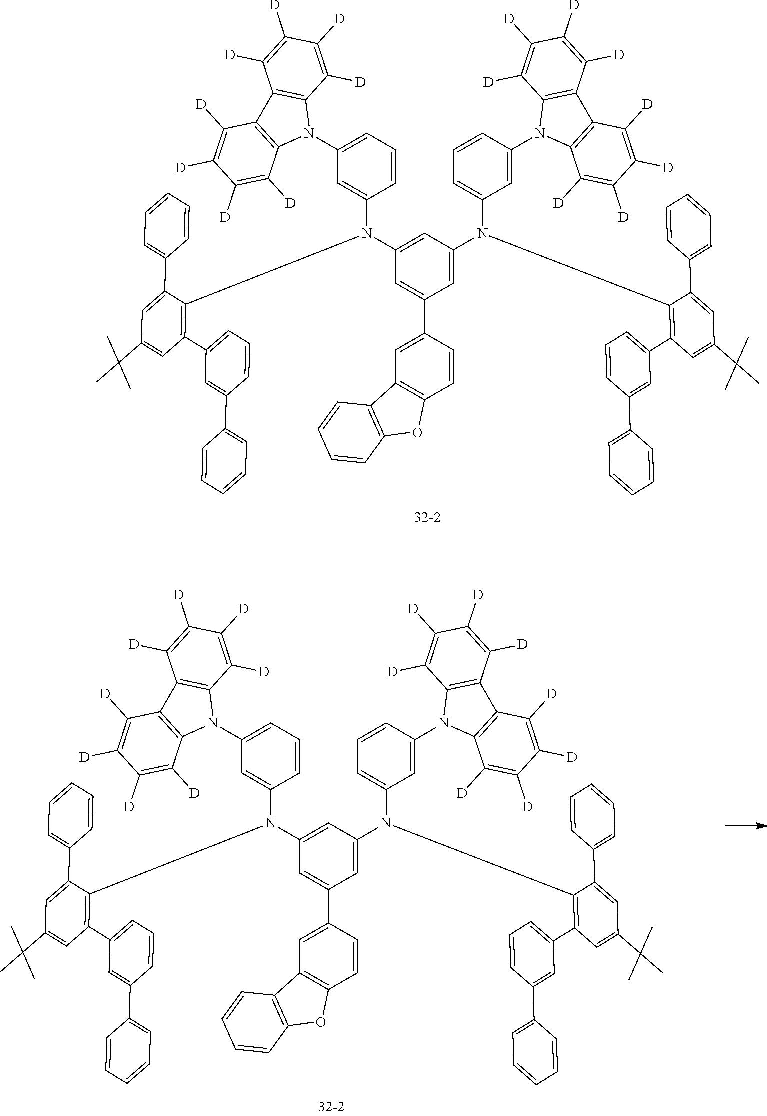

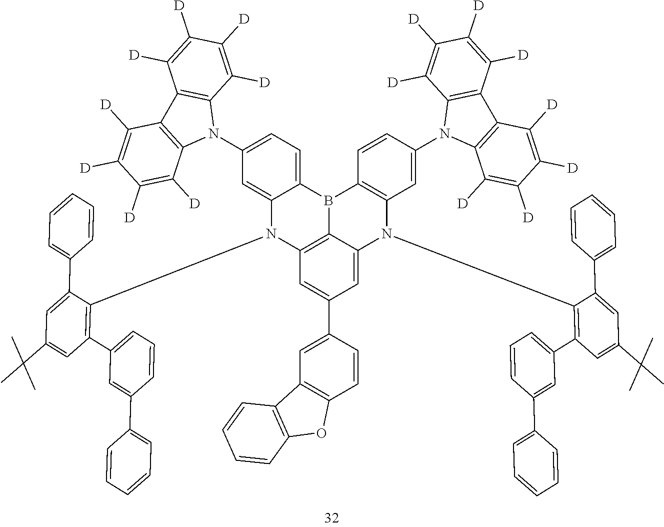 [SMILES: [2H]c1c([2H])c([2H])c2c(c1[2H])c1c([2H])c([2H])c([2H])c([2H])c1n2-c1ccc2c(c1)N(c1c(-c3ccccc3)cc(C(C)(C)C)cc1-c1cccc(-c3ccccc3)c1)c1cc(-c3ccc4oc5ccccc5c4c3)cc3c1B2c1ccc(-n2c4c([2H])c([2H])c([2H])c([2H])c4c4c([2H])c([2H])c([2H])c([2H])c42)cc1N3c1c(-c2ccccc2)cc(C(C)(C)C)cc1-c1cccc(-c2ccccc2)c1]

### Synthesis of Intermediate 32-1

After dissolving 2-(3,5-dichlorophenyl)dibenzo[b,d]furan (1 eq), Intermediate 8-2 (2.2 eq), tris(dibenzylideneacetone)dipalladium(0) (0.1 eq), tri-tert-butylphosphine (0.2 eq), and sodium tert-butoxide (3 eq) in o-xylene, the reactants were stirred at about 150 degrees centigrade (° C.) for about 36 hours. After cooling, the resultant was washed with ethyl acetate and water three times and subjected to layer separation to obtain an organic layer. The organic layer thus obtained was dried over MgSO₄, and dried under a reduced pressure. The resultant was purified by column chromatography utilizing MC and n-hexane to obtain Intermediate 32-1 (yield: 70%).

### Synthesis of Intermediate 32-2

After dissolving Intermediate 32-1 (1 eq), 9-(3-bromophenyl)-9H-carbazole-D₈ (4 eq), tris(dibenzylideneacetone)dipalladium(0) (0.20 eq), tri-tert-butylphosphine (0.4 eq), and sodium tert-butoxide (3 eq) in o-xylene, the reactants were stirred at about 150 degrees centigrade (° C.) for about 60 hours. After cooling, the resultant was washed with ethyl acetate and water three times and subjected to layer separation to obtain an organic layer. The organic layer thus obtained was dried over MgSO₄, and dried under a reduced pressure. The resultant was purified by column chromatography utilizing MC and n-hexane to obtain Intermediate 32-2 (yield: 37%).

### Synthesis of Compound 32

Intermediate 32-2 (1 eq) was dissolved in o-dichlorobenzene and cooled to 0 degrees centigrade (° C.), and BBr₃ (4 eq) was slowly injected thereto under a nitrogen atmosphere. After finishing the dropwise addition, the temperature was raised to about 180 degrees centigrade (° C.), and stirring was performed for about 48 hours. After cooling, triethylamine was added to a flask containing the reaction product slowly and dropwisely to terminate the reaction, ethyl alcohol was added to precipitate the reaction product, and the precipitate was filtered to obtain a solid content (e.g., material). The solid content thus obtained was purified by column chromatography utilizing MC and n-hexane and recrystallized utilizing toluene and acetone to obtain Compound 32 (yield: 8%).

### (5) Synthesis of Fused Polycyclic Compound 45

Fused Polycyclic Compound 45 according to an embodiment may be synthesized by, for example, the acts (e.g., steps) of Reaction 5 below.

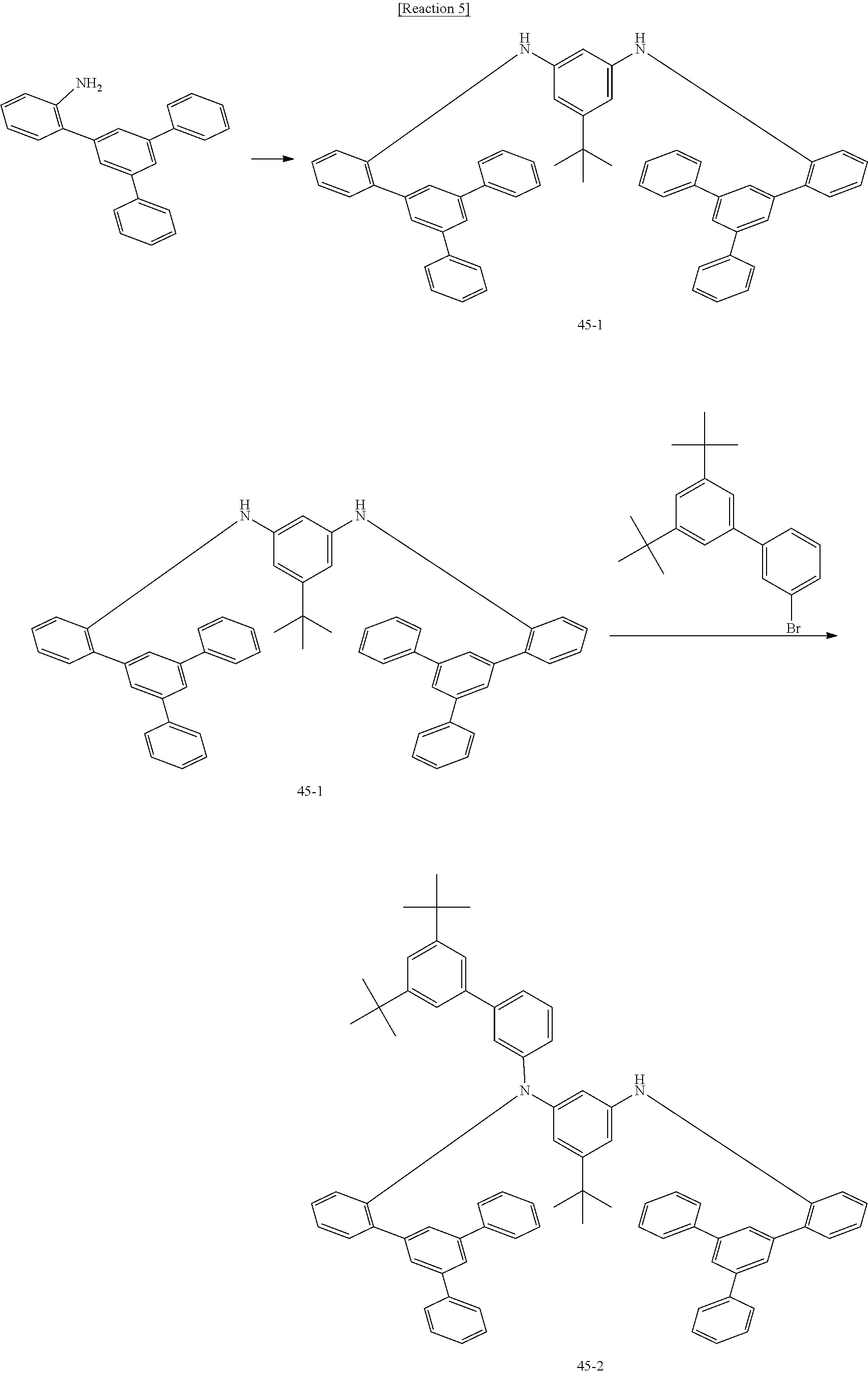 [SMILES: Nc1ccccc1-c1cc(-c2ccccc2)cc(-c2ccccc2)c1 ; CC(C)(C)c1cc(Nc2ccccc2-c2cc(-c3ccccc3)cc(-c3ccccc3)c2)cc(Nc2ccccc2-c2cc(-c3ccccc3)cc(-c3ccccc3)c2)c1 ; CC(C)(C)c1cc(Nc2ccccc2-c2cc(-c3ccccc3)cc(-c3ccccc3)c2)cc(Nc2ccccc2-c2cc(-c3ccccc3)cc(-c3ccccc3)c2)c1 ; CC(C)(C)c1cc(-c2cccc(Br)c2)cc(C(C)(C)C)c1 ; CC(C)(C)c1cc(Nc2ccccc2-c2cc(-c3ccccc3)cc(-c3ccccc3)c2)cc(N(c2cccc(-c3cc(C(C)(C)C)cc(C(C)(C)C)c3)c2)c2ccccc2-c2cc(-c3ccccc3)cc(-c3ccccc3)c2)c1]

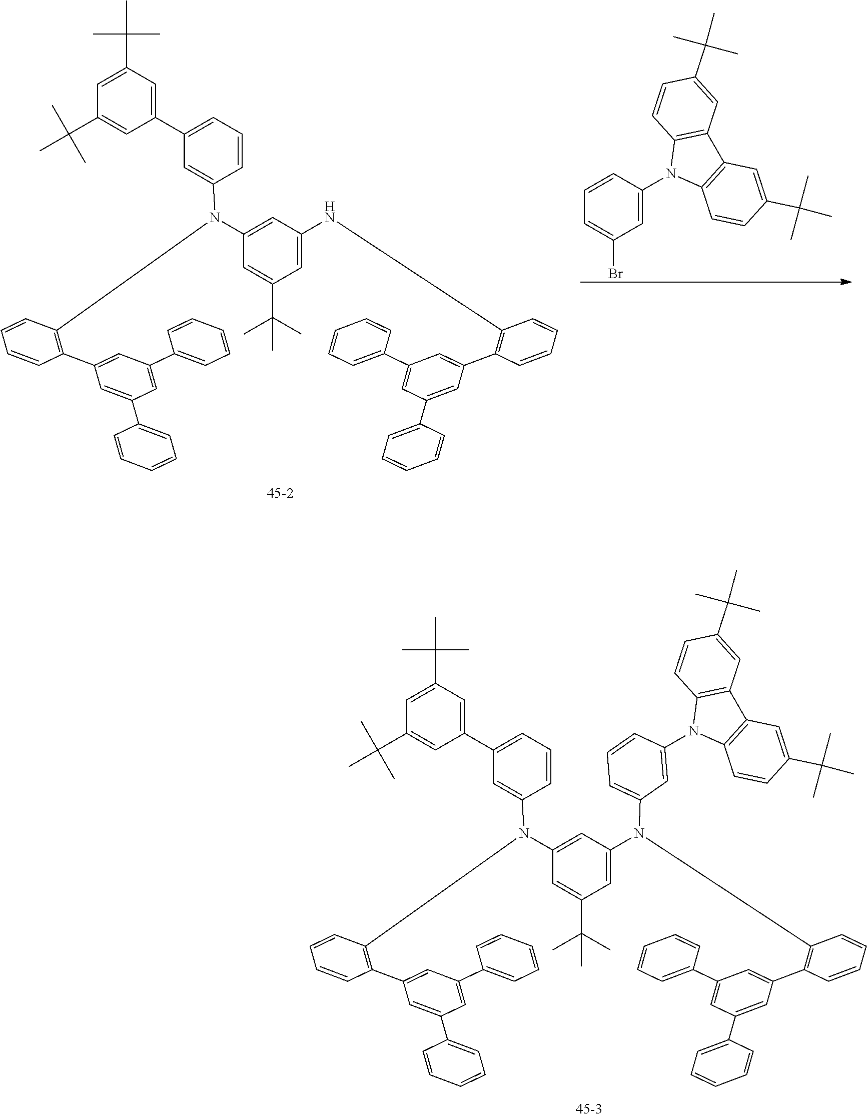 [SMILES: CC(C)(C)c1cc(Nc2ccccc2-c2cc(-c3ccccc3)cc(-c3ccccc3)c2)cc(N(c2cccc(-c3cc(C(C)(C)C)cc(C(C)(C)C)c3)c2)c2ccccc2-c2cc(-c3ccccc3)cc(-c3ccccc3)c2)c1 ; CC(C)(C)c1ccc2c(c1)c1cc(C(C)(C)C)ccc1n2-c1cccc(Br)c1 ; CC(C)(C)c1cc(N(c2cccc(-c3cc(C(C)(C)C)cc(C(C)(C)C)c3)c2)c2ccccc2-c2cc(-c3ccccc3)cc(-c3ccccc3)c2)cc(N(c2cccc(-n3c4ccc(C(C)(C)C)cc4c4cc(C(C)(C)C)ccc43)c2)c2ccccc2-c2cc(-c3ccccc3)cc(-c3ccccc3)c2)c1]

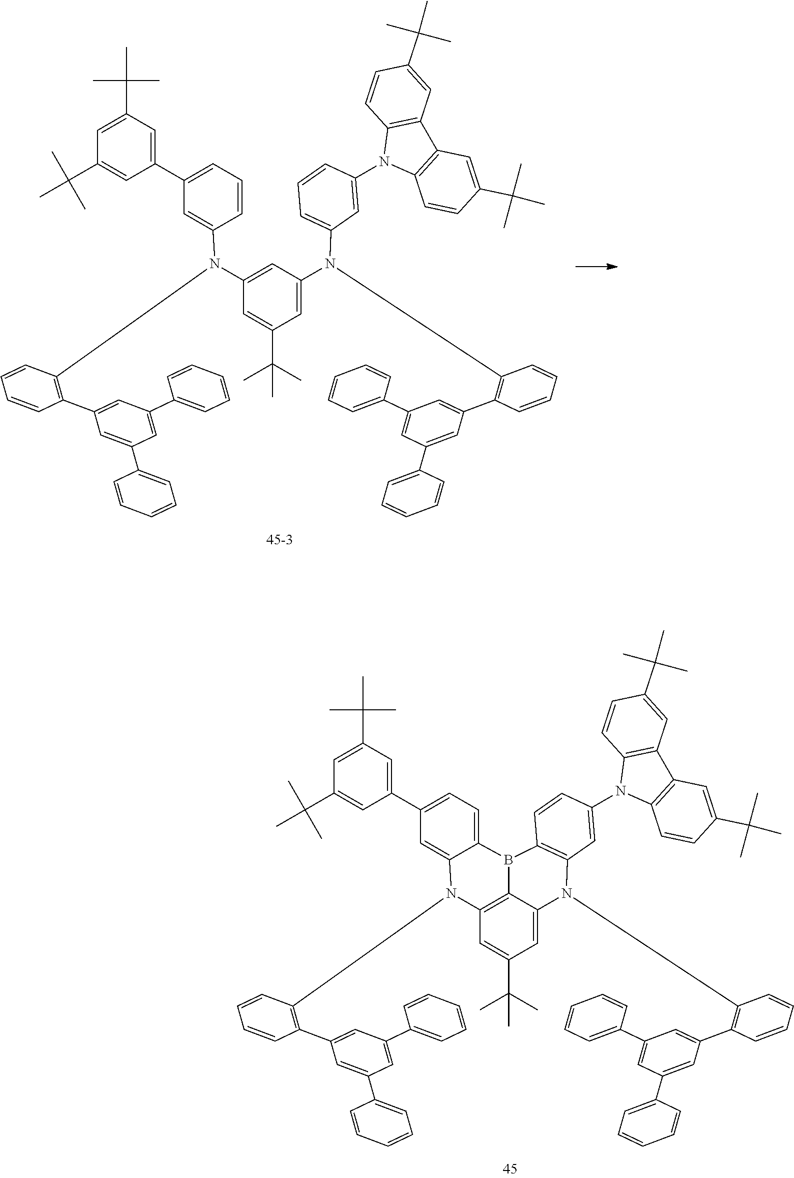 [SMILES: CC(C)(C)c1cc(N(c2cccc(-c3cc(C(C)(C)C)cc(C(C)(C)C)c3)c2)c2ccccc2-c2cc(-c3ccccc3)cc(-c3ccccc3)c2)cc(N(c2cccc(-n3c4ccc(C(C)(C)C)cc4c4cc(C(C)(C)C)ccc43)c2)c2ccccc2-c2cc(-c3ccccc3)cc(-c3ccccc3)c2)c1 ; CC(C)(C)c1cc(-c2ccc3c(c2)N(c2ccccc2-c2cc(-c4ccccc4)cc(-c4ccccc4)c2)c2cc(C(C)(C)C)cc4c2B3c2ccc(-n3c5ccc(C(C)(C)C)cc5c5cc(C(C)(C)C)ccc53)cc2N4c2ccccc2-c2cc(-c3ccccc3)cc(-c3ccccc3)c2)cc(C(C)(C)C)c1]

### Synthesis of Intermediate 45-1

After dissolving 1,3-dibromo-5-(tert-butyl)benzene (1 eq), 5′-phenyl-[1,1′:3′,1″-terphenyl]-2-amine (2.2 eq), tris(dibenzylideneacetone)dipalladium(0) (0.15 eq), tri-tert-butylphosphine (0.3 eq), and sodium tert-butoxide (3 eq) in o-xylene, the reactants were stirred at about 150 degrees centigrade (° C.) for about 48 hours. After cooling, the resultant was washed with ethyl acetate and water three times and subjected to layer separation to obtain an organic layer. The organic layer thus obtained was dried over MgSO₄, and dried under a reduced pressure. The resultant was purified by column chromatography utilizing MC and n-hexane to obtain Intermediate 45-1 (yield: 74%).

### Synthesis of Intermediate 45-2

After dissolving Intermediate 45-1 (1 eq), 3′-bromo-3,5-di-tert-butyl-1,1′-biphenyl (1 eq), tris(dibenzylideneacetone)dipalladium(0) (0.05 eq), tri-tert-butylphosphine (0.1 eq), and sodium tert-butoxide (3 eq) in toluene, the reactants were stirred at about 100 degrees centigrade (° C.) for about 36 hours. After cooling, the resultant was washed with ethyl acetate and water three times and subjected to layer separation to obtain an organic layer. The organic layer thus obtained was dried over MgSO₄, and dried under a reduced pressure. The resultant was purified by column chromatography utilizing MC and n-hexane to obtain Intermediate 45-2 (yield: 27%).

### Synthesis of Intermediate 45-3

After dissolving Intermediate 45-2 (1 eq), 9-(3-bromophenyl)-3,6-di-tert-butyl-9H-carbazole (1.8 eq), tris(dibenzylideneacetone)dipalladium(0) (0.15 eq), tri-tert-butylphosphine (0.3 eq), and sodium tert-butoxide (3 eq) in o-xylene, the reactants were stirred at about 150 degrees centigrade (° C.) for about 48 hours. After cooling, the resultant was washed with ethyl acetate and water three times and subjected to layer separation to obtain an organic layer. The organic layer thus obtained was dried over MgSO₄, and dried under a reduced pressure. The resultant was purified by column chromatography utilizing MC and n-hexane to obtain Intermediate 45-3 (yield: 52%).

### Synthesis of Compound 45

Intermediate 45-3 (1 eq) was dissolved in o-dichlorobenzene and cooled to 0 degrees centigrade (° C.), and BBr₃ (4 eq) was slowly injected thereto under a nitrogen atmosphere. After finishing the dropwise addition, the temperature was raised to about 180 degrees centigrade (° C.), and stirring was performed for about 48 hours. After cooling, triethylamine was added to a flask containing the reaction product slowly and dropwisely to terminate the reaction, ethyl alcohol was added to precipitate the reaction product, and the precipitate was filtered to obtain a solid content (e.g., material). The solid content thus obtained was purified by column chromatography utilizing MC and n-hexane and recrystallized utilizing toluene and acetone to obtain Compound 45 (yield: 3%).

### (6) Synthesis of Fused Polycyclic Compound 49

Fused Polycyclic Compound 49 according to an embodiment may be synthesized by, for example, the acts (e.g., steps) of Reaction 6 below.

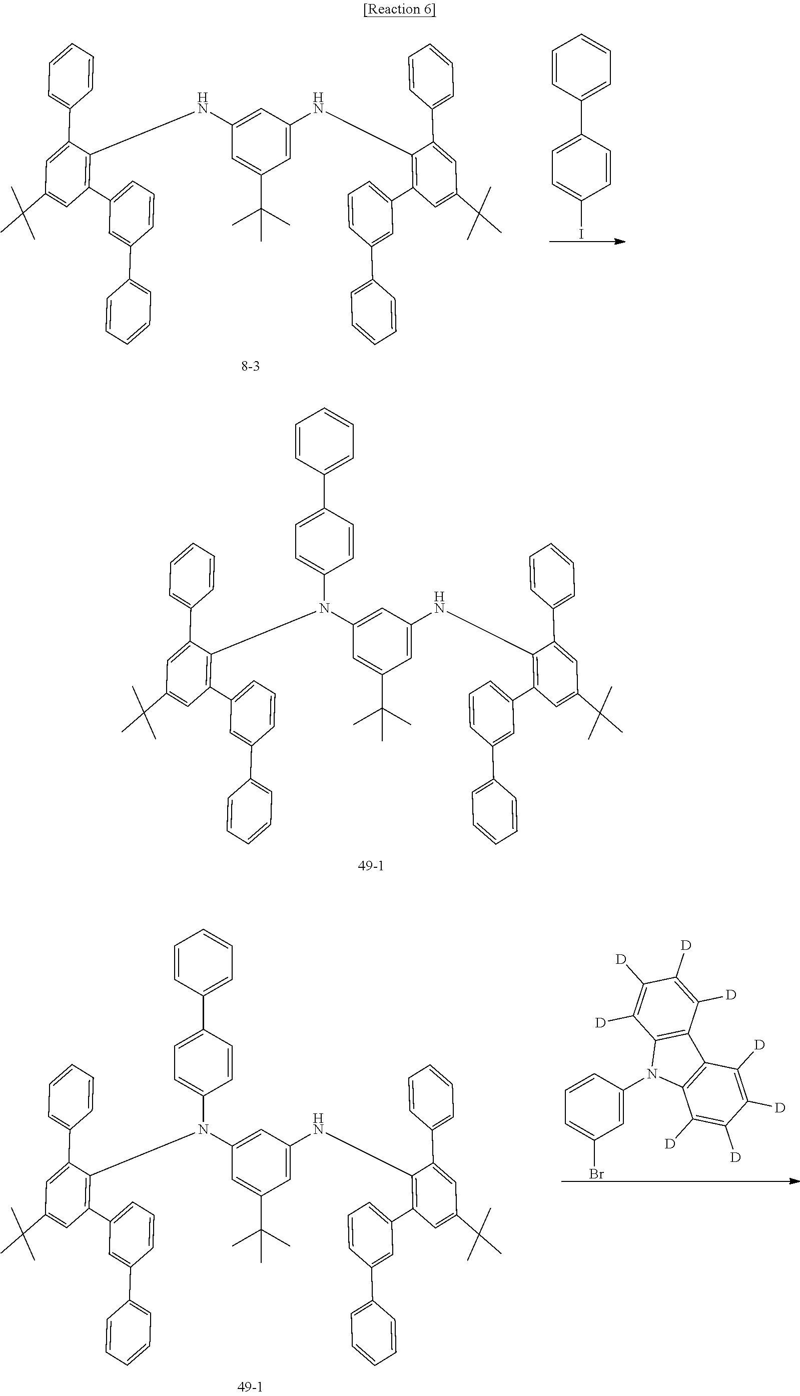

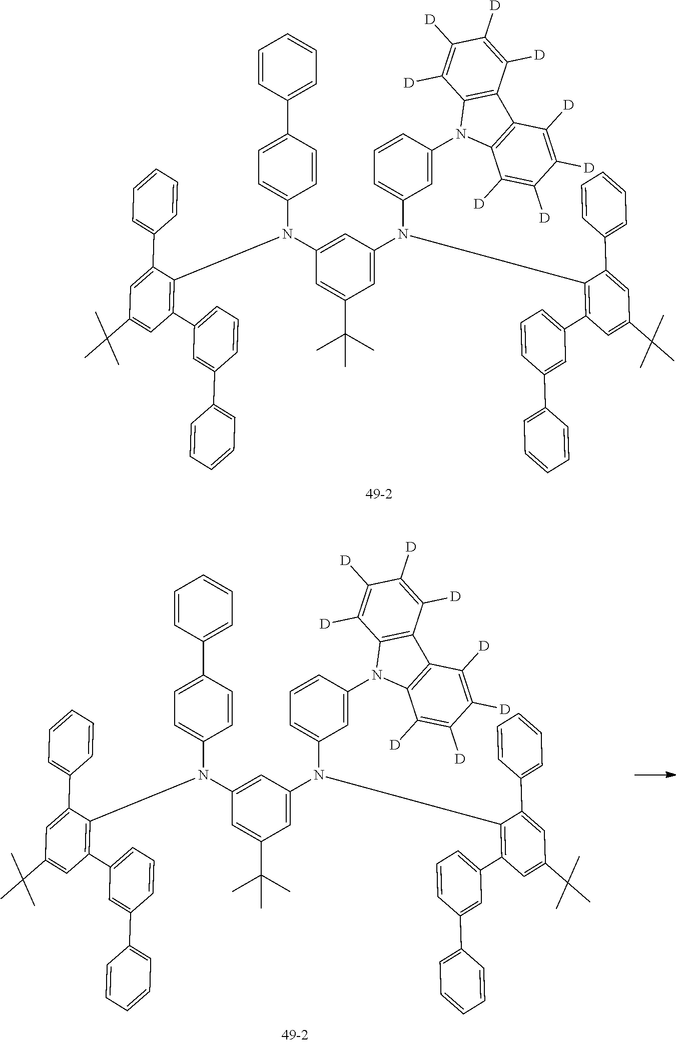

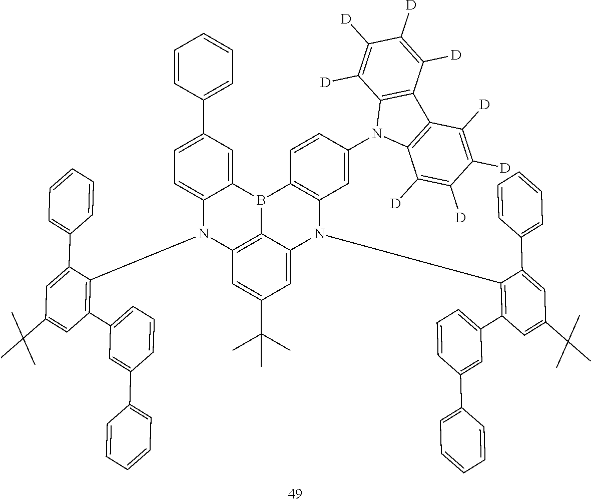 [SMILES: [2H]c1c([2H])c([2H])c2c(c1[2H])c1c([2H])c([2H])c([2H])c([2H])c1n2-c1ccc2c(c1)N(c1c(-c3ccccc3)cc(C(C)(C)C)cc1-c1cccc(-c3ccccc3)c1)c1cc(C(C)(C)C)cc3c1B2c1cc(-c2ccccc2)ccc1N3c1c(-c2ccccc2)cc(C(C)(C)C)cc1-c1cccc(-c2ccccc2)c1]

### Synthesis of Intermediate 49-1

After dissolving Intermediate 8-3 (1 eq), 4-iodo-1,1′-biphenyl (1 eq), tris(dibenzylideneacetone)dipalladium(0) (0.05 eq), tri-tert-butylphosphine (0.1 eq), and sodium tert-butoxide (3 eq) in toluene, the reactants were stirred at about 100 degrees centigrade (° C.) for about 36 hours. After cooling, the resultant was washed with ethyl acetate and water three times and subjected to layer separation to obtain an organic layer. The organic layer thus obtained was dried over MgSO₄, and dried under a reduced pressure. The resultant was purified by column chromatography utilizing MC and n-hexane to obtain Intermediate 49-1 (yield: 30%).

### Synthesis of Intermediate 49-2

After dissolving Intermediate 49-1 (1 eq), 9-(3-bromophenyl)-9H-carbazole-D₈ (1.7 eq), tris(dibenzylideneacetone)dipalladium(0) (0.20 eq), tri-tert-butylphosphine (0.4 eq), and sodium tert-butoxide (3 eq) in o-xylene, the reactants were stirred at about 150 degrees centigrade (° C.) for about 60 hours. After cooling, the resultant was washed with ethyl acetate and water three times and subjected to layer separation to obtain an organic layer. The organic layer thus obtained was dried over MgSO₄, and dried under a reduced pressure. The resultant was purified by column chromatography utilizing MC and n-hexane to obtain Intermediate 49-2 (yield: 47%).

### Synthesis of Compound 49

Intermediate 49-2 (1 eq) was dissolved in o-dichlorobenzene and cooled to 0 degrees centigrade (° C.), and BBr₃ (4 eq) was slowly injected thereto under a nitrogen atmosphere. After finishing the dropwise addition, the temperature was raised to about 180 degrees centigrade (° C.), and stirring was performed for about 48 hours. After cooling, triethylamine was added to a flask containing the reaction product slowly and dropwisely to terminate the reaction, ethyl alcohol was added to precipitate the reaction product, and the precipitate was filtered to obtain a solid content (e.g., material). The solid content thus obtained was purified by column chromatography utilizing MC and n-hexane and recrystallized utilizing toluene and acetone to obtain Compound 49 (yield: 5%).

### (7) Synthesis of Fused Polycyclic Compound 66

Fused Polycyclic Compound 66 according to an embodiment may be synthesized by, for example, the acts (e.g., steps) of Reaction 7 below.

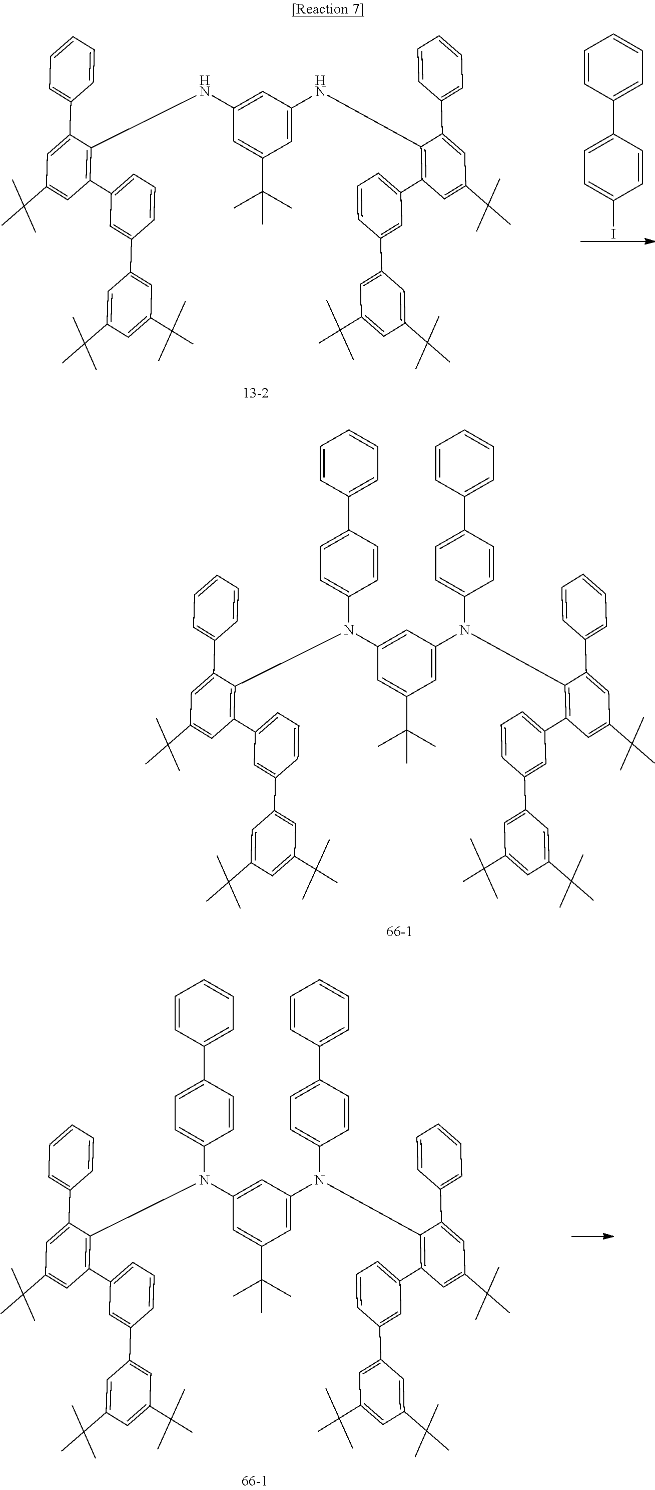

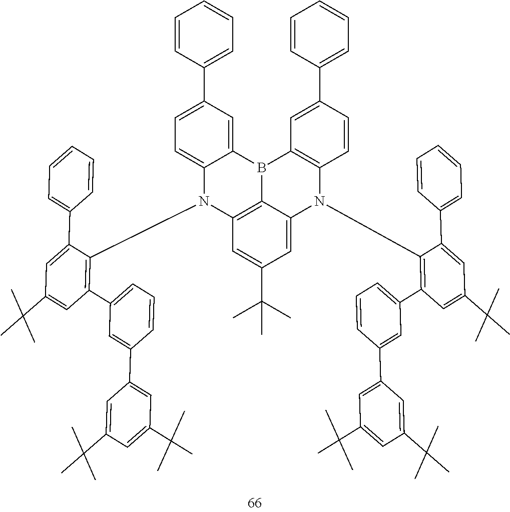 [SMILES: CC(C)(C)c1cc(-c2cccc(-c3cc(C(C)(C)C)cc(-c4ccccc4)c3N3c4ccc(-c5ccccc5)cc4B4c5cc(-c6ccccc6)ccc5N(c5c(-c6ccccc6)cc(C(C)(C)C)cc5-c5cccc(-c6cc(C(C)(C)C)cc(C(C)(C)C)c6)c5)c5cc(C(C)(C)C)cc3c54)c2)cc(C(C)(C)C)c1]

### Synthesis of Intermediate 66-1

After dissolving Intermediate 13-2 (1 eq), 4-iodo-1,1′-biphenyl (4 eq), tris(dibenzylideneacetone)dipalladium(0) (0.25 eq), tri-tert-butylphosphine (0.5 eq), and sodium tert-butoxide (3 eq) in o-xylene, the reactants were stirred at about 150 degrees centigrade (° C.) for about 60 hours. After cooling, the resultant was washed with ethyl acetate and water three times and subjected to layer separation to obtain an organic layer. The organic layer thus obtained was dried over MgSO₄, and dried under a reduced pressure. The resultant was purified by column chromatography utilizing MC and n-hexane to obtain Intermediate 66-1 (yield: 41%).

### Synthesis of Compound 66

Intermediate 66-1 (1 eq) was dissolved in o-dichlorobenzene and cooled to 0 degrees centigrade (° C.), and BBr₃ (4 eq) was slowly injected thereto under a nitrogen atmosphere. After finishing the dropwise addition, the temperature was raised to about 180 degrees centigrade (° C.), and stirring was performed for about 48 hours. After cooling, triethylamine was added to a flask containing the reaction product slowly and dropwisely to terminate the reaction, ethyl alcohol was added to precipitate the reaction product, and the precipitate was filtered to obtain a solid content (e.g., material). The solid content thus obtained was purified by column chromatography utilizing MC and n-hexane and recrystallized utilizing toluene and acetone to obtain Compound 66 (yield: 11%).

### 2. Manufacture and Evaluation of Light Emitting Elements

### (1) Manufacture of Light Emitting Elements

Light emitting elements including the fused polycyclic compounds of embodiments or the Comparative Compounds in an emission layer were manufactured by a method below. Light emitting elements of Example 1 to Example 14 were manufactured utilizing the fused polycyclic compounds of Compounds 8, 13, 18, 32, 45, 49 and 66, respectively, as the dopant materials of an emission layer. The light emitting elements of Comparative Examples 1 to 6 were manufactured utilizing Comparative Compounds C-1 and SR-1 to SR-5, respectively, as the dopant materials of an emission layer.

A glass substrate on which an ITO electrode of about 15 Ω/cm² (about 1200 Å) was formed (product of Corning Co.), was cut into a size of 50 mm×50 mm×0.7 mm, and washed by ultrasonic waves utilizing isopropyl alcohol and pure water for about 5 minutes each. Then, the glass substrate was cleansed by irradiating ultraviolet rays for about 30 minutes and exposing to ozone, and was installed as an anode in a vacuum deposition apparatus.

On the anode, NPD was deposited to a thickness of about 300 Å to form a hole injection layer, and on the hole injection layer, Compound H-1-1 was deposited to a thickness of about 200 Å to form a hole transport layer. On the hole transport layer, CzSi was deposited to a thickness of about 100 Å to form an emission auxiliary layer.

On the emission auxiliary layer, a host mixture, a phosphorescence sensitizer, and a dopant were co-deposited in a weight ratio of about 85:14:1 to a thickness of about 200 Å to form an emission layer. The host mixture was provided from a hole transport host (HT3) and an electron transport host (ETH66 or ETH86) in a weight ratio of about 5:5. As the phosphorescence sensitizer material, AD-37 or AD-38 was utilized. As the dopant material, the Example Compound or the Comparative Compound was utilized.

On the emission layer, TSPO1 was deposited to form a hole blocking layer with a thickness of about 200 Å. On the hole blocking layer, TPBi was deposited to form an electron transport layer with a thickness of about 300 Å. On the electron transport layer, LiF was deposited to form an electron injection layer with a thickness of about 10 Å, and on the electron injection layer, Al was deposited to form a cathode with a thickness of about 3000 Å, to finally manufacture a light emitting element.

### (Materials Utilized for the Manufacture of Light Emitting Elements)

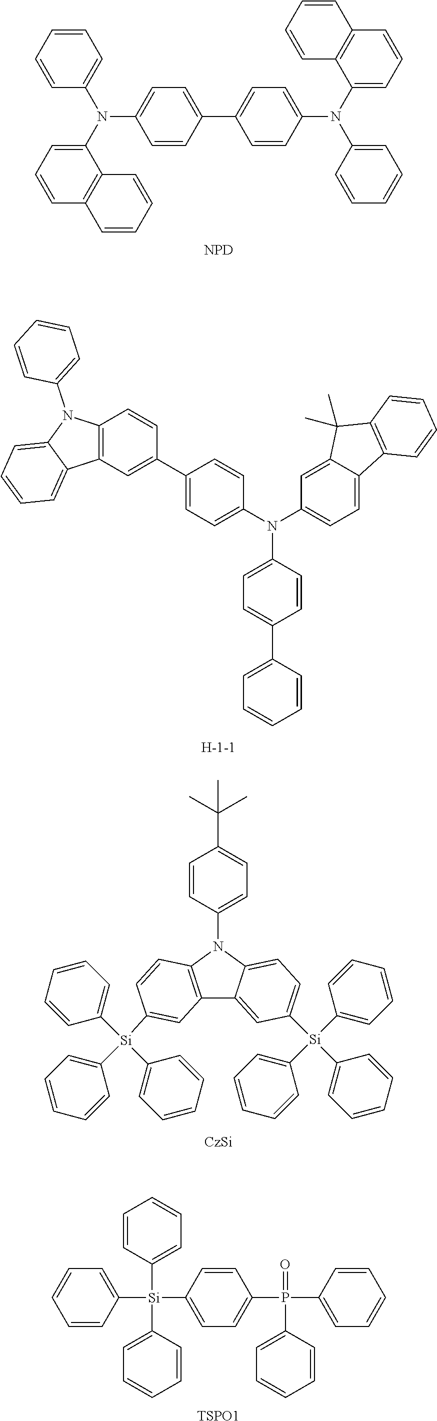

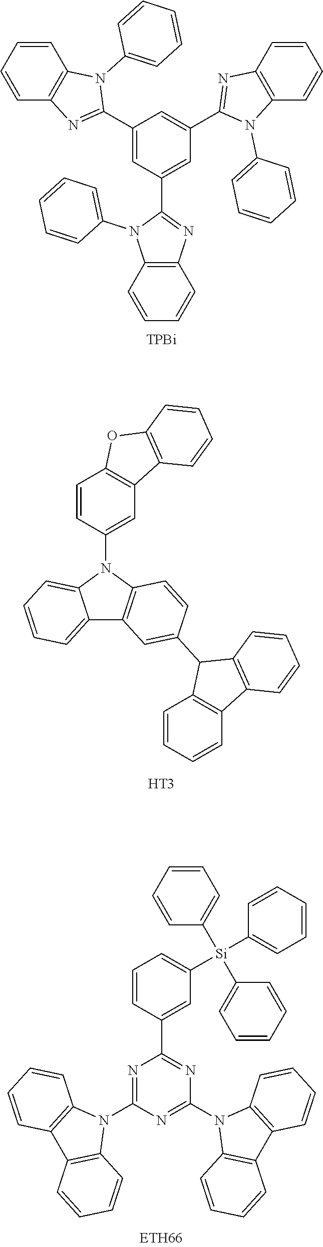

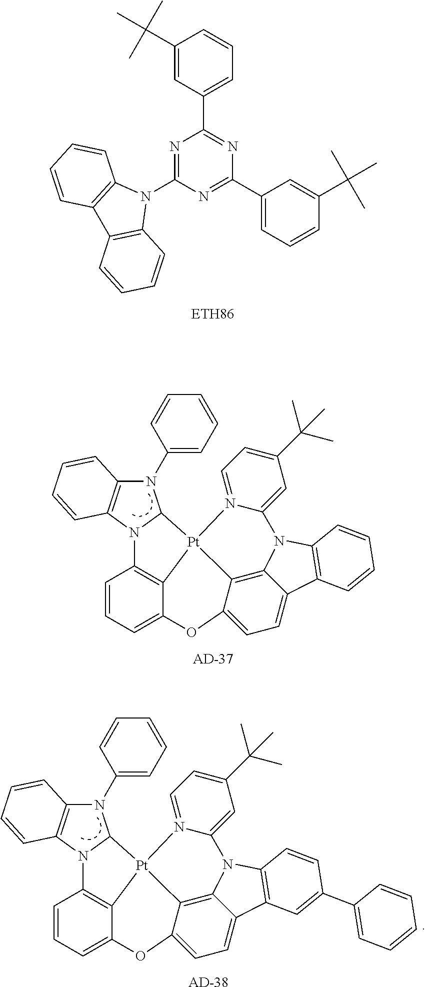

Table 1 shows the Example Compounds and Comparative Compounds utilized for the formation of emission layers of the Examples and Comparative Examples.

TABLE 1

| | |
|---|---|
| Compound 8 | 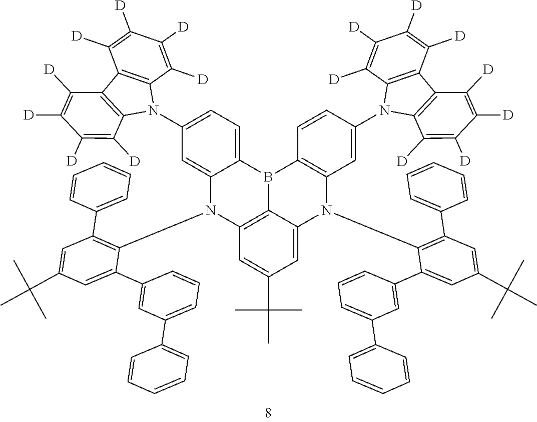 [SMILES: [2H]c1c([2H])c([2H])c2c(c1[2H])c1c([2H])c([2H])c([2H])c([2H])c1n2-c1ccc2c(c1)N(c1c(-c3ccccc3)cc(C(C)(C)C)cc1-c1cccc(-c3ccccc3)c1)c1cc(C(C)(C)C)cc3c1B2c1ccc(-n2c4c([2H])c([2H])c([2H])c([2H])c4c4c([2H])c([2H])c([2H])c([2H])c42)cc1N3c1c(-c2ccccc2)cc(C(C)(C)C)cc1-c1cccc(-c2ccccc2)c1] |
| Compound 13 | 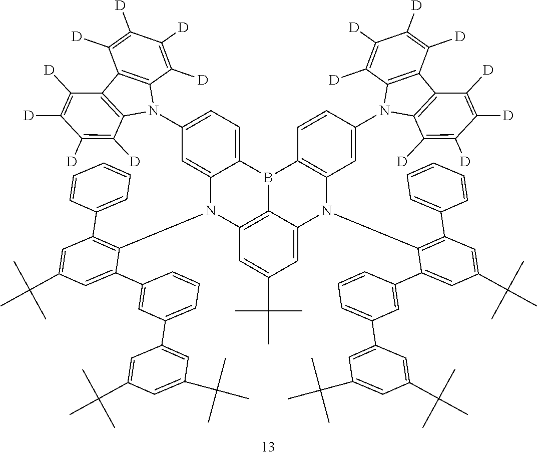 [SMILES: [2H]c1c([2H])c([2H])c2c(c1[2H])c1c([2H])c([2H])c([2H])c([2H])c1n2-c1ccc2c(c1)N(c1c(-c3ccccc3)cc(C(C)(C)C)cc1-c1cccc(-c3cc(C(C)(C)C)cc(C(C)(C)C)c3)c1)c1cc(C(C)(C)C)cc3c1B2c1ccc(-n2c4c([2H])c([2H])c([2H])c([2H])c4c4c([2H])c([2H])c([2H])c([2H])c42)cc1N3c1c(-c2ccccc2)cc(C(C)(C)C)cc1-c1cccc(-c2cc(C(C)(C)C)cc(C(C)(C)C)c2)c1] |
| Compound 18 | 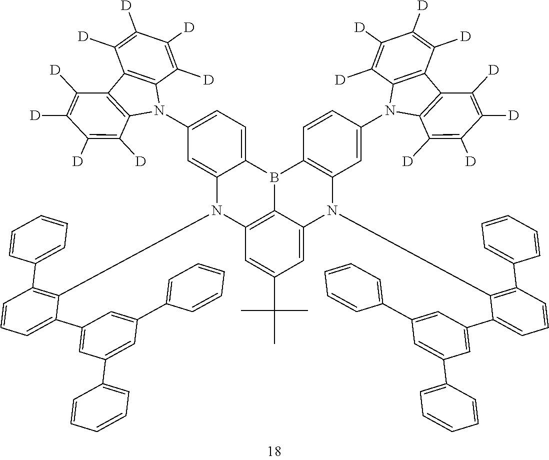 [SMILES: [2H]c1c([2H])c([2H])c2c(c1[2H])c1c([2H])c([2H])c([2H])c([2H])c1n2-c1ccc2c(c1)N(c1c(-c3ccccc3)cccc1-c1cc(-c3ccccc3)cc(-c3ccccc3)c1)c1cc(C(C)(C)C)cc3c1B2c1ccc(-n2c4c([2H])c([2H])c([2H])c([2H])c4c4c([2H])c([2H])c([2H])c([2H])c42)cc1N3c1c(-c2ccccc2)cccc1-c1cc(-c2ccccc2)cc(-c2ccccc2)c1] |
| Compound 32 | 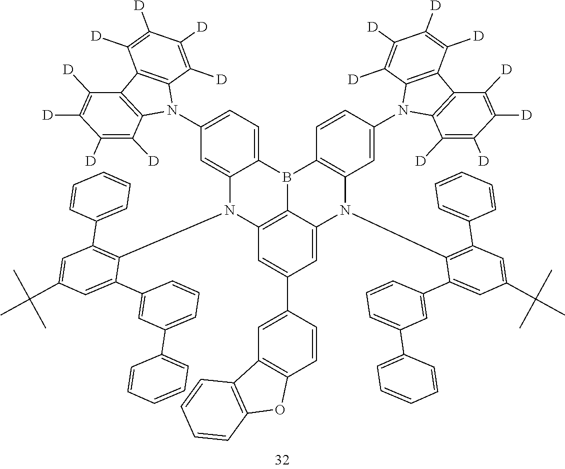 [SMILES: [2H]c1c([2H])c([2H])c2c(c1[2H])c1c([2H])c([2H])c([2H])c([2H])c1n2-c1ccc2c(c1)N(c1c(-c3ccccc3)cc(C(C)(C)C)cc1-c1cccc(-c3ccccc3)c1)c1cc(-c3ccc4oc5ccccc5c4c3)cc3c1B2c1ccc(-n2c4c([2H])c([2H])c([2H])c([2H])c4c4c([2H])c([2H])c([2H])c([2H])c42)cc1N3c1c(-c2ccccc2)cc(C(C)(C)C)cc1-c1cccc(-c2ccccc2)c1] |
| Compound 45 | 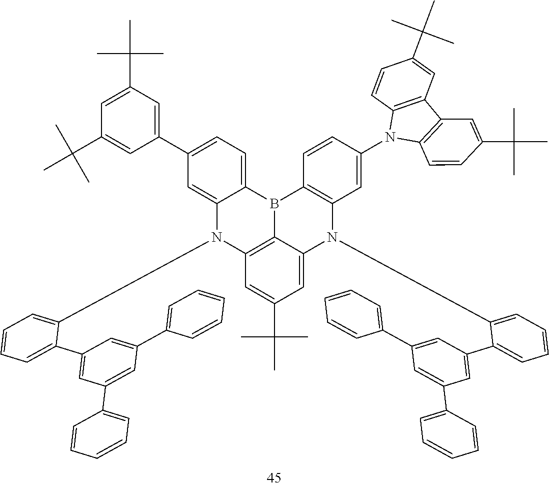 [SMILES: CC(C)(C)c1cc(-c2ccc3c(c2)N(c2ccccc2-c2cc(-c4ccccc4)cc(-c4ccccc4)c2)c2cc(C(C)(C)C)cc4c2B3c2ccc(-n3c5ccc(C(C)(C)C)cc5c5cc(C(C)(C)C)ccc53)cc2N4c2ccccc2-c2cc(-c3ccccc3)cc(-c3ccccc3)c2)cc(C(C)(C)C)c1] |
| Compound 49 | 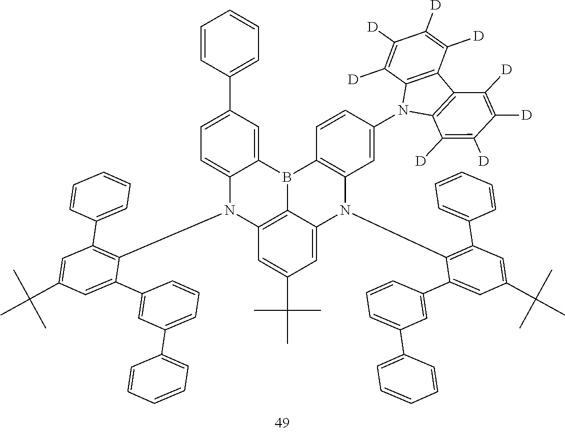 [SMILES: [2H]c1c([2H])c([2H])c2c(c1[2H])c1c([2H])c([2H])c([2H])c([2H])c1n2-c1ccc2c(c1)N(c1c(-c3ccccc3)cc(C(C)(C)C)cc1-c1cccc(-c3ccccc3)c1)c1cc(C(C)(C)C)cc3c1B2c1cc(-c2ccccc2)ccc1N3c1c(-c2ccccc2)cc(C(C)(C)C)cc1-c1cccc(-c2ccccc2)c1] |
| Compound 66 | 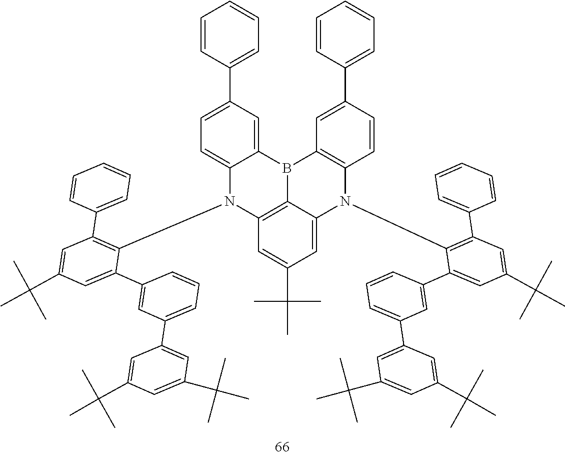 [SMILES: CC(C)(C)c1cc(-c2cccc(-c3cc(C(C)(C)C)cc(-c4ccccc4)c3N3c4ccc(-c5ccccc5)cc4B4c5cc(-c6ccccc6)ccc5N(c5c(-c6ccccc6)cc(C(C)(C)C)cc5-c5cccc(-c6cc(C(C)(C)C)cc(C(C)(C)C)c6)c5)c5cc(C(C)(C)C)cc3c54)c2)cc(C(C)(C)C)c1] |
| — | — |
| Comparative Compound C- 1 | 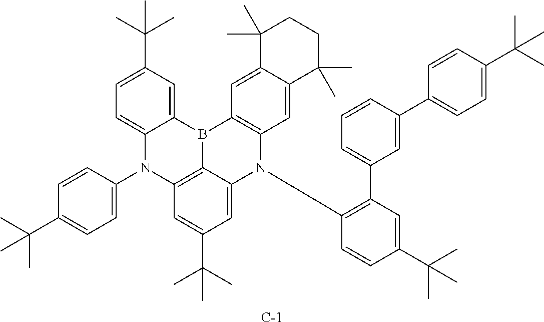 |
| Comparative Compound SR-1 | 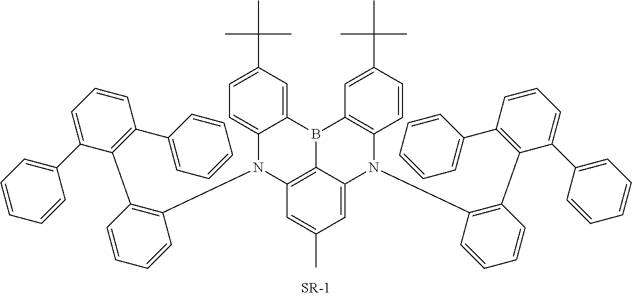 [SMILES: Cc1cc2c3c(c1)N(c1ccccc1-c1c(-c4ccccc4)cccc1-c1ccccc1)c1ccc(C(C)(C)C)cc1B3c1cc(C(C)(C)C)ccc1N2c1ccccc1-c1c(-c2ccccc2)cccc1-c1ccccc1] |
| Comparative Compound SR-2 | 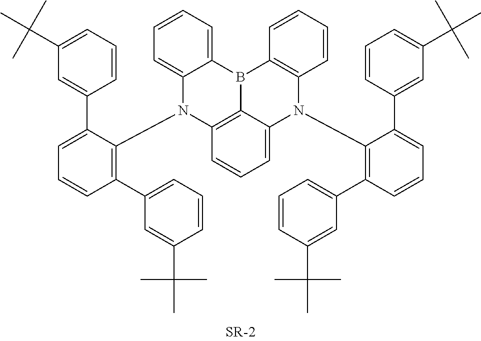 [SMILES: CC(C)(C)c1cccc(-c2cccc(-c3cccc(C(C)(C)C)c3)c2N2c3ccccc3B3c4ccccc4N(c4c(-c5cccc(C(C)(C)C)c5)cccc4-c4cccc(C(C)(C)C)c4)c4cccc2c43)c1] |
| Comparative SR-3 | 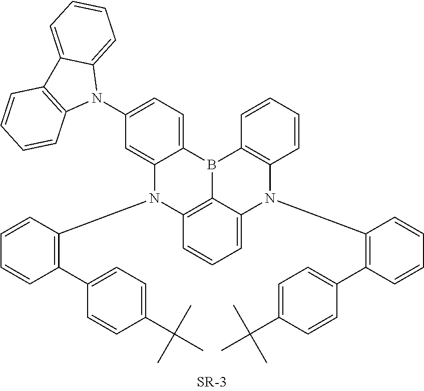 [SMILES: CC(C)(C)c1ccc(-c2ccccc2N2c3ccccc3B3c4ccc(-n5c6ccccc6c6ccccc65)cc4N(c4ccccc4-c4ccc(C(C)(C)C)cc4)c4cccc2c43)cc1] |
| Comparative Compound SR-4 | 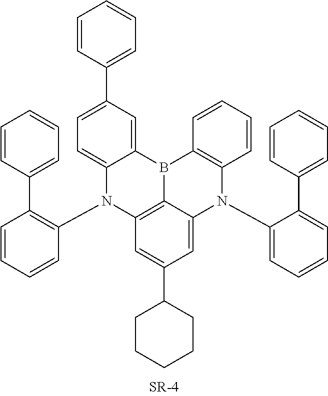 [SMILES: c1ccc(-c2ccc3c(c2)B2c4ccccc4N(c4ccccc4-c4ccccc4)c4cc(C5CCCCC5)cc(c42)N3c2ccccc2-c2ccccc2)cc1] |
| Comparative Compound SR-5 | 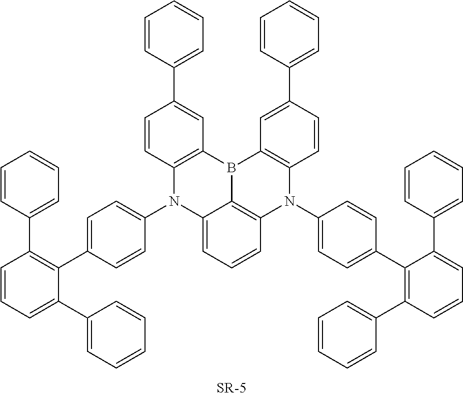 [SMILES: c1ccc(-c2ccc3c(c2)B2c4cc(-c5ccccc5)ccc4N(c4ccc(-c5c(-c6ccccc6)cccc5-c5ccccc5)cc4)c4cccc(c42)N3c2ccc(-c3c(-c4ccccc4)cccc3-c3ccccc3)cc2)cc1] |

### (2) Evaluation of Light Emitting Elements

In Table 2, the light emitting elements of the Examples and Comparative Examples were evaluated and shown. With respect to the light emitting elements of the Examples and Comparative Examples, a driving voltage (V) at a current density of about 1000 cd/cm², emission efficiency (cd/A), and emission wavelength were measured utilizing Keithley MU 236 and a luminance meter PR650. The lifetime was obtained by measuring time consumed for reducing the initial luminance to 95% of the initial value and the values shown in Table 2 are relative values based on utilizing the e value of the light emitting element of Comparative Example 1 as 1. That is, the lifetime values shown in Table 2 are ratios between the lifetime value of the light emitting element of an Example or a Comparative Example with that of Comparative Example 1.

TABLE 2

| Element | | | | Driving | Emission | Emission | |
|---|---|---|---|---|---|---|---|
| manufacturing | Host | | | voltage | efficiency | wavelength | Lifetime |
| example | (HT:ET = 5:5) | Sensitizer | Dopant | (V) | (cd/A) | (nm) | (T95) |
| Example 1 | HT3/ETH66 | AD-38 | Compound 8 | 4.6 | 26.1 | 460 | 5.7 |
| Example 2 | HT3/ETH66 | AD-38 | Compound 13 | 4.4 | 26.0 | 461 | 6.1 |
| Example 3 | HT3/ETH66 | AD-38 | Compound 18 | 4.4 | 25.6 | 461 | 5.9 |
| Example 4 | HT3/ETH66 | AD-38 | Compound 32 | 4.5 | 26.2 | 461 | 5.3 |
| Example 5 | HT3/ETH66 | AD-38 | Compound 45 | 4.6 | 26.7 | 463 | 5.4 |
| Example 6 | HT3/ETH66 | AD-38 | Compound 49 | 4.5 | 25.9 | 462 | 6.2 |
| Example 7 | HT3/ETH66 | AD-38 | Compound 66 | 4.5 | 25.4 | 464 | 5.3 |
| Example 8 | HT3/ETH86 | AD-37 | Compound 8 | 4.5 | 25.9 | 459 | 6.1 |
| Example 9 | HT3/ETH86 | AD-37 | Compound 13 | 4.4 | 25.8 | 461 | 6.0 |
| Example 10 | HT3/ETH86 | AD-37 | Compound 18 | 4.5 | 26.0 | 460 | 5.8 |
| Example 11 | HT3/ETH86 | AD-37 | Compound 32 | 4.6 | 25.1 | 461 | 5.5 |
| Example 12 | HT3/ETH86 | AD-37 | Compound 45 | 4.6 | 24.7 | 462 | 5.1 |
| Example 13 | HT3/ETH86 | AD-37 | Compound 49 | 4.5 | 25.8 | 462 | 5.7 |
| Example 14 | HT3/ETH86 | AD-37 | Compound 66 | 4.7 | 24.3 | 464 | 4.9 |
| Comparative Example 1 | HT3/EHT66 | AD-38 | Comparative Compound C-1 | 5.3 | 19.7 | 462 | 1.0 |
| Comparative Example 2 | HT3/EHT66 | AD-38 | Comparative Compound SR-1 | 5.3 | 18.6 | 459 | 3.1 |
| Comparative Example 3 | HT3/EHT66 | AD-38 | Comparative Compound SR-2 | 5.8 | 15.4 | 456 | 1.3 |
| Comparative Example 4 | HT3/EHT66 | AD-38 | Comparative Compound SR-3 | 5.2 | 17.3 | 463 | 1.8 |
| Comparative Example 5 | HT3/EHT66 | AD-38 | Comparative Compound SR-4 | 5.4 | 18.1 | 464 | 2.2 |
| Comparative Example 6 | HT3/EHT66 | AD-38 | Comparative Compound SR-5 | 5.6 | 16.3 | 466 | 1.4 |

Referring to Table 2, it could be seen that the light emitting elements of Examples 1 to 14 showed higher emission efficiency and longer lifetime when compared to the light emitting elements of Comparative Examples 1 to 6. In addition, it could be seen that the light emitting elements of Examples 1 to 14 showed reduced driving voltages. The light emitting elements of Examples 1 to 14 include Compounds 8, 13, 18, 32, 45, 49, and 66, respectively, and Compounds 8, 13, 18, 32, 45, 49, and 66 are fused polycyclic compounds of embodiments.

Each of Compounds 8, 13, 18, 32, 45, 49, and 66 includes a fused ring of five rings as a central structure, and to each of the two nitrogen atoms which are ring-forming atoms of the fused ring of five rings, three phenyl groups (first to third phenyl groups, and fourth to sixth phenyl groups, respectively) are directly or indirectly bonded. In Compounds 8, 13, 18, 32, 45, 49, and 66, the three phenyl groups protect the central structures to prevent or reduce intermolecular interaction. Accordingly, the light emitting elements including Compounds 8, 13, 18, 32, 45, 49, and 66 may show lower driving voltages, higher efficiency and longer life characteristics.

The light emitting element of Comparative Example 1 includes Comparative Compound C-1, and in Comparative Compound C-1, three phenyl groups are bonded to only one nitrogen atom. The light emitting element of Comparative Example 2 includes Comparative Compound SR-1, and Comparative Compound SR-1 is different from the fused polycyclic compound of an embodiment in the bonding position of the third phenyl group with respect to the second phenyl group and the bonding position of the sixth phenyl group with respect to the fifth phenyl group. Accordingly, the light emitting elements of Comparative Examples 1 and 2 showed relatively higher driving voltages, lower emission efficiency and shorter lifetime.

The light emitting element of Comparative Example 3 includes Comparative Compound SR-2 which is different from the fused polycyclic compound of an embodiment in that the second and fifth phenyl groups are directly bonded to the nitrogen atoms. As described above, in the fused polycyclic compound of an embodiment, the first and fourth phenyl groups may be directly bonded to nitrogen atoms. Accordingly, the light emitting element of Comparative Examples 3 showed a relatively higher driving voltage, lower emission efficiency and shorter lifetime.

The light emitting elements of Comparative Examples 4 and 5 include Comparative Compounds SR-3 and SR-4, in which only two phenyl groups are bonded to the nitrogen atoms. The light emitting element of Comparative Example 6 includes Comparative Compound SR-5, and in Comparative Compound SR-5, three phenyl groups are bonded to the two nitrogen atoms, respectively. However, Comparative Compound SR-5 is different from the fused polycyclic compound of an embodiment in that the second and fifth phenyl groups are indirectly bonded to the nitrogen atoms via linkers (i.e., phenyl groups). In the fused polycyclic compound of an embodiment, the first and fourth phenyl groups may be directly bonded to nitrogen atoms. Accordingly, the light emitting elements of Comparative Examples 4 to 6 showed relatively higher driving voltages, lower emission efficiency and shorter lifetime.

In the light emitting element of an embodiment, the emission layer may include the fused polycyclic compound of an embodiment. The fused polycyclic compound of an embodiment may include a fused ring of five rings, including two nitrogen atoms and one boron atom as ring-forming atoms, as a central structure, and to each of the two nitrogen atoms, three phenyl groups may be bonded. Because the three phenyl groups may protect the central structure, the intermolecular interaction of the fused polycyclic compound of an embodiment may be prevented or reduced. Accordingly, the light emitting element including the fused polycyclic compound of an embodiment may show a low driving voltage, high efficiency and long-life characteristics.

The light emitting element of an embodiment includes the fused polycyclic compound of an embodiment and may show high efficiency and long-life characteristics.

The fused polycyclic compound of an embodiment may contribute to the improvement of the light efficiency and the increase of the lifetime of a light emitting element.

As used herein, the expression “at least one of a, b or c”, “at least one selected from a, b, and c”, “at least one selected from the group consisting of a, b, and c”, “at least one from among a, b, and c”, “at least one among a to c”, etc., indicates only a, only b, only c, both (e.g., simultaneously) a and b, both (e.g., simultaneously) a and c, both (e.g., simultaneously) b and c, all of a, b, and c, or variations thereof.

The use of “may” when describing embodiments of the present disclosure refers to “one or more embodiments of the present disclosure”.

As used herein, the terms “substantially”, “about”, and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

The display device, and/or any other relevant devices or components according to embodiments of the present invention described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

Although the embodiments of the present disclosure have been described, it is understood that the subject matter of the present disclosure should not be limited to these embodiments, but various suitable changes and modifications can be made by one ordinary skilled in the art within the spirit and scope of the present disclosure as hereinafter claimed, and equivalents thereof.

What is claimed is:

1. A light emitting element, comprising:
a first electrode;
a second electrode on the first electrode; and
an emission layer between the first electrode and the second electrode, wherein the emission layer comprises:
a first compound represented by Formula 1; and
at least one among a second compound represented by Formula HT-1, a third compound represented by Formula ET-1, and a fourth compound represented by Formula M-b: 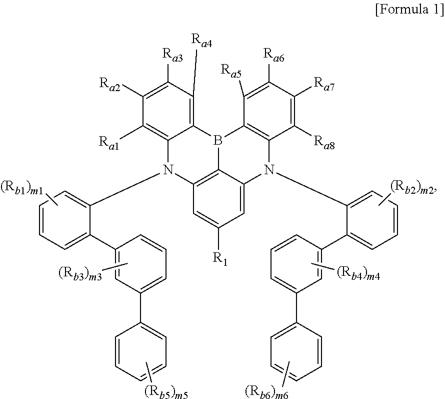
wherein in Formula 1,
R₁ is a hydrogen atom, a deuterium atom, a substituted or unsubstituted alkyl group of 1 to 60 carbon atoms, a substituted or unsubstituted aryl group of 6 to 60 ring-forming carbon atoms, or a substituted or unsubstituted heteroaryl group of 2 to 60 ring-forming carbon atoms,
m1 to m4 are each independently an integer of 0 to 4,
m5 and m6 are each independently an integer of 0 to 5,
R_{b1} to R_{b6} are each independently a hydrogen atom, a deuterium atom, a cyano group, a halogen atom, a substituted or unsubstituted alkyl group of 1 to 60 carbon atoms, a substituted or unsubstituted aryl group of 6 to 60 ring-forming carbon atoms, or a substituted or unsubstituted heteroaryl group of 2 to 60 ring-forming carbon atoms,
at least one among Rₐ₁ to Rₐ₄ is a substituted or unsubstituted aryl amine group, a substituted or unsubstituted aryl group of 6 to 60 ring-forming carbon atoms, or a substituted or unsubstituted heteroaryl group of 2 to 60 ring-forming carbon atoms, and any remainder thereof are each independently a hydrogen atom or a deuterium atom, and
at least one among Rₐ₅ to Rₐ₈ is a substituted or unsubstituted aryl amine group, a substituted or unsubstituted aryl group of 6 to 60 ring-forming carbon atoms, or a substituted or unsubstituted heteroaryl group of 2 to 60 ring-forming carbon atoms, and any remainder thereof are each independently a hydrogen atom or a deuterium atom: 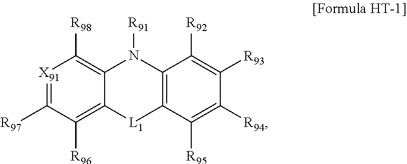
wherein in Formula HT-1,
L₁ is a direct linkage, CR₉₉R₁₀₀, or SiR₁₀₁R₁₀₂,
X₉₁ is N or CR₁₀₃, and
R₉₁ to R₁₀₃ are each independently a hydrogen atom, a deuterium atom, a cyano group, a substituted or unsubstituted silyl group, a substituted or unsubstituted oxy group, a substituted or unsubstituted alkyl group of 1 to 60 carbon atoms, a substituted or unsubstituted aryl group of 6 to 60 ring-forming carbon atoms, or a substituted or unsubstituted heteroaryl group of 2 to 60 ring-forming carbon atoms, and/or combined with an adjacent group to form a ring: 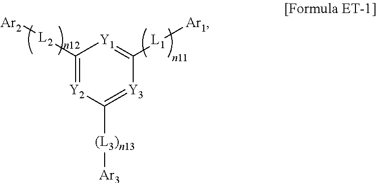
wherein in Formula ET-1,
at least one among Y₁ to Y₃ is N, and any remainder thereof are each independently CR₈₁,
R₈₁ is a hydrogen atom, a deuterium atom, a substituted or unsubstituted alkyl group of 1 to 20 carbon atoms, a substituted or unsubstituted aryl group of 6 to 60 ring-forming carbon atoms, or a substituted or unsubstituted heteroaryl group of 2 to 60 ring-forming carbon atoms,
n11 to n13 are each independently an integer of 0 to 10,
L₁ to L₃ are each independently a direct linkage, a substituted or unsubstituted arylene group of 6 to 30 ring-forming carbon atoms, or a substituted or unsubstituted heteroarylene group of 2 to 30 ring-forming carbon atoms, and
Ar₁ to Ar₃ are each independently a hydrogen atom, a deuterium atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms: 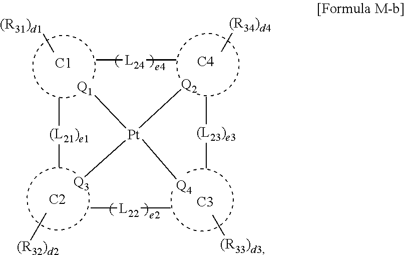
wherein in Formula M-b,
Q₁ to Q₄ are each independently C or N,
C1 to C4 are each independently a substituted or unsubstituted hydrocarbon ring of 5 to 30 ring-forming carbon atoms, or a substituted or unsubstituted heterocycle of 2 to 30 ring-forming carbon atoms,
e1 to e4 are each independently 0 or 1,
L₂₁ to L₂₄ are each independently a direct linkage, 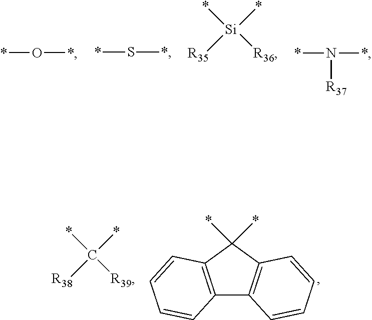
a substituted or unsubstituted divalent alkyl group of 1 to 20 carbon atoms, a substituted or unsubstituted arylene group of 6 to 30 ring-forming carbon atoms, or a substituted or unsubstituted heteroarylene group of 2 to 30 ring-forming carbon atoms,
d1 to d4 are each independently an integer of 0 to 4, and
R₃₁ to R₃₉ are each independently a hydrogen atom, a deuterium atom, a halogen atom, a cyano group, a substituted or unsubstituted amine group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, and/or combined with an adjacent group to form a ring.

2. The light emitting element of claim 1, wherein the first compound represented by Formula 1 is represented by any one among Formula 1-1 to Formula 1-3: 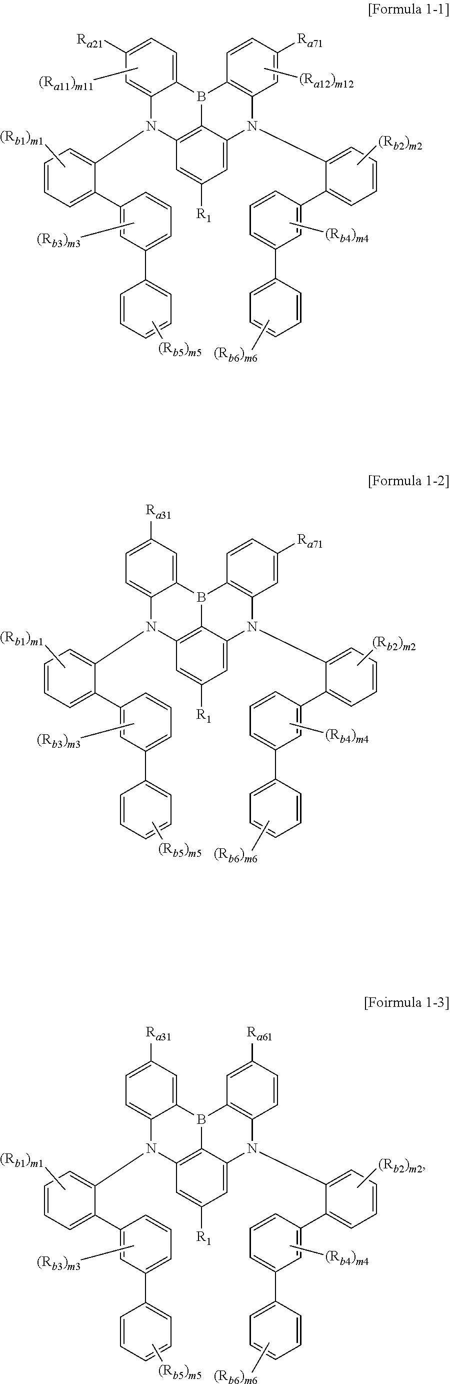
wherein in Formula 1-1,
m11 and m12 are each independently an integer of 0 to 3, and
Rₐ₁₁ and Rₐ₁₂ are each independently a hydrogen atom or a deuterium atom, and
in Formula 1-1 to Formula 1-3,
Rₐ₂₁, Rₐ₃₁, Rₐ₆₁, and Rₐ₇₁ are each independently a substituted or unsubstituted aryl amine group, a substituted or unsubstituted aryl group of 6 to 60 ring-forming carbon atoms, or a substituted or unsubstituted heteroaryl group of 2 to 60 ring-forming carbon atoms, and
R₁, m1 to m6, and R_{b1} to R_{b6} are the same as defined in Formula 1.

3. The light emitting element of claim 2, wherein, in Formula 1-1 to Formula 1-3, Rₐ₂₁, Rₐ₃₁, Rₐ₆₁, and Rₐ₇₁ are each independently a substituted or unsubstituted diphenylamine group, a substituted or unsubstituted phenyl group, a substituted or unsubstituted carbazole group, a substituted or unsubstituted dibenzofuran group, or a substituted or unsubstituted phenoxazine group.

4. The light emitting element of claim 2, wherein, in Formula 1-1 to Formula 1-3, Rₐ₂₁, Rₐ₃₁, Rₐ₆₁, and Rₐ₇₁ are each independently represented by any one among Formulae RA-1 to RA-6: 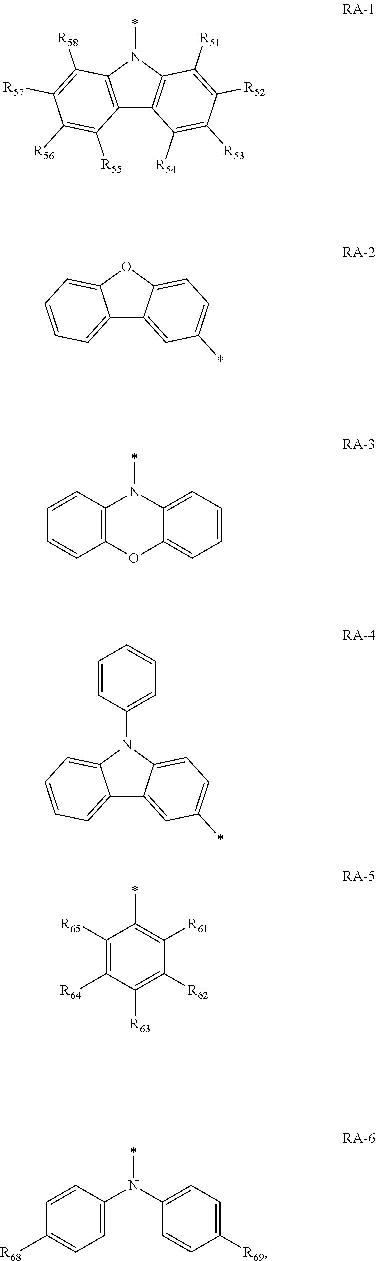
wherein in Formula RA-1,
R₅₁ to R₅₈ are each independently a hydrogen atom, a deuterium atom, a cyano group, an unsubstituted t-butyl group, or an unsubstituted phenyl group,
in Formula RA-5,
R₆₁ to R₆₅ are each independently a hydrogen atom, a deuterium atom, an unsubstituted t-butyl group, an unsubstituted phenyl group, or an unsubstituted carbazole group, and
in Formula RA-6,
R₆₈ and R₆₉ are each independently a hydrogen atom, a deuterium atom, or an unsubstituted t-butyl group.

5. The light emitting element of claim 1, wherein the first compound represented by Formula 1 is represented by Formula 1-A or Formula 1-B: 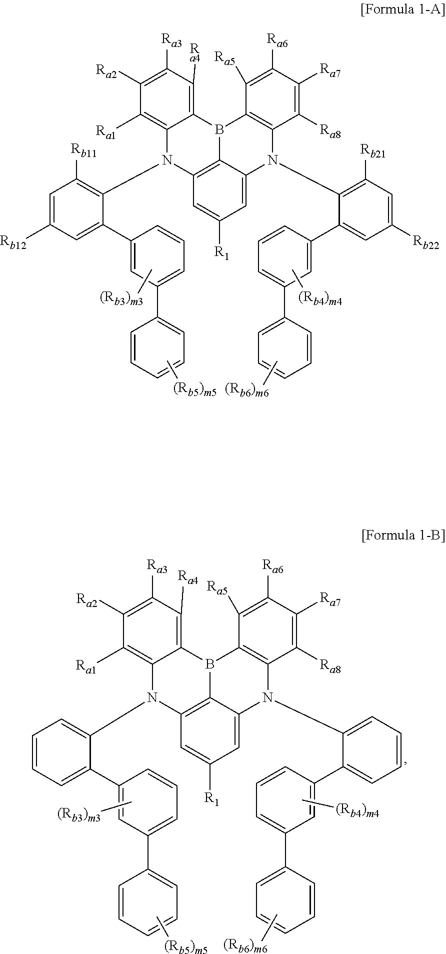
wherein in Formula 1-A,
R_{b11}, R_{b12}, R_{b21}, and R_{b22} are each independently a substituted or unsubstituted alkyl group of 1 to 20 carbon atoms or a substituted or unsubstituted aryl group of 6 to 20 ring-forming carbon atoms, and
in Formula 1-A and Formula 1-B,
Rₐ₁ to Rₐ₈, R₁, m3 to m6, and R_{b3} to R_{b6} are the same as defined in Formula 1.

6. The light emitting element of claim 5, wherein, in Formula 1-A, R_{b11}, R_{b12}, R_{b21}, and R_{b22} are each independently a substituted or unsubstituted t-butyl group or a substituted or unsubstituted phenyl group.

7. The light emitting element of claim 5, wherein the first compound represented by Formula 1-A is represented by Formula 1-A1 or Formula 1-A2: 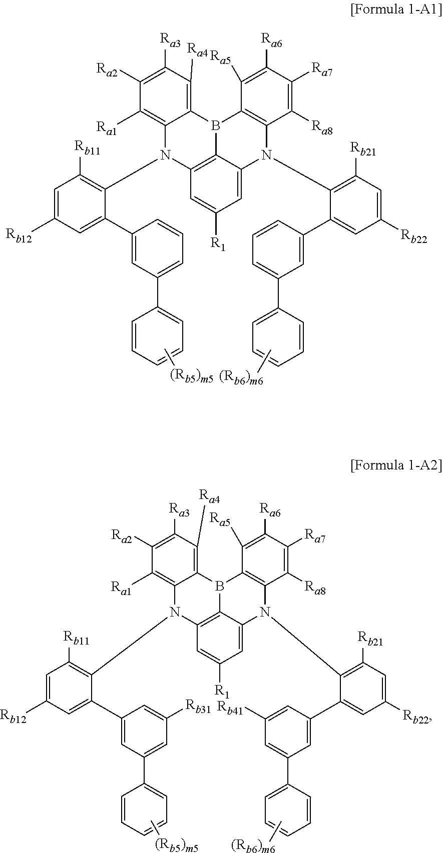
wherein in Formula 1-A2,
R_{b31} and R_{b41} are each independently a substituted or unsubstituted alkyl group of 1 to 20 carbon atoms or a substituted or unsubstituted aryl group of 6 to 20 ring-forming carbon atoms, and
in Formula 1-A1 and Formula 1-A2,
Rₐ₁ to Rₐ₈, R₁, m5, m6, R_{b5}, R_{b6}, R_{b11}, R_{b12}, R_{b21}, and R_{b22} are the same as defined in Formula 1-A.

8. The light emitting element of claim 7, wherein the first compound represented by Formula 1-A1 is represented by Formula 1-A11 or Formula 1-A12: 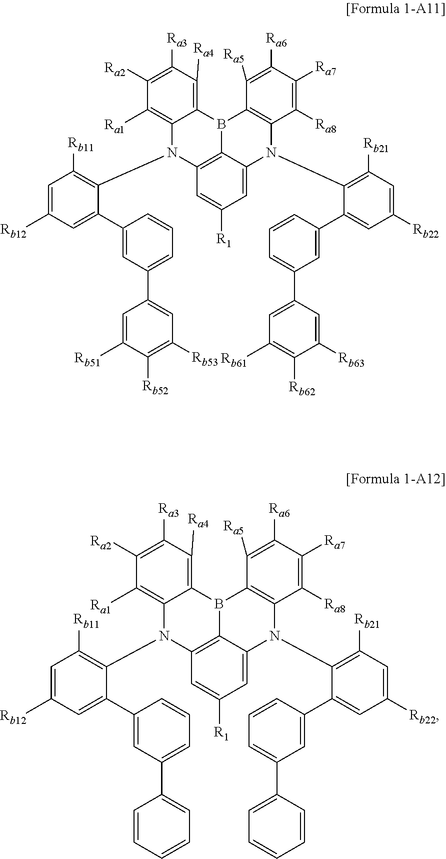
wherein in Formula 1-A11,
at least one among R_{b51} to R_{b53} is a substituted or unsubstituted alkyl group of 1 to 20 carbon atoms or a substituted or unsubstituted aryl group of 6 to 20 ring-forming carbon atoms, and any remainder thereof are hydrogen atoms, and
at least one among R_{b61} to R_{b63} is a substituted or unsubstituted alkyl group of 1 to 20 carbon atoms or a substituted or unsubstituted aryl group of 6 to 20 ring-forming carbon atoms, and any remainder thereof are hydrogen atoms, and
in Formula 1-A11 and Formula 1-A12,
Rₐ₁ to Rₐ₈, R₁, R_{b11}, R_{b12}, R_{b21}, and R_{b22} are the same as defined in Formula 1-A1.

9. The light emitting element of claim 1, wherein, in Formula 1, R₁ is a substituted or unsubstituted t-butyl group, a substituted or unsubstituted phenyl group, a substituted or unsubstituted dibenzofuran group, or a substituted or unsubstituted carbazole group.

10. The light emitting element of claim 1, wherein, in Formula 1, R₁ is represented by any one among Formulae R1-1 to R1-9:

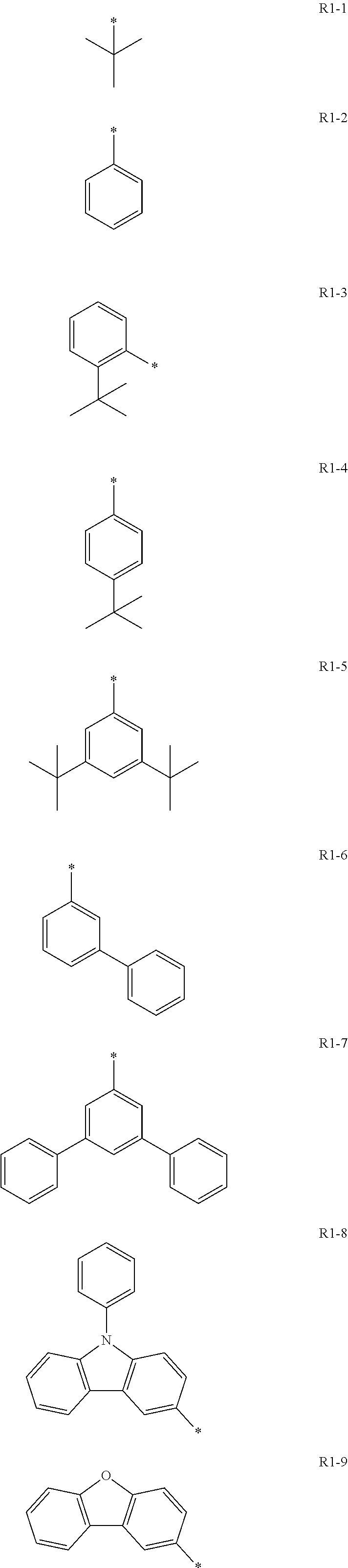

11. The light emitting element of claim 1, wherein, in Formula 1, at least one among Rₐ₁ to Rₐ₈ comprises a deuterium atom, or a substituent comprising a deuterium atom.

12. The light emitting element of claim 1, wherein the first compound is represented by any one among compounds in Compound Group 1: 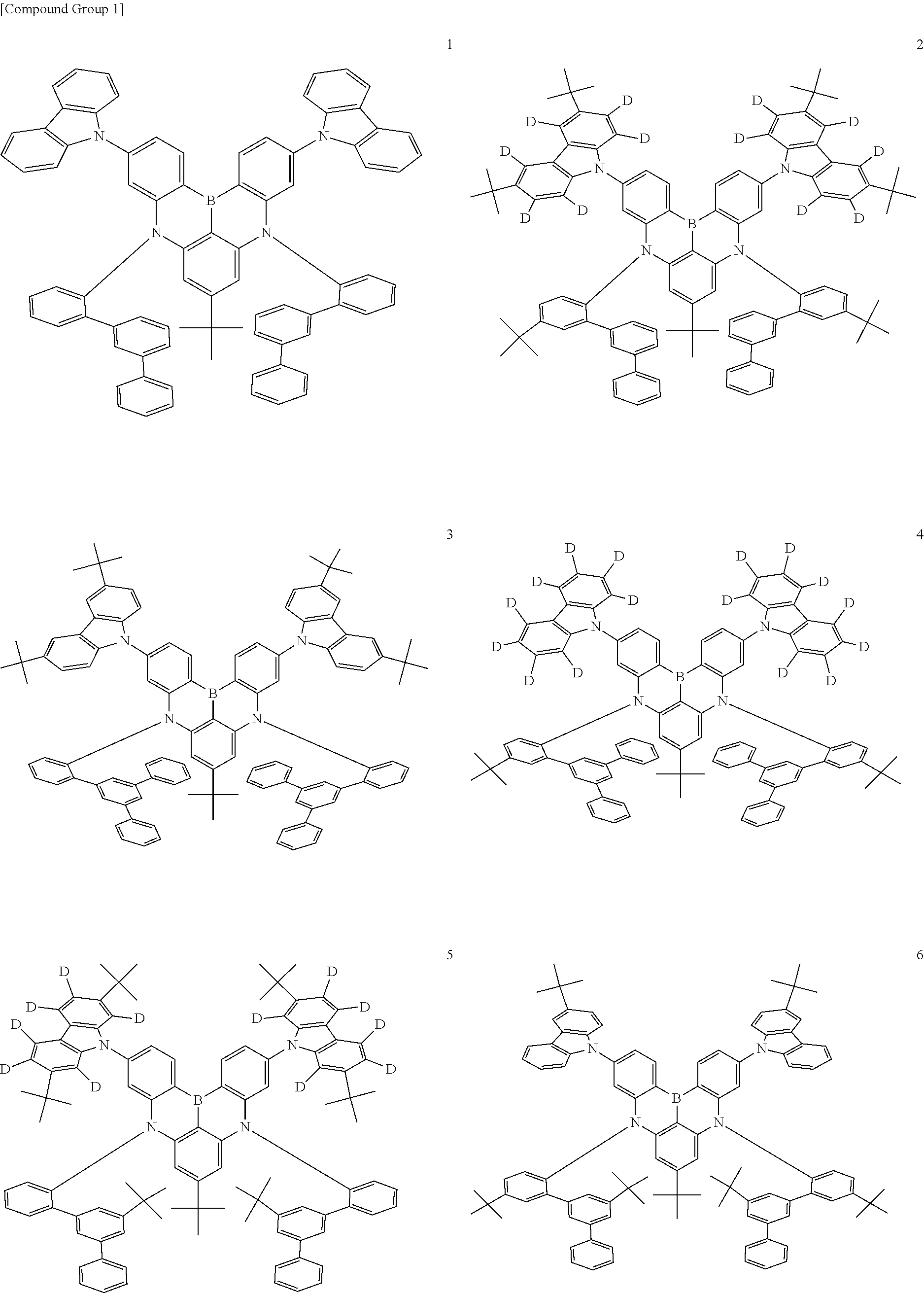 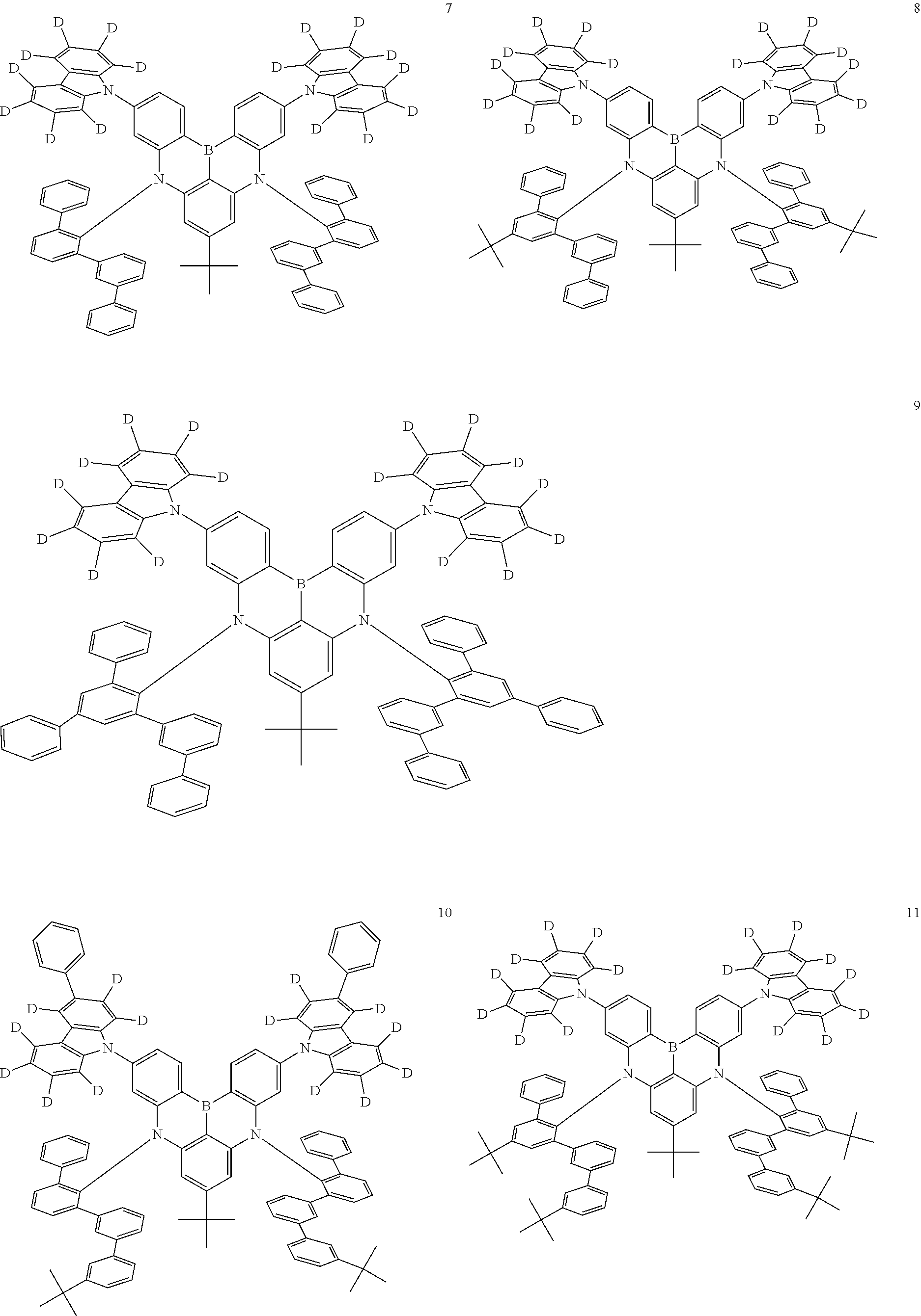 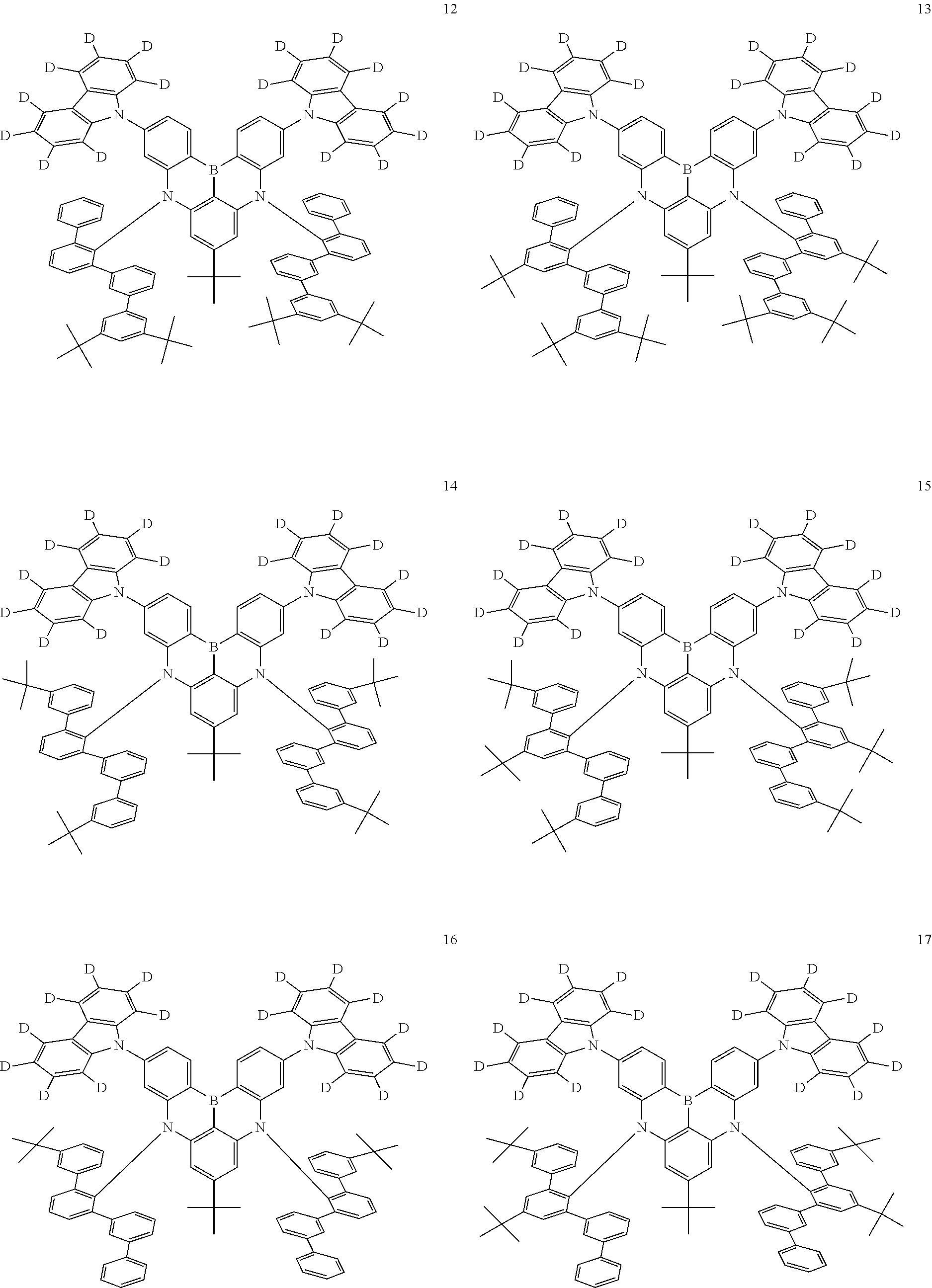 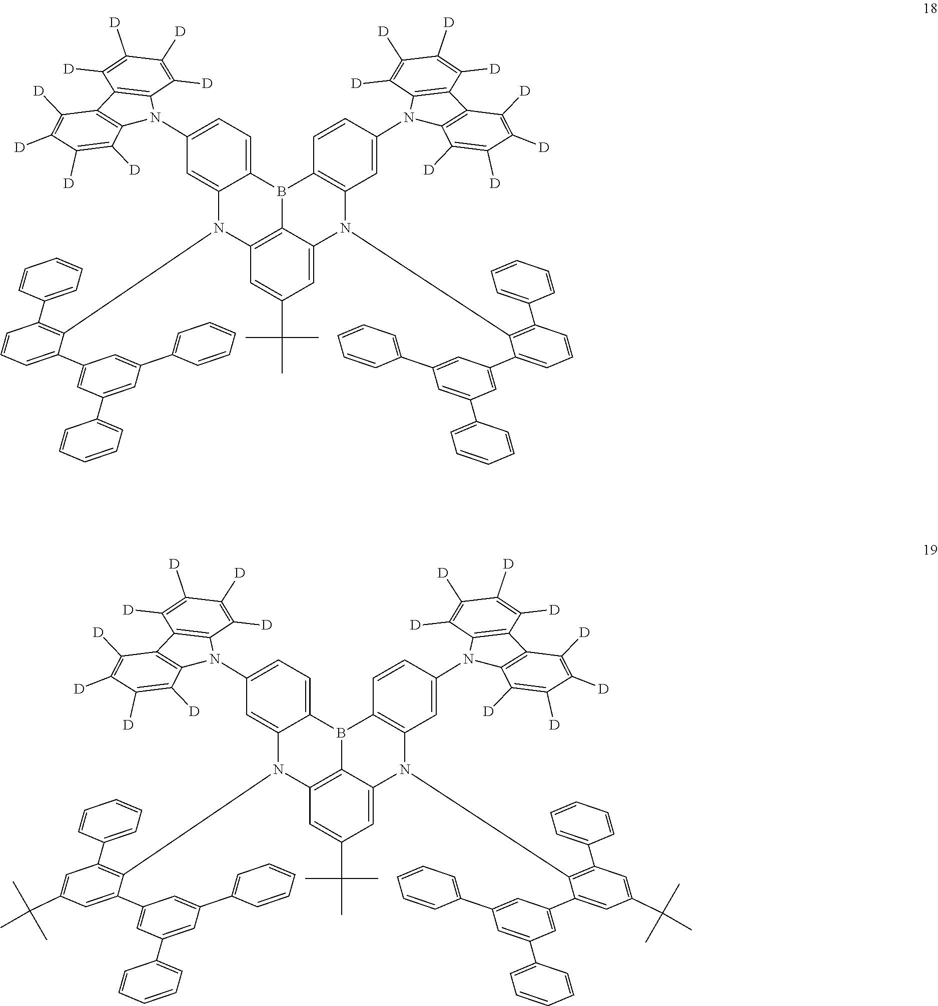 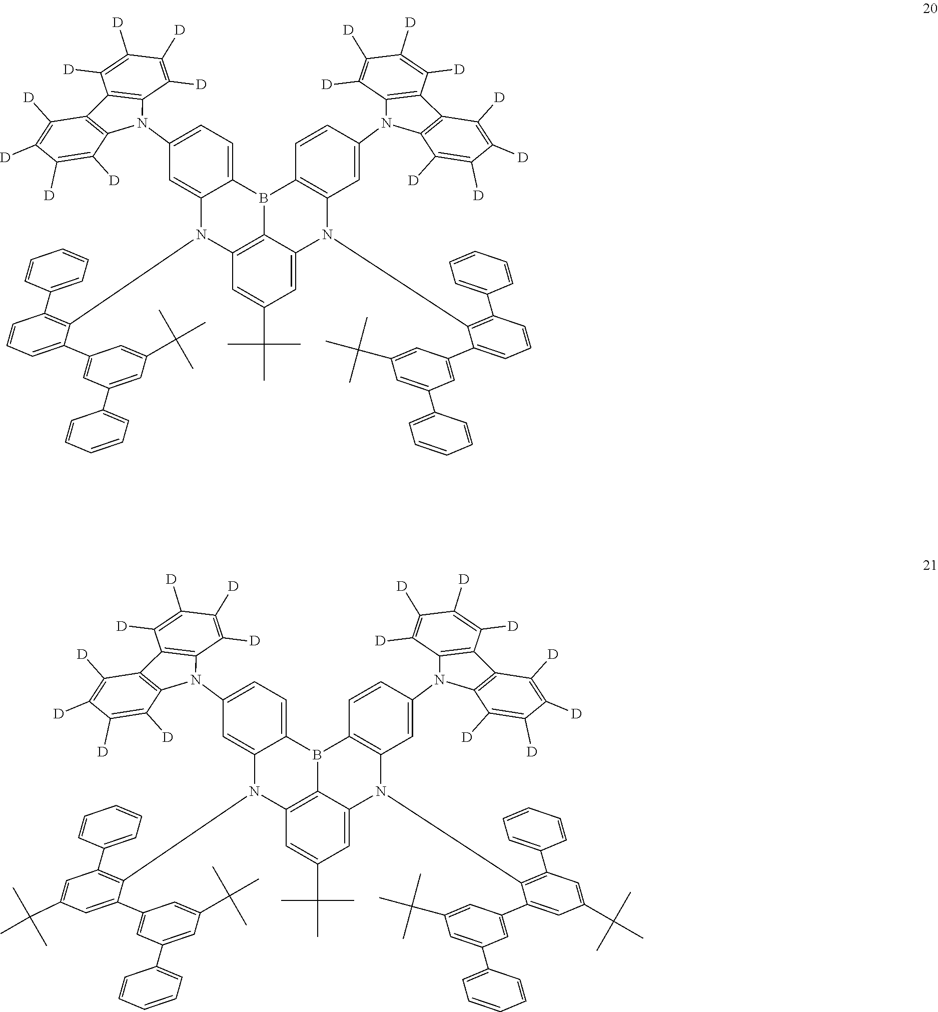 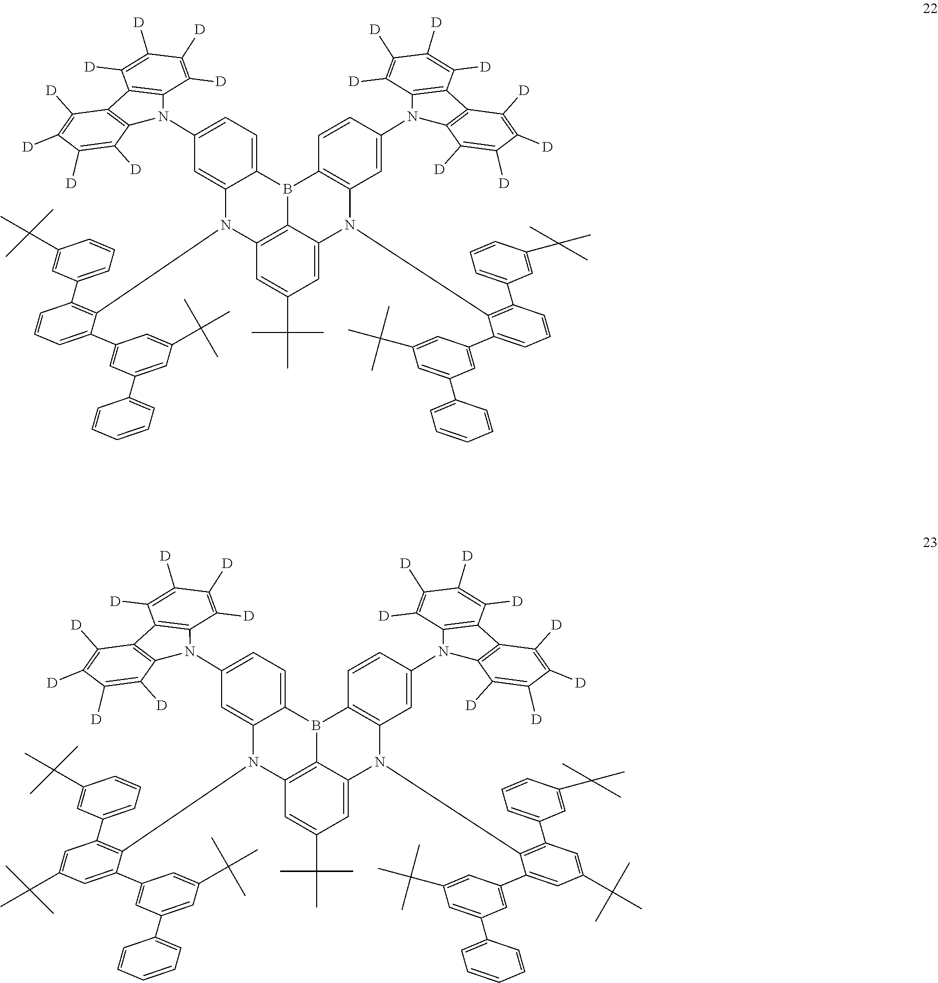 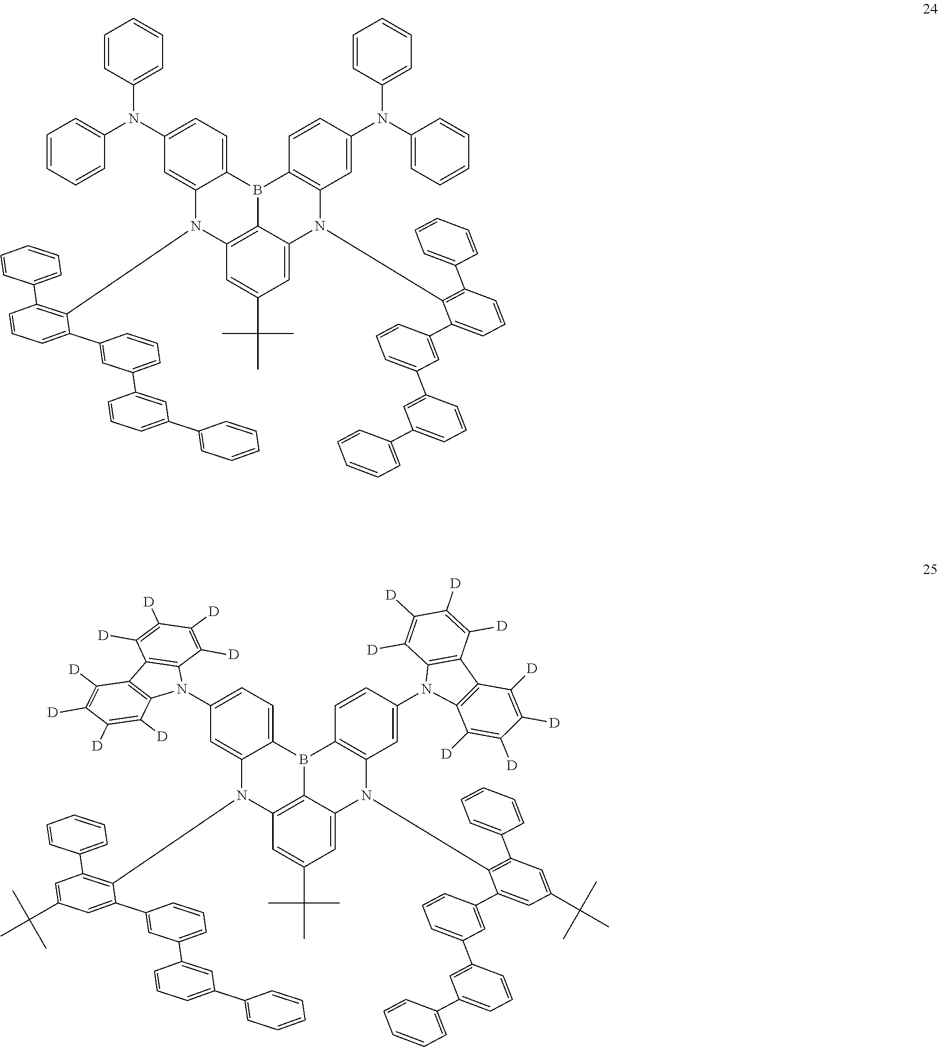 [SMILES: CC(C)(C)c1cc2c3c(c1)N(c1c(-c4ccccc4)cccc1-c1cccc(-c4cccc(-c5ccccc5)c4)c1)c1cc(N(c4ccccc4)c4ccccc4)ccc1B3c1ccc(N(c3ccccc3)c3ccccc3)cc1N2c1c(-c2ccccc2)cccc1-c1cccc(-c2cccc(-c3ccccc3)c2)c1 ; [2H]c1c([2H])c([2H])c2c(c1[2H])c1c([2H])c([2H])c([2H])c([2H])c1n2-c1ccc2c(c1)N(c1c(-c3ccccc3)cc(C(C)(C)C)cc1-c1cccc(-c3cccc(-c4ccccc4)c3)c1)c1cc(C(C)(C)C)cc3c1B2c1ccc(-n2c4c([2H])c([2H])c([2H])c([2H])c4c4c([2H])c([2H])c([2H])c([2H])c42)cc1N3c1c(-c2ccccc2)cc(C(C)(C)C)cc1-c1cccc(-c2cccc(-c3ccccc3)c2)c1] 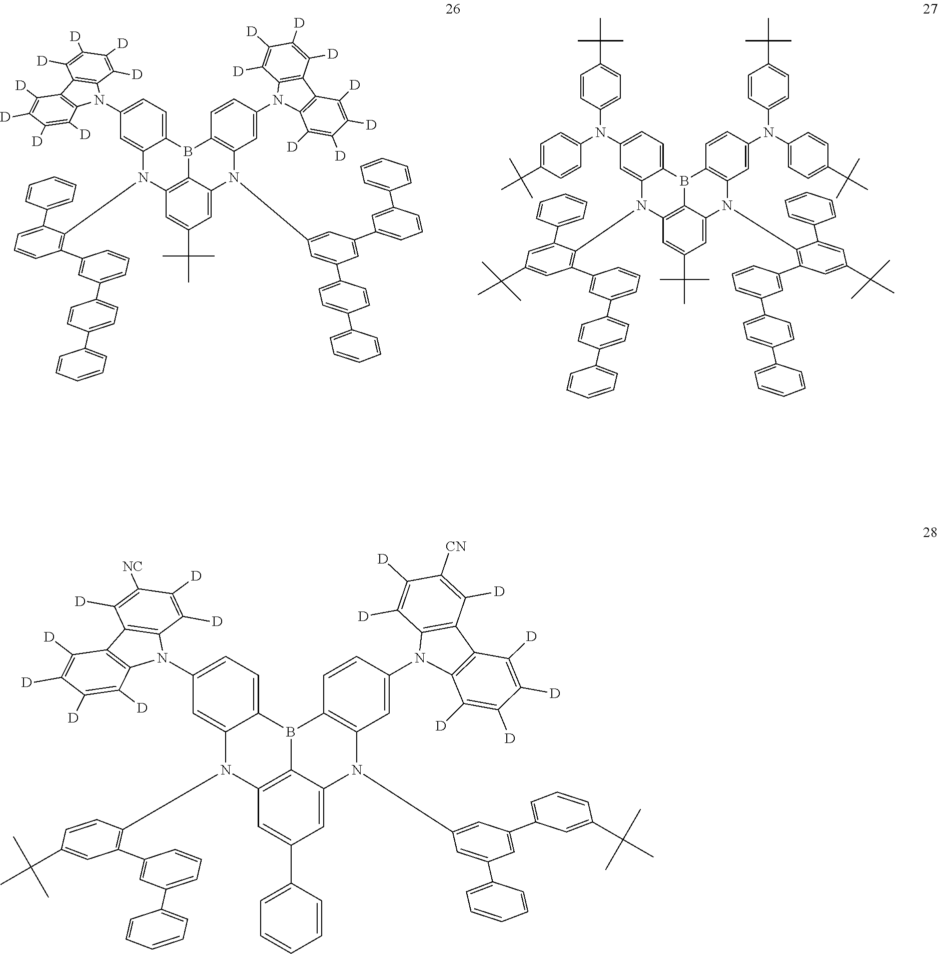 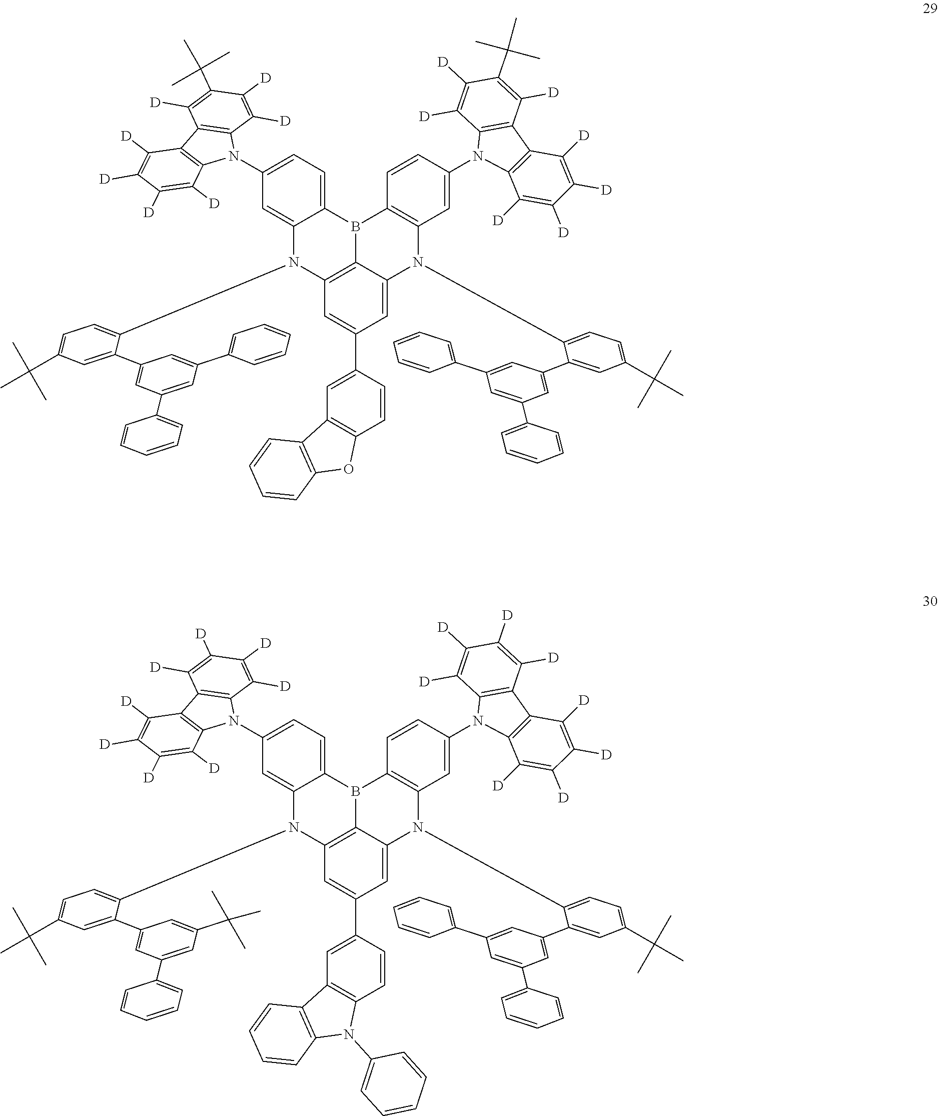 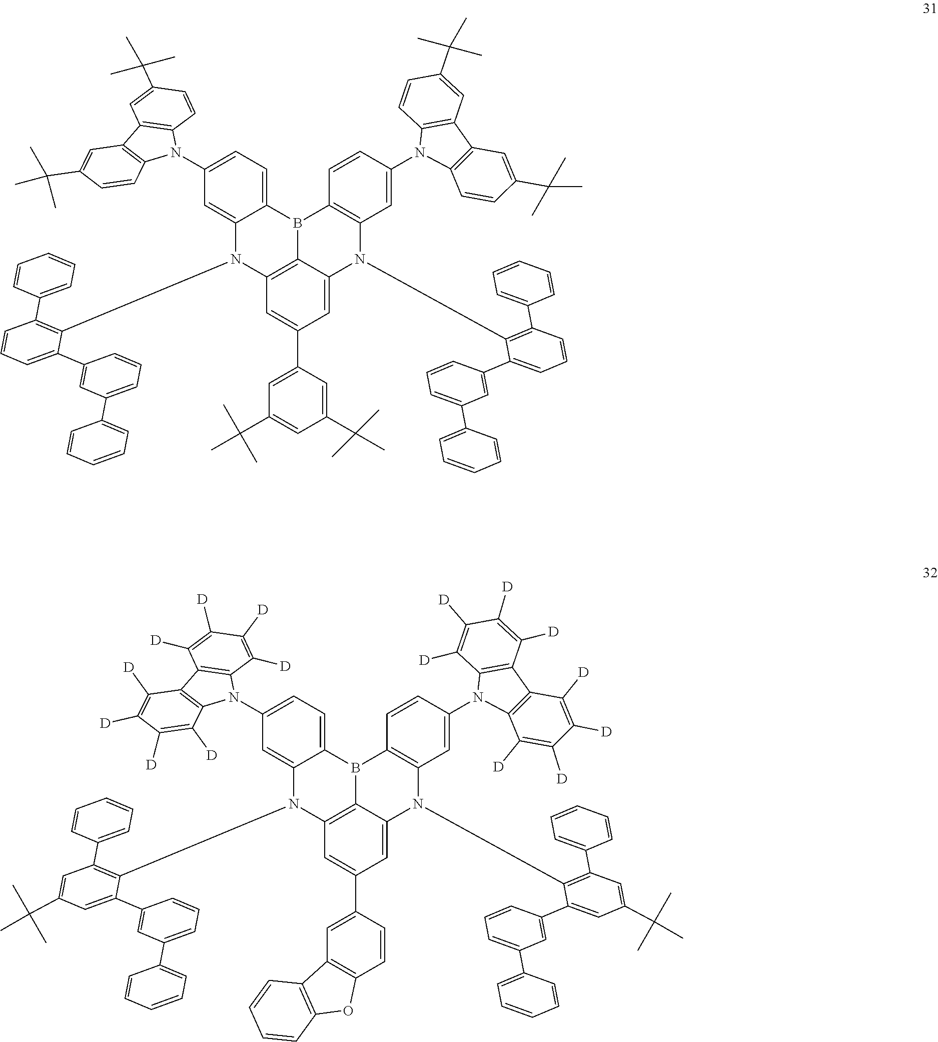 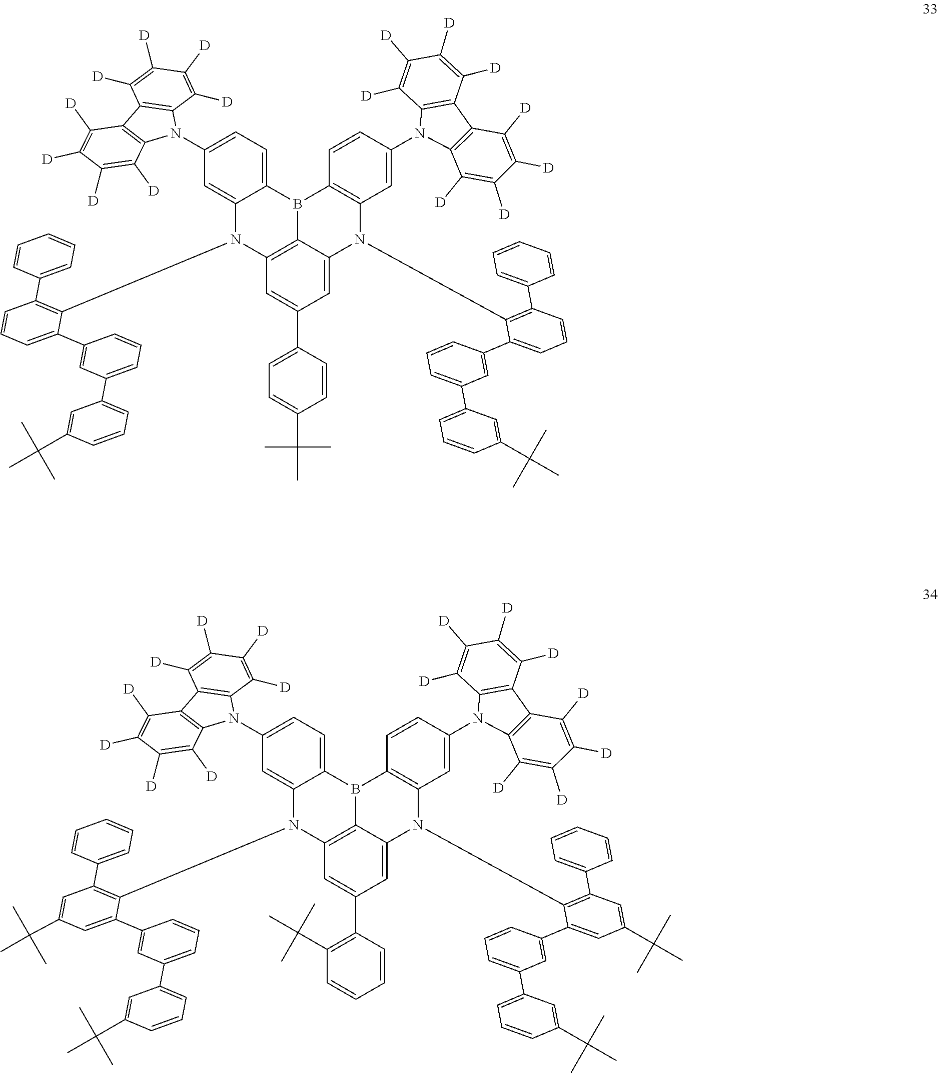 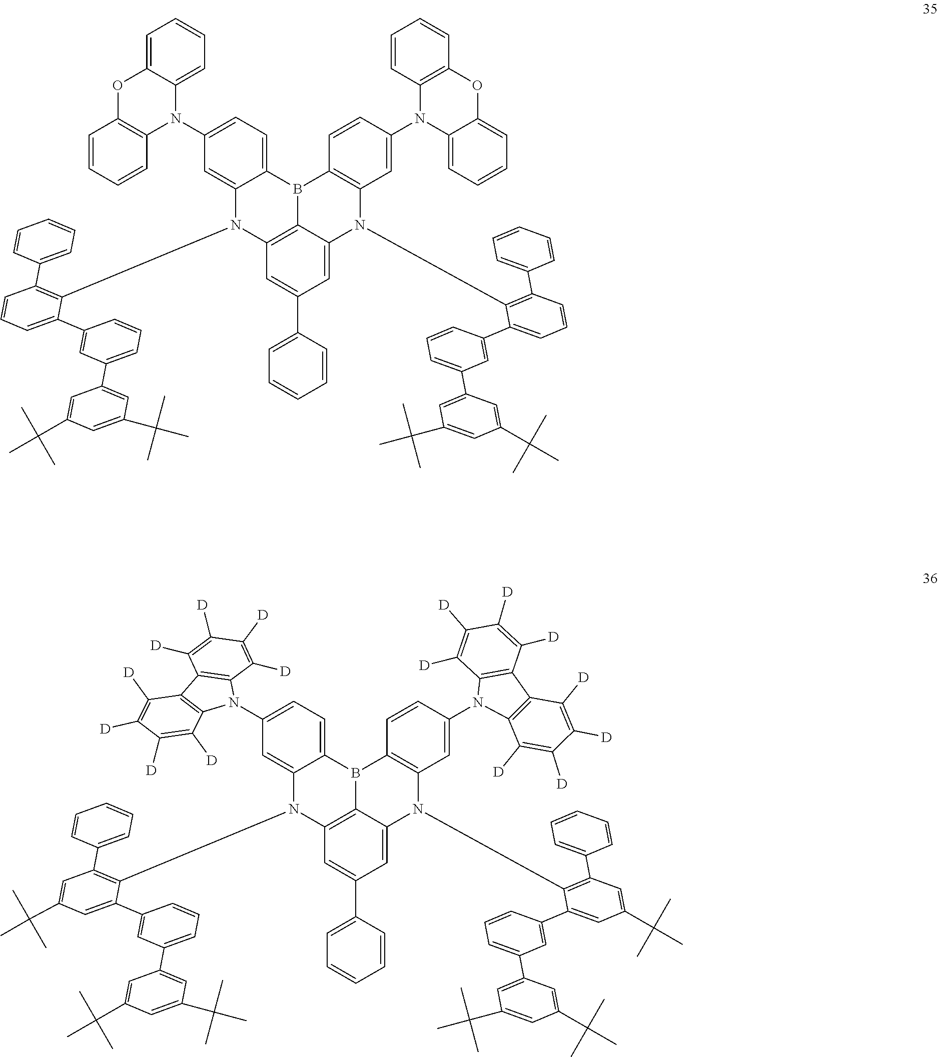 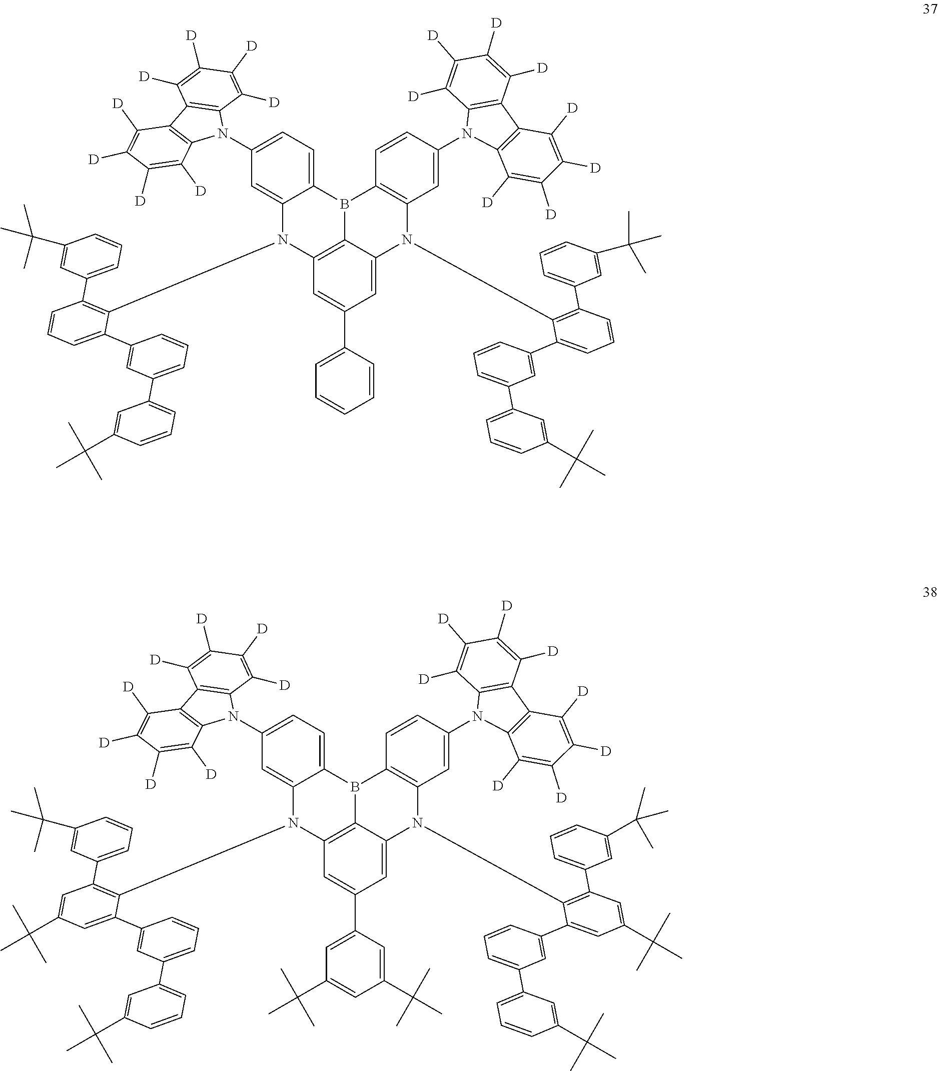 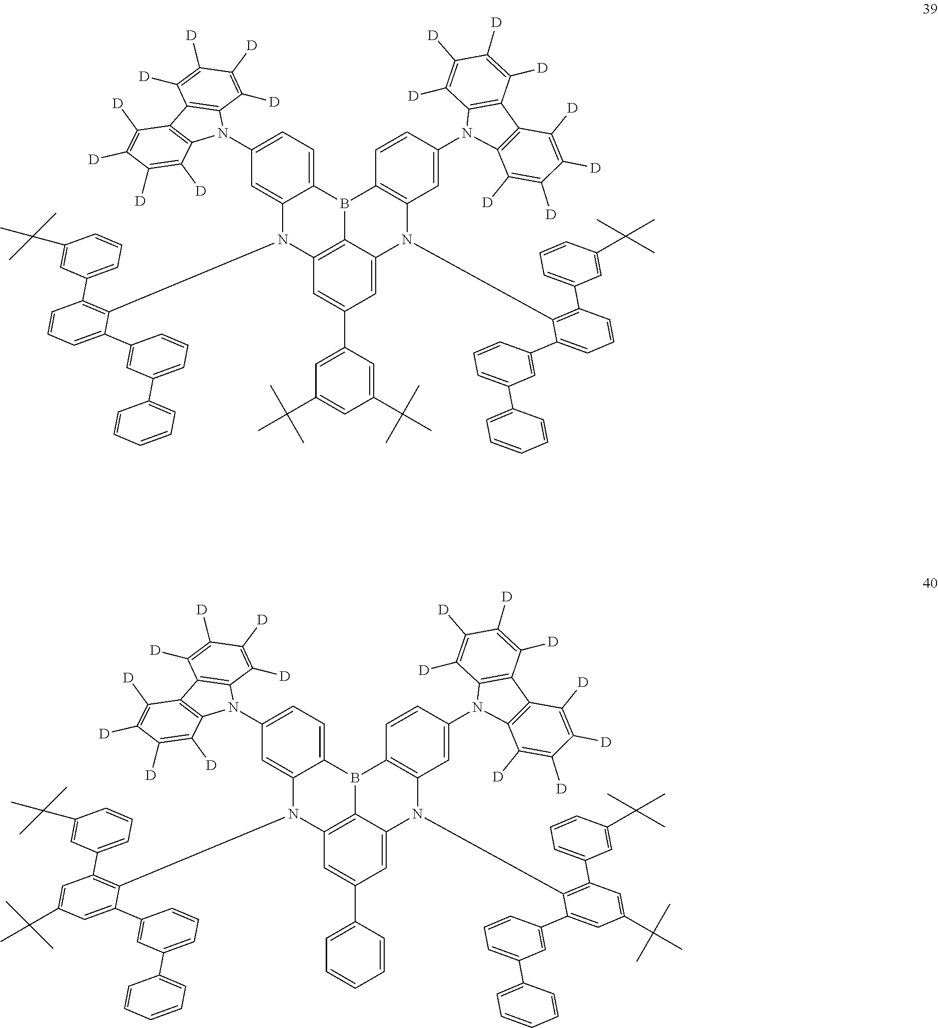 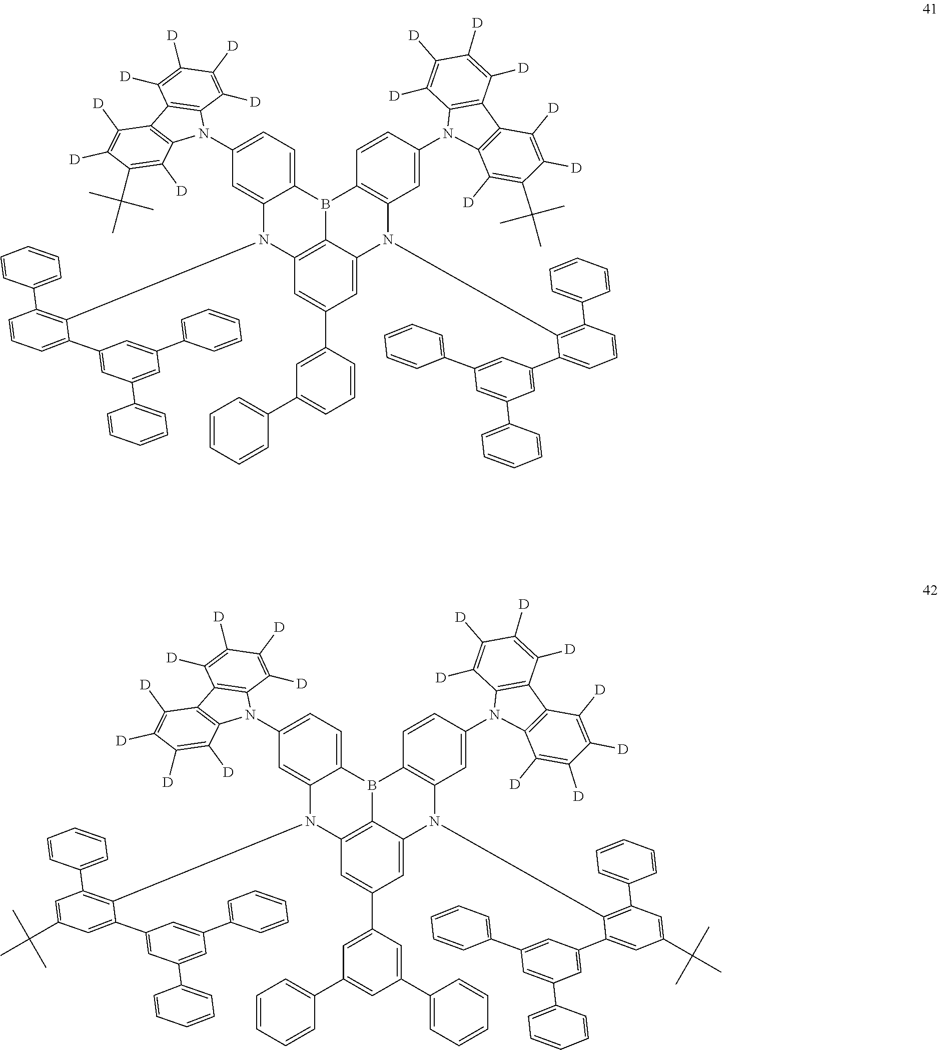 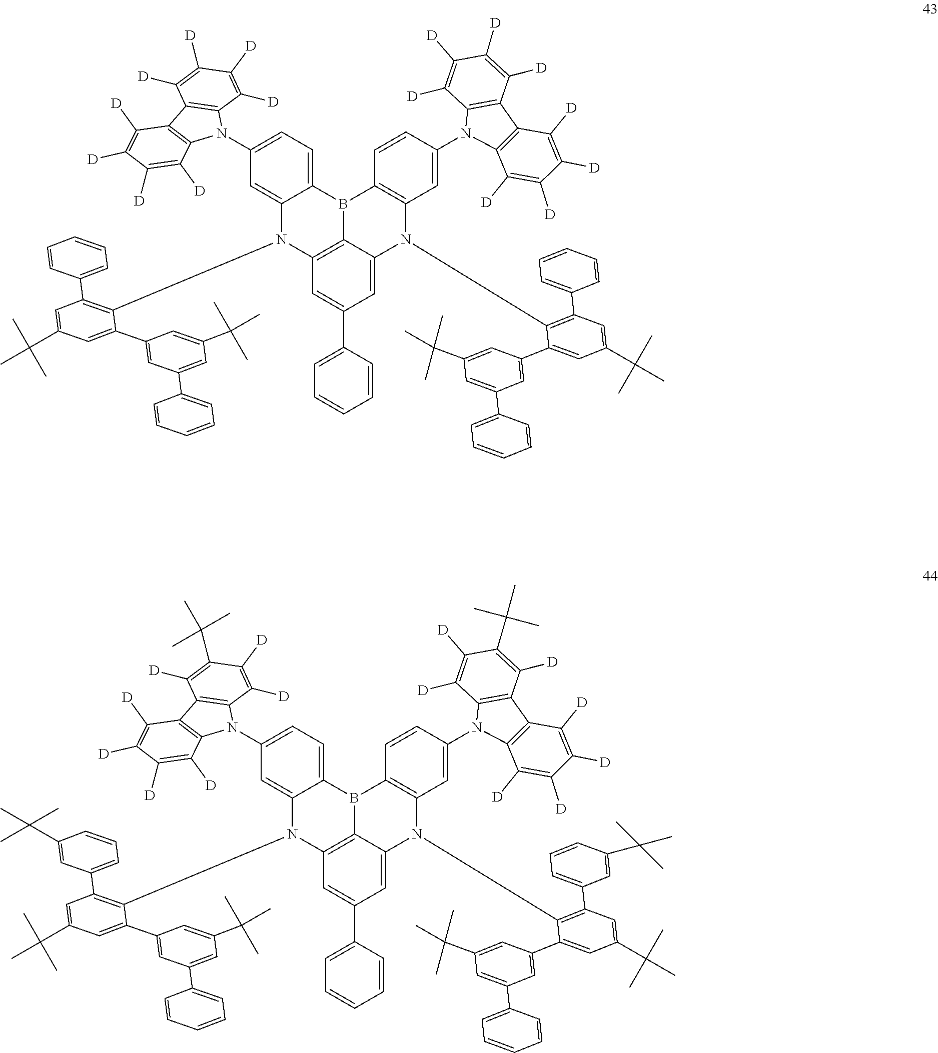 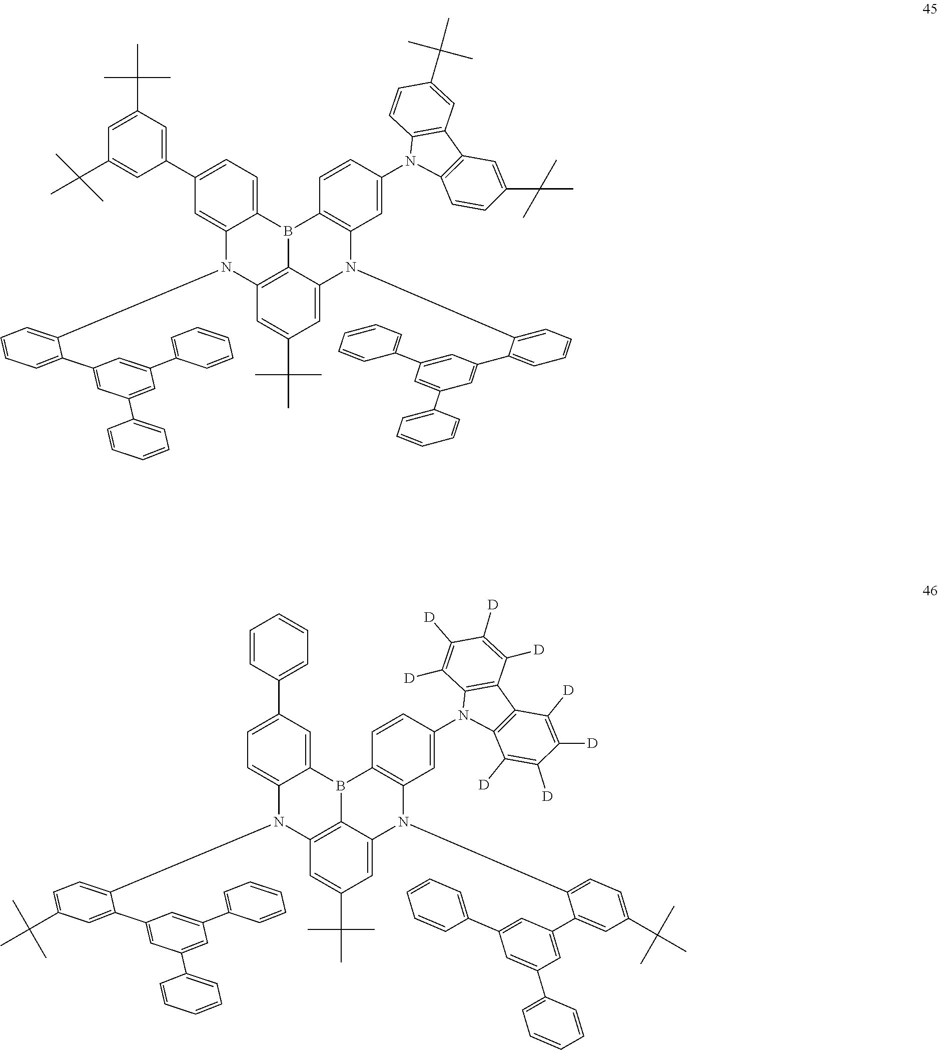 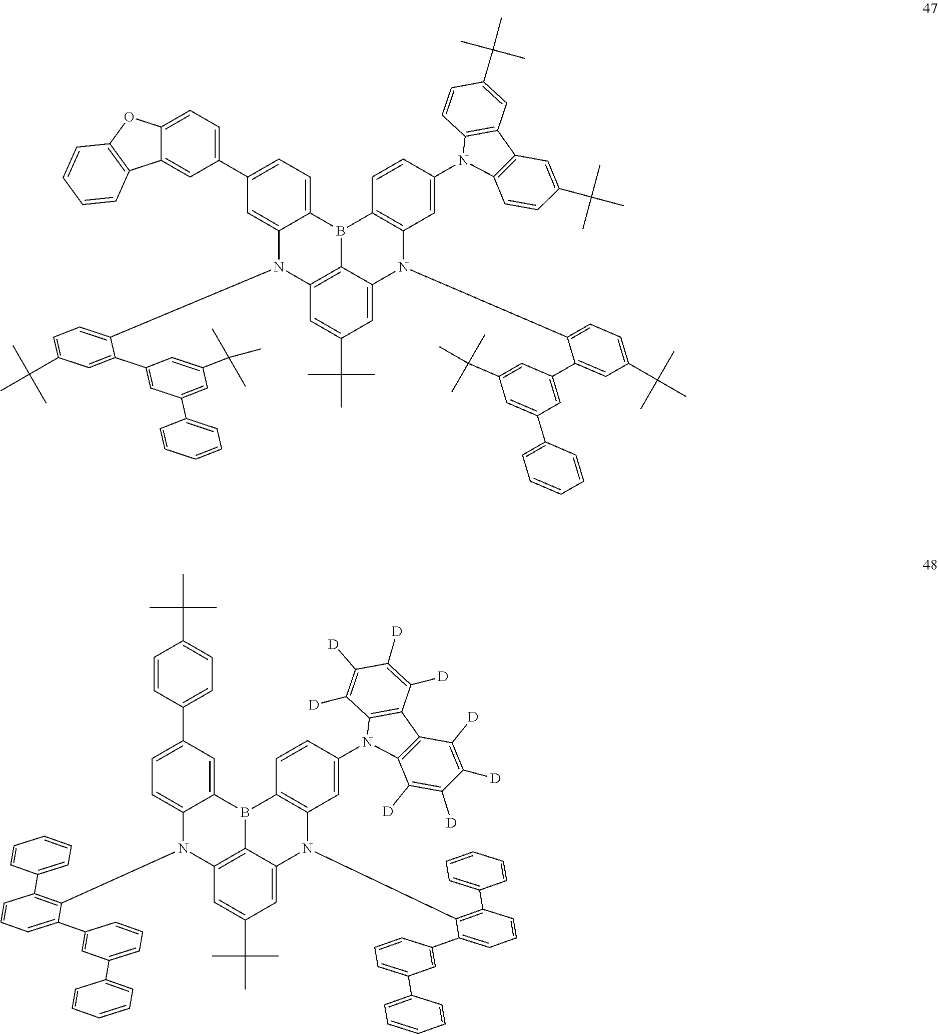 [SMILES: CC(C)(C)c1cc(-c2ccccc2)cc(-c2cc(C(C)(C)C)ccc2N2c3cc(-c4ccc5oc6ccccc6c5c4)ccc3B3c4ccc(-n5c6ccc(C(C)(C)C)cc6c6cc(C(C)(C)C)ccc65)cc4N(c4ccc(C(C)(C)C)cc4-c4cc(-c5ccccc5)cc(C(C)(C)C)c4)c4cc(C(C)(C)C)cc2c43)c1 ; [2H]c1c([2H])c([2H])c2c(c1[2H])c1c([2H])c([2H])c([2H])c([2H])c1n2-c1ccc2c(c1)N(c1c(-c3ccccc3)cccc1-c1cccc(-c3ccccc3)c1)c1cc(C(C)(C)C)cc3c1B2c1cc(-c2ccc(C(C)(C)C)cc2)ccc1N3c1c(-c2ccccc2)cccc1-c1cccc(-c2ccccc2)c1] 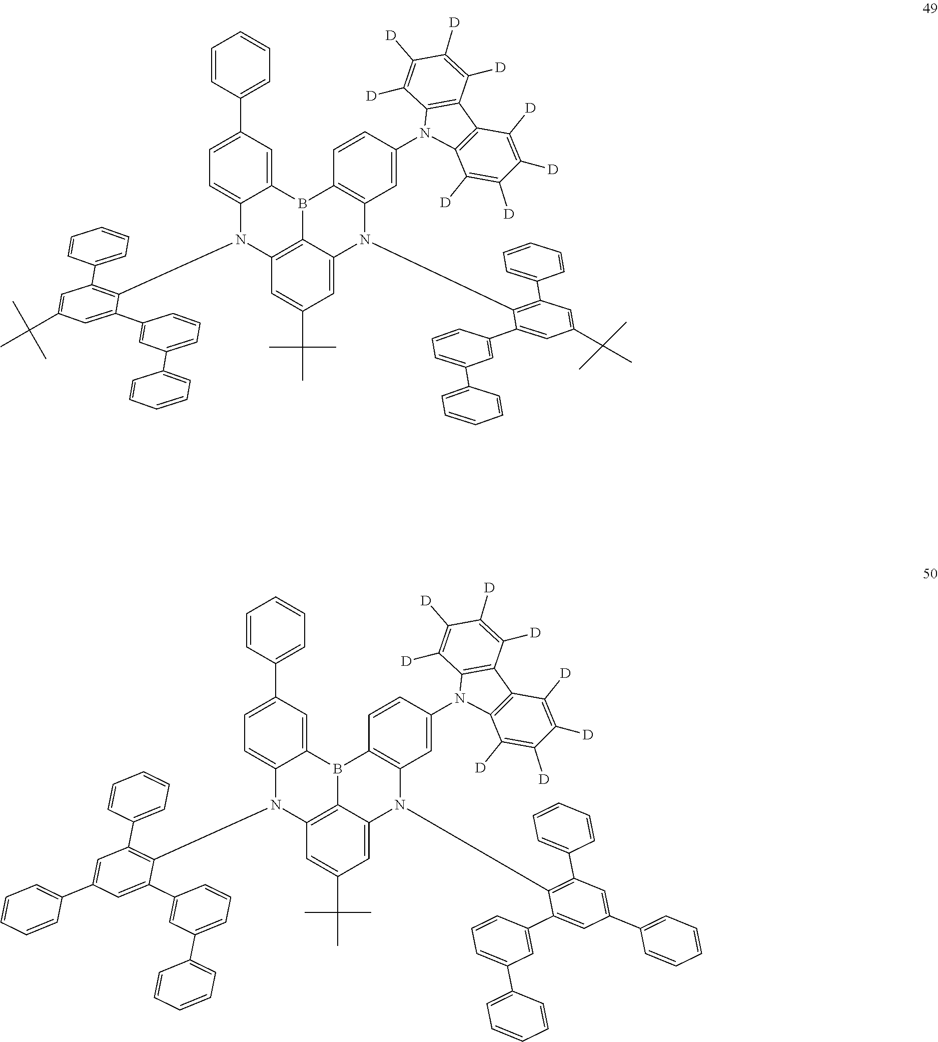 [SMILES: [2H]c1c([2H])c([2H])c2c(c1[2H])c1c([2H])c([2H])c([2H])c([2H])c1n2-c1ccc2c(c1)N(c1c(-c3ccccc3)cc(C(C)(C)C)cc1-c1cccc(-c3ccccc3)c1)c1cc(C(C)(C)C)cc3c1B2c1cc(-c2ccccc2)ccc1N3c1c(-c2ccccc2)cc(C(C)(C)C)cc1-c1cccc(-c2ccccc2)c1 ; [2H]c1c([2H])c([2H])c2c(c1[2H])c1c([2H])c([2H])c([2H])c([2H])c1n2-c1ccc2c(c1)N(c1c(-c3ccccc3)cc(-c3ccccc3)cc1-c1cccc(-c3ccccc3)c1)c1cc(C(C)(C)C)cc3c1B2c1cc(-c2ccccc2)ccc1N3c1c(-c2ccccc2)cc(-c2ccccc2)cc1-c1cccc(-c2ccccc2)c1] 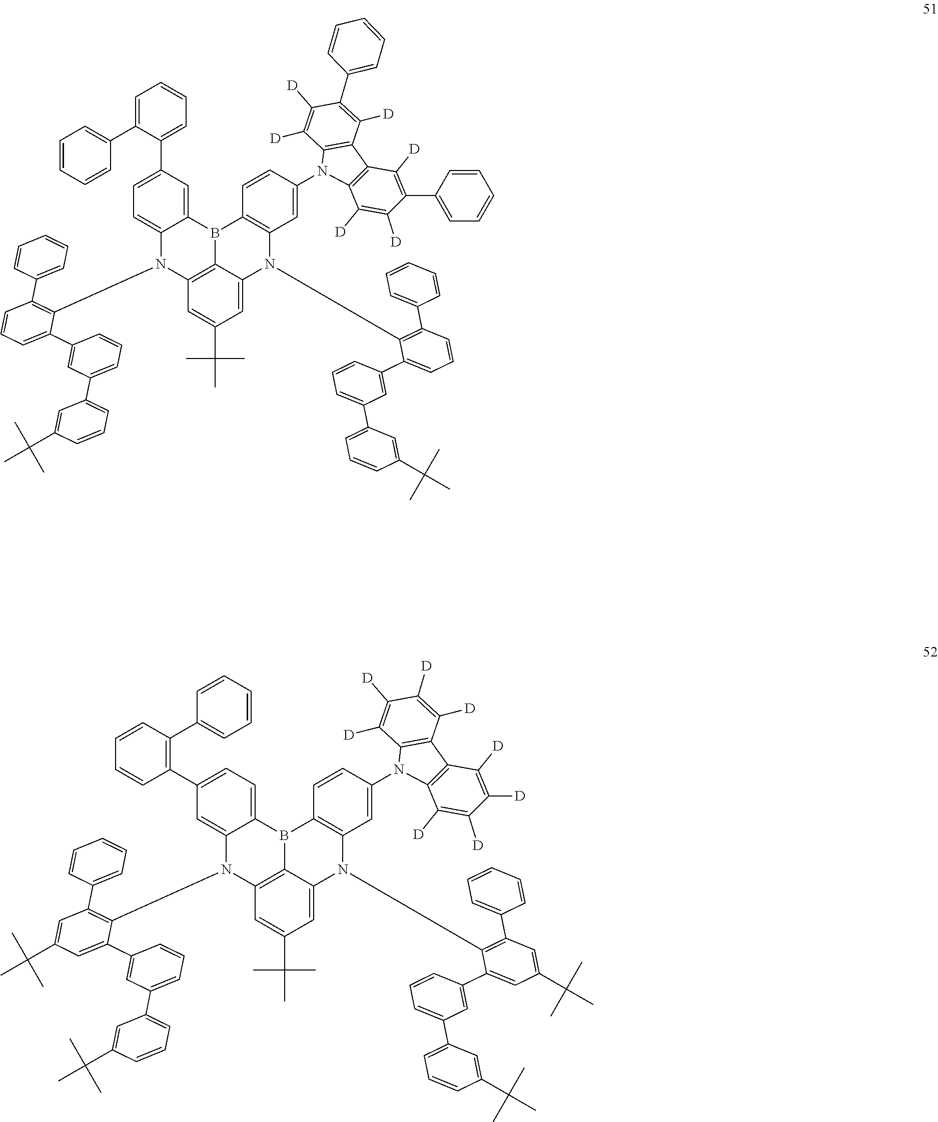 [SMILES: [2H]c1c(-c2ccccc2)c([2H])c2c3c([2H])c(-c4ccccc4)c([2H])c([2H])c3n(-c3ccc4c(c3)N(c3c(-c5ccccc5)cccc3-c3cccc(-c5cccc(C(C)(C)C)c5)c3)c3cc(C(C)(C)C)cc5c3B4c3cc(-c4ccccc4-c4ccccc4)ccc3N5c3c(-c4ccccc4)cccc3-c3cccc(-c4cccc(C(C)(C)C)c4)c3)c2c1[2H] ; [2H]c1c([2H])c([2H])c2c(c1[2H])c1c([2H])c([2H])c([2H])c([2H])c1n2-c1ccc2c(c1)N(c1c(-c3ccccc3)cc(C(C)(C)C)cc1-c1cccc(-c3cccc(C(C)(C)C)c3)c1)c1cc(C(C)(C)C)cc3c1B2c1ccc(-c2ccccc2-c2ccccc2)cc1N3c1c(-c2ccccc2)cc(C(C)(C)C)cc1-c1cccc(-c2cccc(C(C)(C)C)c2)c1] 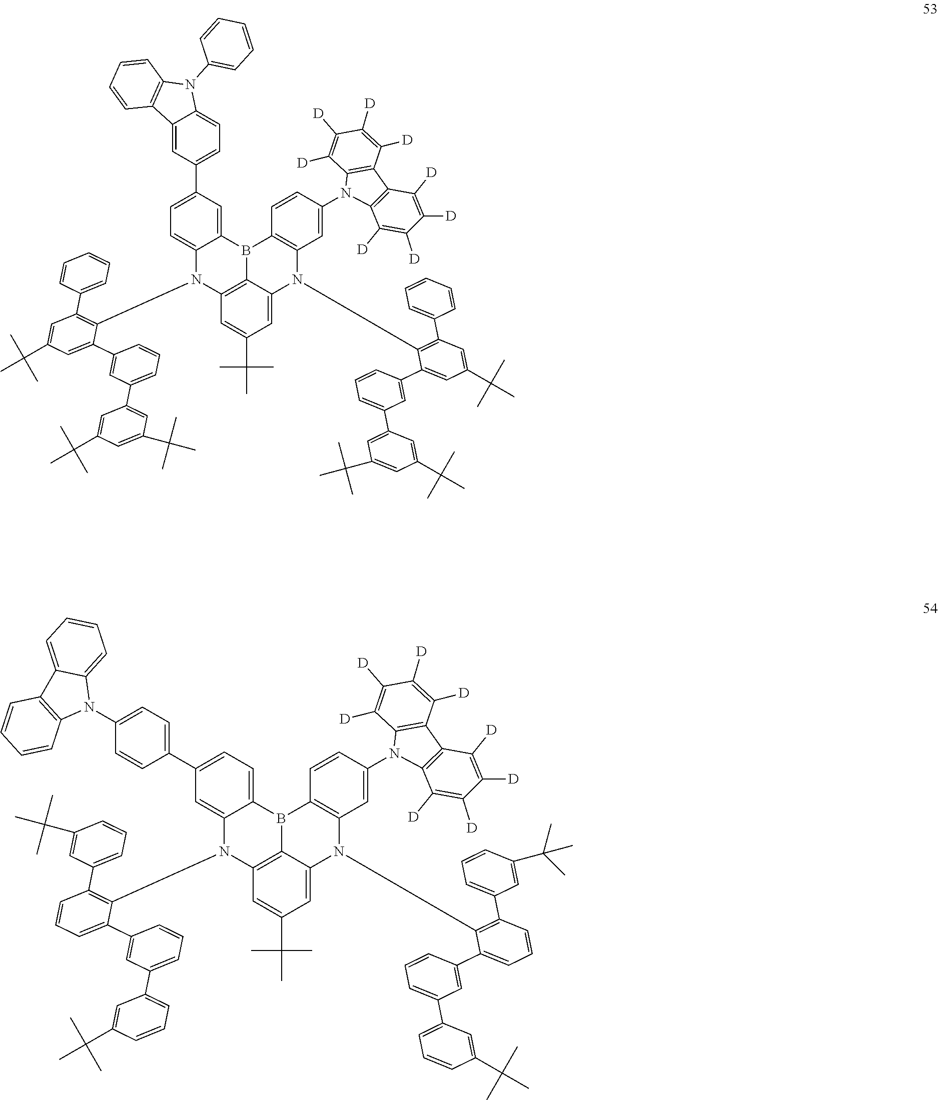 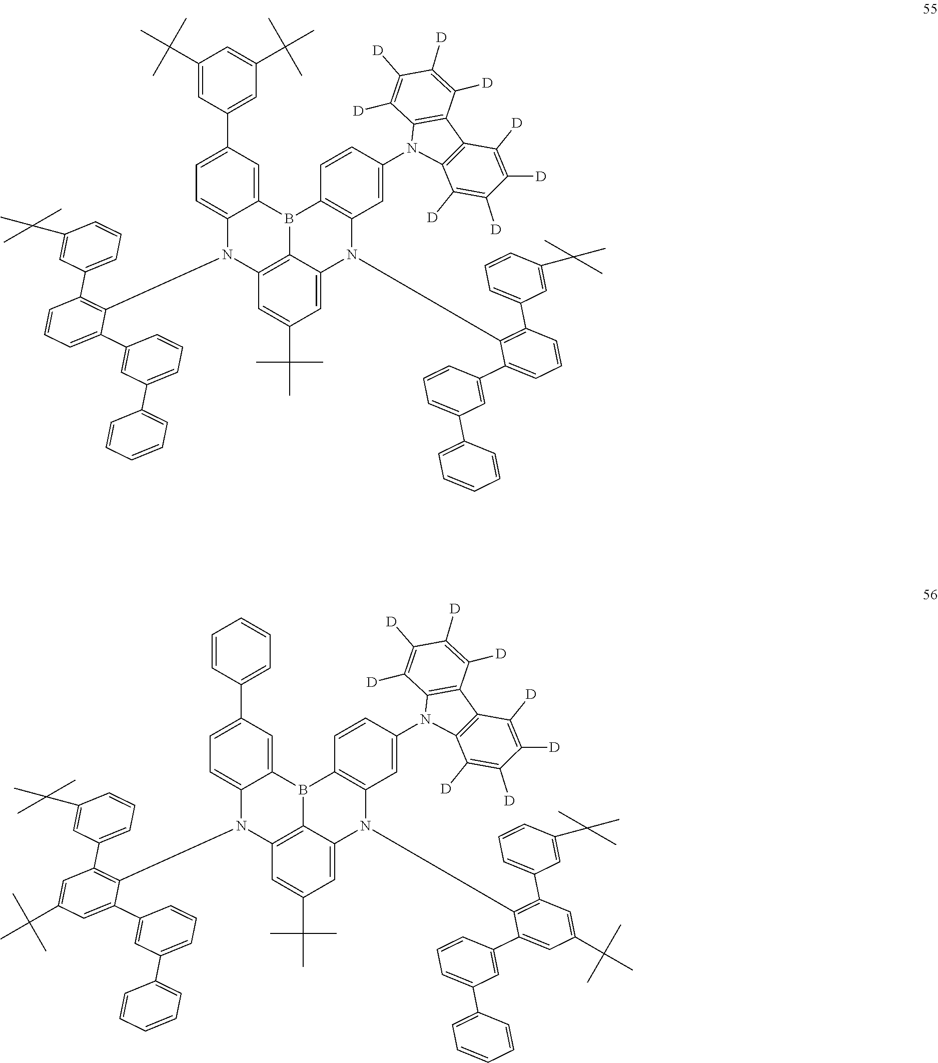 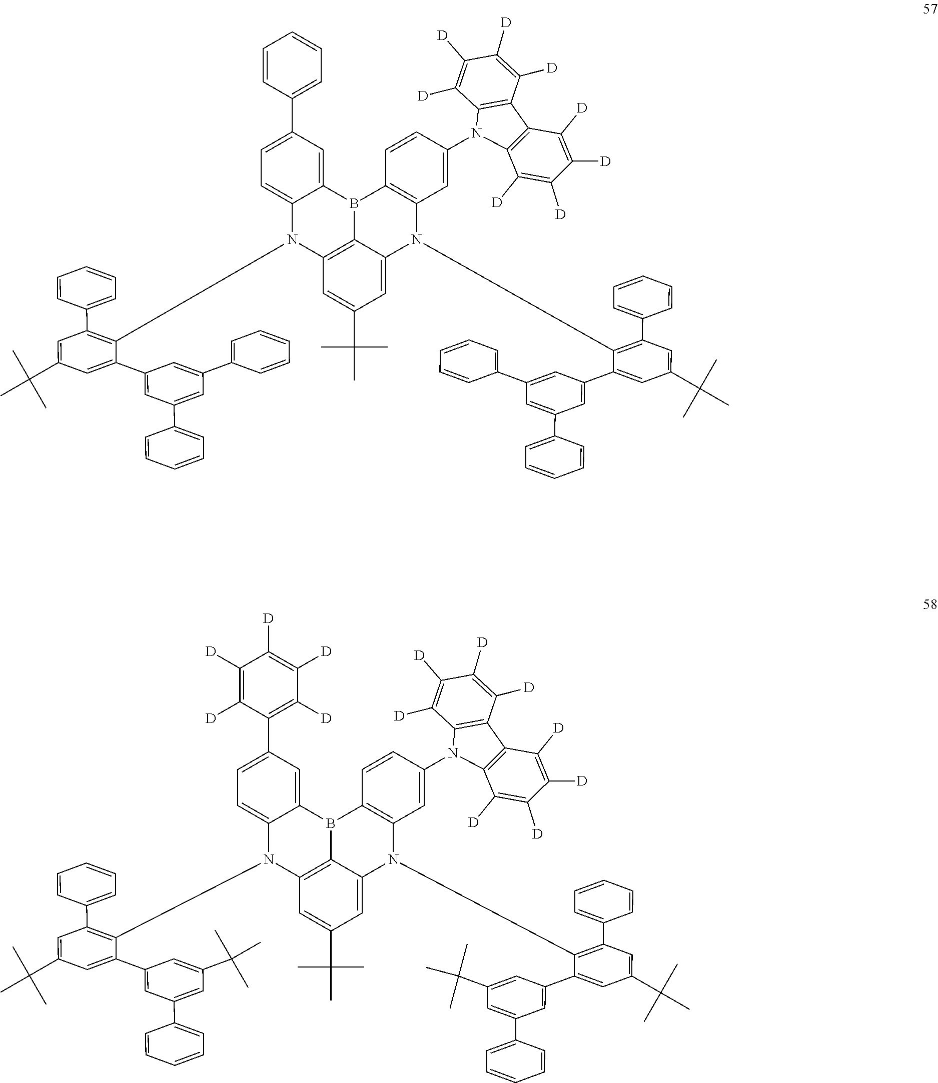 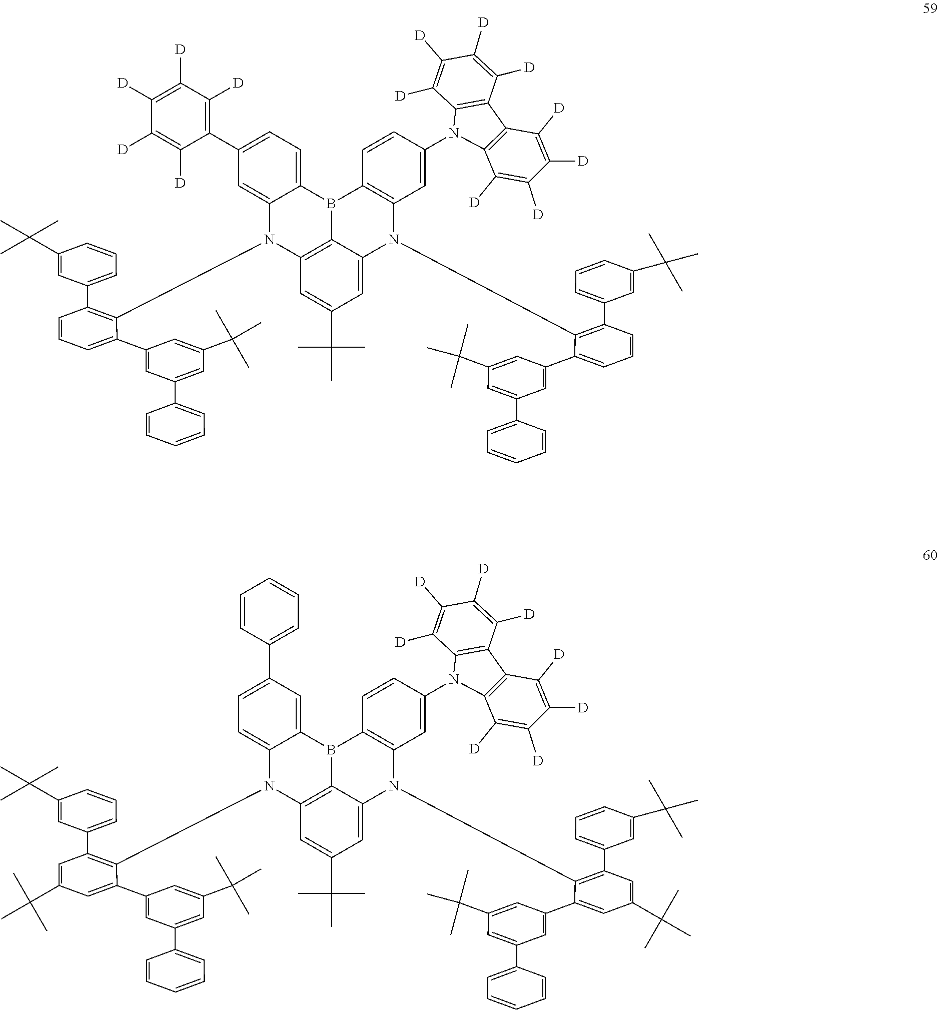 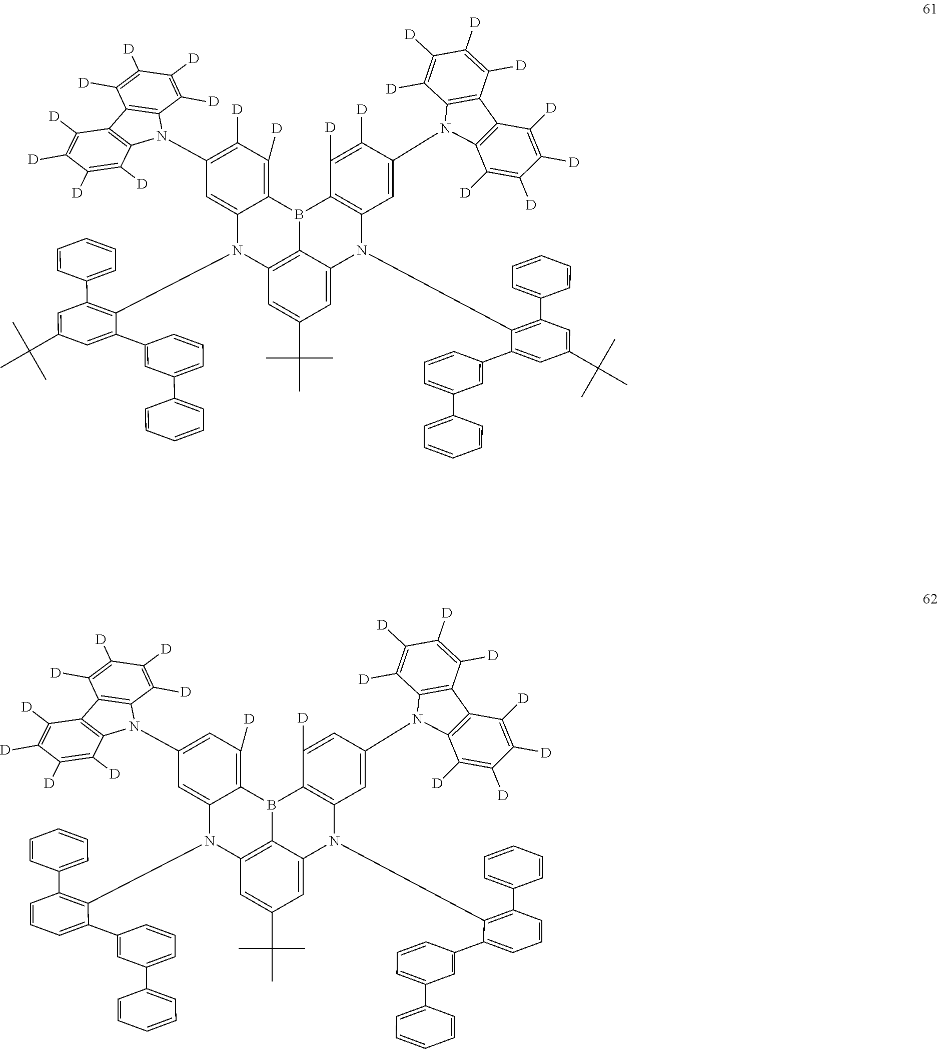 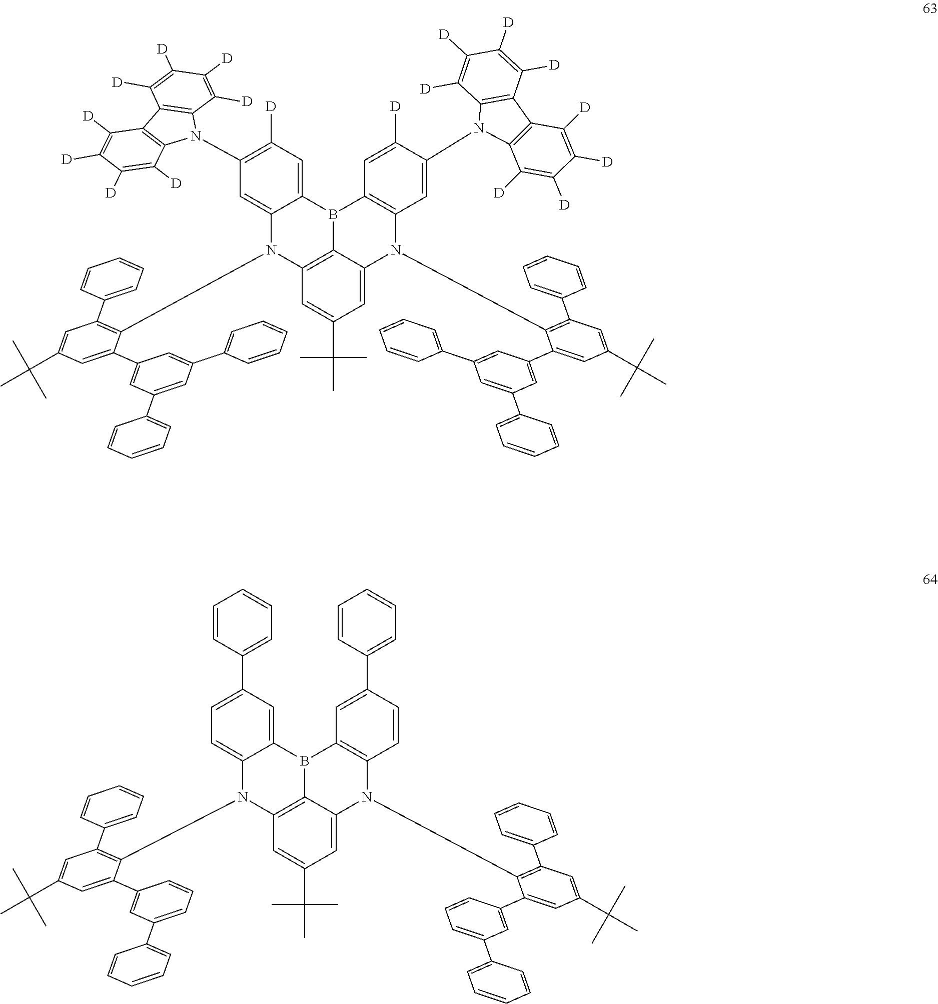 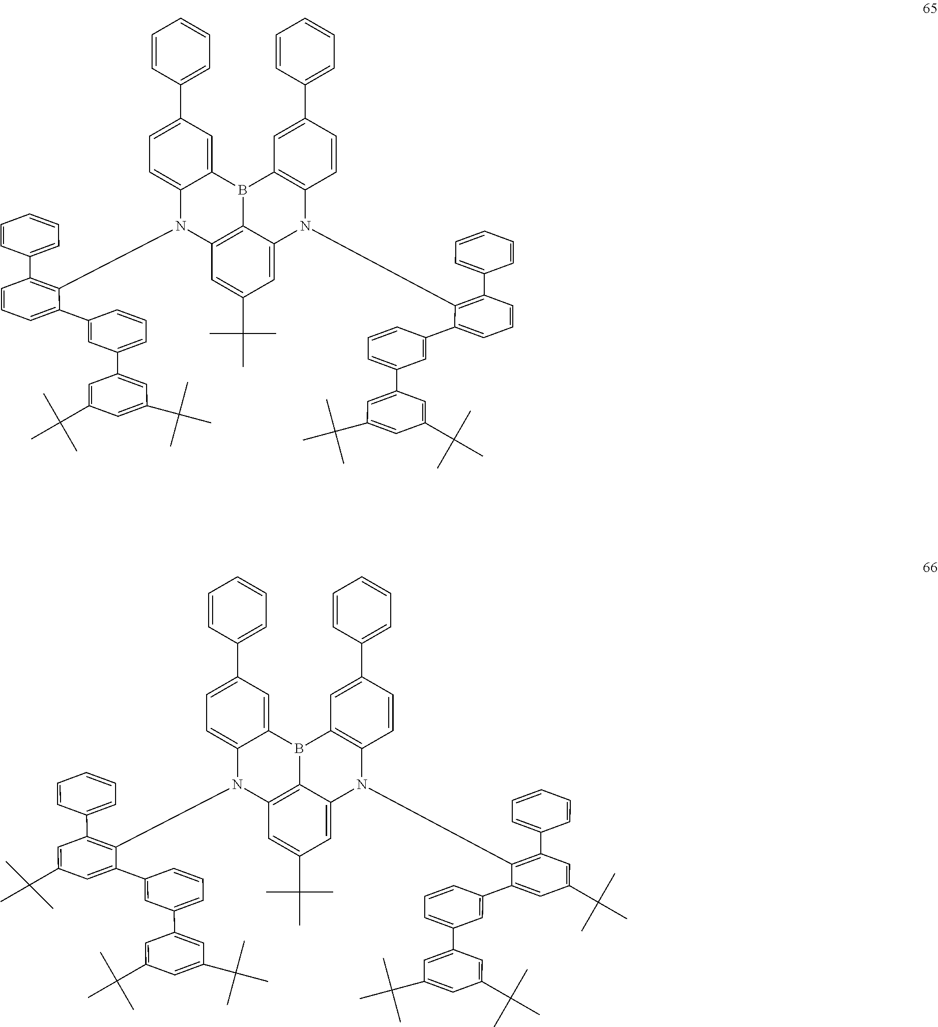 [SMILES: CC(C)(C)c1cc(-c2cccc(-c3cccc(-c4ccccc4)c3N3c4ccc(-c5ccccc5)cc4B4c5cc(-c6ccccc6)ccc5N(c5c(-c6ccccc6)cccc5-c5cccc(-c6cc(C(C)(C)C)cc(C(C)(C)C)c6)c5)c5cc(C(C)(C)C)cc3c54)c2)cc(C(C)(C)C)c1 ; CC(C)(C)c1cc(-c2cccc(-c3cc(C(C)(C)C)cc(-c4ccccc4)c3N3c4ccc(-c5ccccc5)cc4B4c5cc(-c6ccccc6)ccc5N(c5c(-c6ccccc6)cc(C(C)(C)C)cc5-c5cccc(-c6cc(C(C)(C)C)cc(C(C)(C)C)c6)c5)c5cc(C(C)(C)C)cc3c54)c2)cc(C(C)(C)C)c1] 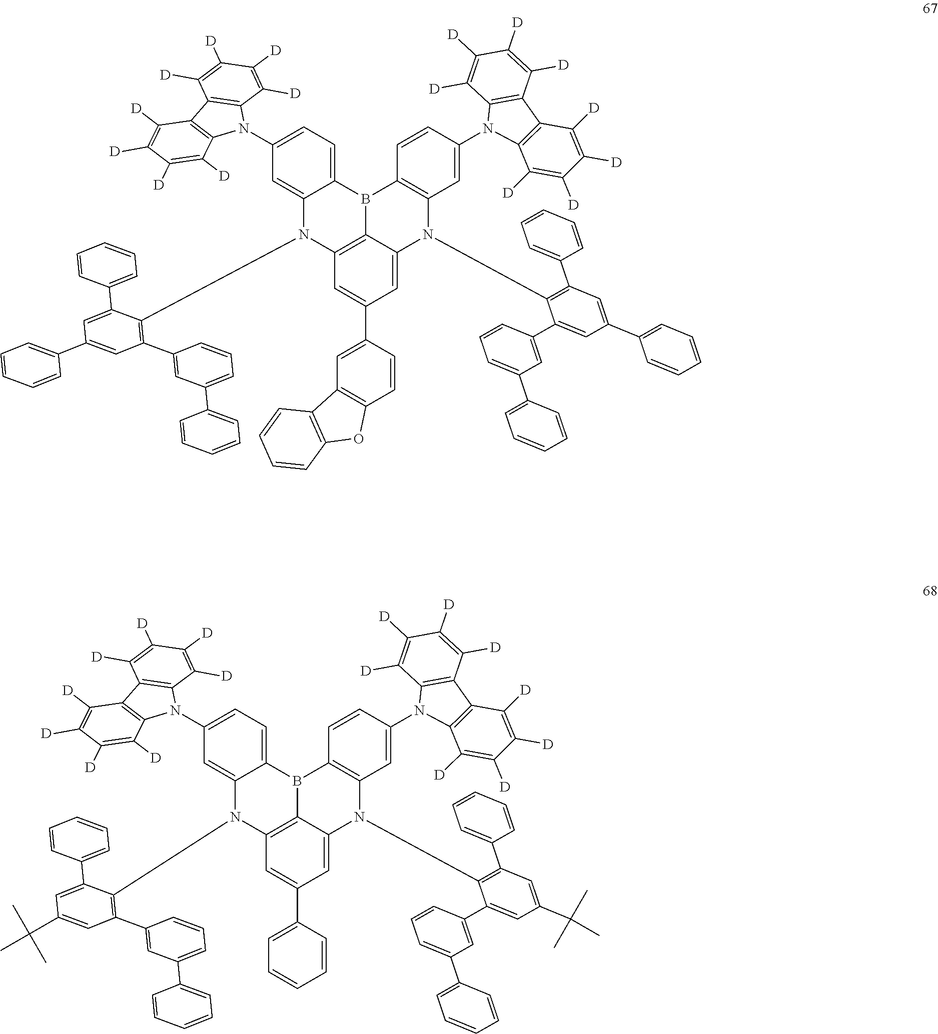 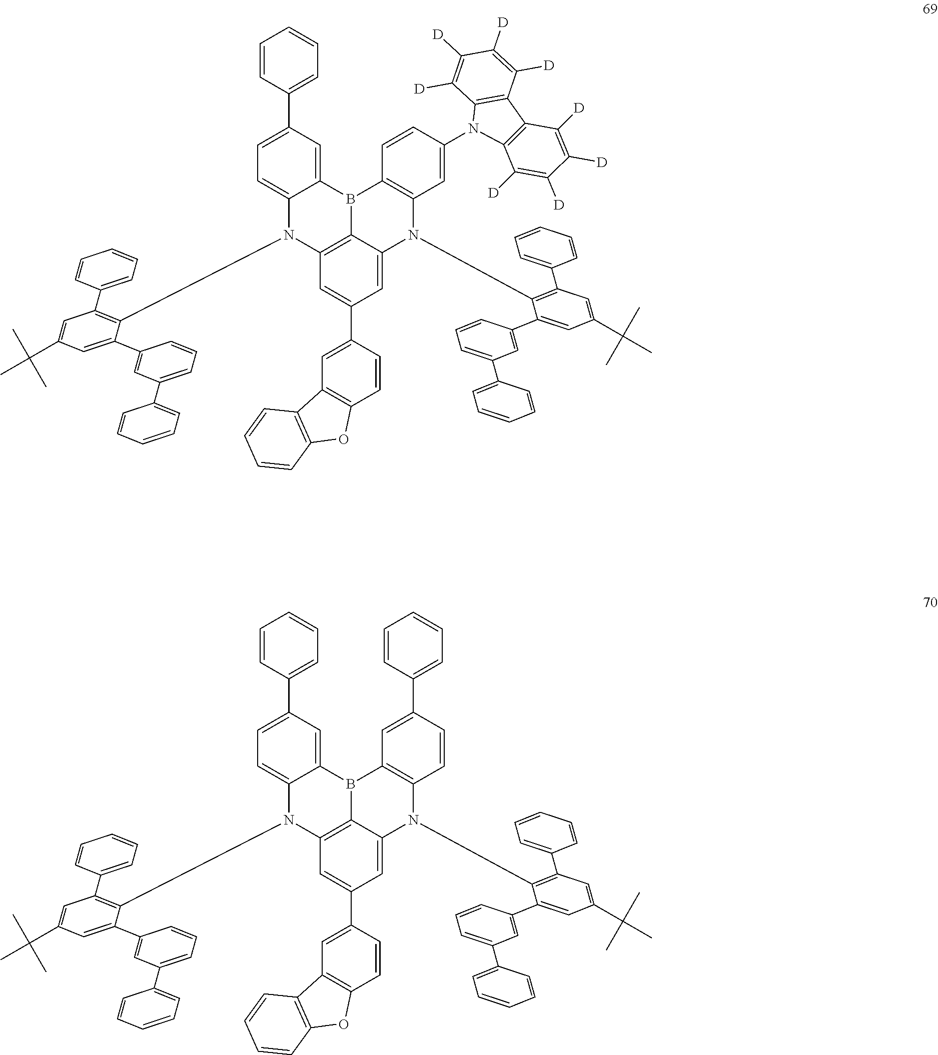
wherein in Compound Group 1, D is a deuterium atom.

13. A fused polycyclic compound represented by Formula 1: 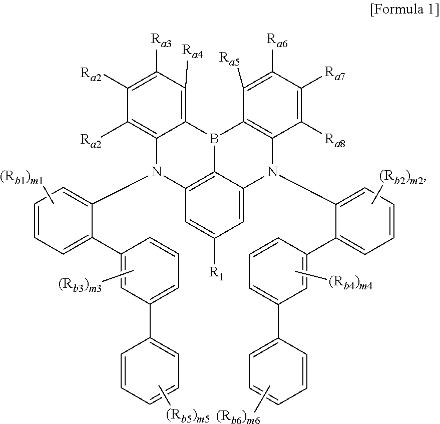
wherein in Formula 1,
R₁ is a hydrogen atom, a deuterium atom, a substituted or unsubstituted alkyl group of 1 to 60 carbon atoms, a substituted or unsubstituted aryl group of 6 to 60 ring-forming carbon atoms, or a substituted or unsubstituted heteroaryl group of 2 to 60 ring-forming carbon atoms,
m1 to m4 are each independently an integer of 0 to 4,
m5 and m6 are each independently an integer of 0 to 5,
R_{b1} to R_{b6} are each independently a hydrogen atom, a deuterium atom, a cyano group, a halogen atom, a substituted or unsubstituted alkyl group of 1 to 60 carbon atoms, a substituted or unsubstituted aryl group of 6 to 60 ring-forming carbon atoms, or a substituted or unsubstituted heteroaryl group of 2 to 60 ring-forming carbon atoms,
at least one among Rₐ₁ to Rₐ₄ is a substituted or unsubstituted aryl amine group, a substituted or unsubstituted aryl group of 6 to 60 ring-forming carbon atoms, or a substituted or unsubstituted heteroaryl group of 2 to 60 ring-forming carbon atoms, and any remainder thereof are each independently a hydrogen atom or a deuterium atom, and
at least one among Rₐ₅ to Rₐ₈ is a substituted or unsubstituted aryl amine group, a substituted or unsubstituted aryl group of 6 to 60 ring-forming carbon atoms, or a substituted or unsubstituted heteroaryl group of 2 to 60 ring-forming carbon atoms, and any remainder thereof are each independently a hydrogen atom or a deuterium atom.

14. The fused polycyclic compound of claim 13, wherein the fused polycyclic compound represented by Formula 1 is represented by any one among Formula 1-1 to Formula 1-3: 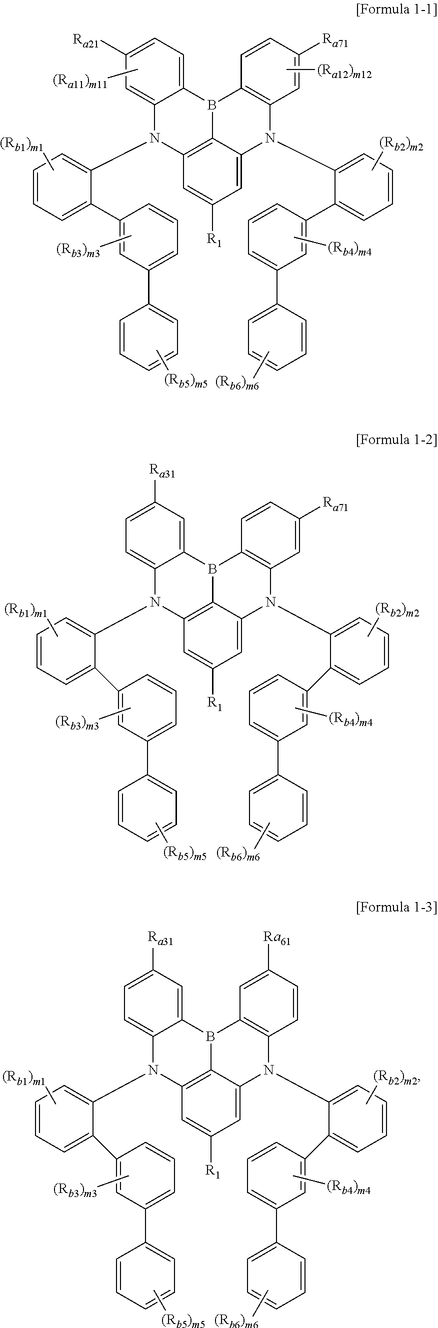
wherein in Formula 1-1,
m11 and m12 are each independently an integer of 0 to 3, and
Rₐ₁₁ and Rₐ₁₂ are each independently a hydrogen atom or a deuterium atom, and
in Formula 1-1 to Formula 1-3,
Rₐ₂₁, Rₐ₃₁, Rₐ₆₁, and Rₐ₇₁ are each independently a substituted or unsubstituted aryl amine group, a substituted or unsubstituted aryl group of 6 to 60 ring-forming carbon atoms, or a substituted or unsubstituted heteroaryl group of 2 to 60 ring-forming carbon atoms, and
R₁, m1 to m6, and R_{b1} to R_{b6} are the same as defined in Formula 1.

15. The fused polycyclic compound of claim 14, wherein, in Formula 1-1 to Formula 1-3, Rₐ₂₁, Rₐ₃₁, Rₐ₆₁, and Rₐ₇₁ are each independently a substituted or unsubstituted diphenylamine group, a substituted or unsubstituted phenyl group, a substituted or unsubstituted carbazole group, a substituted or unsubstituted dibenzofuran group, or a substituted or unsubstituted phenoxazine group.

16. The fused polycyclic compound of claim 14, wherein, in Formula 1-1 to Formula 1-3, Rₐ₂₁, Rₐ₃₁, Rₐ₆₁, and Rₐ₇₁ are each independently represented by any one among Formulae RA-1 to RA-6: 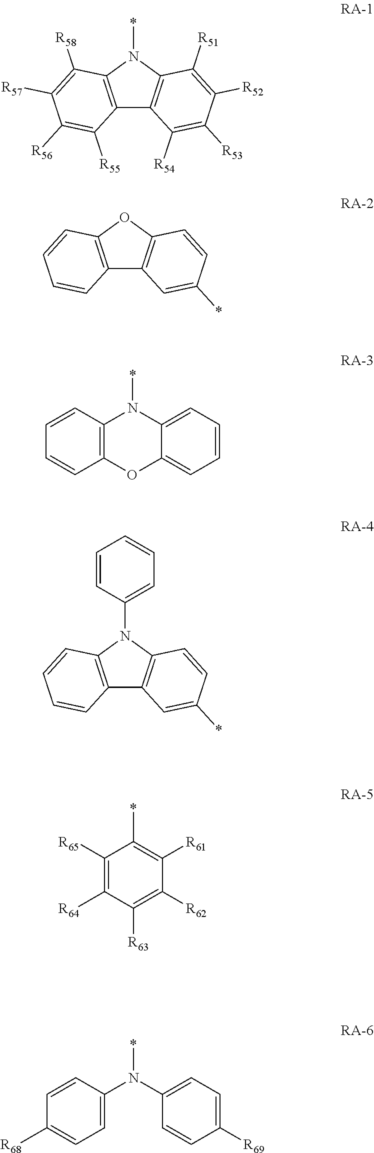
wherein in RA-1,
R₅₁ to R₅₈ are each independently a hydrogen atom, a deuterium atom, a cyano group, an unsubstituted t-butyl group, or an unsubstituted phenyl group,
in RA-5,
R₆₁ to R₆₅ are each independently a hydrogen atom, a deuterium atom, an unsubstituted t-butyl group, an unsubstituted phenyl group, or an unsubstituted carbazole group, and
in RA-6,
R₆₈ and R₆₉ are each independently a hydrogen atom, a deuterium atom, or an unsubstituted t-butyl group.

17. The fused polycyclic compound of claim 13, wherein the fused polycyclic compound represented by Formula 1 is represented by Formula 1-A or Formula 1-B: 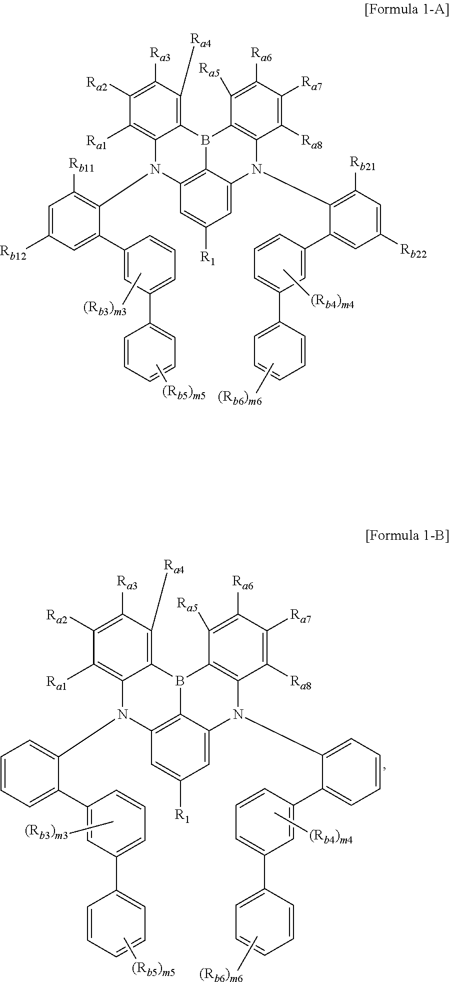
in Formula 1-A,
R_{b11}, R_{b12}, R_{b21}, and R_{b22} are each independently a substituted or unsubstituted alkyl group of 1 to 20 carbon atoms or a substituted or unsubstituted aryl group of 6 to 20 ring-forming carbon atoms, and
in Formula 1-A and Formula 1-B,
Rₐ₁ to Rₐ₈, R₁, m3 to m6, and R_{b3} to R_{b6} are the same as defined in Formula 1.

18. The fused polycyclic compound of claim 17, wherein, in Formula 1-A, R_{b11}, R_{b12}, R_{b21}, and R_{b22} are each independently a substituted or unsubstituted t-butyl group or a substituted or unsubstituted phenyl group.

19. The fused polycyclic compound of claim 17, wherein the fused polycyclic compound represented by Formula 1-A is represented by Formula 1-A1 or Formula 1-A2: 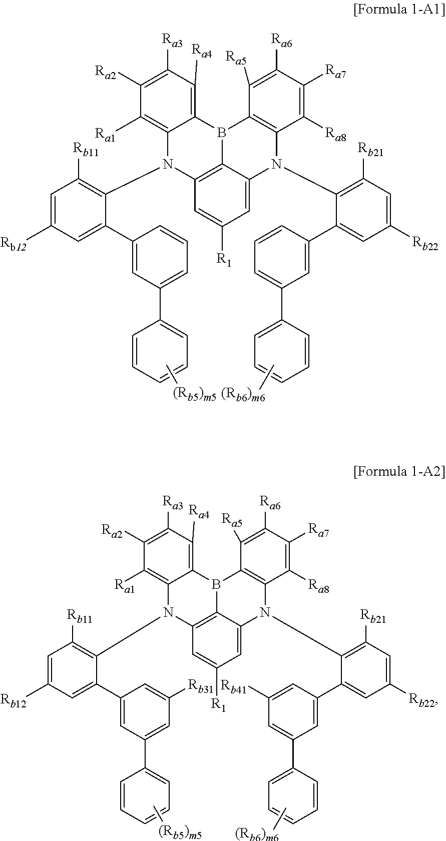
wherein in Formula 1-A2,
R_{b31} and R_{b41} are each independently a substituted or unsubstituted alkyl group of 1 to 20 carbon atoms or a substituted or unsubstituted aryl group of 6 to 20 ring-forming carbon atoms, and
in Formula 1-A1 and Formula 1-A2,
Rₐ₁ to Rₐ₈, R₁, m5, m6, R_{b5}, R_{b6}, R_{b11}, R_{b12}, R_{b21}, and R_{b22} are the same as defined in Formula 1-A.

20. The fused polycyclic compound of claim 19, wherein the fused polycyclic compound represented by Formula 1-A1 is represented by Formula 1-A11 or Formula 1-A12: 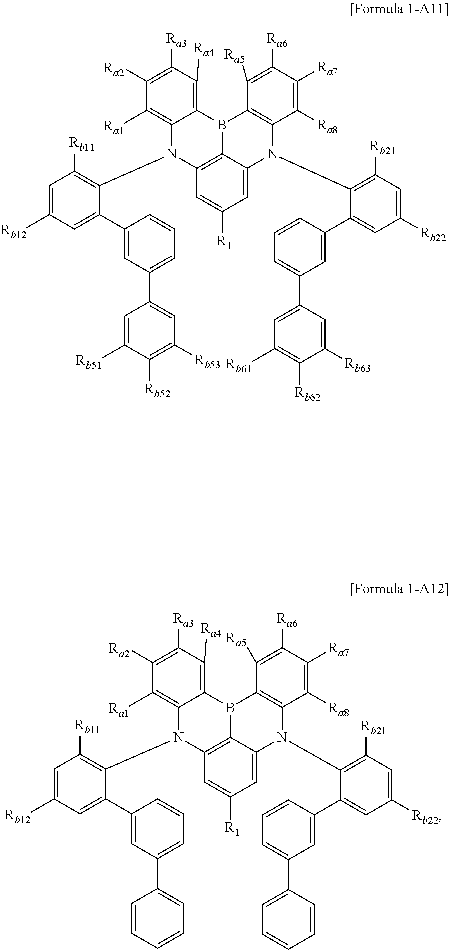
wherein in Formula 1-A11,
at least one among R_{b51} to R_{b53} is a substituted or unsubstituted alkyl group of 1 to 20 carbon atoms or a substituted or unsubstituted aryl group of 6 to 20 ring-forming carbon atoms, and any remainder thereof are hydrogen atoms, and
at least one among R_{b61} to R_{b63} is a substituted or unsubstituted alkyl group of 1 to 20 carbon atoms or a substituted or unsubstituted aryl group of 6 to 20 ring-forming carbon atoms, and any remainder thereof are hydrogen atoms, and
in Formula 1-A11 and Formula 1-A12,
Rₐ₁ to Rₐ₈, R₁, R_{b11}, R_{b12}, R_{b21}, and R_{b22} are the same as defined in Formula 1-A1.

21. The fused polycyclic compound of claim 13, wherein, in Formula 1, R₁ is a substituted or unsubstituted t-butyl group, a substituted or unsubstituted phenyl group, a substituted or unsubstituted dibenzofuran group, or a substituted or unsubstituted carbazole group.

22. The fused polycyclic compound of claim 13, wherein, in Formula 1, R₁ is represented by any one among Formulae R1-1 to R1-9:

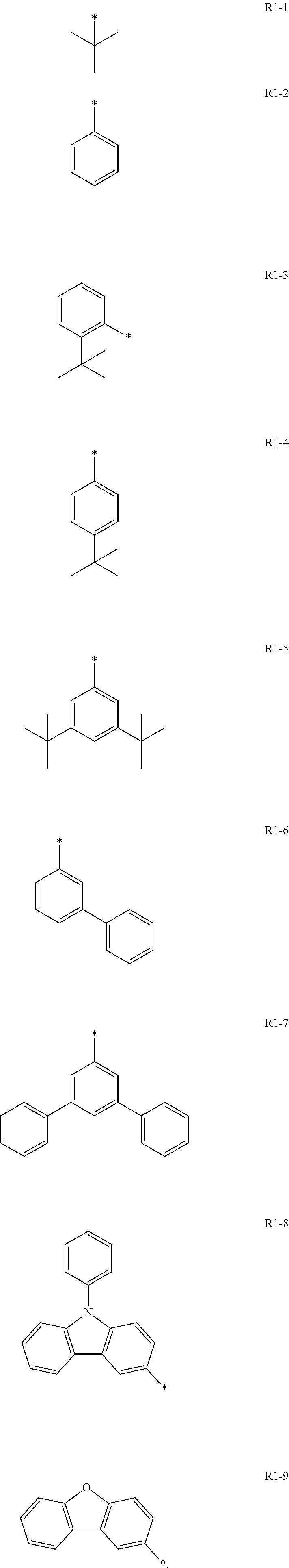

23. The fused polycyclic compound of claim 13, wherein, in Formula 1, at least one among Rai to Rₐ₈ comprises a deuterium atom, or a substituent comprising a deuterium atom.

24. The fused polycyclic compound of claim 13, wherein the first compound is represented by any one among compounds in Compound Group 1: 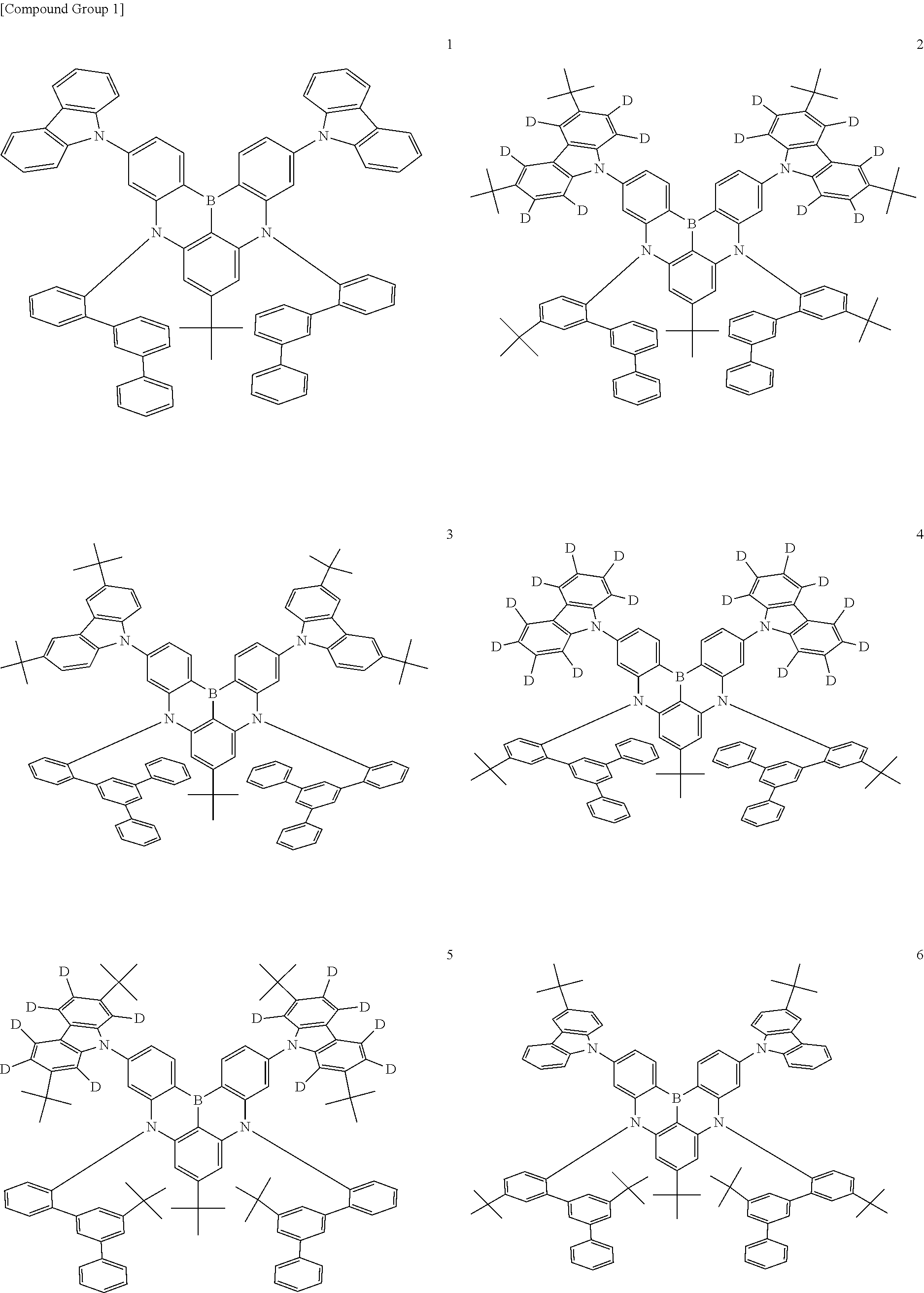 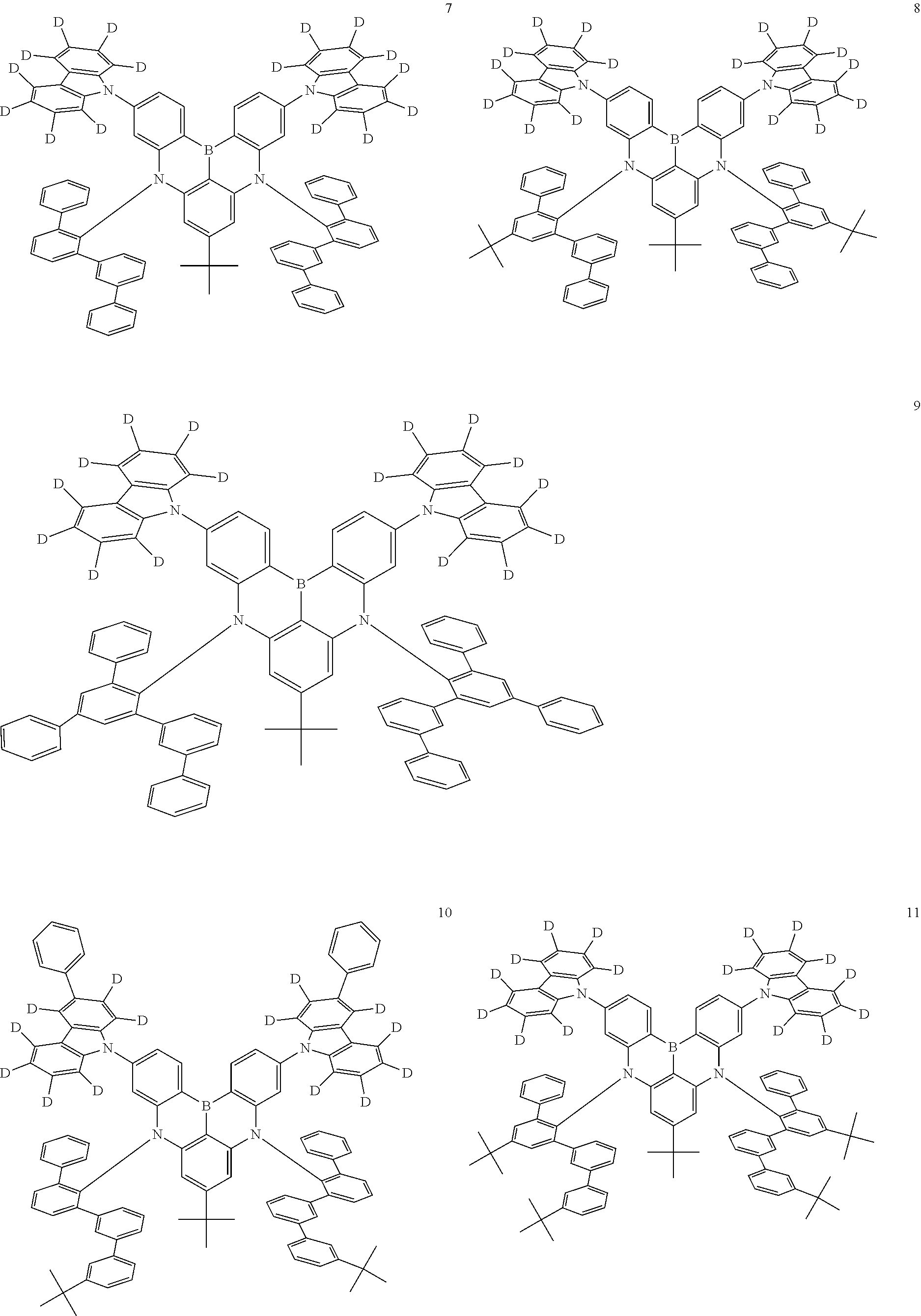 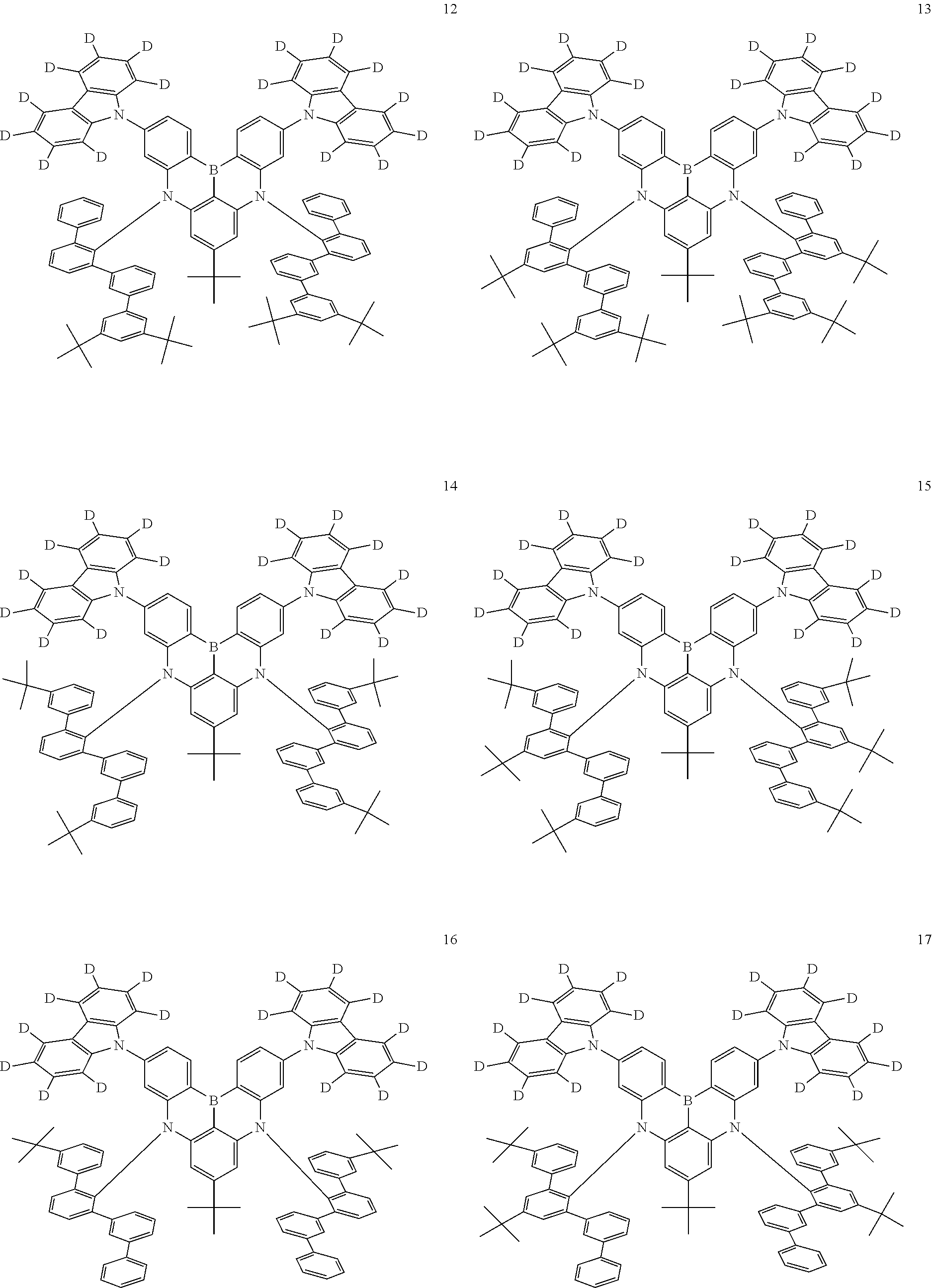 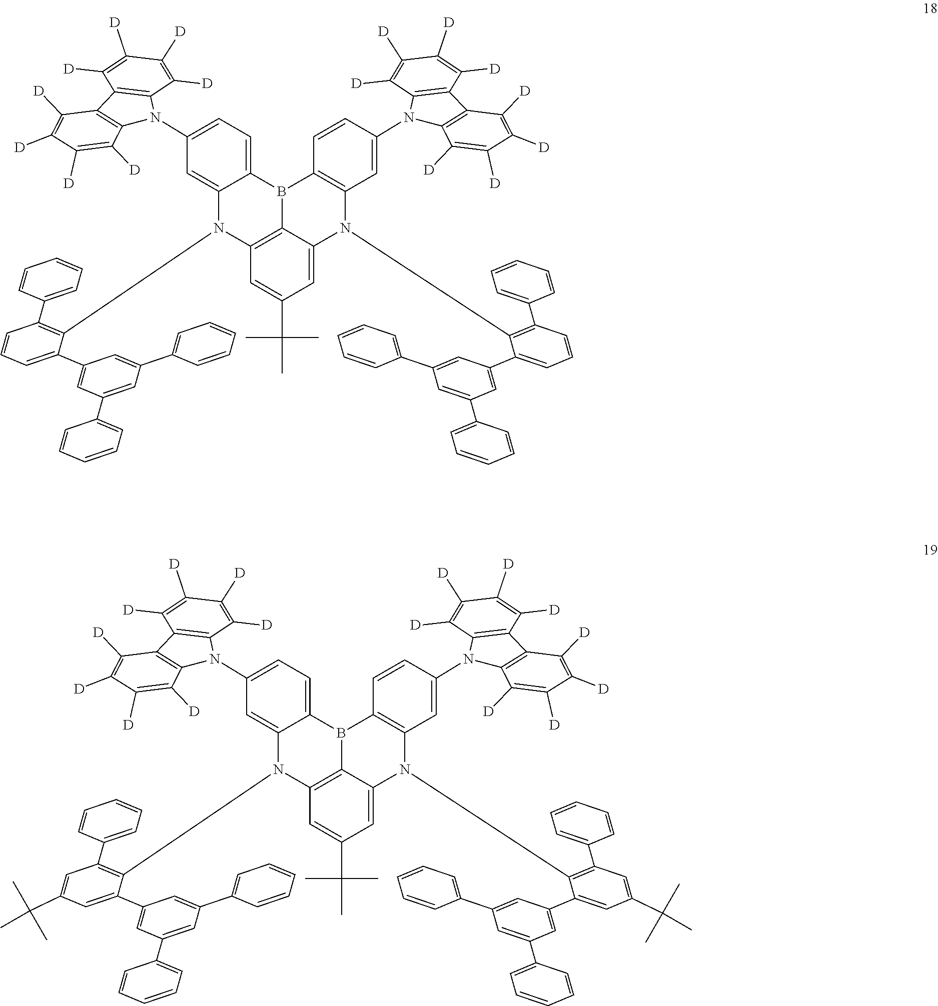 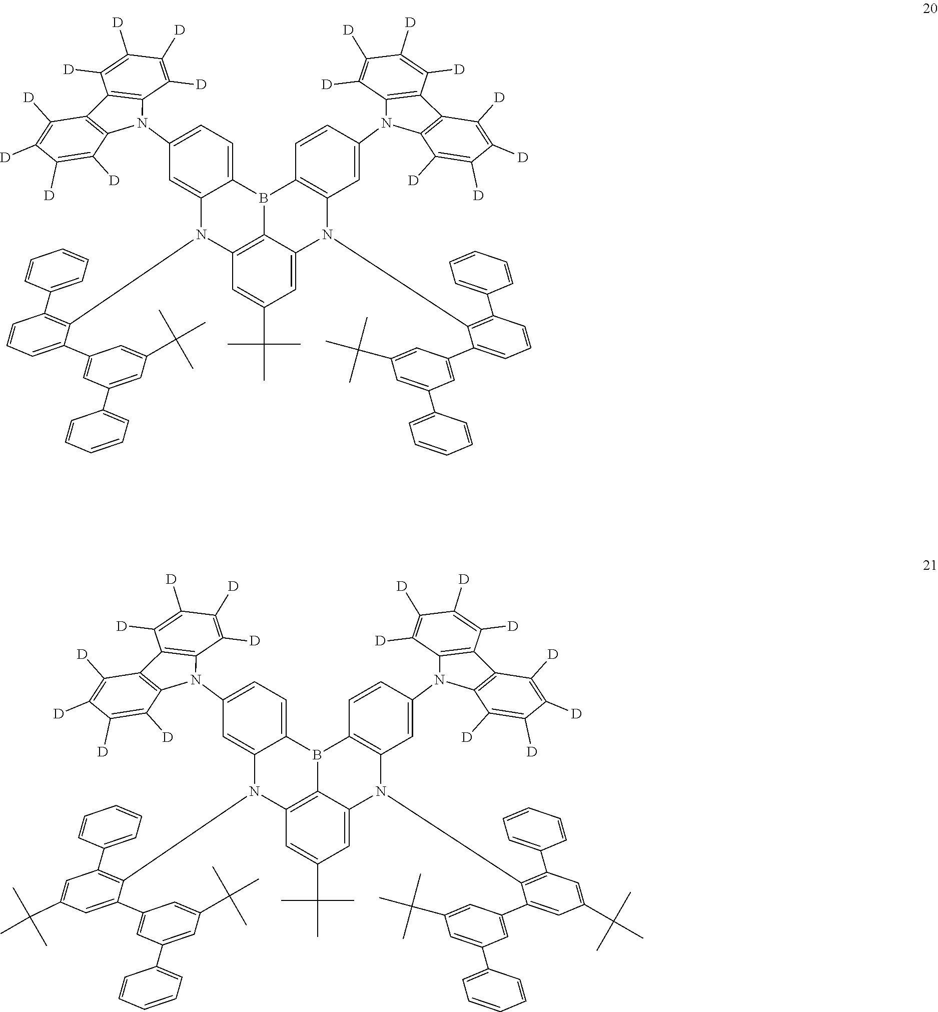 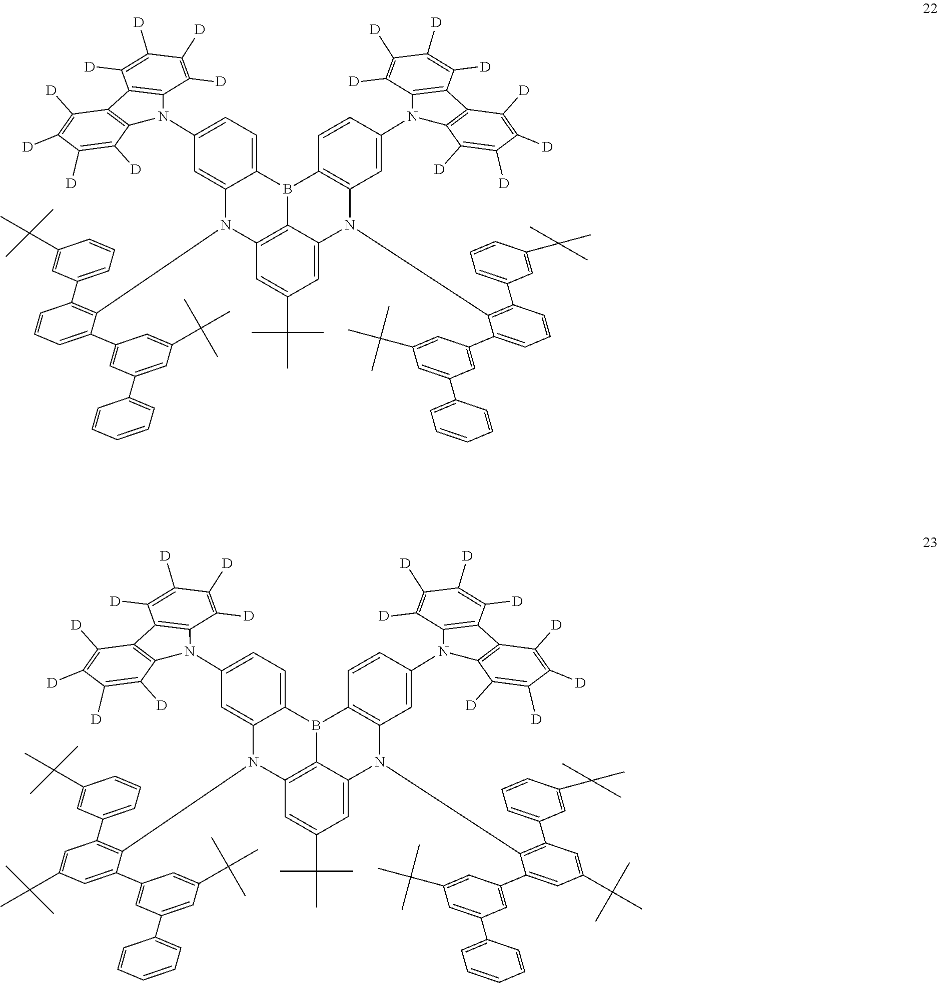 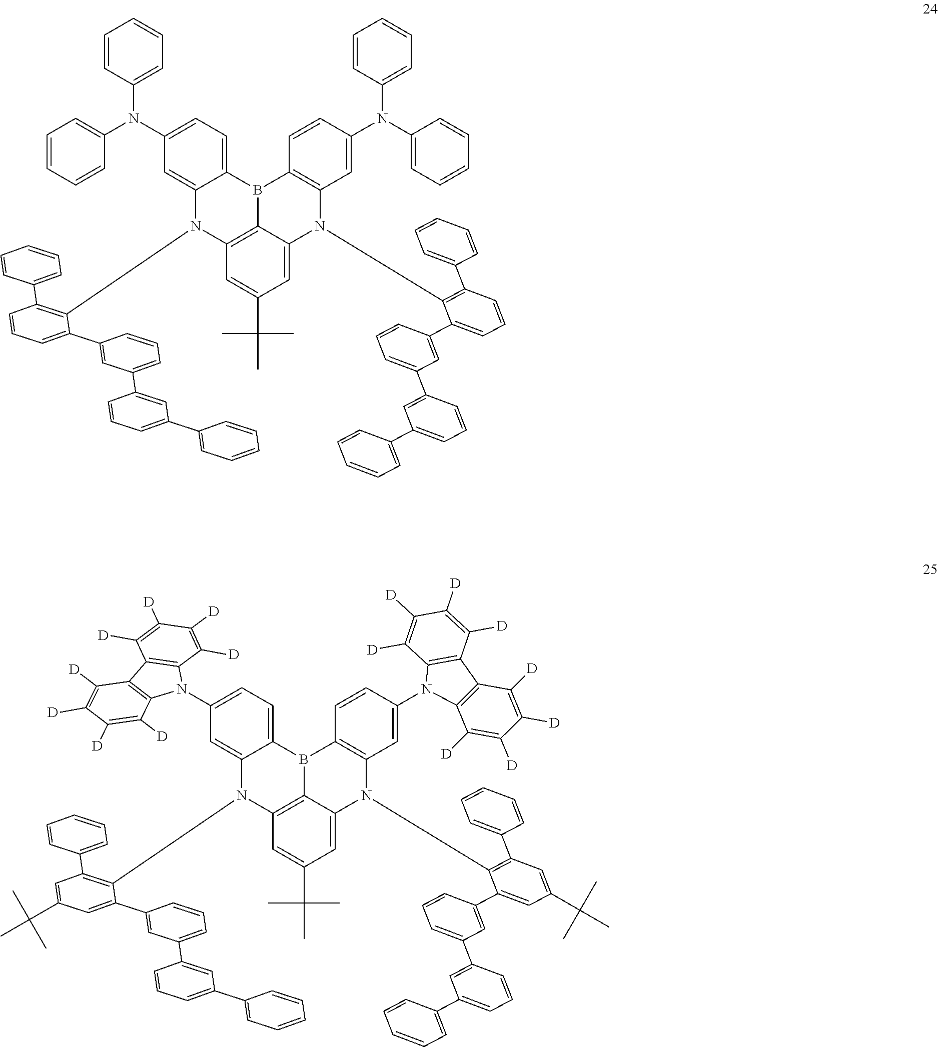 [SMILES: CC(C)(C)c1cc2c3c(c1)N(c1c(-c4ccccc4)cccc1-c1cccc(-c4cccc(-c5ccccc5)c4)c1)c1cc(N(c4ccccc4)c4ccccc4)ccc1B3c1ccc(N(c3ccccc3)c3ccccc3)cc1N2c1c(-c2ccccc2)cccc1-c1cccc(-c2cccc(-c3ccccc3)c2)c1 ; [2H]c1c([2H])c([2H])c2c(c1[2H])c1c([2H])c([2H])c([2H])c([2H])c1n2-c1ccc2c(c1)N(c1c(-c3ccccc3)cc(C(C)(C)C)cc1-c1cccc(-c3cccc(-c4ccccc4)c3)c1)c1cc(C(C)(C)C)cc3c1B2c1ccc(-n2c4c([2H])c([2H])c([2H])c([2H])c4c4c([2H])c([2H])c([2H])c([2H])c42)cc1N3c1c(-c2ccccc2)cc(C(C)(C)C)cc1-c1cccc(-c2cccc(-c3ccccc3)c2)c1] 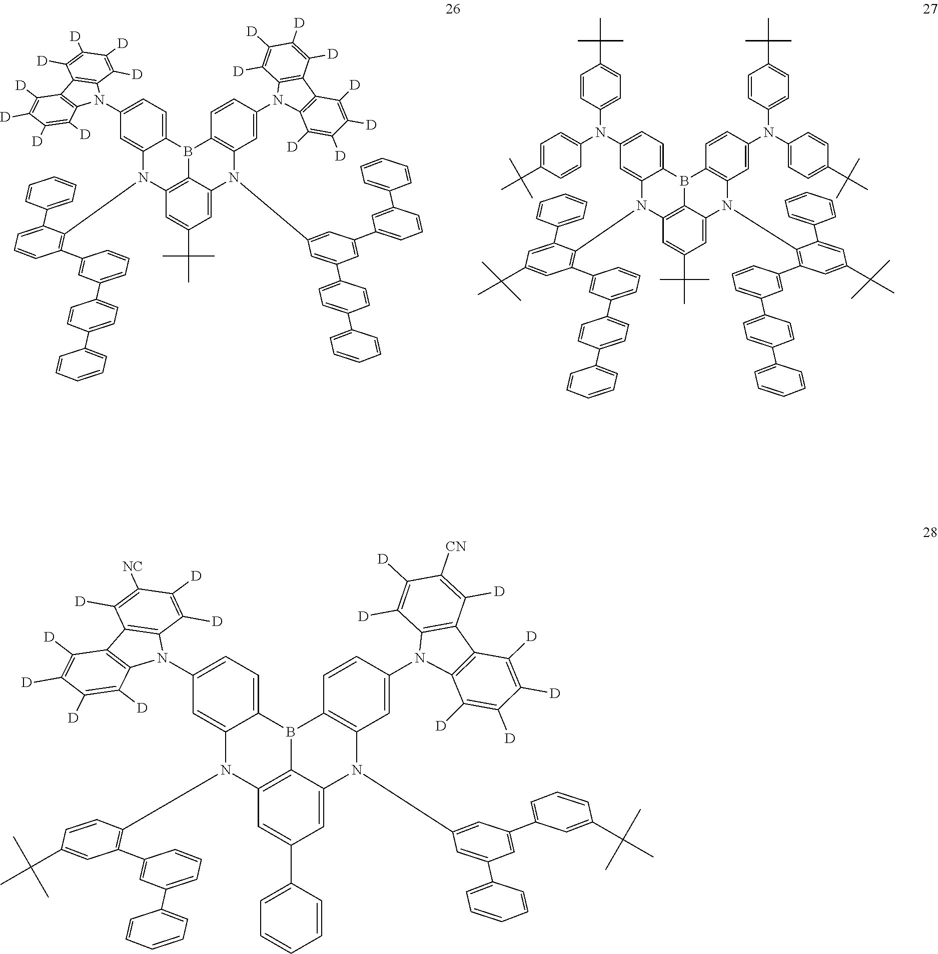 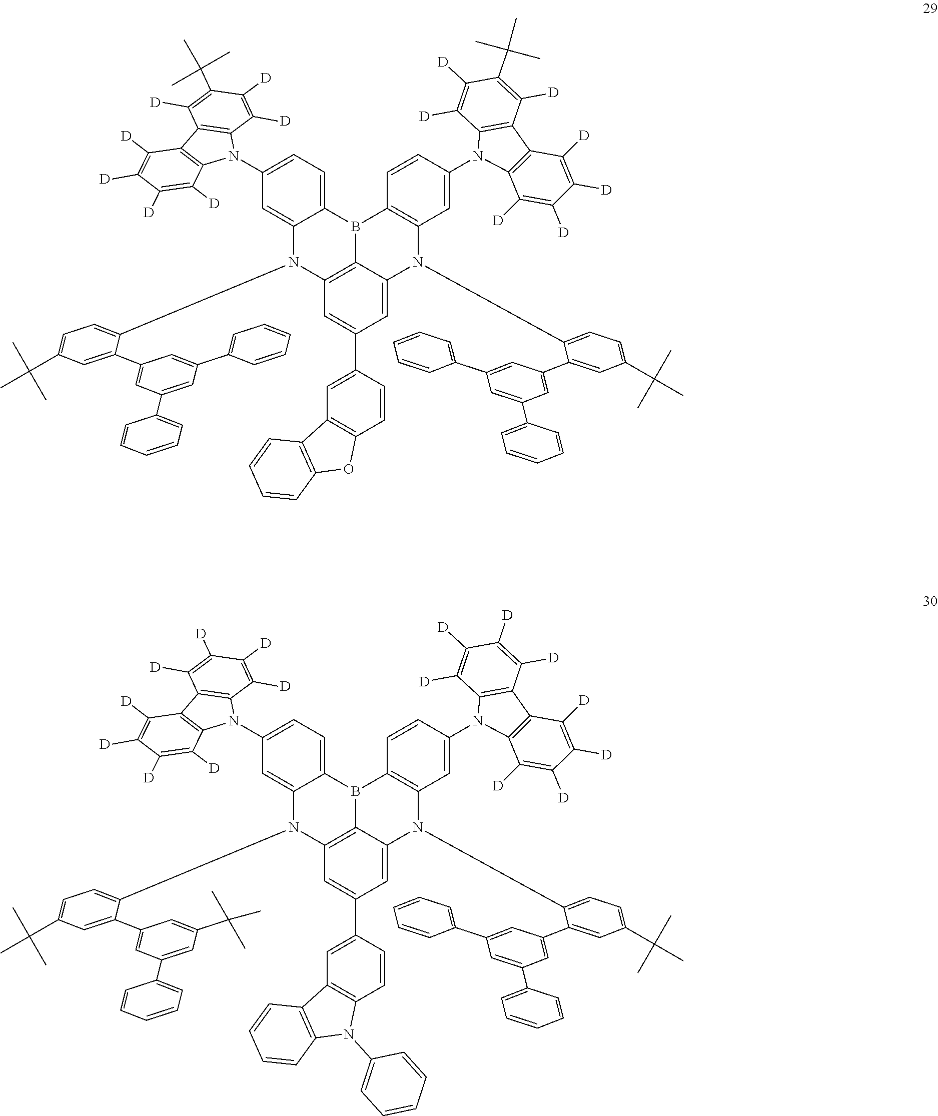 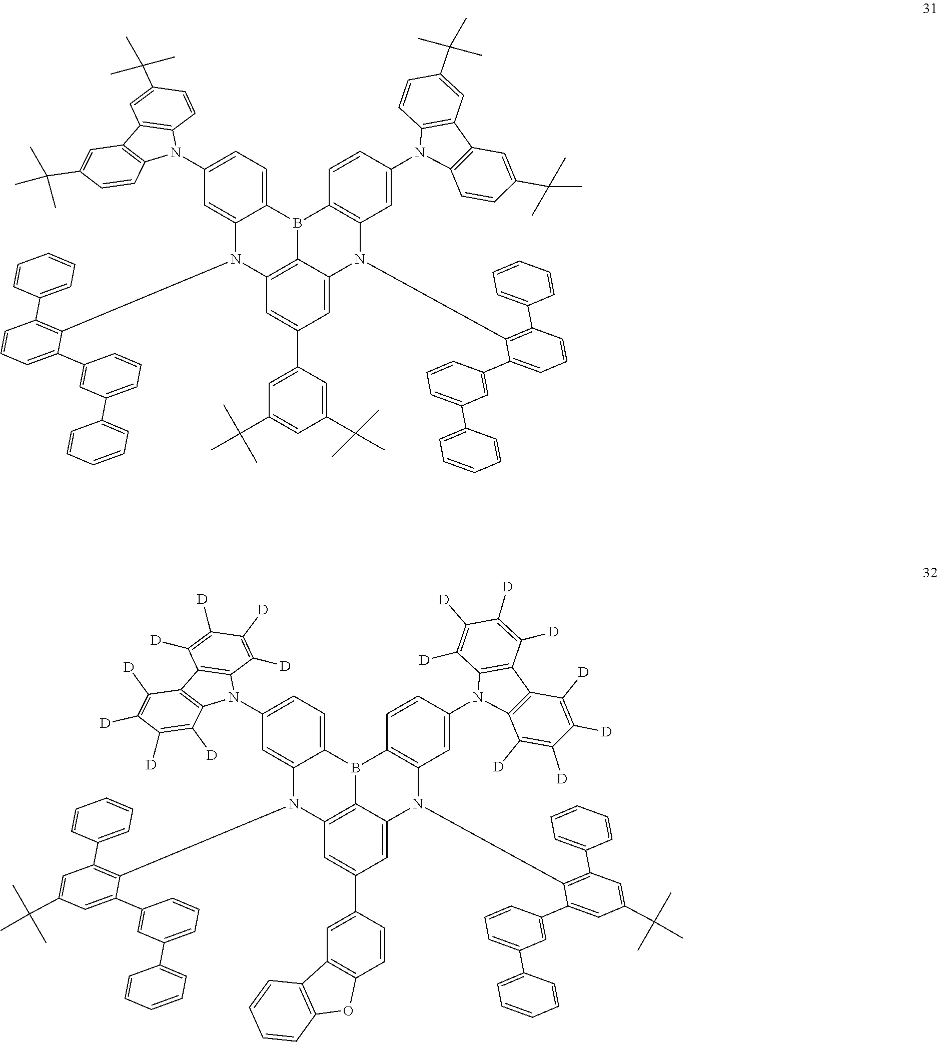 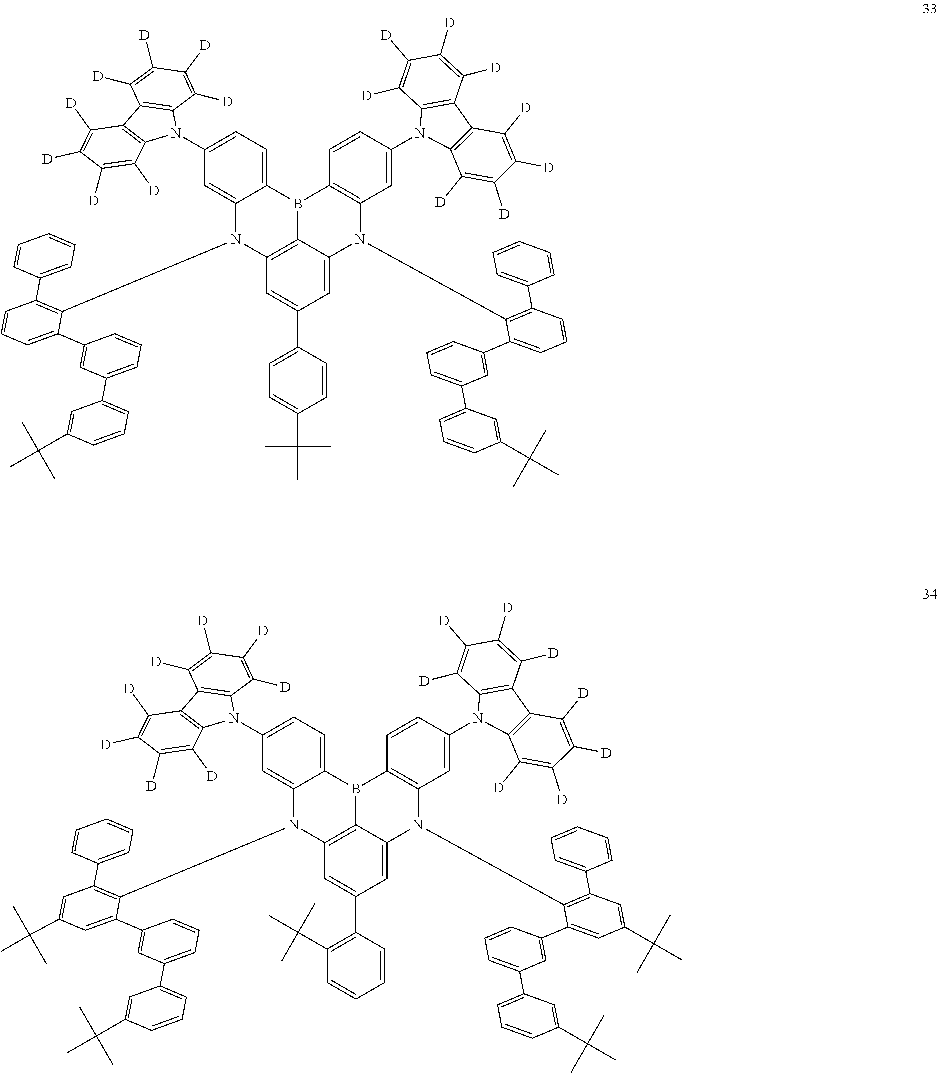 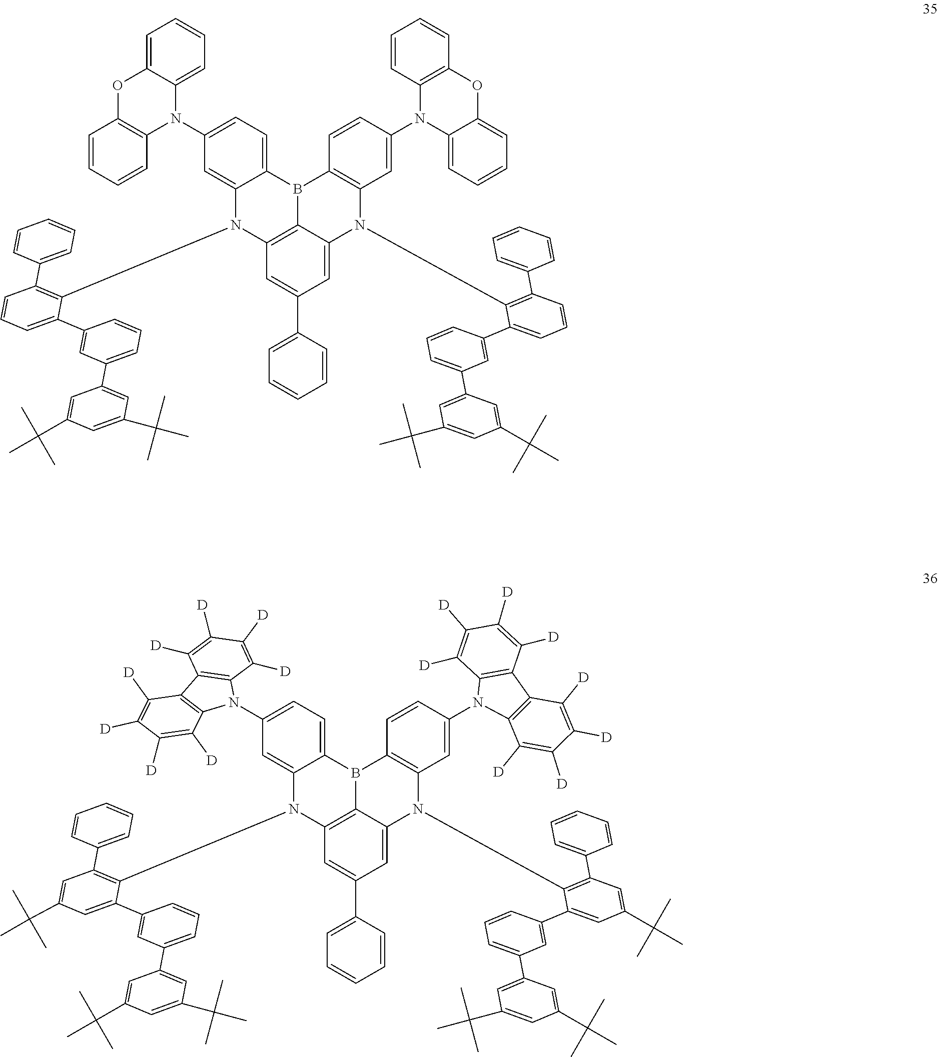 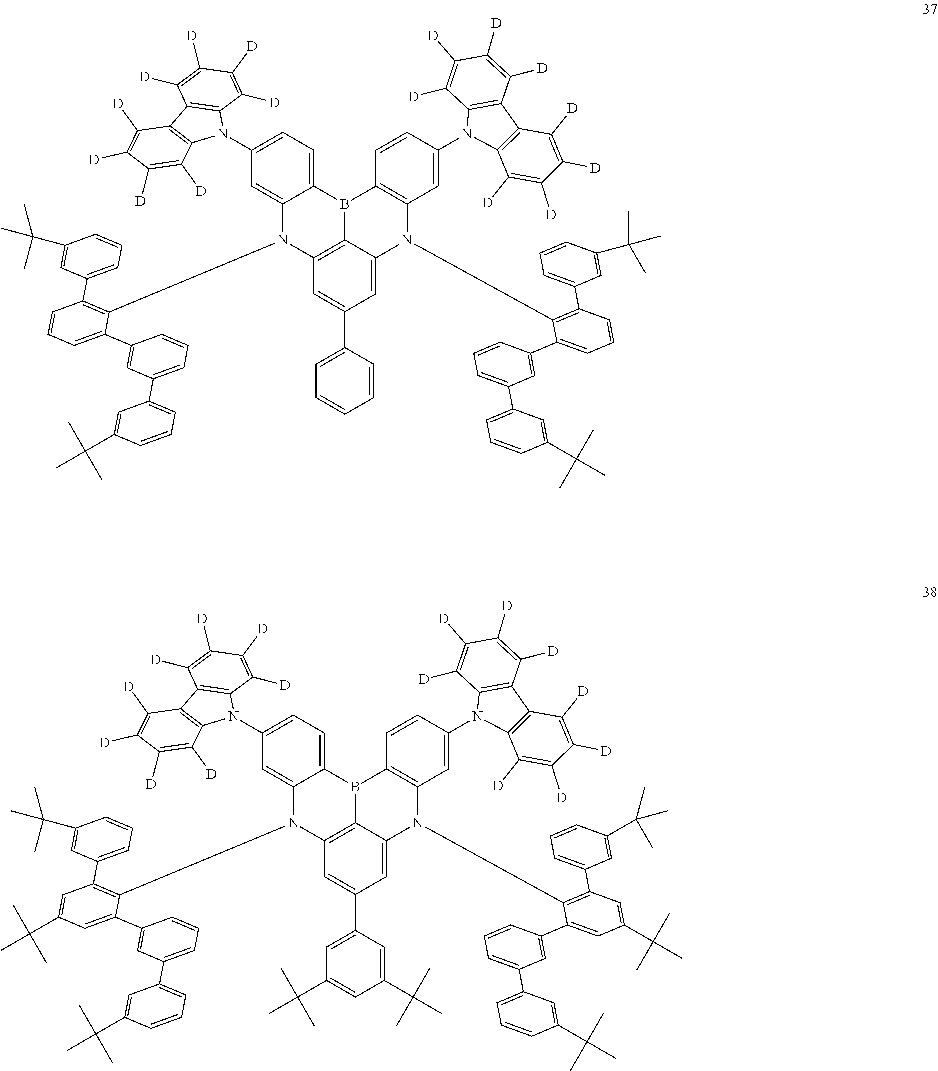 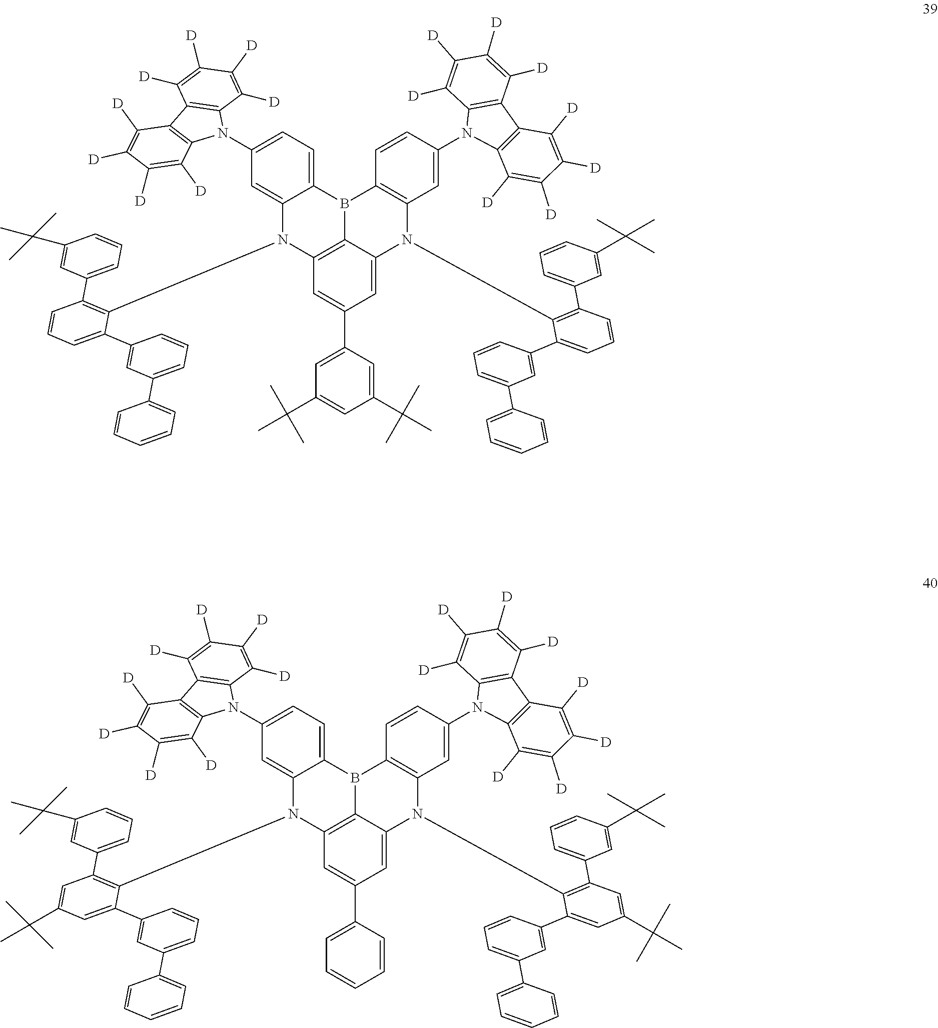 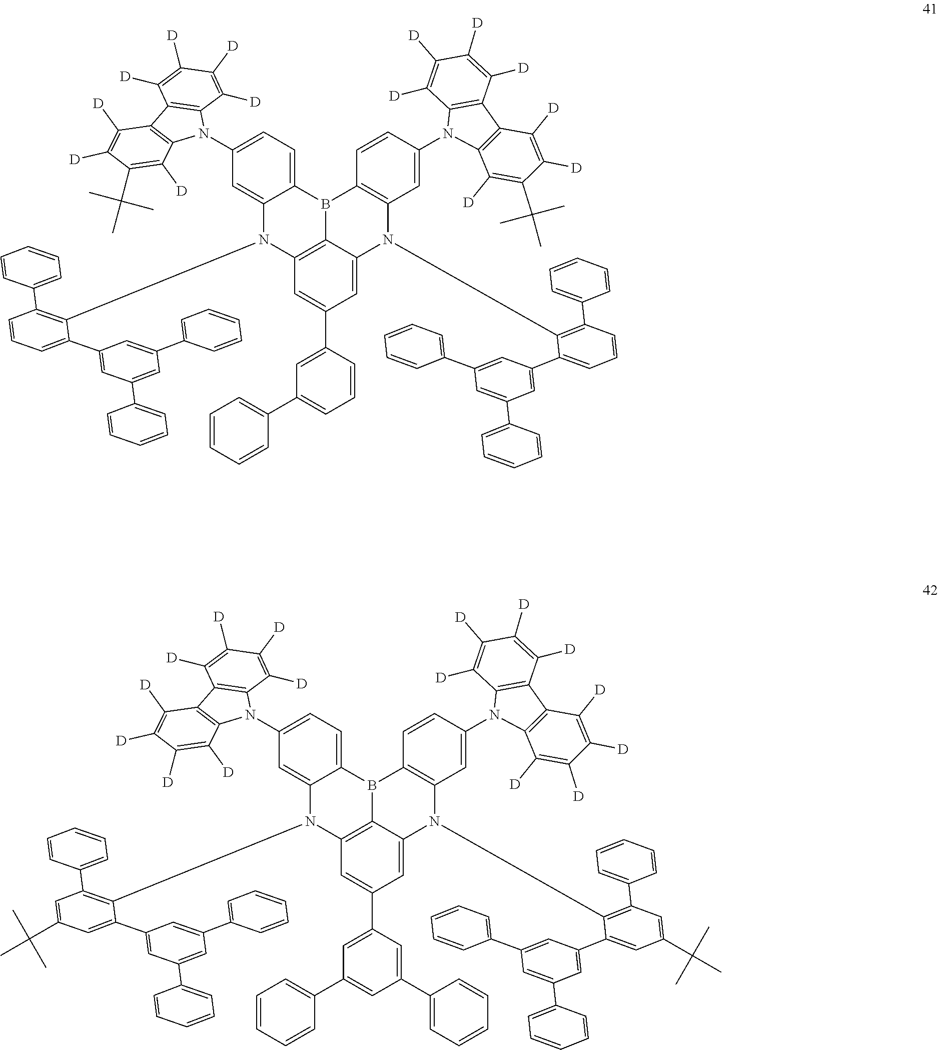 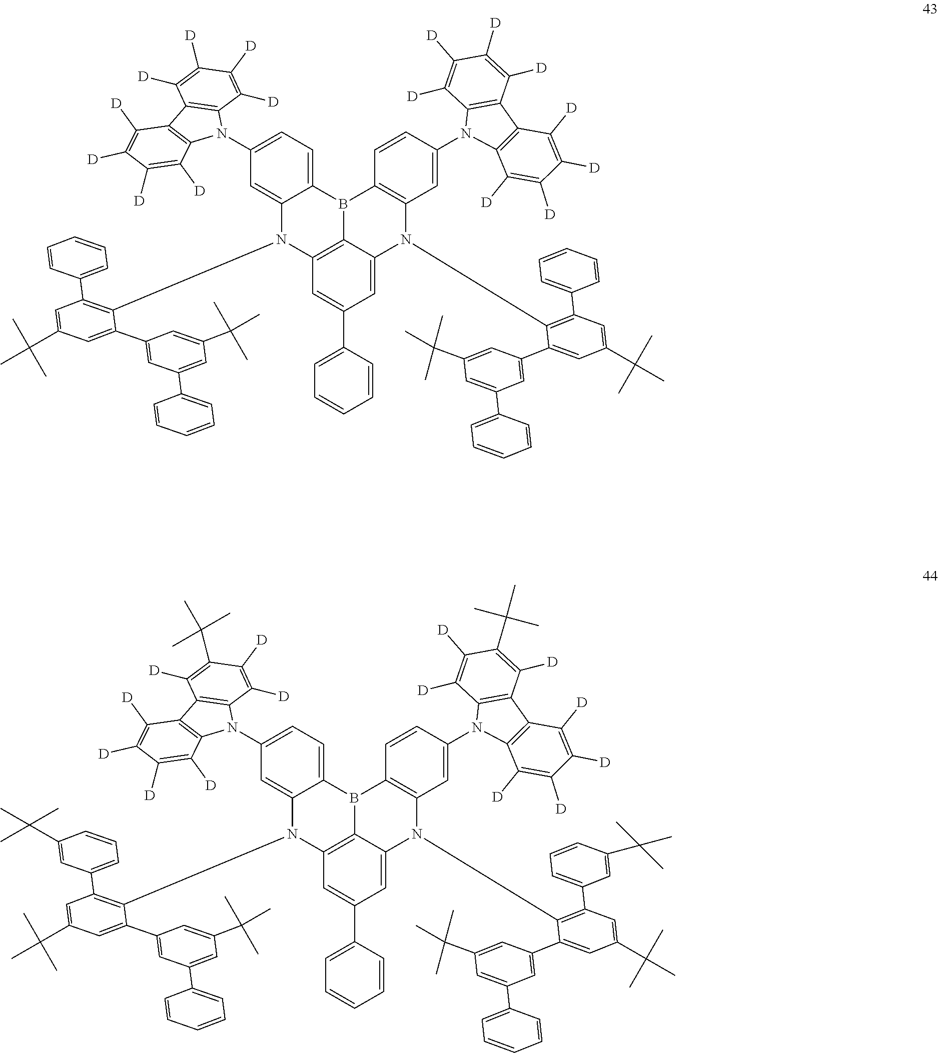 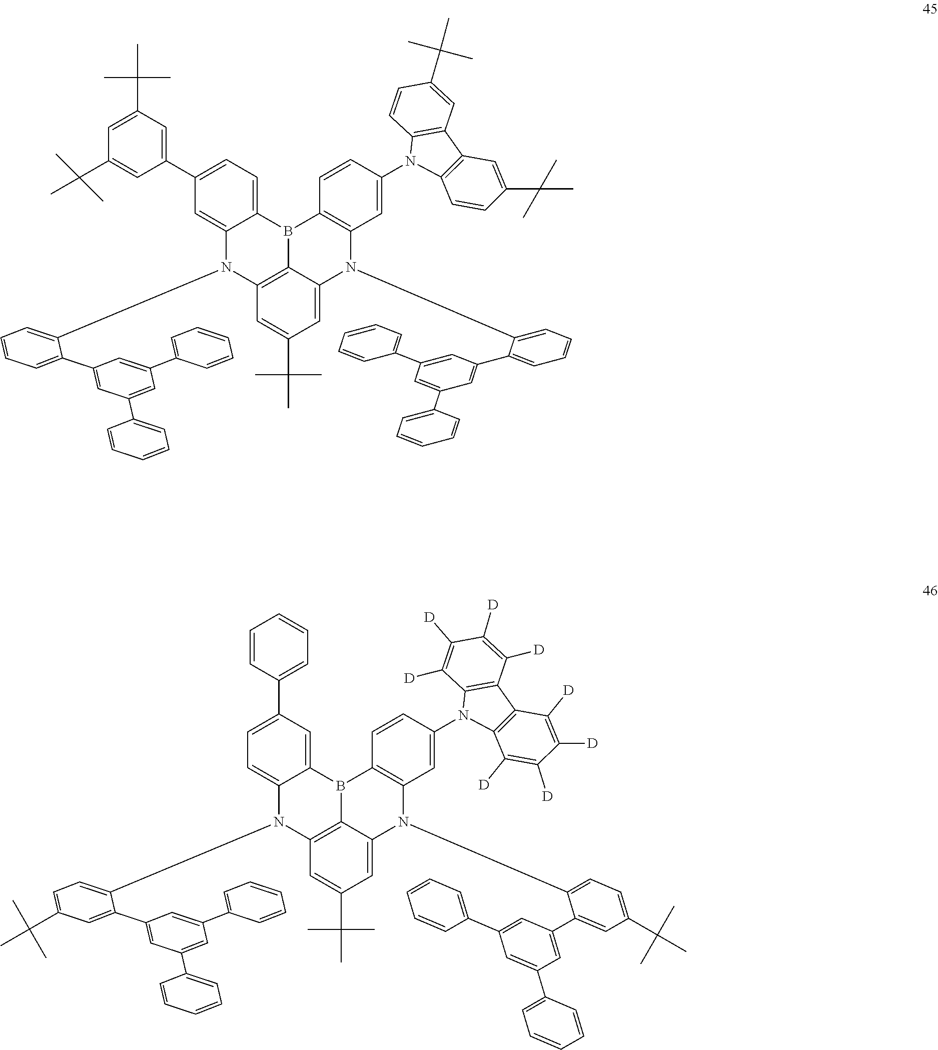 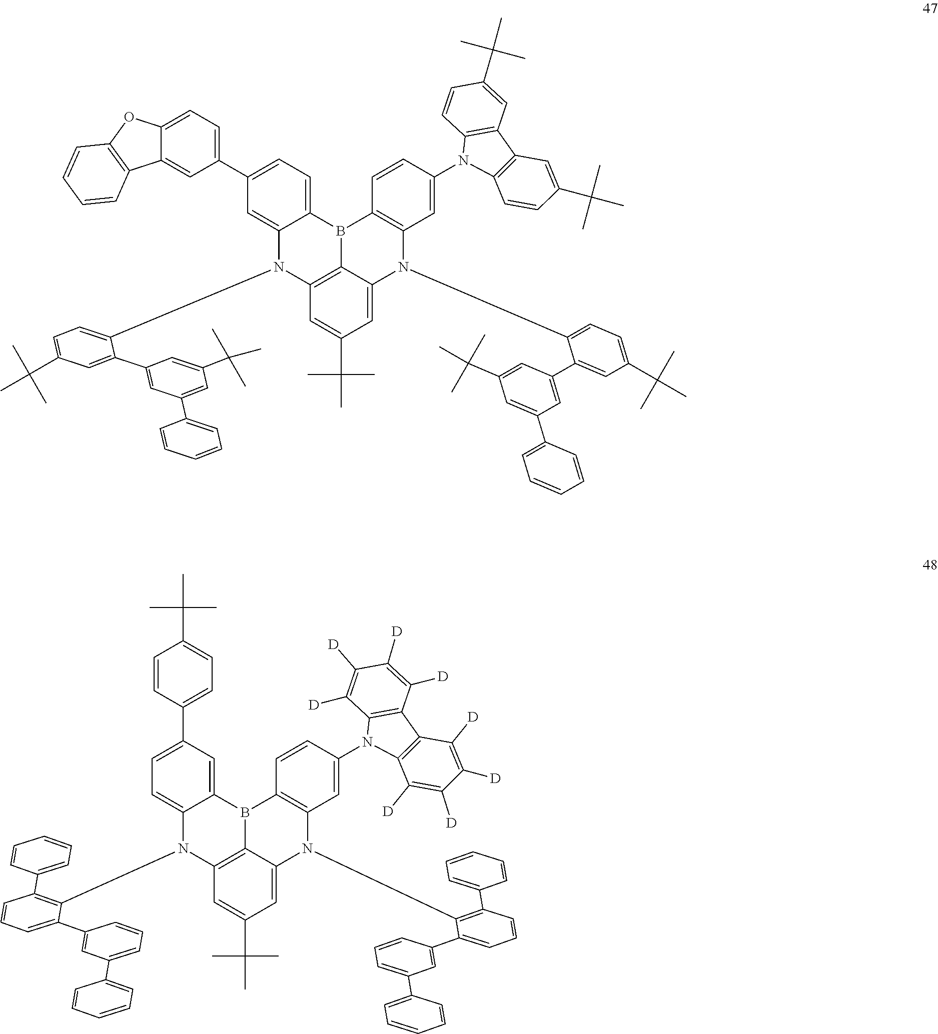 [SMILES: CC(C)(C)c1cc(-c2ccccc2)cc(-c2cc(C(C)(C)C)ccc2N2c3cc(-c4ccc5oc6ccccc6c5c4)ccc3B3c4ccc(-n5c6ccc(C(C)(C)C)cc6c6cc(C(C)(C)C)ccc65)cc4N(c4ccc(C(C)(C)C)cc4-c4cc(-c5ccccc5)cc(C(C)(C)C)c4)c4cc(C(C)(C)C)cc2c43)c1 ; [2H]c1c([2H])c([2H])c2c(c1[2H])c1c([2H])c([2H])c([2H])c([2H])c1n2-c1ccc2c(c1)N(c1c(-c3ccccc3)cccc1-c1cccc(-c3ccccc3)c1)c1cc(C(C)(C)C)cc3c1B2c1cc(-c2ccc(C(C)(C)C)cc2)ccc1N3c1c(-c2ccccc2)cccc1-c1cccc(-c2ccccc2)c1] 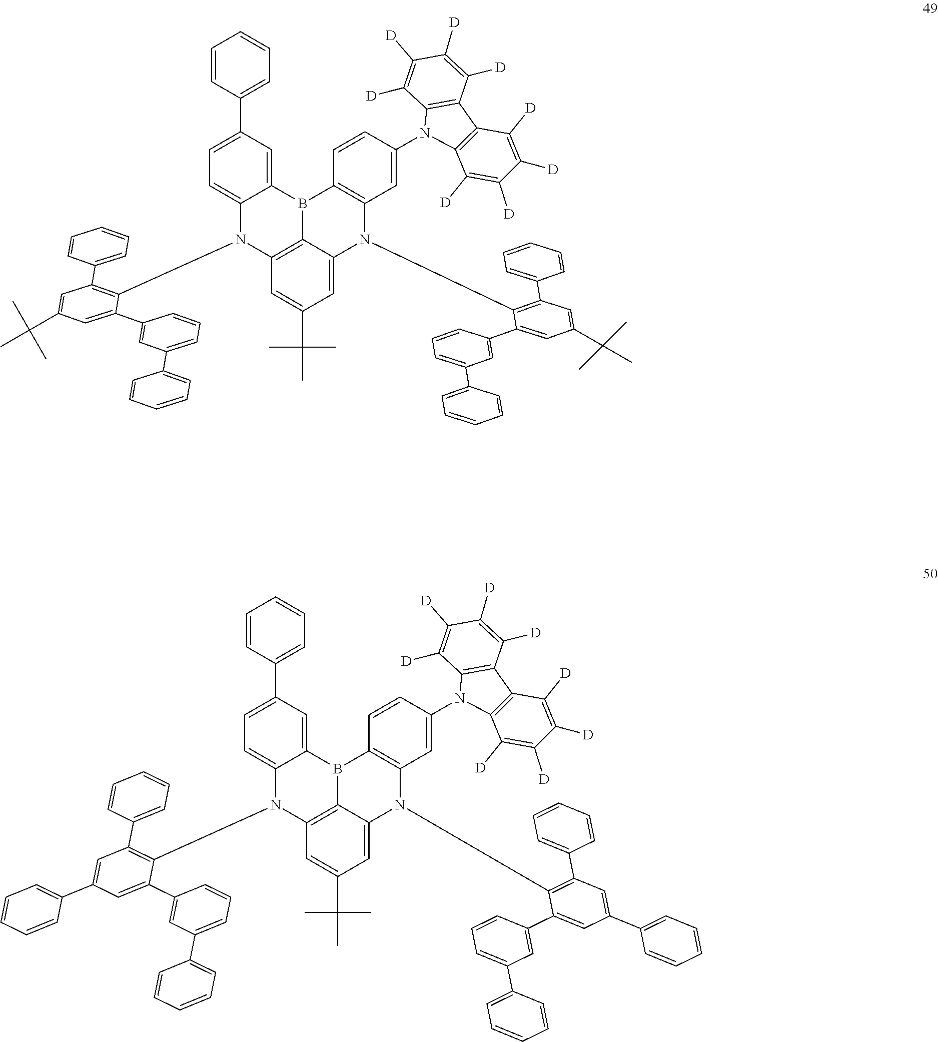 [SMILES: [2H]c1c([2H])c([2H])c2c(c1[2H])c1c([2H])c([2H])c([2H])c([2H])c1n2-c1ccc2c(c1)N(c1c(-c3ccccc3)cc(C(C)(C)C)cc1-c1cccc(-c3ccccc3)c1)c1cc(C(C)(C)C)cc3c1B2c1cc(-c2ccccc2)ccc1N3c1c(-c2ccccc2)cc(C(C)(C)C)cc1-c1cccc(-c2ccccc2)c1 ; [2H]c1c([2H])c([2H])c2c(c1[2H])c1c([2H])c([2H])c([2H])c([2H])c1n2-c1ccc2c(c1)N(c1c(-c3ccccc3)cc(-c3ccccc3)cc1-c1cccc(-c3ccccc3)c1)c1cc(C(C)(C)C)cc3c1B2c1cc(-c2ccccc2)ccc1N3c1c(-c2ccccc2)cc(-c2ccccc2)cc1-c1cccc(-c2ccccc2)c1] 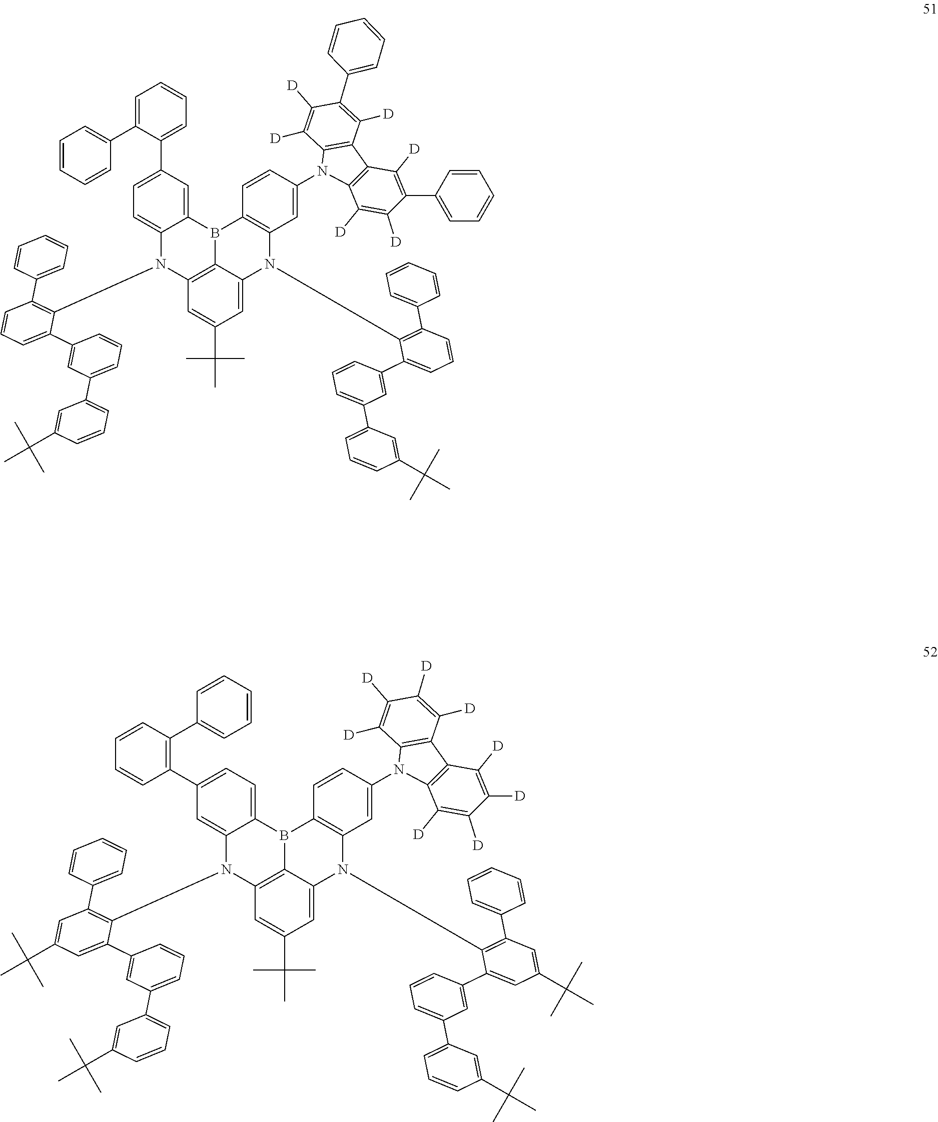 [SMILES: [2H]c1c(-c2ccccc2)c([2H])c2c3c([2H])c(-c4ccccc4)c([2H])c([2H])c3n(-c3ccc4c(c3)N(c3c(-c5ccccc5)cccc3-c3cccc(-c5cccc(C(C)(C)C)c5)c3)c3cc(C(C)(C)C)cc5c3B4c3cc(-c4ccccc4-c4ccccc4)ccc3N5c3c(-c4ccccc4)cccc3-c3cccc(-c4cccc(C(C)(C)C)c4)c3)c2c1[2H] ; [2H]c1c([2H])c([2H])c2c(c1[2H])c1c([2H])c([2H])c([2H])c([2H])c1n2-c1ccc2c(c1)N(c1c(-c3ccccc3)cc(C(C)(C)C)cc1-c1cccc(-c3cccc(C(C)(C)C)c3)c1)c1cc(C(C)(C)C)cc3c1B2c1ccc(-c2ccccc2-c2ccccc2)cc1N3c1c(-c2ccccc2)cc(C(C)(C)C)cc1-c1cccc(-c2cccc(C(C)(C)C)c2)c1] 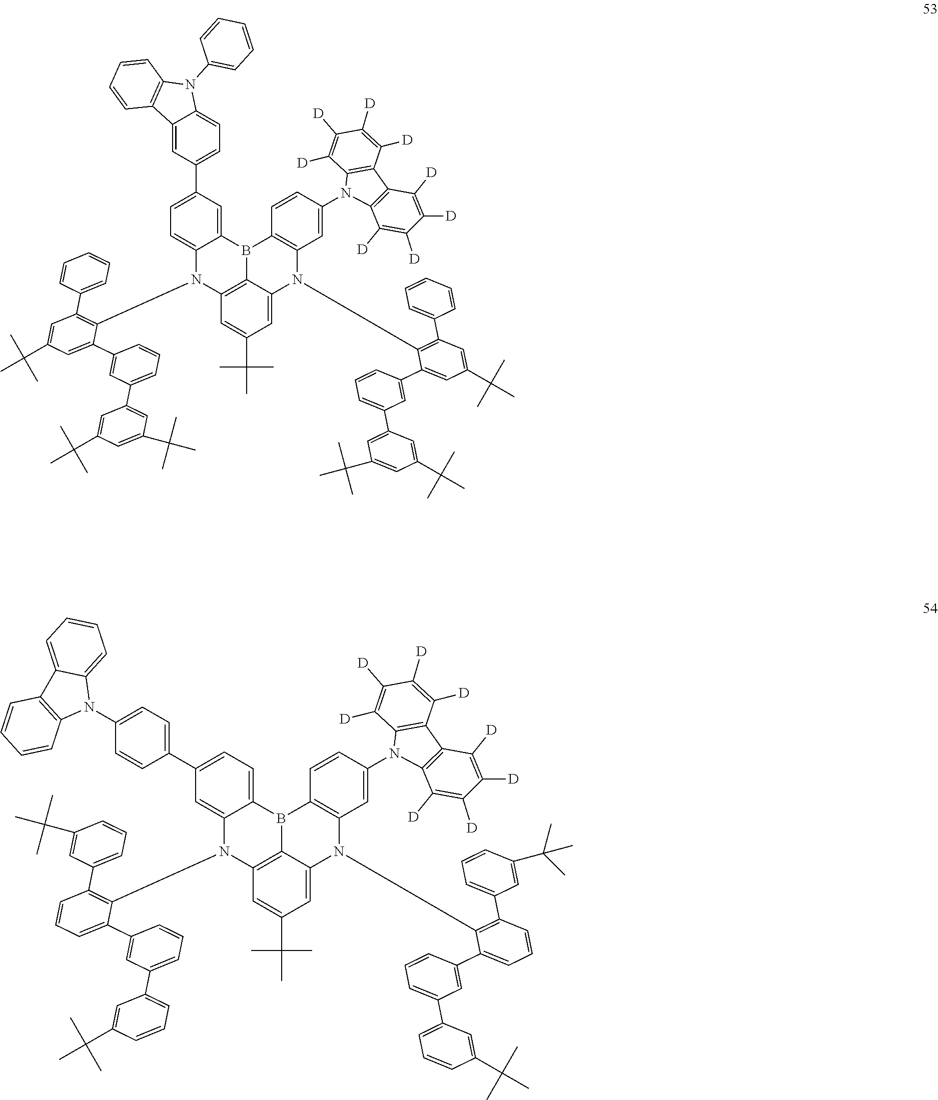 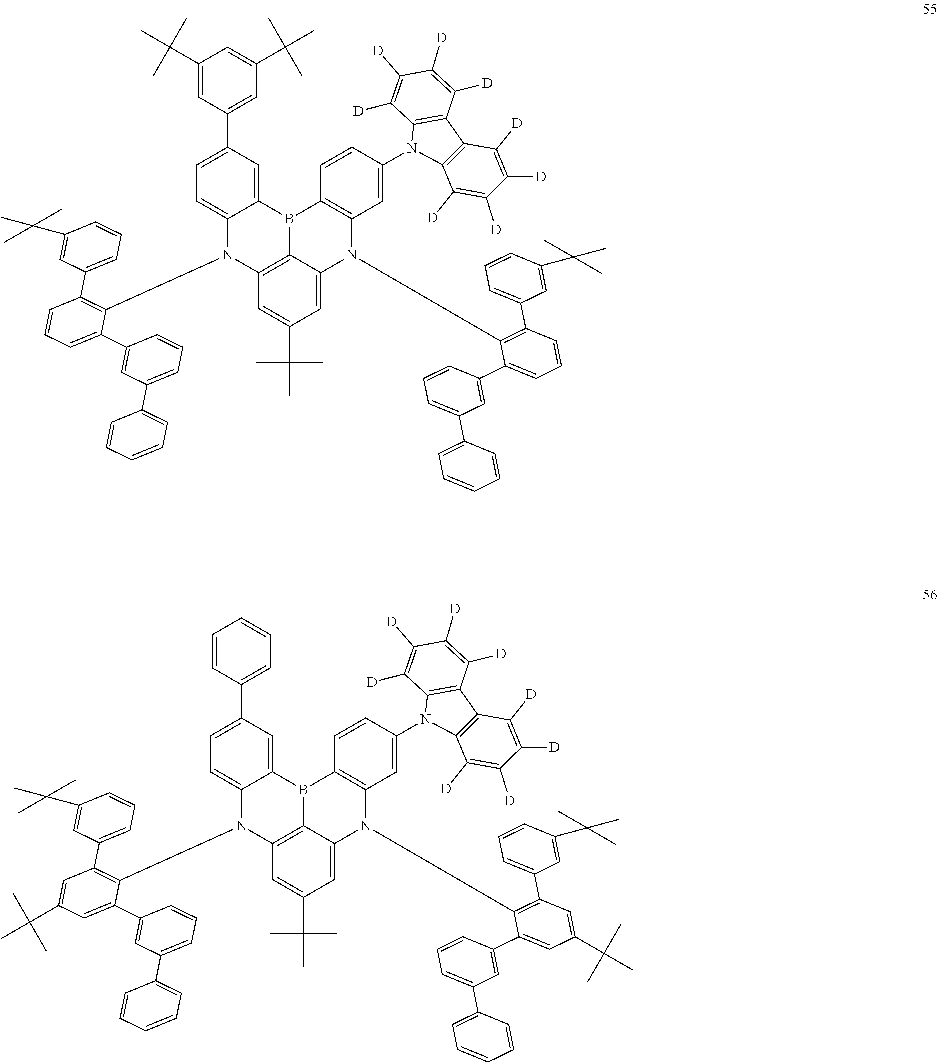 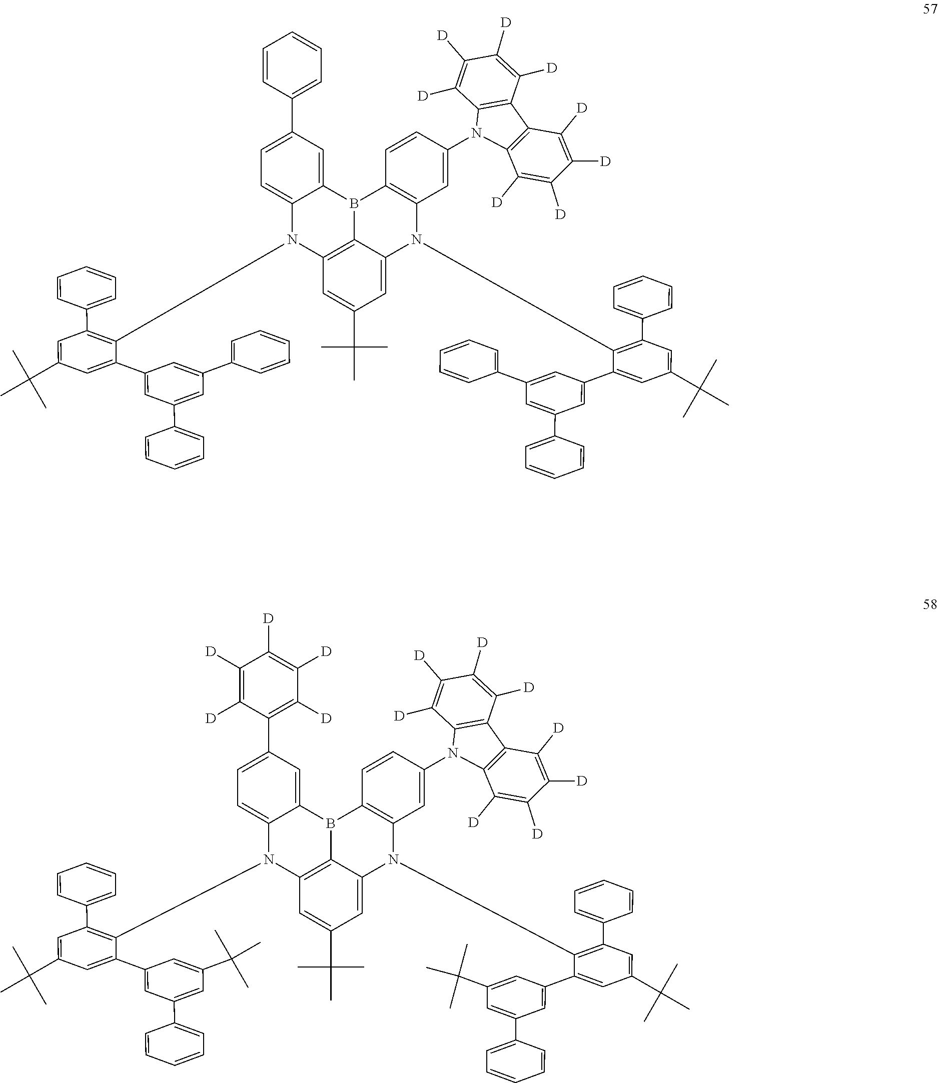 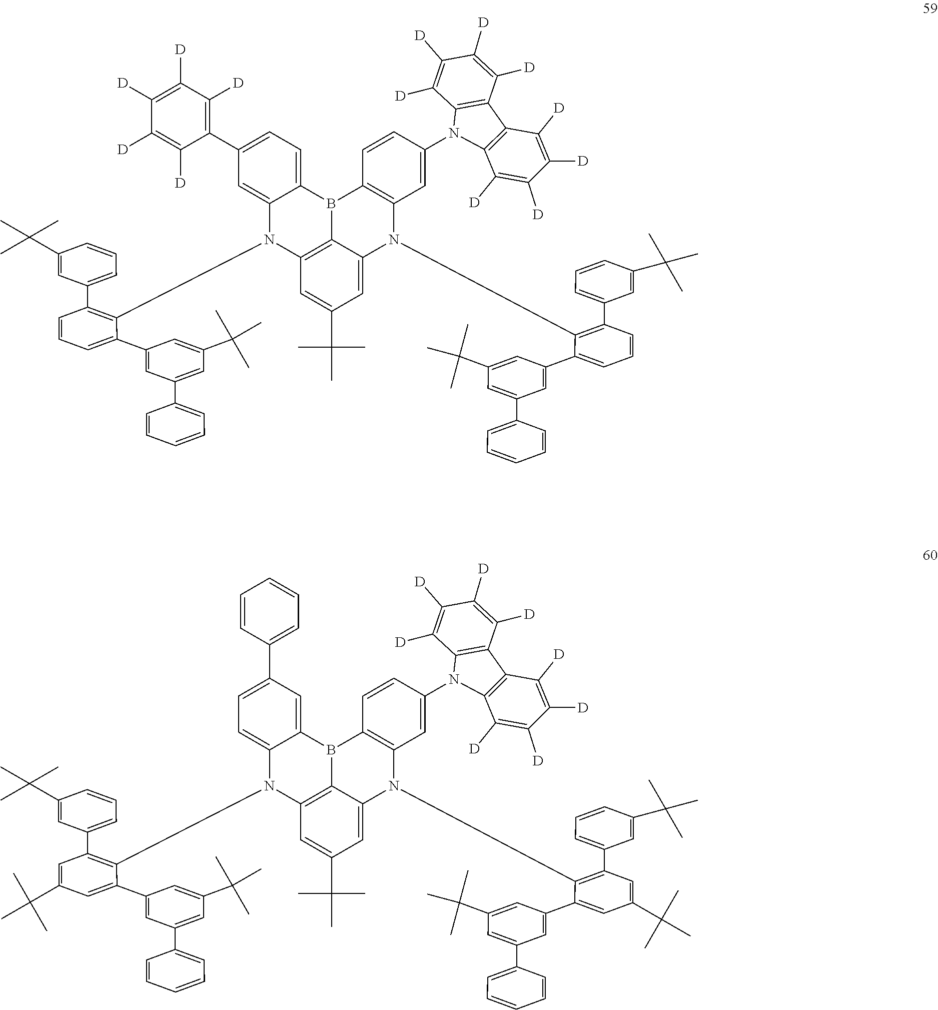 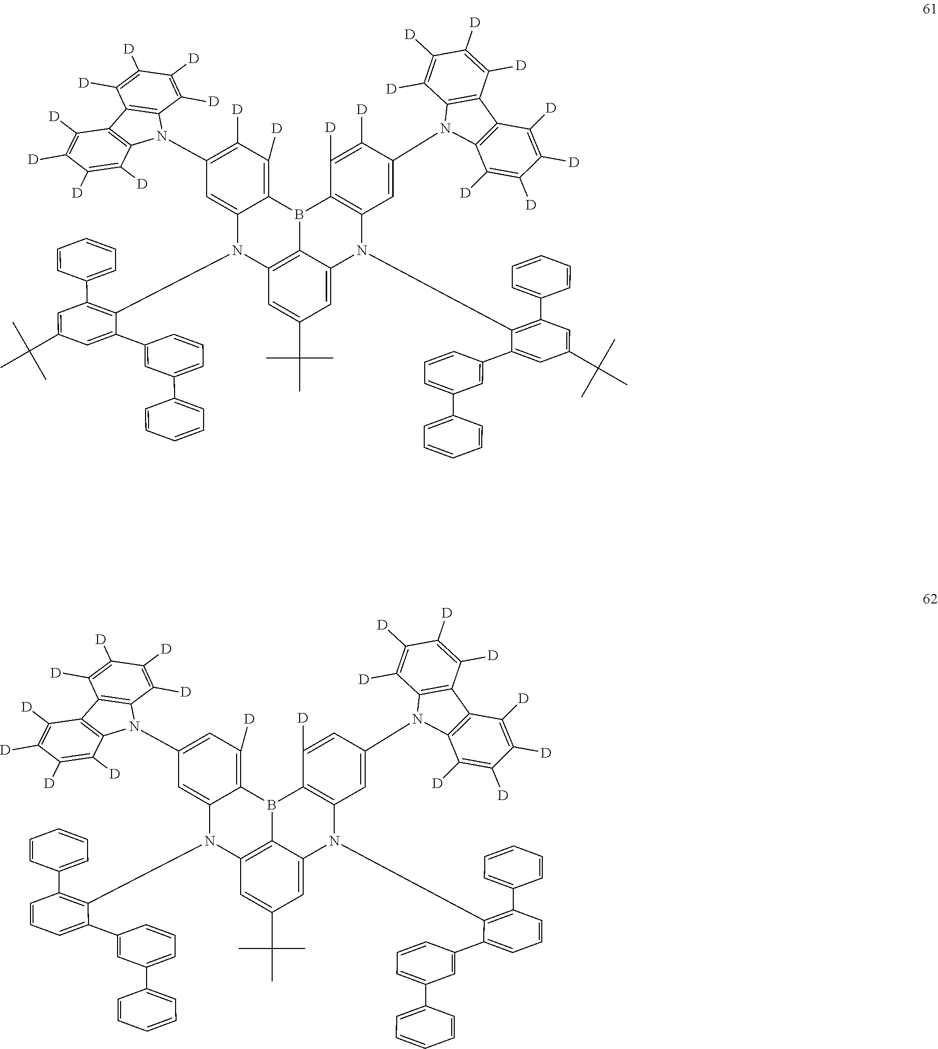 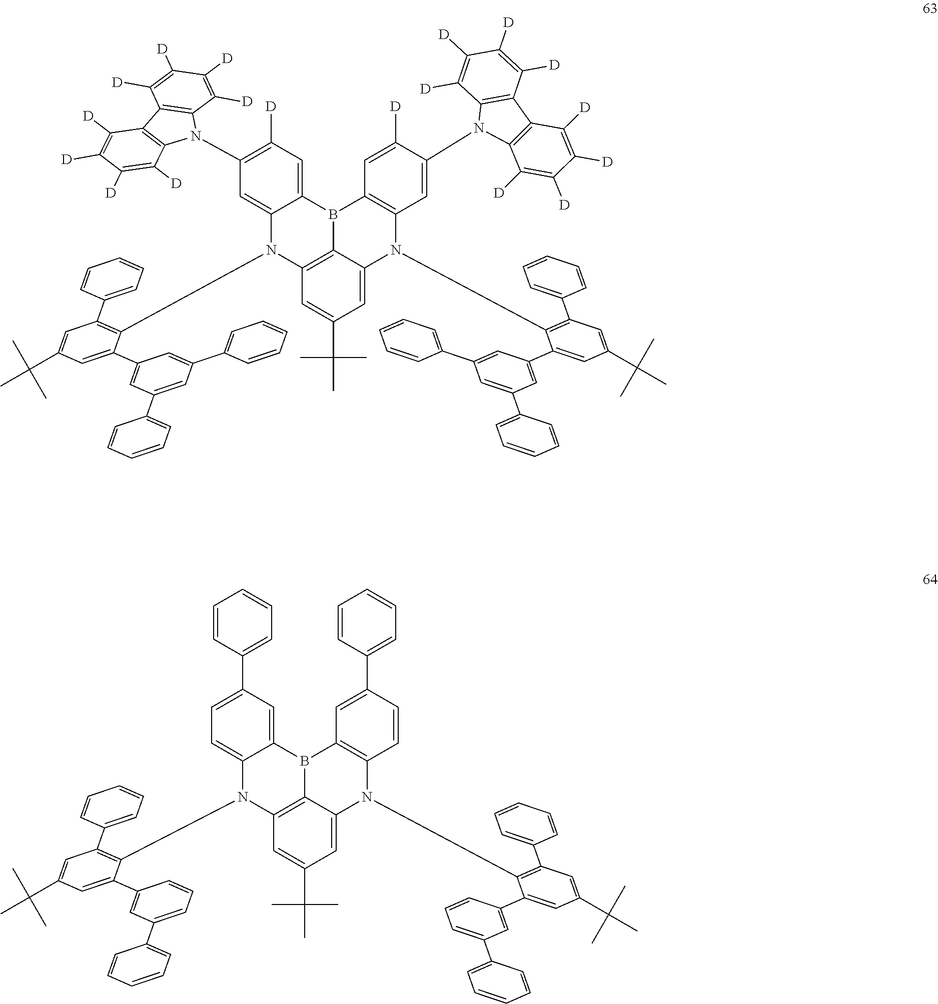 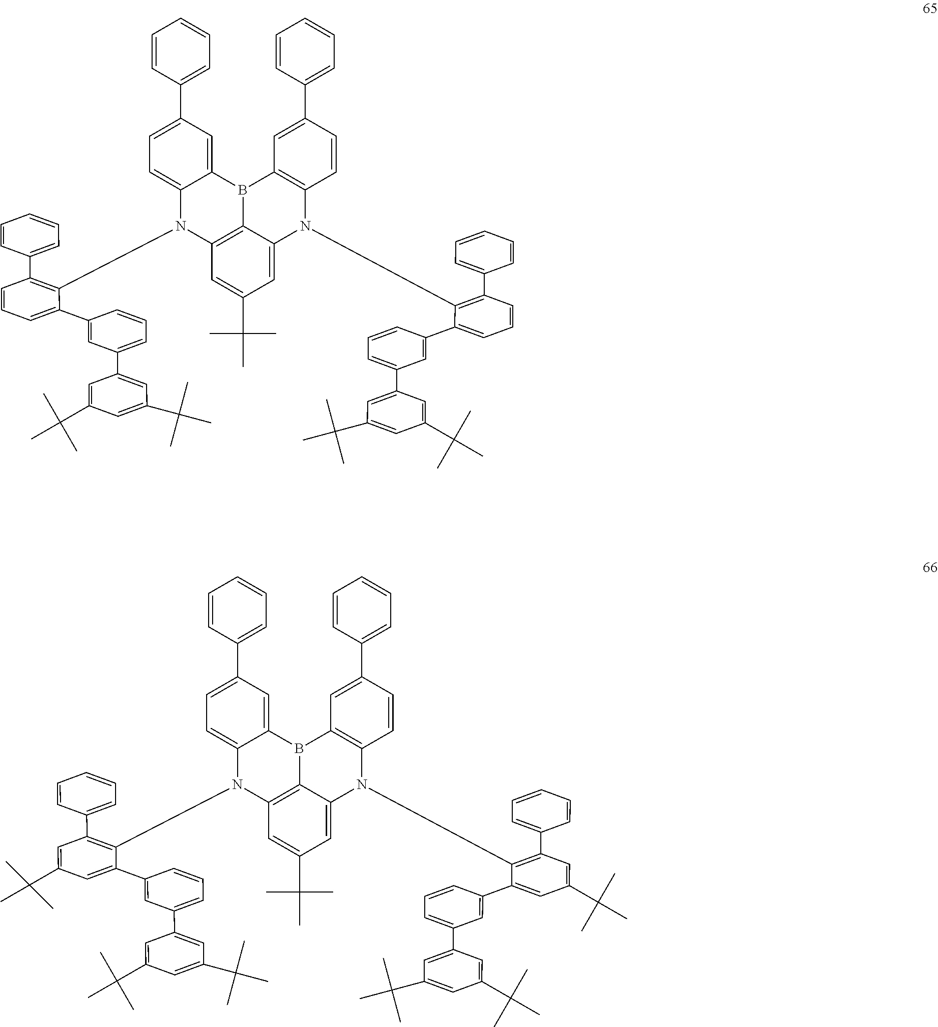 [SMILES: CC(C)(C)c1cc(-c2cccc(-c3cccc(-c4ccccc4)c3N3c4ccc(-c5ccccc5)cc4B4c5cc(-c6ccccc6)ccc5N(c5c(-c6ccccc6)cccc5-c5cccc(-c6cc(C(C)(C)C)cc(C(C)(C)C)c6)c5)c5cc(C(C)(C)C)cc3c54)c2)cc(C(C)(C)C)c1 ; CC(C)(C)c1cc(-c2cccc(-c3cc(C(C)(C)C)cc(-c4ccccc4)c3N3c4ccc(-c5ccccc5)cc4B4c5cc(-c6ccccc6)ccc5N(c5c(-c6ccccc6)cc(C(C)(C)C)cc5-c5cccc(-c6cc(C(C)(C)C)cc(C(C)(C)C)c6)c5)c5cc(C(C)(C)C)cc3c54)c2)cc(C(C)(C)C)c1] 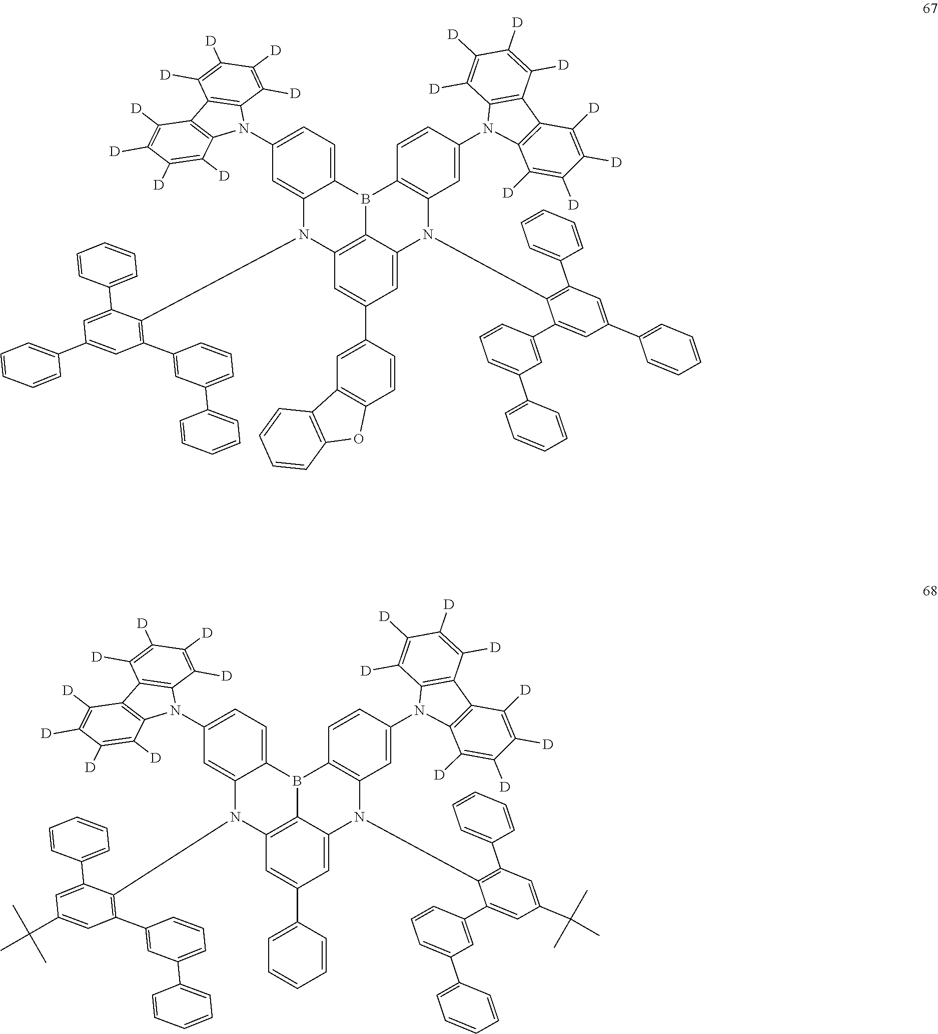 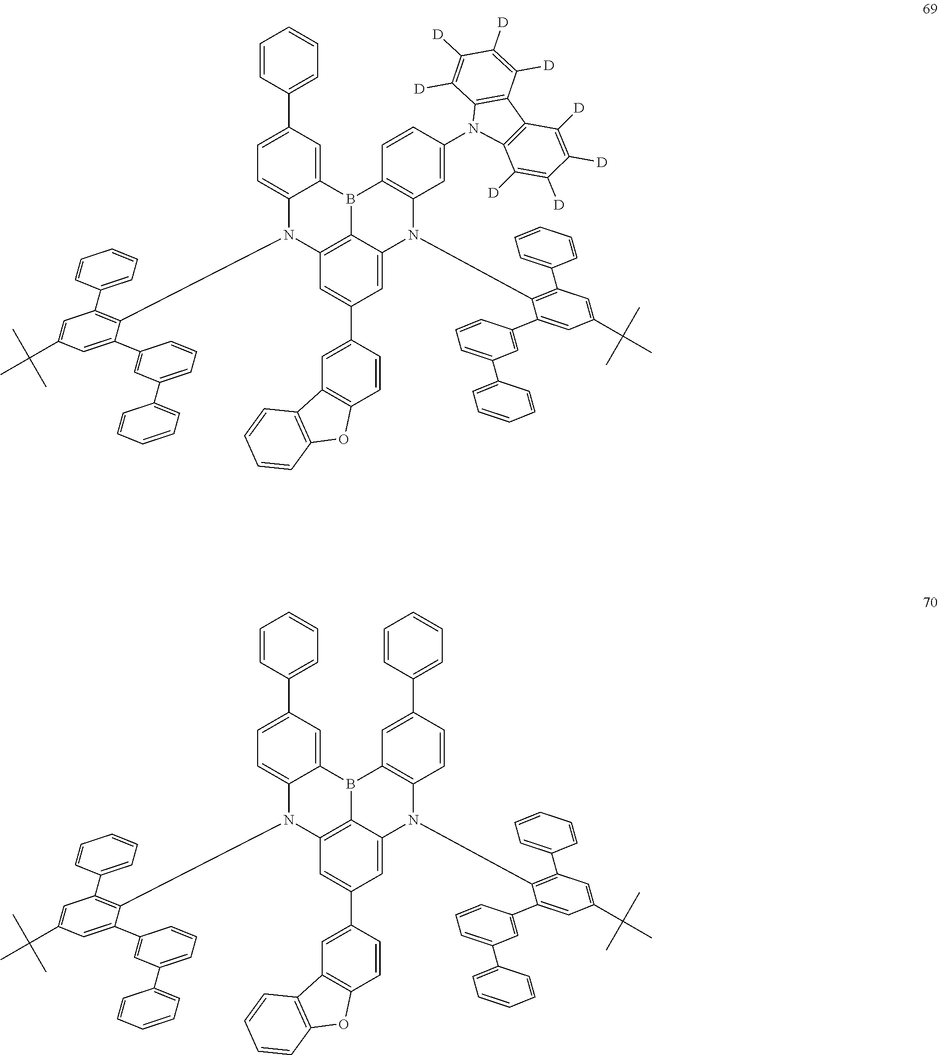
wherein in Compound Group 1, D is a deuterium atom.
